(19) United States
(12) Patent Application Publication
(10) Pub. No.: US 2026/0118765 A1
(43) Pub. Date: Apr. 30, 2026

(54) RESIST UNDERLAYER FILM FORMING COMPOSITION

(71) Applicant: NISSAN CHEMICAL CORPORATION, Tokyo (JP)

(72) Inventors: Hikaru TOKUNAGA, Toyama-shi (JP); Makoto NAKAJIMA, Toyama-shi (JP); Hirokazu NISHIMAKI, Toyama-shi (JP)

(73) Assignee: NISSAN CHEMICAL CORPORATION, Tokyo (JP)

(21) Appl. No.: 18/852,760

(22) PCT Filed: Mar. 20, 2023
(86) PCT No.: PCT/JP2023/010827

§ 371 Date: Sep. 30, 2024

(30) Foreign Application Priority Data
Mar. 28, 2022 (JP) 2022-051965

(51) Int. Cl. G03F 7/09; C08G 16/02; C08G 61/12; G03F 7/004; G03F 7/16; H01L 21/308; H01L 21/311

(52) U.S. Cl. CPC G03F 7/094; C08G 16/0231; C08G 16/0237; C08G 61/12; G03F 7/0045; G03F 7/0046; G03F 7/168; H10P 50/692; H10P 50/73

(57) ABSTRACT

A resist underlayer film forming composition exhibits excellent filling properties and planarization properties with respect to a substrate with level difference, while having high storage stability of a polymer that serves as a main component of a resist underlayer film; a resist pattern forming method uses this resist underlayer film forming composition; and a method for producing a semiconductor device using this resist underlayer film forming composition. A resist underlayer film forming composition contains (a) a thermal acid generator that is represented by formula (1), (b) a polymer that contains an aromatic ring, (c) a base B² and (d) a solvent. In formula (1), A¹ represents an optionally substituted linear, branched or cyclic, saturated or unsaturated aliphatic hydrocarbon group, or an optionally substituted aromatic ring residue. In formula (1), B¹ represents a counter base; and at least one base among B¹ and B² has a higher pKa than pyridine.

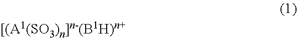

### TECHNICAL FIELD

The present invention relates to a resist underlayer film forming composition suited for lithographic processing of semiconductor substrates, a resist underlayer film obtained from the resist underlayer film forming composition, a method for forming a resist pattern using the resist underlayer film-forming composition, and a method for manufacturing a semiconductor device using the composition.

### BACKGROUND ART

In the recent lithographic process of semiconductor device manufacturing, semiconductor processing materials including resist underlayer films are required to have excellent material characteristics and also to be further enhanced in stability of resist underlayer film forming compositions.

When, for example, a workpiece substrate as a base has steps or when a wafer has a densely patterned region and a pattern-free region, such irregularities need to be covered with a flat surface of an underlayer film. Resins suited for this purpose have been proposed (Patent Literature 1).

To form thermoset films as above, resist underlayer film forming compositions contain a polymer resin as a main component and also contain a crosslinking compound (a crosslinking agent) or a catalyst (a crosslinking catalyst) for promoting the crosslinking reaction. These components have not been fully studied from the point of view of flattening of the surface with an underlayer film.

A new problem that is encountered recently is that crosslinking agents, and polymer resins that are the main components of resist underlayer films are denatured by crosslinking catalysts and solvents present in the resist underlayer film forming compositions. The resistance to such denaturation is also desired.

Patent Literature 2 discloses an ionic thermal acid generator of formula (A⁻)(BH)⁺ in which A⁻ is the anion of an organic or inorganic acid having a pKa of 3 or less; and (BH)⁺ is the monoprotonated form of a nitrogen-containing base B having a pKa between 0 and 5.0, and a boiling point of below 170° C. Specifically, combinations of perfluorobutane sulfonate with ammonium, pyridinium, 3-fluoropyridinium, or pyridazinium are described.

Patent Literature 3 discloses a thermal acid generator of formula X⁻YH⁺ where X is an anionic component and Y is a substituted pyridine. Specifically, combinations of methylbenzene sulfonate with fluoropyridinium or trifluoromethylpyridinium are described.

Patent Literature 4 discloses a thermal acid generator including a hydroxyl-free sulfonic acid component and a pyridinium component having a ring substituent. Specifically, combinations of methylbenzene sulfonate with methylpyridinium, methoxypyridinium, or trimethylpyridinium are described.

Patent Literature 5 discloses a thermal acid generator including para-toluenesulfonic acid triethylamine salt, para-toluenesulfonic acid ammonia salt, mesitylenesulfonic acid ammonia salt, dodecylbenzenesulfonic acid ammonia salt, or para-toluenesulfonic acid dimethylamine salt.

Patent Literature 6 discloses a thermal acid generator containing a sulfonic acid and NH₄⁺ or a primary, secondary, tertiary, or quaternary ammonium ion.

### CITATION LIST

### Patent Literature

Patent Literature 1: WO 2014/024836 A1
Patent Literature 2: JP 6334900 B2
Patent Literature 3: JP 2019-56903 A
Patent Literature 4: JP 6453378 B2
Patent Literature 5: JP 4945091 B2
Patent Literature 6: JP 6256719 B2

### SUMMARY OF INVENTION

### Technical Problem

However, the thermal acid generators disclosed in the related art documents are aimed at improving the shape of resists, and the documents are completely silent with respect to the performance in gap-filling and flattening on non-planar substrates. Some inventions disclose a relationship between storage stability and sublimates but do not specifically evaluate or mention the denaturation of thermal acid generators and polymers, and do not study the performance in gap-filling and flattening on non-planar substrates. In recent years, it has become clear that the thermal acid generators described above denature polymers unless an appropriate amine component is selected. Thus, thermal acid generators are desired that do not denature polymers and satisfy both gap-filling properties and flattening properties on non-planar substrates.

Objects of the present invention are therefore to provide a resist underlayer film forming composition that has excellent performance in gap-filling and flattening on a non-planar substrate and has high storage stability of a polymer that is the main component of a resist underlayer film; to provide a method for forming a resist pattern using the resist underlayer film forming composition; and to provide a method for manufacturing a semiconductor device using the composition.

### Solution to Problem

Aspects of the present invention include the following.

[1]

A resist underlayer film forming composition comprising:
(a)
   a thermal acid generator represented by formula (1) below:

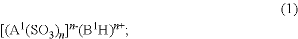

(b)
   an aromatic ring-containing polymer;
(c)
   one, or two or more kinds of bases B²; and
(d)
   a solvent, wherein
   A¹ in the formula (1) is an optionally substituted, linear, branched, or cyclic, saturated or unsaturated, aliphatic hydrocarbon group, or an optionally substituted aromatic ring residue,
   n in the formula (1) indicates the number of the sulfonate anion groups and is 1 or 2,
   B¹ in the formula (1) denotes one, or two or more kinds of counter bases and is a monoacidic base or a monoacidic base moiety of a diacidic base or a triacidic base,
   A¹ and B¹ are optionally connected via a single bond or a linking group, and
   at least one or more bases of B¹ and B² have a higher pKa than pyridine.
      [2]

The resist underlayer film forming composition according to [1], wherein the aromatic ring-containing polymer is a novolac resin.

[3]

The resist underlayer film forming composition according to [2], wherein the aromatic ring-containing polymer is a novolac resin containing a unit structure having an optionally substituted aromatic ring, and
(i)
   the aromatic ring contains a heteroatom in a substituent on the aromatic ring,
(ii)
   the unit structure contains a plurality of aromatic rings, at least two of the aromatic rings are connected to one another via a linking group, and the linking group contains a heteroatom, or
(iii)
   the aromatic ring is an aromatic heterocyclic ring or an aromatic ring forming a condensed ring with one or more heterocyclic rings.
      [4]

The resist underlayer film forming composition according to [3], wherein the unit structure in (i) or (ii) is a unit structure having an aromatic ring with at least one oxygen-containing substituent or is a unit structure having aromatic rings connected via at least one —NH—.

[5]

The resist underlayer film forming composition according to any one of [2] to [4], wherein the aromatic ring-containing polymer is a novolac resin comprising:
(i) one, or two or more kinds of unit structures having an optionally substituted aromatic ring; and
(ii) a unit structure including an optionally substituted 4- to 17-membered monocyclic, bicyclic, tricyclic, or tetracyclic organic group, wherein the monocyclic ring is a non-aromatic monocyclic ring; and at least one of the monocyclic rings constituting the bicyclic, tricyclic, or tetracyclic ring is a non-aromatic monocyclic ring, and the remaining monocyclic ring or rings are optionally aromatic monocyclic rings or non-aromatic monocyclic rings;
the monocyclic, bicyclic, tricyclic, or tetracyclic organic group is optionally further condensed with one or more aromatic rings to form a pentacyclic or higher condensed ring; and the unit structures (i) and (ii) are bonded at least by a covalent bond of a carbon atom on any of the non-aromatic monocyclic rings in (ii) with a carbon atom on the aromatic ring in (i).
   [6]

The resist underlayer film forming composition according to any one of [2] to [4], wherein the aromatic ring-containing polymer comprises a structure represented by formula (AB) below:

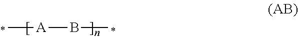

wherein in the formula (AB), n indicates the number of composite unit structures A-B,
the unit structures A comprise one, or two or more kinds of unit structures having an optionally substituted aromatic ring, and are optionally such that:
   the aromatic ring is substituted with a substituent containing a heteroatom,
   the unit structure includes a plurality of aromatic rings, the aromatic rings are connected to one another via a linking group, and the linking group contains a heteroatom, or
   the aromatic ring is an aromatic heterocyclic ring or is an aromatic ring forming a condensed ring with one or more heterocyclic rings, and
the unit structures B comprise one, or two or more kinds of unit structures including a structure represented by formula (B1), (B2), or (B3) below:

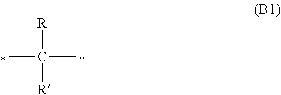

[in the formula (B1), R and R′ each independently denote a hydrogen atom, an optionally substituted C6-C30 aromatic ring residue, an optionally substituted C3-C30 heterocyclic ring residue, or an optionally substituted C10 or lower, linear, branched, or cyclic alkyl group]

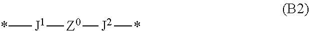

[in the formula (B²), Z⁰ denotes an optionally substituted C6-C30 aromatic ring residue, aliphatic ring residue, or organic group including two aromatic ring residues or aliphatic ring residues connected to each other via a single bond, and J¹ and J² each independently denote a direct bond or an optionally substituted divalent organic group]

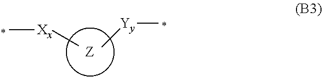

[in the formula (B3),
Z is an optionally substituted C4-C25 monocyclic ring or bicyclic, tricyclic, or tetracyclic condensed ring, wherein the monocyclic ring is a non-aromatic monocyclic ring; at least one of the monocyclic rings constituting the bicyclic, tricyclic, or tetracyclic ring is a non-aromatic monocyclic ring, and the remaining monocyclic ring or rings are optionally aromatic monocyclic rings or non-aromatic monocyclic rings; and the monocyclic ring or the bicyclic, tricyclic, or tetracyclic condensed ring is optionally further condensed with one or more aromatic rings to form a pentacyclic or higher condensed ring,
X and Y denote identical or different —CR³¹R³²— groups, R³¹ and R³² are the same as or different from each other and each denote a hydrogen atom or a C1-C6 hydrocarbon group,
x and y indicate the numbers of X and Y, respectively, and are each independently 0 or 1,

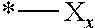

is bonded to any carbon atom (referred to as “carbon atom 1”) constituting any of the non-aromatic monocyclic rings in Z (when x=1) or extends from the carbon atom 1 (when x=0),

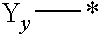

is bonded to any carbon atom (referred to as “carbon atom 2”) constituting any of the non-aromatic monocyclic rings in Z (when y=1) or extends from the carbon atom 2 (when y=0),
the carbon atom 1 and the carbon atom 2 are the same as or different from each other, and when the carbon atom 1 and the carbon atom 2 are different from each other, they belong to the same non-aromatic monocyclic ring or to different non-aromatic monocyclic rings, and
* indicates a valence bond].
   [7]

The resist underlayer film forming composition according to [6], wherein the formula (B3) is formula (B31) below:

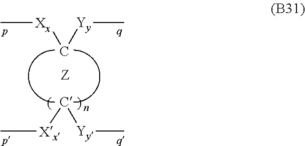

[in the formula (B31),
Z is an optionally substituted 4- to 17-membered monocyclic, bicyclic, tricyclic, or tetracyclic organic group, wherein the monocyclic ring is a non-aromatic monocyclic ring; and at least one of the monocyclic rings constituting the bicyclic, tricyclic, or tetracyclic ring is a non-aromatic monocyclic ring, and the remaining monocyclic ring or rings are optionally aromatic monocyclic rings or non-aromatic monocyclic rings,
the monocyclic, bicyclic, tricyclic, or tetracyclic organic group is optionally further condensed with one or more aromatic rings to form a pentacyclic or higher condensed ring,
C and C′ each denote a carbon atom among atoms constituting a ring moiety of any of the non-aromatic monocyclic rings in Z, and C and C′ belong to the same non-aromatic monocyclic ring or to different non-aromatic monocyclic rings,
n indicates the number of the carbon atoms C′ and denotes an integer of 0 to 2,
p, q, p′, and q′ indicate the number of a valence bond and each independently denote 0 or 1,
when n is 0, p and q are 1,
when n is 1 or 2, at least one of p or q, and at least one of p′ or q′ in each C′ are each 1,
when n is 2, the two C′ atoms belong to the same non-aromatic monocyclic ring while optionally bonding directly to each other, or the two C′ atoms belong to different non-aromatic monocyclic rings,
X, Y, X′, and Y′ denote identical or different —CR¹R²— groups; R¹ and R² are the same as or different from each other and each denote a hydrogen atom or a C1-C3 hydrocarbon group; and when n is 2, the two groups X′ are the same as or different from each other, and the two groups Y′ are the same as or different from each other, and
x, y, x′, and y′ indicate the numbers of X, Y, X′, and Y′, respectively, and each independently denote 0 or 1].
   [8]

The resist underlayer film forming composition according to any one of [1] to [7], wherein when the amount of a base required to neutralize the same number of moles of sulfonic acid (a monobasic acid) as the sulfonate anion groups (SO₃⁻) contained in the thermal acid generator (a) is 1 equivalent, the base or bases having a higher pKa than pyridine among the counter base or bases B¹ in the formula (1) of the component (a) and the base or bases B² in the component (c) represent 1.05 equivalents or more.

[9]

The resist underlayer film forming composition according to any one of [1] to [7], wherein when the amount of a base required to neutralize the same number of moles of sulfonic acid (a monobasic acid) as the sulfonate anion groups (SO₃⁻) contained in the thermal acid generator (a) is 1 equivalent, the amount added of the base or bases B² is 0.05 to 3.0 equivalents.

[10]

The resist underlayer film forming composition according to any one of [1] to [9], wherein
the counter base or bases B¹ in the formula (1) of the component (a) and/or the base or bases B² in the component (c) are R^{I}R^{II}R^{III}N,
R^{I} and R^{II} each independently denote a hydrogen atom, an optionally substituted, linear or branched, saturated or unsaturated, aliphatic hydrocarbon group,
R^{I} and R^{II} optionally form a ring together via a heteroatom or without a heteroatom, or optionally form a ring together via an aromatic ring,
R^{III} denotes a hydrogen atom, an optionally substituted aromatic ring residue, or an optionally substituted, linear or branched, saturated or unsaturated, aliphatic hydrocarbon group, and
when R^{I} and R^{II} do not form a ring together, R^{III} is a hydrogen atom or an optionally substituted aromatic ring residue.
   [11]

The resist underlayer film forming composition according to any one of [1] to [9], wherein
the counter base or bases B¹ in the formula (1) of the component (a) and/or the base or bases B² in the component (c) are each:
   a base represented by:

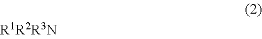

[wherein
R¹ and R² each independently denote an optionally substituted, linear or branched, saturated or unsaturated, aliphatic hydrocarbon group, and
R³ denotes a hydrogen atom or an optionally substituted aromatic hydrocarbon group] or
   a cyclic amine compound represented by formula (3) below:

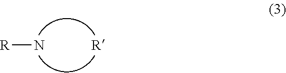

[in the formula (3),
R is:
   a hydrogen atom;
   a C1-C10 alkyl group, a C2-C10 alkenyl group, a C2-C10 alkynyl group, a C1-C10 hydroxyalkyl group, a C6-C40 aryl group, an ether bond-containing organic group, a ketone bond-containing organic group, or an ester bond-containing organic group, each of which is optionally substituted with a nitro group, a cyano group, an amino group, a carboxyl group, a hydroxyl group, an amide group, an aldehyde group, a (meth)acryloyl group, a halogen atom, or a C1-C10 alkoxy group; or
   a group including a combination of the above groups, and
R′ is an aromatic ring forming a condensed ring together with a ring in the cyclic amine in the formula (3) or is:

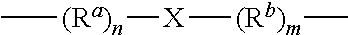

wherein R^{a} and R^{b} each independently denote an optionally substituted alkylene group,
X is O, S, SO₂, CO, CONH, COO, or NH, and
n and m are each independently 2, 3, 4, 5, or 6].
   [12]

The resist underlayer film forming composition according to [11], wherein the base or bases are such that:
R³ in the formula (2) denotes an optionally substituted phenyl, naphthyl, anthracenyl, pyrenyl, or phenanthrenyl group, or
R in the formula (3) is a hydrogen atom, a methyl group, an ethyl group, an isobutyl group, an allyl group, or a cyanomethyl group, and
R′ in the formula (3) is represented by:

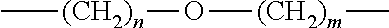

wherein n and m are each independently 2, 3, 4, 5, or 6.
   [13]

The resist underlayer film forming composition according to any one of [1] to [12], wherein the counter base or bases B¹ in the formula (1) of the component (a) and/or the base or bases B² in the component (c) are one, or two or more selected from N-methylmorpholine, N-isobutylmorpholine, N-allylmorpholine, and N,N-diethylaniline.

[14]

The resist underlayer film forming composition according to any one of [1] to [13], wherein A¹ in the formula (1) is a methyl group, a trifluoromethyl group, a naphthyl group, a norbornanylmethyl group, a dimethylphenyl group, or a tolyl group.

[15]

The resist underlayer film forming composition according to any one of [1] to [14], further comprising a crosslinking agent.

[16]

The resist underlayer film forming composition according to [15], wherein the crosslinking agent is an aminoplast crosslinking agent or a phenoplast crosslinking agent.

[17]

The resist underlayer film forming composition according to [16], wherein the aminoplast crosslinking agent is a highly alkylated, alkoxylated, or alkoxyalkylated melamine, benzoguanamine, glycoluril, or urea, or a polymer thereof.

[18]

The resist underlayer film forming composition according to [16], wherein the phenoplast crosslinking agent is a highly alkylated, alkoxylated, or alkoxyalkylated aromatic, or a polymer thereof.

[19]

The resist underlayer film forming composition according to any one of [1] to [18], wherein the solvent (d) is a compound having an alcoholic hydroxyl group or a compound having a group capable of forming an alcoholic hydroxyl group.

[20]

The resist underlayer film forming composition according to [19], wherein the compound having an alcoholic hydroxyl group or the compound having a group capable of forming an alcoholic hydroxyl group is a propylene glycol solvent, an oxyisobutyric acid ester solvent, or a butylene glycol solvent.

[21]

The resist underlayer film forming composition according to [19], wherein the compound having an alcoholic hydroxyl group or the compound having a group capable of forming an alcoholic hydroxyl group is propylene glycol monomethyl ether, methyl 2-hydroxy-2-methylpropionate, cyclohexanone, propylene glycol monomethyl ether acetate, or ethyl lactate.

[22]

The resist underlayer film forming composition according to any one of [1] to [21], further comprising a surfactant.

[23]

On a semiconductor substrate, a resist underlayer film comprising a baked product of a coating film comprising the resist underlayer film forming composition described in any one of [1] to [22].

[24]

A method for forming a resist pattern used in semiconductor manufacturing, the method comprising a step of applying the resist underlayer film forming composition described in any one of [1] to onto a semiconductor substrate, and baking the resist underlayer film forming composition to form a resist underlayer film.

[25]

A method for manufacturing a semiconductor device, comprising:
a step of forming on a semiconductor substrate a resist underlayer film from the resist underlayer film forming composition described in any one of [1] to [22];
a step of forming a resist film on the resist underlayer film;
a step of forming a resist pattern by irradiation with light or electron beam followed by development;
a step of etching the resist underlayer film through the resist pattern; and
a step of processing the semiconductor substrate through the resist underlayer film having been patterned.
   [26]

A method for manufacturing a semiconductor device, comprising:
a step of forming on a semiconductor substrate a resist underlayer film from the resist underlayer film forming composition described in any one of [1] to [22];
a step of forming a hard mask on the resist underlayer film;
a step of forming a resist film on the hard mask;
a step of forming a resist pattern by irradiation with light or electron beam followed by development;
a step of etching the hard mask through the resist pattern;
a step of etching the resist underlayer film through the hard mask having been patterned; and
a step of processing the semiconductor substrate through the resist underlayer film having been patterned.
   [27]

A method for manufacturing a semiconductor device, comprising:
a step of forming on a semiconductor substrate a resist underlayer film from the resist underlayer film forming composition described in any one of [1] to [22];
a step of forming a hard mask on the resist underlayer film;
a step of forming a resist film on the hard mask;
a step of forming a resist pattern by irradiation with light or electron beam followed by development;
a step of etching the hard mask through the resist pattern;
a step of etching the resist underlayer film through the hard mask having been patterned;
a step of removing the hard mask; and
a step of processing the semiconductor substrate through the resist underlayer film having been patterned.
   [28]

A method for manufacturing a semiconductor device, comprising:
a step of forming on a semiconductor substrate a resist underlayer film from the resist underlayer film forming composition described in any one of [1] to [22];
a step of forming a hard mask on the resist underlayer film;
a step of forming a resist film on the hard mask;
a step of forming a resist pattern by irradiation with light or electron beam followed by development;
a step of etching the hard mask through the resist pattern;
a step of etching the resist underlayer film through the hard mask having been patterned;
a step of removing the hard mask;
a step of forming a deposited film (a spacer) on the resist underlayer film cleaned of the hard mask;
a step of processing the deposited film (the spacer) by etching;
a step of removing the resist underlayer film having been patterned while leaving the deposited film (the spacer) having been patterned; and
a step of processing the semiconductor substrate through the deposited film (the spacer) having been patterned.
   [29]

The manufacturing method according to any one of [26] to [28], wherein the hard mask is formed by applying an inorganic substance or by depositing an inorganic substance.

[30]

The manufacturing method according to any one of [25] to [28], wherein the resist film is patterned by a nanoimprinting method or by using a self-assembled film.

[31]

The method for manufacturing a semiconductor device according to [27] or [28], wherein the hard mask is removed by etching or with an alkaline chemical solution.

### Advantageous Effects of Invention

In the underlayer film forming composition according to the present invention, one, or two or more kinds of bases B² are separately added as additional base components. The bases trap the acid generated at the time of baking and thereby slow down the curing rate. As a result, the composition can form cured films on various kinds of films, such as SiO₂, TiN, and SiN, while exhibiting high flattening properties and high gap-filling properties. Furthermore, the bases eliminate influences of the acid generator on the polymer that is a main component of the resist underlayer film, and the storage stability of the polymer can be ensured. Thus, the composition is free from coloration and can form films that are not dissolved by photoresist solvents. The present invention further provides a resist underlayer film obtained from the resist underlayer film forming composition, and methods for manufacturing a semiconductor device using the composition.

### DESCRIPTION OF EMBODIMENTS

### I. Definition of Terms

The definitions of the main terms in the present specification related to novolac resins constituting an aspect of the present invention will be described below. Unless otherwise specified separately, the terms related to novolac resins are based on the following definitions.

### (I-1) “Novolac Resins”

The term “novolac resins” refers not only to narrowly defined phenol-formaldehyde resins (so-called novolac-type phenol resins) and aniline-formaldehyde resins (so-called novolac-type aniline resins) but also to a broad range of general polymers formed by the formation of covalent bonds (such as a substitution reaction, an addition reaction, a condensation reaction, or an addition condensation reaction) between an organic compound that has a functional group enabling covalent bonding to an aromatic ring in the presence of an acid catalyst or under similar reaction conditions [such as, for example, an aldehyde group, a ketone group, an acetal group, a ketal group; a hydroxyl or alkoxy group bonded to a secondary or tertiary carbon; a hydroxyl, alkoxy, or halo group bonded to an α-carbon atom in an alkylaryl group (such as a benzylic carbon atom); or a carbon-carbon unsaturated bond, such as divinylbenzene or dicyclopentadiene], and an aromatic ring in an aromatic ring-containing compound (preferably having, on the aromatic ring, a substituent containing a heteroatom, such as an oxygen atom, a nitrogen atom, or a sulfur atom).

Thus, the novolac resins referred to in the present specification are polymers in which the organic compound that contains a carbon atom derived from the above functional group (sometimes written as the “linking carbon atom”) connects a plurality of molecules of the aromatic ring-containing compound by forming, via the linking carbon atoms, covalent bonds with the aromatic rings in the molecules of the aromatic ring-containing compound.

In the present specification, the unit structures constituting a “novolac resin” are written as unit structures A, unit structures B, and unit structures C. The unit structure A is a unit structure derived from an aromatic ring-containing compound. The unit structure B is a unit structure derived from a compound having a functional group enabling covalent bonding to the aromatic ring in the unit structure A. The unit structure C is a unit structure that is equivalent, in bonding mode, to a composite unit structure A-B, and is derived from a compound having an aromatic ring and also having a functional group enabling covalent bonding to the aromatic ring in the unit structure A. Due to the identicalness in bonding mode, the unit structure C may be replaced with the composite unit structure A-B.

### (I-2) “Residues”

The term “residue” indicates an organic group that has a valence bond in place of a hydrogen atom bonded to a carbon atom or a heteroatom (such as a nitrogen atom, an oxygen atom, or a sulfur atom) and may be a monovalent group or a polyvalent group. For example, the substitution of one hydrogen atom with one valence bond results in a monovalent organic group, and the substitution of two hydrogen atoms with valence bonds yields a divalent organic group.

### (I-3) “Aromatic Rings” (Aromatic Groups, Aryl Groups, Arylene Groups)

The concept of “aromatic rings” comprehends aromatic hydrocarbon rings, aromatic heterocyclic rings, and residues thereof [also written as “aromatic groups”, “aryl groups” (in the case of monovalent groups), or “arylene groups” (in the case of divalent groups)], and the rings may be monocyclic (aromatic monocyclic rings) or polycyclic (aromatic polycyclic rings). In the case of polycyclic rings, at least one monocyclic ring is an aromatic monocyclic ring, but the remaining monocyclic ring or rings that form the condensed ring with that aromatic monocyclic ring may be monocyclic heterocyclic rings (heteromonocyclic rings) or monocyclic alicyclic hydrocarbons (alicyclic monocyclic rings).

Examples of the aromatic rings include, but are not limited to, aromatic hydrocarbon rings, such as benzene, indene, naphthalene, azulene, styrene, toluene, xylene, mesitylene, cumene, anthracene, phenanthrene, triphenylene, benzanthracene, pyrene, chrysene, fluorene, biphenyl, corannulene, perylene, fluoranthene, benzo[k]fluoranthene, benzo[b]fluoranthene, benzo[ghi]perylene, coronene, dibenzo[g,p]chrysene, acenaphthylene, acenaphthene, naphthacene, pentacene, and cyclooctatetraene, more typically, such aromatic hydrocarbon rings as benzene, naphthalene, anthracene, and pyrene; and aromatic heterocyclic rings, such as furan, pyran, pyridine, pyrimidine, pyrazine, thithiophene, pyrrole, N-alkylpyrrole, N-arylpyrrole, imidazole, pyridine, pyrimidine, pyrazine, triazine, thiazole, indole, phenylindole, bisindolefluorene, bisindolebenzofluorene, bisindoledibenzofluorene, purine, quinoline, isoquinoline, chromene, thianthrene, phenothiazine, phenoxazine, xanthene, acridine, phenazine, carbazole, and indolocarbazole, more typically, furan, thiophene, pyrrole, indole, phenylindole, bisindolefluorene, phenothiazine, carbazole, and indolocarbazole.

The aromatic rings (such as, for example, benzene ring or naphthalene ring) may optionally have a substituent. Examples of such substituents include halogen atoms; saturated or unsaturated, linear, branched, or cyclic hydrocarbon groups (—R) (the hydrocarbon chains may be interrupted with an oxygen atom one or more times; examples of R include alkyl groups, alkenyl groups, alkynyl groups, and propargyl group); alkoxy groups or aryloxy groups (—OR wherein R denotes the hydrocarbon group —R described above); alkylamino groups [—NHR or —NR₂ (the two groups R may be the same as or different from each other), wherein R denotes the hydrocarbon group —R described above and may be, for example, an alkyl group, an alkenyl group, an alkynyl group, or a propargyl group, and the hydrocarbon chains may be interrupted with an oxygen atom one or more times]; hydroxyl group; amino group (—NH₂); carboxyl group; cyano group; nitro group; ester groups (—CO₂R or —OCOR wherein R denotes the hydrocarbon group —R described above); amide groups (—NHCOR, —CONHR, —NRCOR (the two groups R may be the same as or different from each other), or —CONR₂ (the two groups R may be the same as or different from each other), wherein R denotes the hydrocarbon group —R described above); sulfonyl-containing groups (—SO₂R wherein R denotes the hydrocarbon group —R described above or the hydroxyl group —OH); thiol group (—SH); sulfide-containing groups (—SR wherein R denotes the hydrocarbon group —R described above); ether bond-containing organic groups [residues of an ether compound represented by R¹¹—O—R¹¹ (R¹¹ independently at each occurrence denotes a C1-C6 alkyl group, such as a methyl group or an ethyl group, or an aryl group, such as a phenyl group, a naphthyl group, an anthranyl group, or a pyrenyl group); for example, organic groups containing an ether bond as a methoxy group, an ethoxy group, or a phenoxy group]; and aryl groups.

Furthermore, the aromatic rings may be organic groups having a condensed ring formed of one or more aromatic rings (such as benzene, naphthalene, anthracene, or pyrene) with one or more aliphatic rings or heterocyclic rings. Examples of the aliphatic rings here include cyclobutane, cyclobutene, cyclopentane, cyclopentene, cyclohexane, cyclohexene, methylcyclohexane, methylcyclohexene, cycloheptane, and cycloheptene. Examples of the heterocyclic rings include furan, thiophene, pyrrole, imidazole, pyran, pyridine, pyrimidine, pyrazine, pyrrolidine, piperidine, piperazine, and morpholine.

The aromatic rings may be organic groups having a structure in which two or more aromatic rings are connected via a divalent linking group, such as an alkylene group.

### (I-4) “Heterocyclic Rings”

The concept of “heterocyclic rings” comprehends both aliphatic heterocyclic rings and aromatic heterocyclic rings and includes not only monocyclic rings (heteromonocyclic rings) but also polycyclic rings (heteropolycyclic rings). In the case of polycyclic rings, at least one monocyclic ring is a heteromonocyclic ring, but the remaining monocyclic ring or rings may be aromatic hydrocarbon monocyclic rings or alicyclic monocyclic rings. Examples of the aromatic heterocyclic rings include those described in (I-3) above. Similarly to the aromatic rings in (I-3), the heterocyclic rings may have a substituent.

(I-5) “Non-aromatic rings” (aliphatic rings)

The term “non-aromatic monocyclic rings” refers to monocyclic hydrocarbons that are not aromatic, and typically indicates monocyclic rings of alicyclic compounds. The rings may also be referred to as aliphatic monocyclic rings (including aliphatic heteromonocyclic rings) (the rings may contain an unsaturated bond as long as the rings do not belong to aromatic compounds). Similarly to the aromatic rings in (I-3), the non-aromatic monocyclic rings may have a substituent.

Examples of the non-aromatic monocyclic rings (aliphatic rings, aliphatic monocyclic rings) include cyclopropane, cyclobutane, cyclobutene, cyclopentane, cyclopentene, cyclohexane, methylcyclohexane, cyclohexene, methylcyclohexene, cycloheptane, and cycloheptene.

The term “non-aromatic polycyclic rings” refers to polycyclic hydrocarbons that are not aromatic, and typically indicates polycyclic rings of alicyclic compounds. The rings may also be referred to as aliphatic polycyclic rings [including aliphatic heteropolycyclic rings (at least one of the monocyclic rings constituting the polycyclic ring is an aliphatic heterocyclic ring) (the rings may contain an unsaturated bond as long as the rings do not belong to aromatic compounds)]. The non-aromatic polycyclic rings include non-aromatic bicyclic rings, non-aromatic tricyclic rings, and non-aromatic tetracyclic rings.

The term “non-aromatic bicyclic rings” refers to condensed rings composed of two monocyclic hydrocarbons that are not aromatic, and typically indicates condensed rings composed of two alicyclic compounds. In the present specification, the rings are also referred to as aliphatic bicyclic rings (including aliphatic heterobicyclic rings) (the rings may contain an unsaturated bond as long as the rings do not belong to aromatic compounds). Examples of the non-aromatic bicyclic rings include bicyclopentane, bicyclooctane, and bicycloheptene.

The term “non-aromatic tricyclic rings” refers to condensed rings composed of three monocyclic hydrocarbons that are not aromatic, and typically indicates condensed rings composed of three alicyclic compounds (that may be each a heterocyclic ring and may contain an unsaturated bond as long as the compound does not belong to aromatic compounds). Examples of the non-aromatic tricyclic rings include tricyclooctane, tricyclononane, and tricyclodecane.

The term “non-aromatic tetracyclic rings” refers to condensed rings composed of four monocyclic hydrocarbons that are not aromatic, and typically indicates condensed rings composed of four alicyclic compounds (that may be each a heterocyclic ring and may contain an unsaturated bond as long as the compound does not belong to aromatic compounds). Examples of the non-aromatic tetracyclic rings include hexadecahydropyrene.

### (I-6)

The term “carbon atoms constituting a ring (moiety)” means the carbon atoms constituting a hydrocarbon ring (which may be an aromatic ring, an aliphatic ring, or a heterocyclic ring) in a substituent-free form.

### (I-7)

The term “hydrocarbon groups” refers to groups resulting from the removal of one, or two or more hydrogen atoms from a hydrocarbon. The hydrocarbons include saturated or unsaturated aliphatic hydrocarbons, saturated or unsaturated alicyclic hydrocarbons, and aromatic hydrocarbons.

### (I-8)

In the chemical structural formulas showing unit structures of novolac resins in the present specification, valence bonds (indicated by *) are sometimes described for the purpose of convenience. Such valence bonds may be present at any possible bonding positions in the unit structures unless otherwise specified, and the bonding positions in the unit structures are not limited to those that are illustrated.

### II. Thermal Acid Generators

### (II-1)

A resist underlayer film forming composition according to an aspect of the present invention includes a thermal acid generator represented by formula (1) below as component (a).

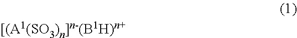

In the formula (1),

A¹ is an optionally substituted, linear, branched, or cyclic, saturated or unsaturated, aliphatic hydrocarbon group, or an optionally substituted aromatic ring residue, and is preferably a methyl group, a trifluoromethyl group, a naphthyl group, a norbornanylmethyl group, a dimethylphenyl group, or a tolyl group.

Here, the concept of “aromatic ring” comprehends aromatic hydrocarbon ring and aromatic heterocyclic ring. The term “residue” indicates an organic group that has a valence bond in place of a hydrogen atom bonded to a carbon atom or a heteroatom (a nitrogen atom, an oxygen atom) and may be a monovalent group or a polyvalent group.

In the formula (1), n indicates the number of the sulfonate anion groups and is 1 or 2, preferably 1.

In the formula (1), B¹ denotes one, or two or more kinds of counter bases and is a monoacidic base or a monoacidic base moiety of a diacidic base or a triacidic base. When B¹ is a diacidic base or a triacidic base, the structure is such that two or three moieties each corresponding to B¹ are covalently bonded to one another.

A¹ and B¹ may be connected via a single bond or a linking group.

Among the counter base or bases B¹ and the base or bases B² in the component (c) described later, at least one or more bases have a higher pKa than pyridine.

The pKa requirement, the equivalent ratio of the counter base(s) B¹ to the base(s) B² in the component (c), and other conditions will be described later in (IV-2) to (IV-3).

### (II-2)

The counter base or bases B¹ in the formula (1) of the component (a) and/or the base or bases B² in the component (c) are preferably each R^{I}R^{II}R^{III}N

[wherein
R^{I} and R^{II} each independently denote a hydrogen atom, an optionally substituted, linear or branched, saturated or unsaturated, aliphatic hydrocarbon group,
R^{I} and R^{II} optionally form a ring together via a heteroatom or without a heteroatom, or optionally form a ring together via an aromatic ring, and the heteroatom is preferably an oxygen atom, a nitrogen atom, or a sulfur atom,
R^{III} denotes a hydrogen atom, an optionally substituted aromatic ring residue, or an optionally substituted, linear or branched, saturated or unsaturated, aliphatic hydrocarbon group, and
when R^{I} and R^{II} do not form a ring together, R^{III} is a hydrogen atom or an optionally substituted aromatic ring residue].

The counter base or bases B¹ in the formula (1) of the component (a) and/or the base or bases B² in the component (c) are more preferably each a base represented by:

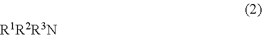

[wherein
R¹ and R² each independently denote an optionally substituted, linear or branched, saturated or unsaturated, aliphatic hydrocarbon group, and
R³ denotes a hydrogen atom or an optionally substituted aromatic group, and preferably denotes an optionally substituted phenyl, naphthyl, anthracenyl, pyrenyl, or phenanthrenyl group] or
a cyclic amine compound represented by formula (3) below:

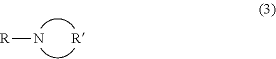

[in the formula (3),
R is:
   a hydrogen atom;
   a nitro group, a cyano group, an amino group, a carboxyl group, a hydroxyl group, an amide group, an aldehyde group, a (meth)acryloyl group, a halogen atom (for example, a fluorine atom, a chlorine atom, a bromine atom, or an iodine atom), or a C1-C10 alkyl group, a C2-C10 alkenyl group, a C2-C10 alkynyl group, a C1-C10 hydroxyalkyl group, a C6-C40 aryl group, an ether bond-containing organic group, a ketone bond-containing organic group, or an ester bond-containing organic group each of which is optionally substituted with a C1-C10 alkoxy group; or
   a group including a combination of the above groups, and
R′ is an aromatic ring forming a condensed ring together with a ring in the cyclic amine in the formula (3) or is:

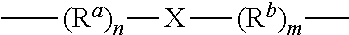

wherein R^{a} and R^{b} each independently denote an optionally substituted alkylene group,
X is O, S, SO₂, CO, CONH, COO, or NH, and
n and m are each independently 2, 3, 4, 5, or 6].
R in the formula (3) is preferably a hydrogen atom, a methyl group, an ethyl group, an isobutyl group, an allyl group, or a cyanomethyl group.

Furthermore, R′ in the formula (3) is preferably represented by:

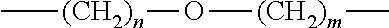

wherein n and m are each independently 2, 3, 4, 5, or 6.

### (II-3)

### (II-3-1)

Examples of the “linear or branched, saturated aliphatic hydrocarbon group” in the definition of A¹ in the formula (1), in the definitions of R^{I}, R^{II}, and R^{III} in R^{I}R^{II}R^{III}N, or in the definitions of R¹ and R² in R¹R²R³N include methyl group, ethyl group, n-propyl group, i-propyl group, n-butyl group, i-butyl group, s-butyl group, t-butyl group, n-pentyl group, 1-methyl-n-butyl group, 2-methyl-n-butyl group, 3-methyl-n-butyl group, 1,1-dimethyl-n-propyl group, 1,2-dimethyl-n-propyl group, 2,2-dimethyl-n-propyl group, 1-ethyl-n-propyl group, n-hexyl group, 1-methyl-n-pentyl group, 2-methyl-n-pentyl group, 3-methyl-n-pentyl group, 4-methyl-n-pentyl group, 1,1-dimethyl-n-butyl group, 1,2-dimethyl-n-butyl group, 1,3-dimethyl-n-butyl group, 2,2-dimethyl-n-butyl group, 2,3-dimethyl-n-butyl group, 3,3-dimethyl-n-butyl group, 1-ethyl-n-butyl group, 2-ethyl-n-butyl group, 1,1,2-trimethyl-n-propyl group, 1,2,2-trimethyl-n-propyl group, 1-ethyl-1-methyl-n-propyl group, and 1-ethyl-2-methyl-n-propyl group.

### (II-3-2)

Examples of the “cyclic saturated aliphatic hydrocarbon group” in the definition of A¹ in the formula (1) include cyclopropyl group, cyclobutyl group, 1-methyl-cyclopropyl group, 2-methyl-cyclopropyl group, cyclopentyl group, 1-methyl-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, cyclohexyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2,2-dimethyl-cyclobutyl group, 2,3-dimethyl-cyclobutyl group, 2,4-dimethyl-cyclobutyl group, 3,3-dimethyl-cyclobutyl group, 1-n-propyl-cyclopropyl group, 2-n-propyl-cyclopropyl group, 1-i-propyl-cyclopropyl group, 2-i-propyl-cyclopropyl group, 1,2,2-trimethyl-cyclopropyl group, 1,2,3-trimethyl-cyclopropyl group, 2,2,3-trimethyl-cyclopropyl group, 1-ethyl-2-methyl-cyclopropyl group, 2-ethyl-1-methyl-cyclopropyl group, 2-ethyl-2-methyl-cyclopropyl group, and 2-ethyl-3-methyl-cyclopropyl group.

### (II-3-3)

Examples of the “linear or branched, unsaturated aliphatic hydrocarbon group” in the definition of A¹ in the formula (1), in the definitions of R^{I}, R^{II}, and R^{III} in R^{I}R^{II}R^{III}N, or in the definitions of R¹ and R² in R¹R²R³N include ethenyl group, 1-propenyl group, 2-propenyl group, 1-methyl-1-ethenyl group, 1-butenyl group, 2-butenyl group, 3-butenyl group, 2-methyl-1-propenyl group, 2-methyl-2-propenyl group, 1-ethylethenyl group, 1-methyl-1-propenyl group, 1-methyl-2-propenyl group, 1-pentenyl group, 2-pentenyl group, 3-pentenyl group, 4-pentenyl group, 1-n-propylethenyl group, 1-methyl-1-butenyl group, 1-methyl-2-butenyl group, 1-methyl-3-butenyl group, 2-ethyl-2-propenyl group, 2-methyl-1-butenyl group, 2-methyl-2-butenyl group, 2-methyl-3-butenyl group, 3-methyl-1-butenyl group, 3-methyl-2-butenyl group, 3-methyl-3-butenyl group, 1,1-dimethyl-2-propenyl group, 1-i-propylethenyl group, 1,2-dimethyl-1-propenyl group, 1,2-dimethyl-2-propenyl group, 1-hexenyl group, 2-hexenyl group, 3-hexenyl group, 4-hexenyl group, 5-hexenyl group, 1-methyl-1-pentenyl group, 1-methyl-2-pentenyl group, 1-methyl-3-pentenyl group, 1-methyl-4-pentenyl group, 1-n-butylethenyl group, 2-methyl-1-pentenyl group, 2-methyl-2-pentenyl group, 2-methyl-3-pentenyl group, 2-methyl-4-pentenyl group, 2-n-propyl-2-propenyl group, 3-methyl-1-pentenyl group, 3-methyl-2-pentenyl group, 3-methyl-3-pentenyl group, 3-methyl-4-pentenyl group, 3-ethyl-3-butenyl group, 4-methyl-1-pentenyl group, 4-methyl-2-pentenyl group, 4-methyl-3-pentenyl group, 4-methyl-4-pentenyl group, 1,1-dimethyl-2-butenyl group, 1,1-dimethyl-3-butenyl group, 1,2-dimethyl-1-butenyl group, 1,2-dimethyl-2-butenyl group, 1,2-dimethyl-3-butenyl group, 1-methyl-2-ethyl-2-propenyl group, 1-s-butylethenyl group, 1,3-dimethyl-1-butenyl group, 1,3-dimethyl-2-butenyl group, 1,3-dimethyl-3-butenyl group, 1-i-butylethenyl group, 2,2-dimethyl-3-butenyl group, 2,3-dimethyl-1-butenyl group, 2,3-dimethyl-2-butenyl group, 2,3-dimethyl-3-butenyl group, 2-i-propyl-2-propenyl group, 3,3-dimethyl-1-butenyl group, 1-ethyl-1-butenyl group, 1-ethyl-2-butenyl group, 1-ethyl-3-butenyl group, 1-n-propyl-1-propenyl group, 1-n-propyl-2-propenyl group, 2-ethyl-1-butenyl group, 2-ethyl-2-butenyl group, 2-ethyl-3-butenyl group, 1,1,2-trimethyl-2-propenyl group, 1-t-butylethenyl group, 1-methyl-1-ethyl-2-propenyl group, 1-ethyl-2-methyl-1-propenyl group, 1-ethyl-2-methyl-2-propenyl group, 1-i-propyl-1-propenyl group, and 1-i-propyl-2-propenyl group.

### (II-3-4)

Examples of the “cyclic unsaturated aliphatic hydrocarbon group” in the definition of A¹ in the formula (1) include 1-cyclopentenyl group, 2-cyclopentenyl group, 3-cyclopentenyl group, 1-methyl-2-cyclopentenyl group, 1-methyl-3-cyclopentenyl group, 2-methyl-1-cyclopentenyl group, 2-methyl-2-cyclopentenyl group, 2-methyl-3-cyclopentenyl group, 2-methyl-4-cyclopentenyl group, 2-methyl-5-cyclopentenyl group, 2-methylene-cyclopentyl group, 3-methyl-1-cyclopentenyl group, 3-methyl-2-cyclopentenyl group, 3-methyl-3-cyclopentenyl group, 3-methyl-4-cyclopentenyl group, 3-methyl-5-cyclopentenyl group, 3-methylene-cyclopentyl group, 1-cyclohexenyl group, 2-cyclohexenyl group, and 3-cyclohexenyl group.

### (II-3-5)

The “aromatic ring residue” in the definition of A¹ in the formula (1) or in the definition of R in the formula (3) may be an aromatic hydrocarbon group, with examples including phenyl group, o-methylphenyl group, m-methylphenyl group, p-methylphenyl group, 2,3-dimethylphenyl group, 2,4-dimethylphenyl group, 2,5-dimethylphenyl group, 2,6-dimethylphenyl group, 3,4-dimethylphenyl group, 3,5-dimethylphenyl group, o-chlorophenyl group, m-chlorophenyl group, p-chlorophenyl group, o-fluorophenyl group, p-fluorophenyl group, o-methoxyphenyl group, p-methoxyphenyl group, p-nitrophenyl group, p-cyanophenyl group, a-naphthyl group, β-naphthyl group, o-biphenylyl group, m-biphenylyl group, p-biphenylyl group, 1-anthryl group, 2-anthryl group, 9-anthryl group, 1-phenanthryl group, 2-phenanthryl group, 3-phenanthryl group, 4-phenanthryl group, 9-phenanthryl group, 1-pyrenyl group, 2-pyrenyl group, and 3-pyrenyl group.

Furthermore, the “aromatic ring residue” in the definition of A¹ in the formula (1) may be an aromatic heterocyclic ring residue, with examples including furanyl group, thiophenyl group, pyrrolyl group, imidazolyl group, pyranyl group, pyridinyl group, pyrimidinyl group, pyrazinyl group, pyrrolidinyl group, piperidinyl group, piperazinyl group, morpholinyl group, quinuclidinyl group, indolyl group, purinyl group, quinolinyl group, isoquinolinyl group, chromenyl group, thianthrenyl group, phenothiazinyl group, phenoxazinyl group, xanthenyl group, acridinyl group, phenazinyl group, and carbazolyl group.

Examples of the “aromatic ring” or the “aromatic ring” in the definition of R^{III} in R^{I}R^{II}R^{III}N or in the definition of R³ in R¹R²R³N are the same as described above.

### (II-3-6)

In the definition of A¹ in the formula (1), in the definitions of R^{I}, R^{II}, and R^{III} in R^{I}R^{II}R^{III}N, in the definitions of R¹, R², and R³ in R¹R²R³N, or in the definitions of R^{a} and R^{b}, the phrase “optionally substituted” means that a substituent may be present. Examples thereof include nitro group, amino group, cyano group, sulfo group, hydroxyl group, carboxyl group, aldehyde group, propargylamino group, propargyloxy group, halogen atoms, C1-C10 alkoxy groups, C1-C10 alkyl groups, C2-C10 alkenyl groups, C2-C10 alkynyl groups, C6-C40 aryl groups, ether bond-containing organic groups, ketone bond-containing organic groups, ester bond-containing organic groups, and combinations thereof.

The ether bond-containing organic groups, the ketone bond-containing organic groups, and the ester bond-containing organic groups may be exemplified by the groups described later in (II-3-9).

### (II-3-7)

Examples of the “alkoxy group” in the definition of R in the formula (3) include methoxy group, ethoxy group, n-propoxy group, i-propoxy group, n-butoxy group, i-butoxy group, s-butoxy group, t-butoxy group, n-pentyloxy group, 1-methyl-n-butoxy group, 2-methyl-n-butoxy group, 3-methyl-n-butoxy group, 1,1-dimethyl-n-propoxy group, 1,2-dimethyl-n-propoxy group, 2,2-dimethyl-n-propoxy group, 1-ethyl-n-propoxy group, n-hexyloxy group, 1-methyl-n-pentyloxy group, 2-methyl-n-pentyloxy group, 3-methyl-n-pentyloxy group, 4-methyl-n-pentyloxy group, 1,1-dimethyl-n-butoxy group, 1,2-dimethyl-n-butoxy group, 1,3-dimethyl-n-butoxy group, 2,2-dimethyl-n-butoxy group, 2,3-dimethyl-n-butoxy group, 3,3-dimethyl-n-butoxy group, 1-ethyl-n-butoxy group, 2-ethyl-n-butoxy group, 1,1,2-trimethyl-n-propoxy group, 1,2,2-trimethyl-n-propoxy group, 1-ethyl-1-methyl-n-propoxy group, and 1-ethyl-2-methyl-n-propoxy group.

### (II-3-8)

Examples of the “alkylene group” in the definition of R in the formula (3) or in the definitions of R^{a} and R^{b} include alkylene groups derived from the alkyl groups described in (II-3-1) and (II-3-2) by replacing a hydrogen atom with an additional valence bond.

Examples of the “alkenyl group” in the definition of R in the formula (3) include those described in (II-3-3) and (II-3-4).

Examples of the “hydroxyalkyl group” in the definition of R in the formula (3) include the following organic groups. In the formulas, * indicates a valence bond on the carbon atom.

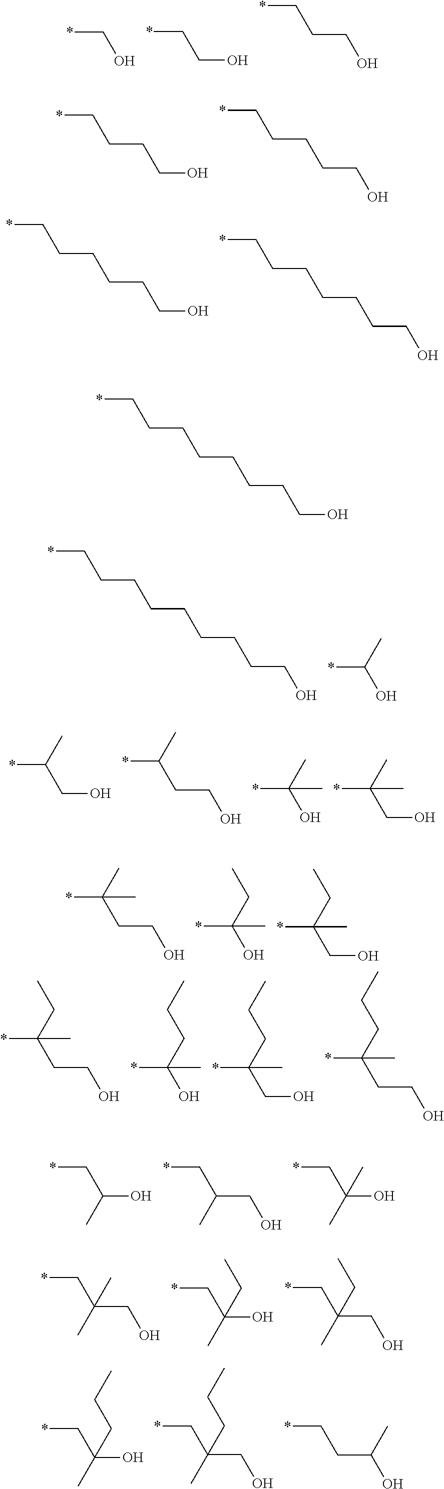

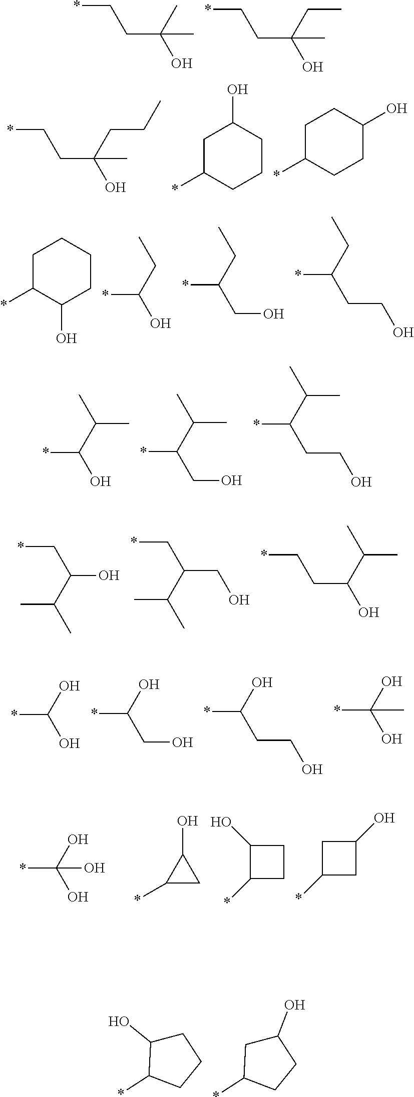

The “alkynyl group” in the definition of R in the formula (3) may be such that an aliphatic hydrocarbon chain contains a carbon-carbon triple bond (at an end of the chain or in the middle of the chain) and optionally further contains a heteroatom (such as an oxygen atom or a nitrogen atom) or may be such that a plurality of alkynyl groups are connected to one another. Examples include the following organic groups. In the formulas, * indicates a valence bond on the carbon atom.

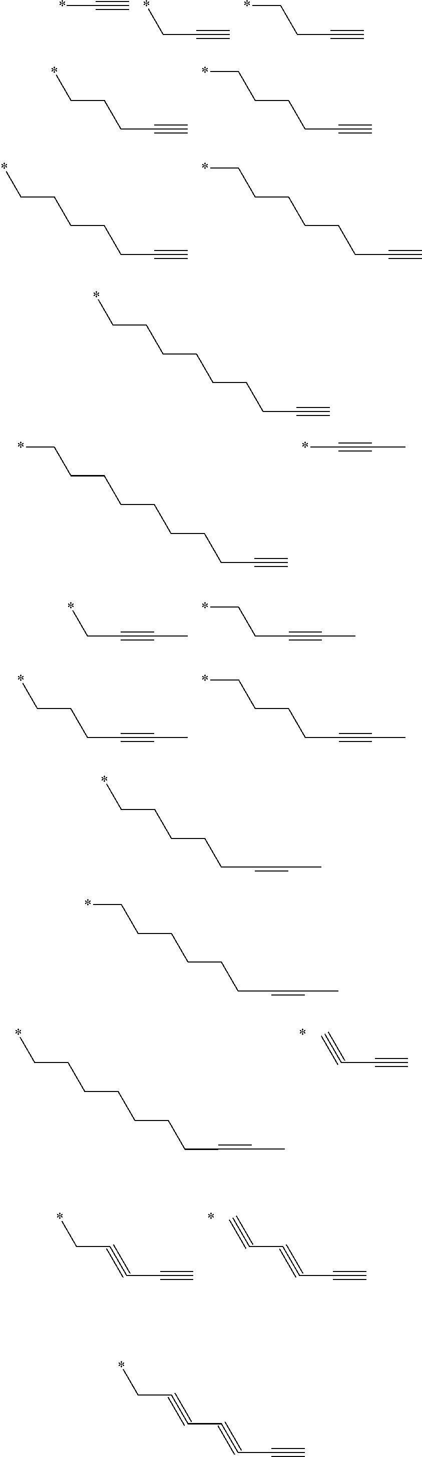

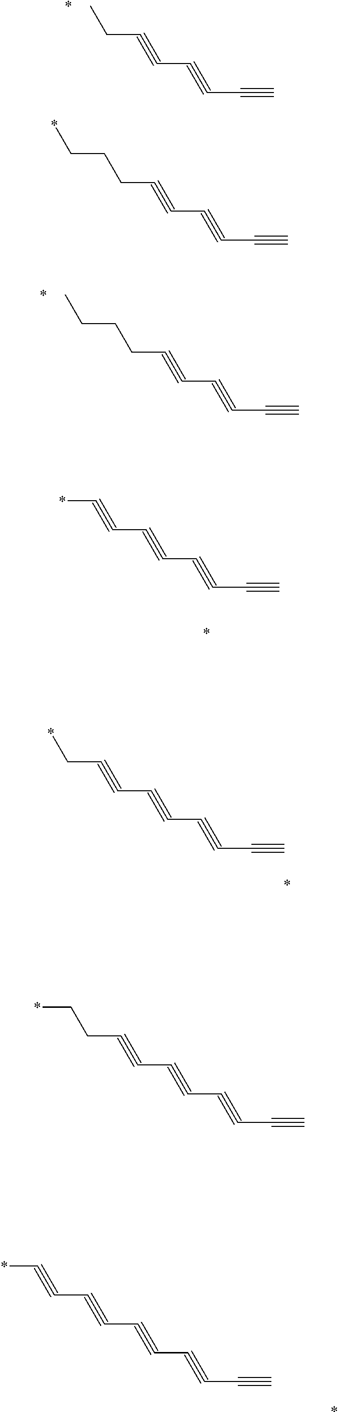

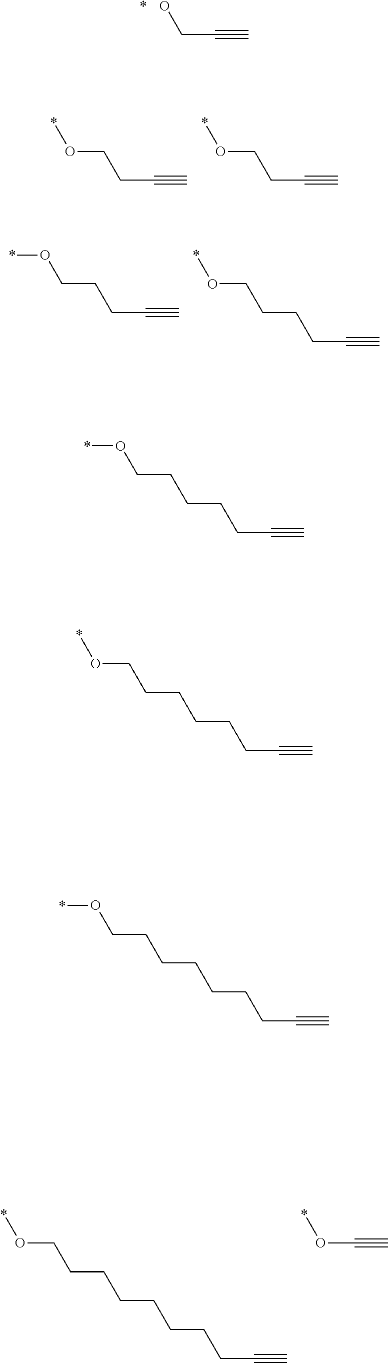

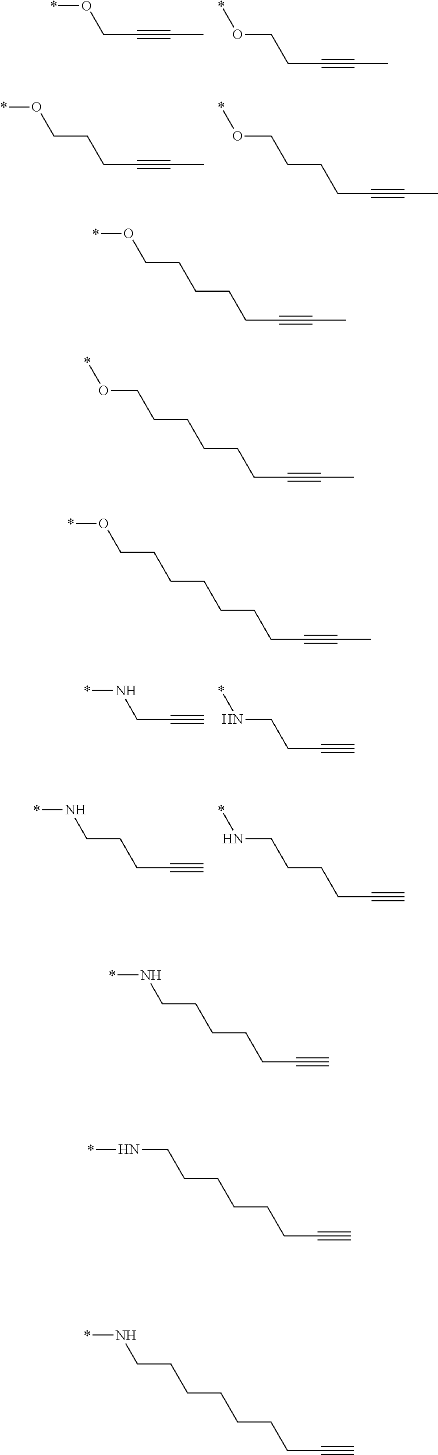

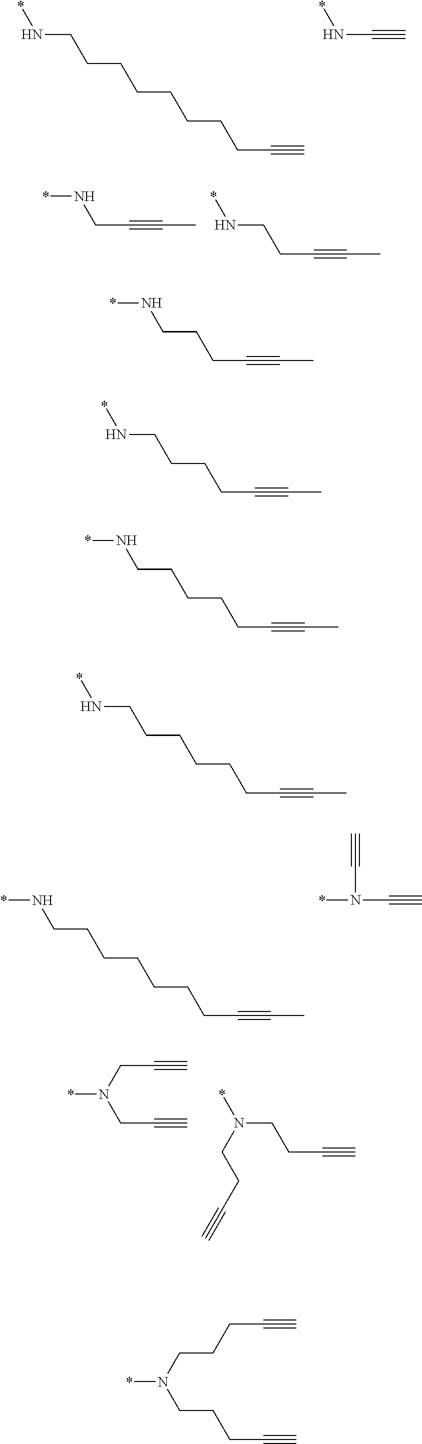

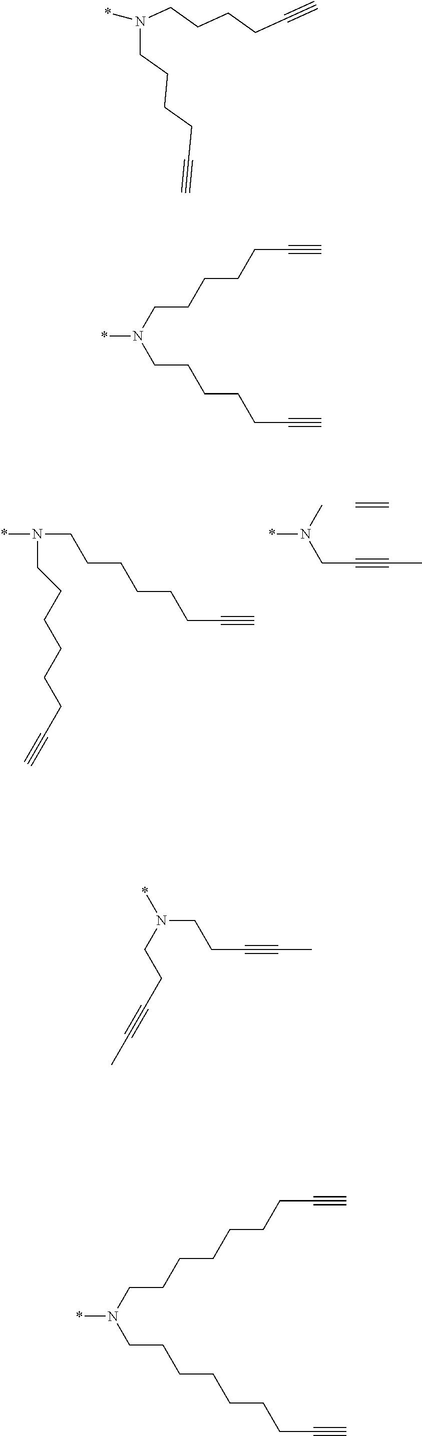

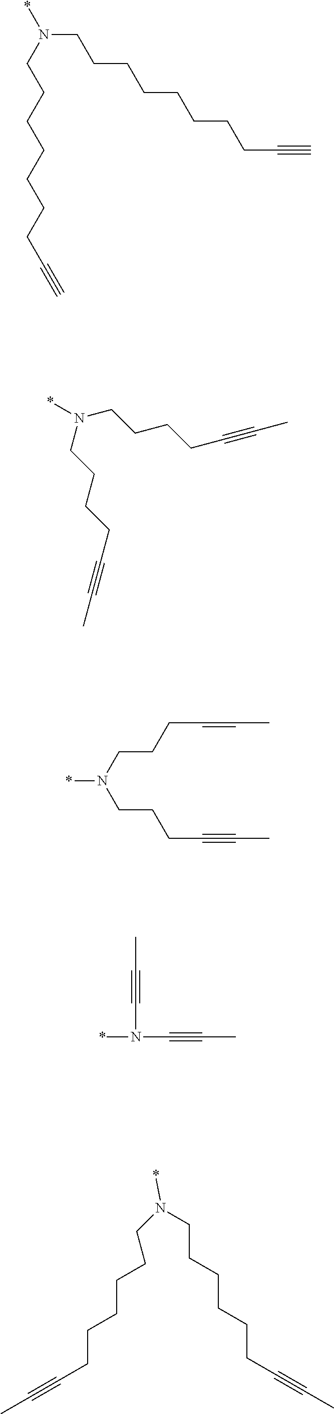

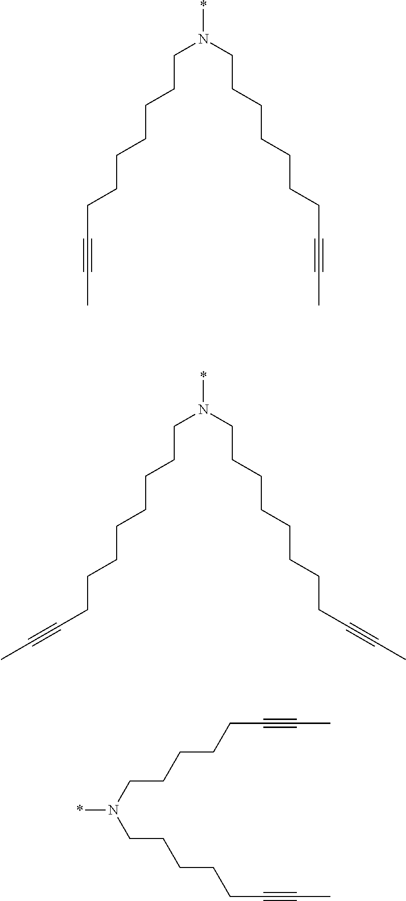 [SMILES: *N(CCCCCCCC#CC)CCCCCCCC#CC ; *N(CCCCCCCCC#CC)CCCCCCCCC#CC ; *N(CCCCCC#CC)CCCCCC#CC]

### (II-3-9)

The “ether bond-containing organic group” in the definition of R in the formula (3) may be a residue of an ether compound represented by R¹¹—O—R¹¹ (R¹¹ independently at each occurrence denotes a C1-C6 alkyl group, such as a methyl group or an ethyl group, an alkylene group, a phenyl group, a phenylene group, a naphthyl group, a naphthylene group, an anthranyl group, or a pyrenyl group). Examples of the ether bond-containing organic groups include those containing a methoxy group, an ethoxy group, or a phenoxy group.

The “ketone bond-containing organic group” in the definition of R in the formula (3) may be a residue of a ketone compound represented by R²¹—C(═O)—R²¹ (R²¹ independently at each occurrence denotes a C1-C6 alkyl group, such as a methyl group or an ethyl group, an alkylene group, a phenyl group, a phenylene group, a naphthyl group, a naphthylene group, an anthranyl group, or a pyrenyl group). Examples of the ketone bond-containing organic groups include those containing an acetoxy group or a benzoyl group.

The “ester bond-containing organic group” in the definition of R in the formula (3) may be a residue of an ester compound represented by R³¹—C(═O)O—R³¹ (R³¹ independently at each occurrence denotes a C1-C6 alkyl group, such as a methyl group or an ethyl group, an alkylene group, a phenyl group, a phenylene group, a naphthyl group, a naphthylene group, an anthranyl group, or a pyrenyl group). Examples of the ester bond-containing organic groups include those containing a methyl ester, an ethyl ester, or a phenyl ester.

### (II-4)

Examples of the thermal acid generators represented by the formula (1) include, but are not limited to, those that appropriately combine at least one of the exemplary counter base cations illustrated below and at least one of the exemplary sulfonate anions illustrated below so that the charges are neutralized.

### (II-4-1: Examples of Counter Base Cations)

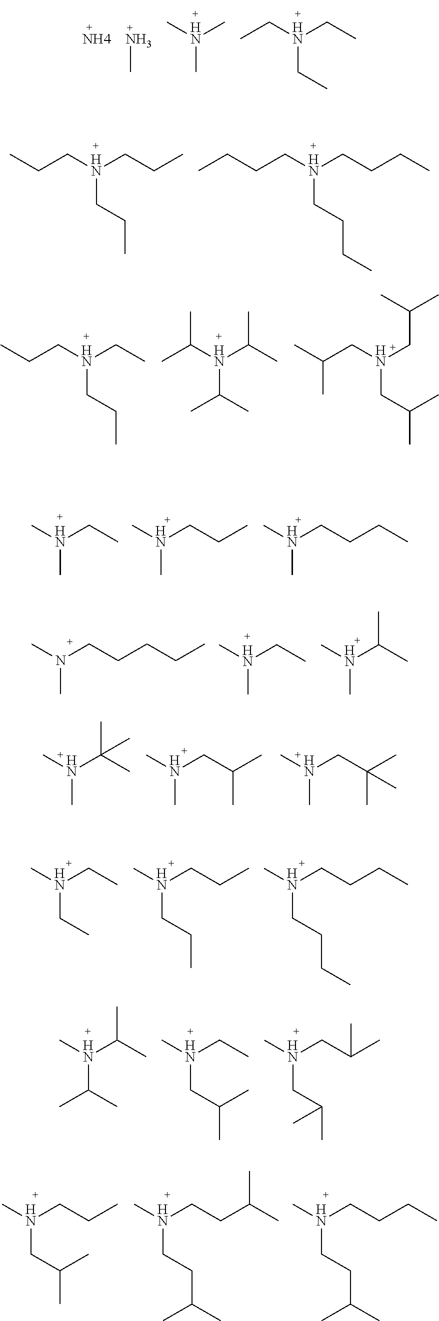

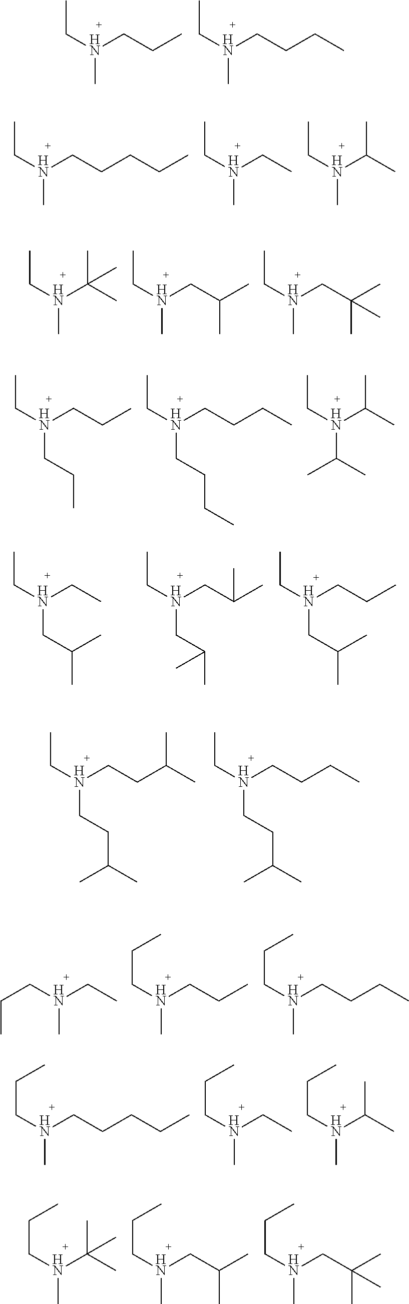

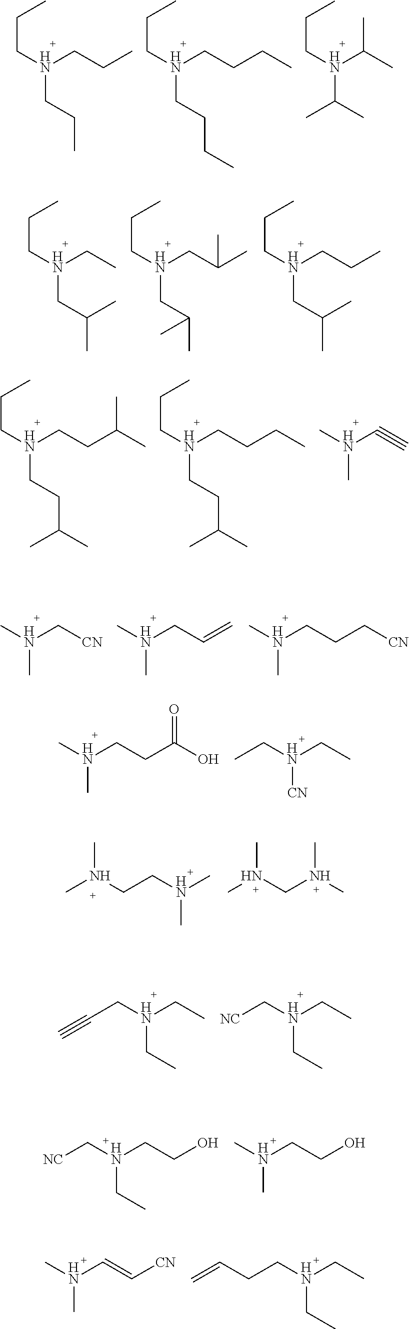

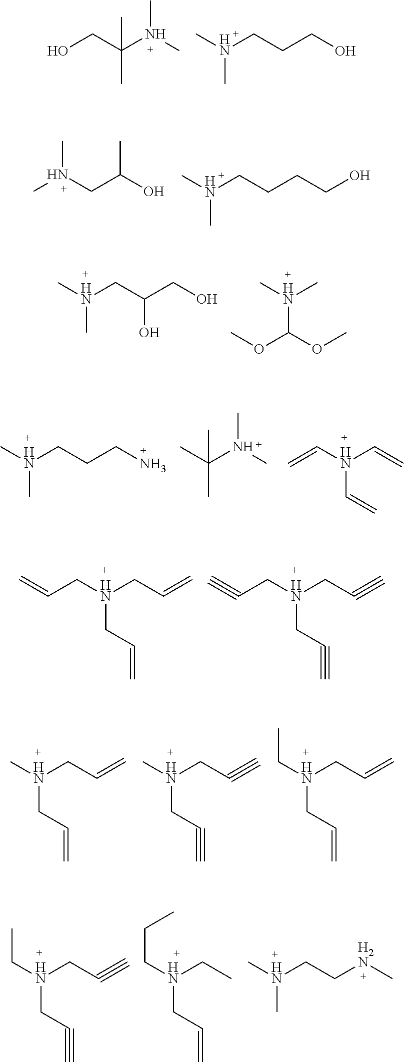

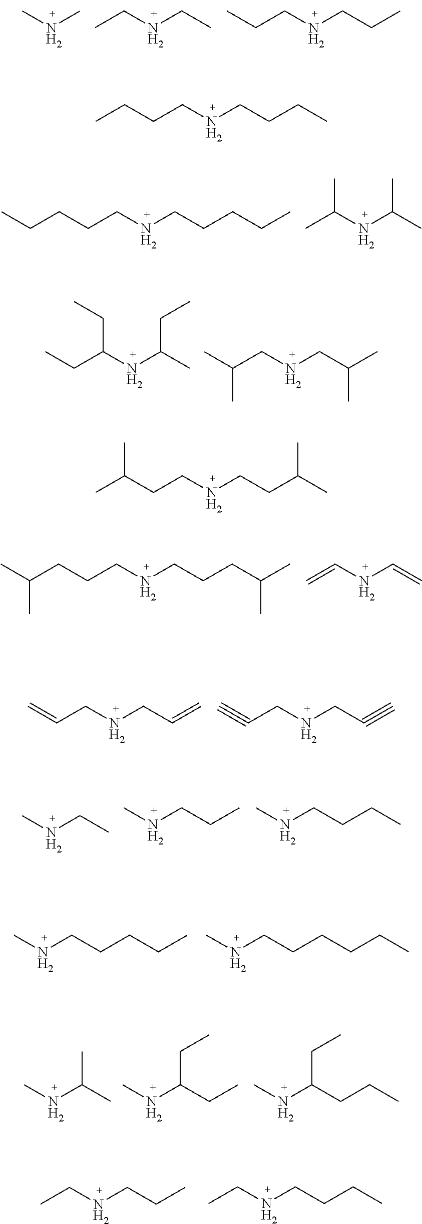

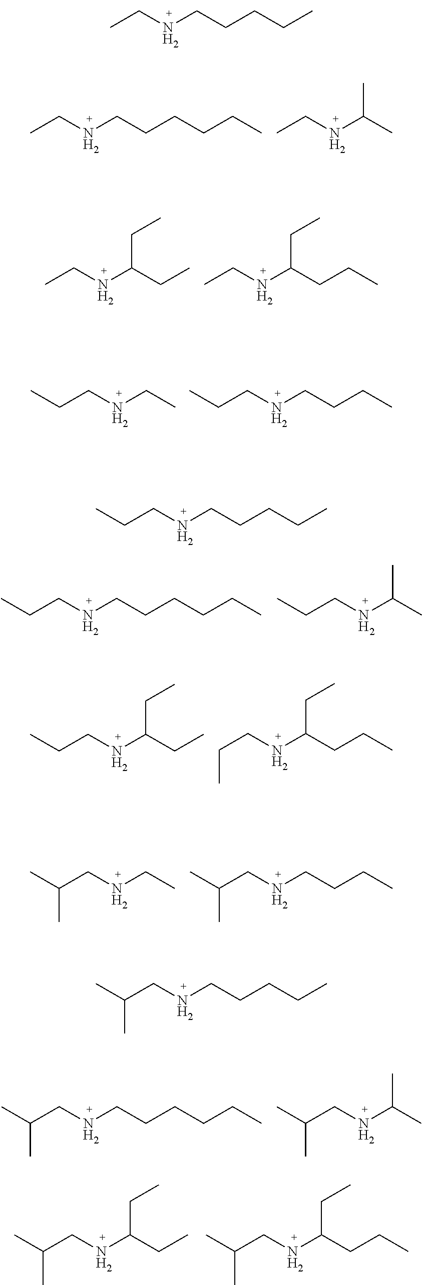

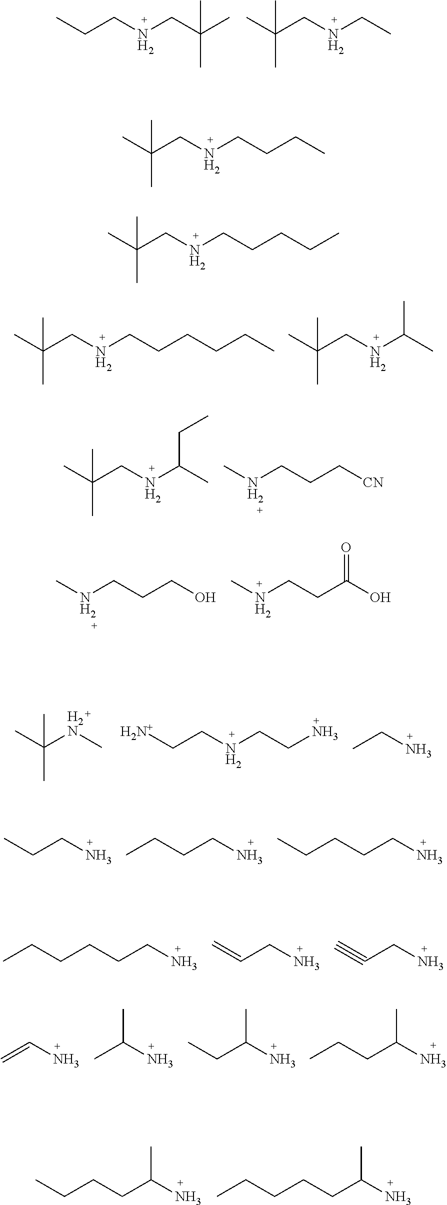

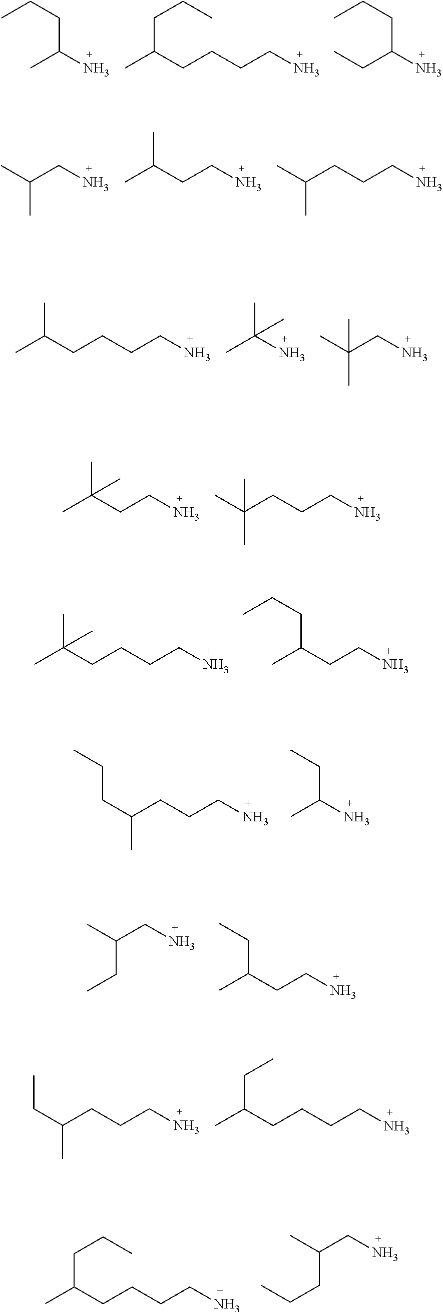

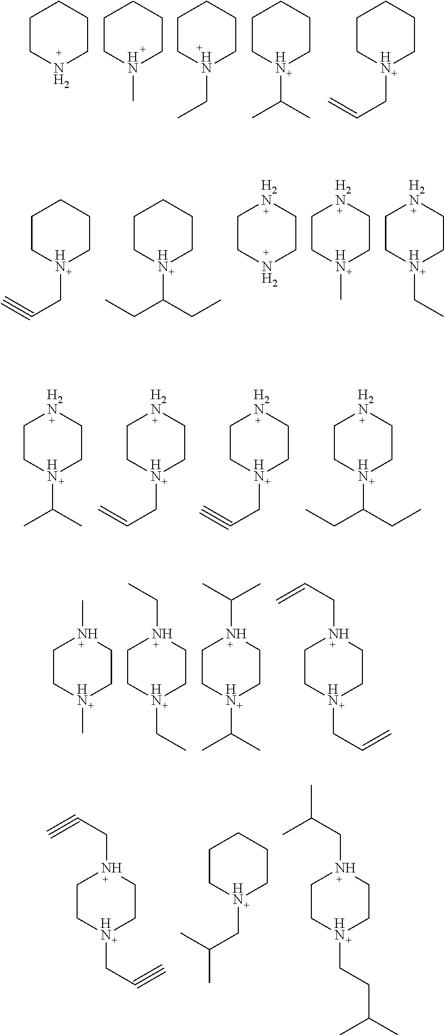

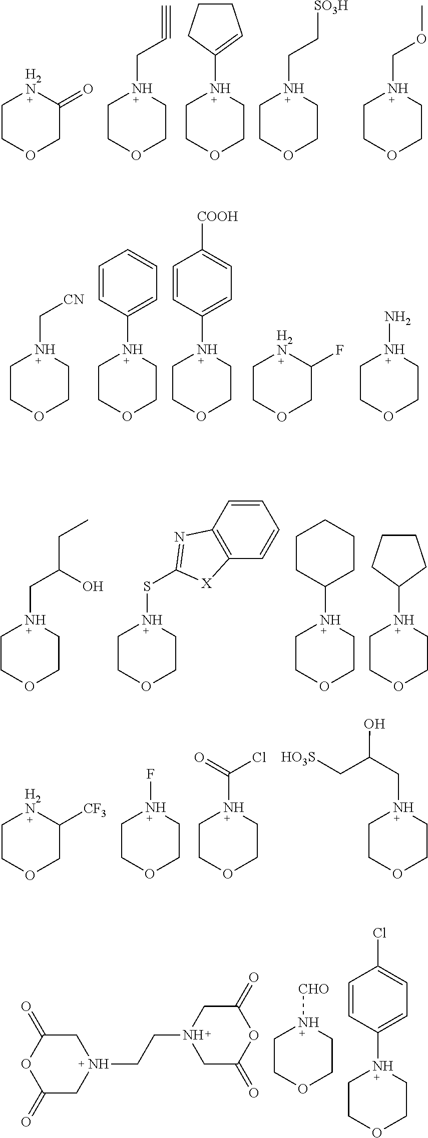

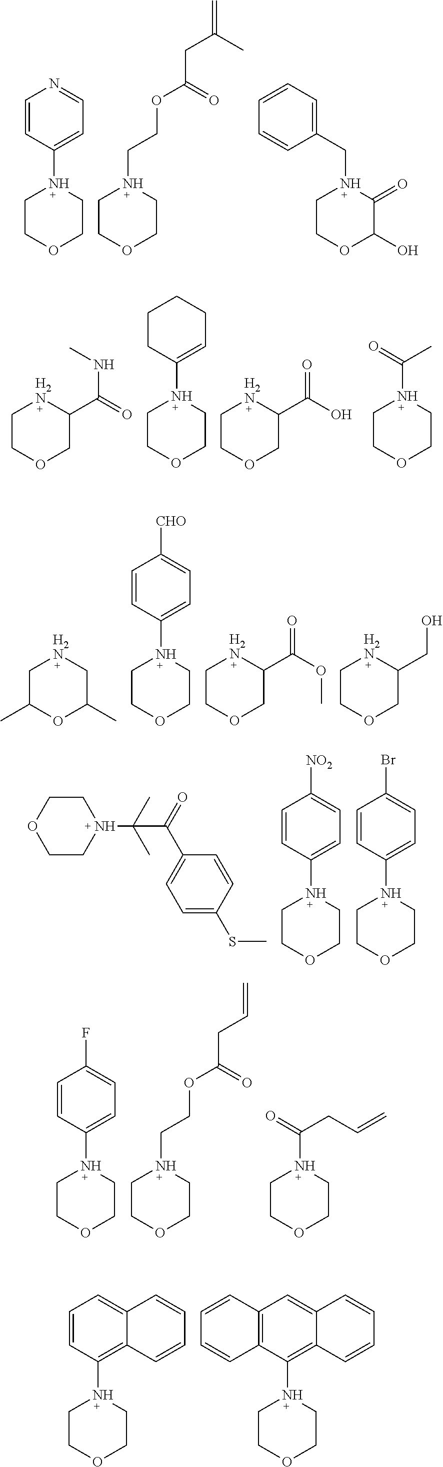

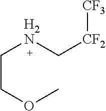

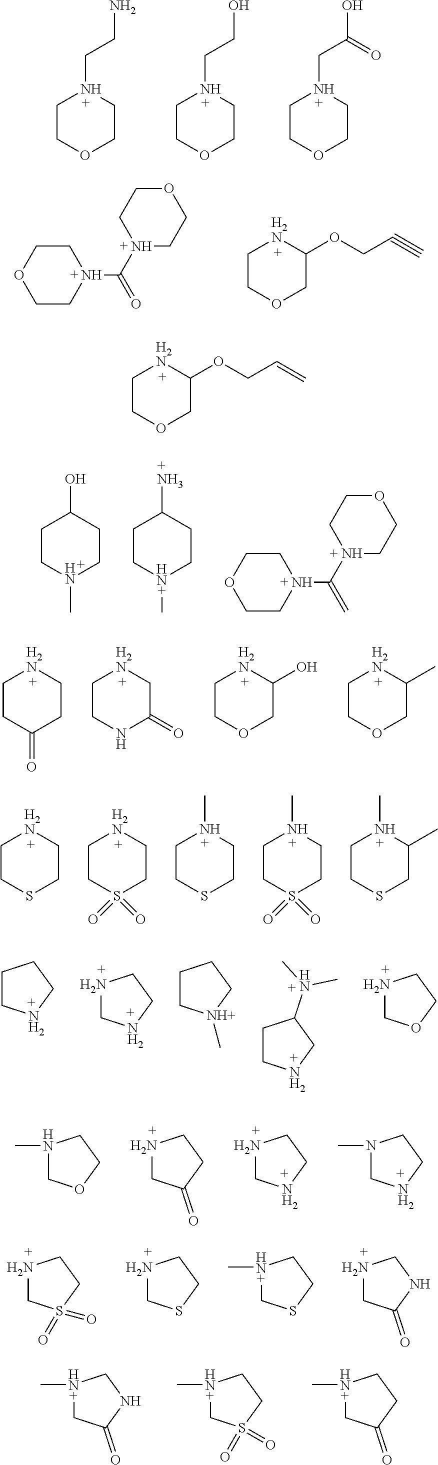

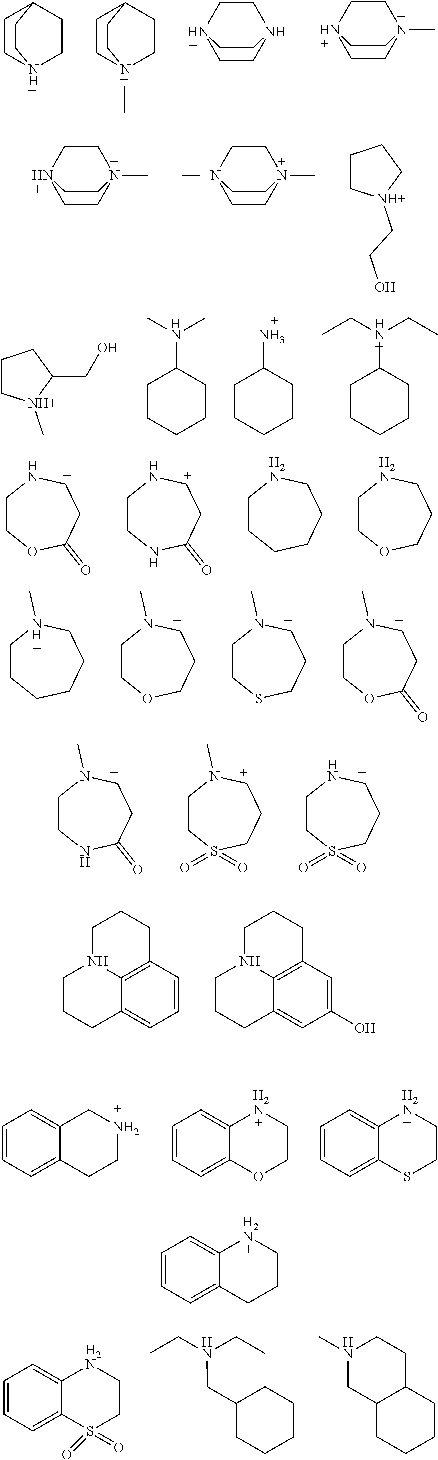

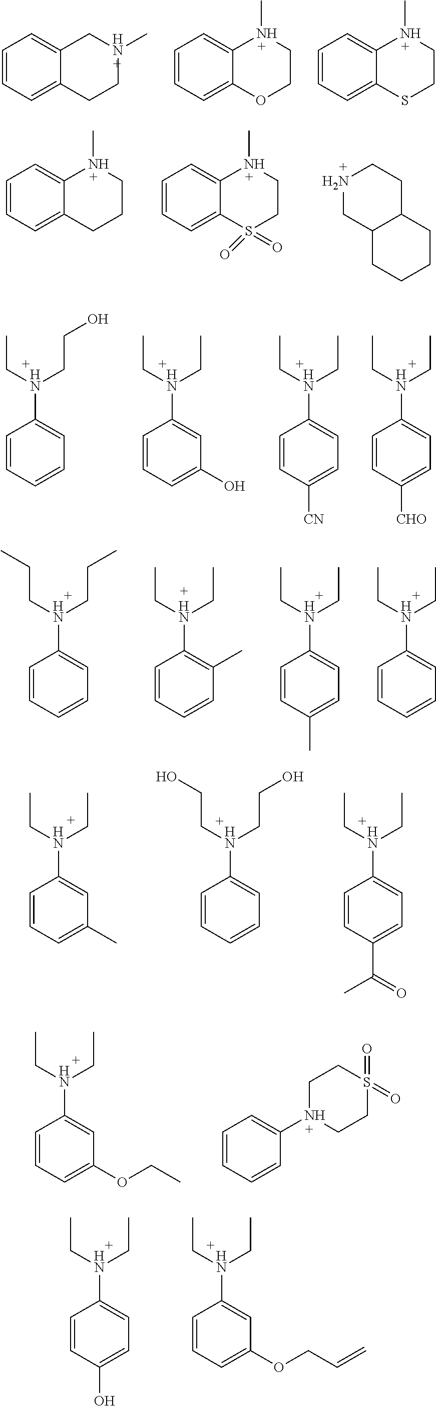

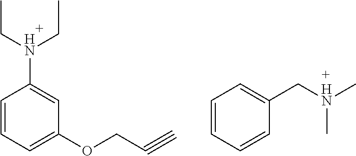

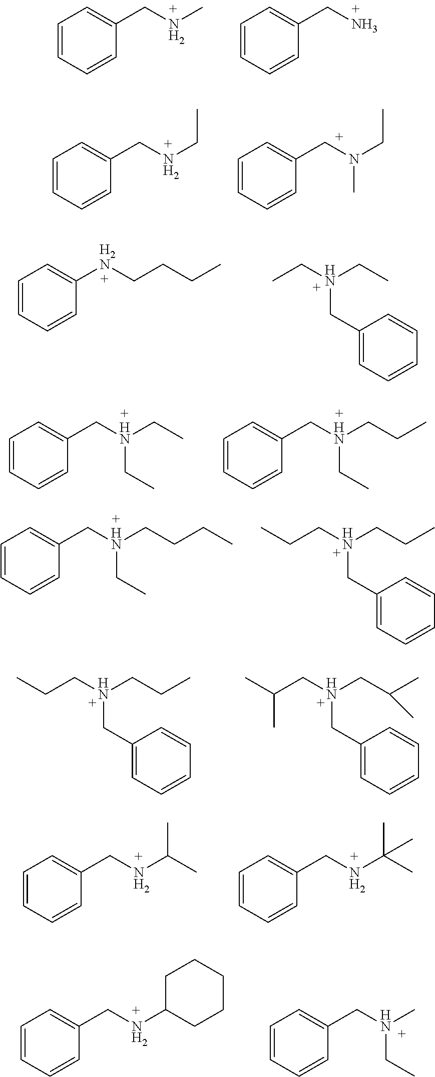

### (II-4-2: Examples of Sulfonate Anions)

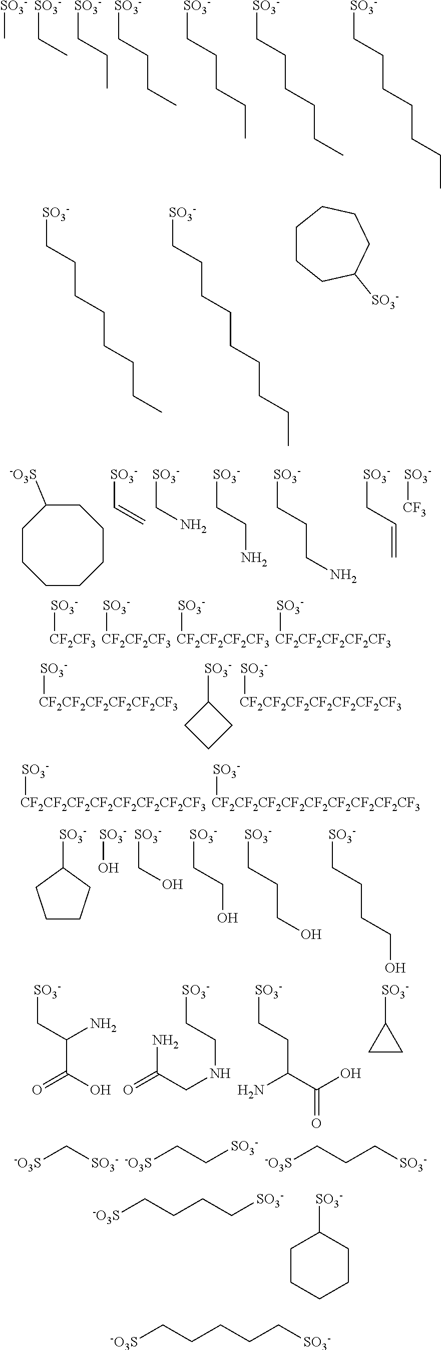

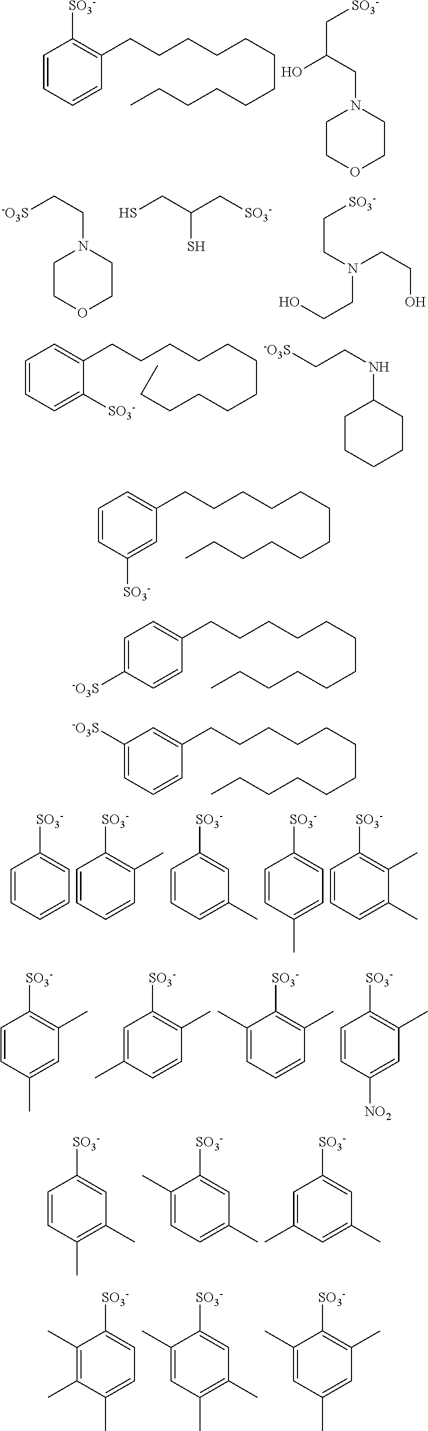

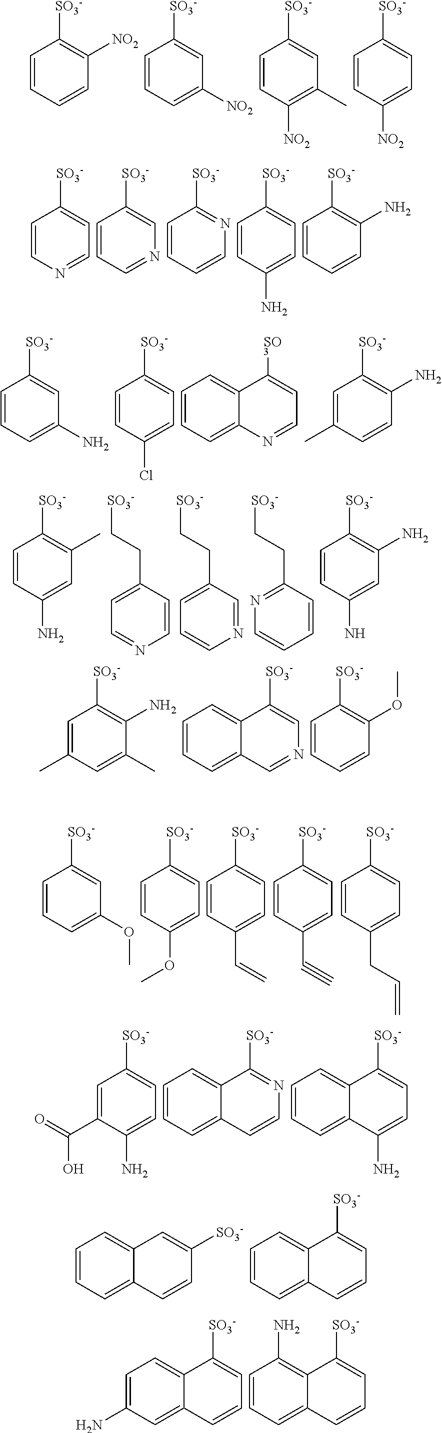

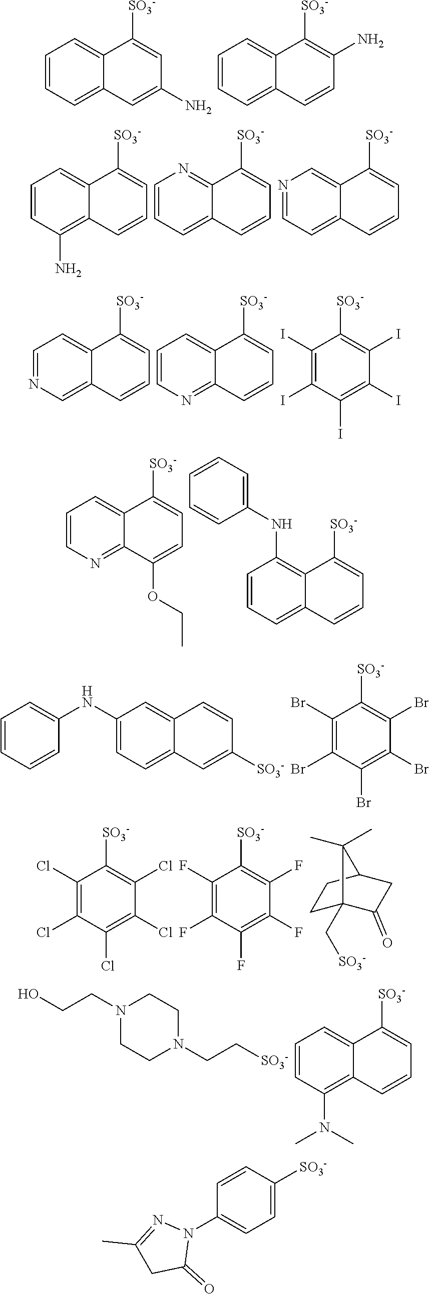

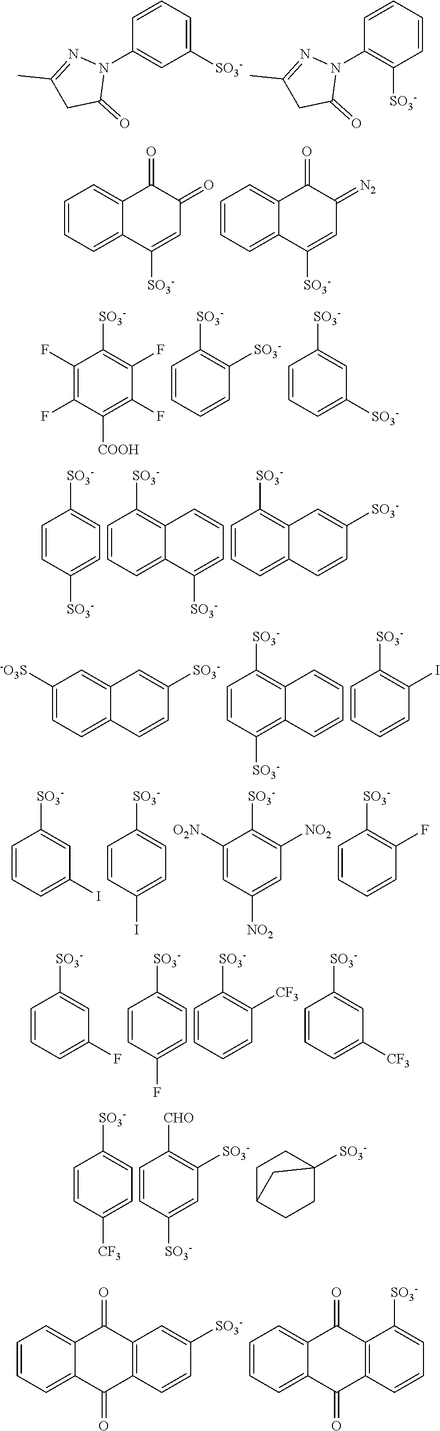

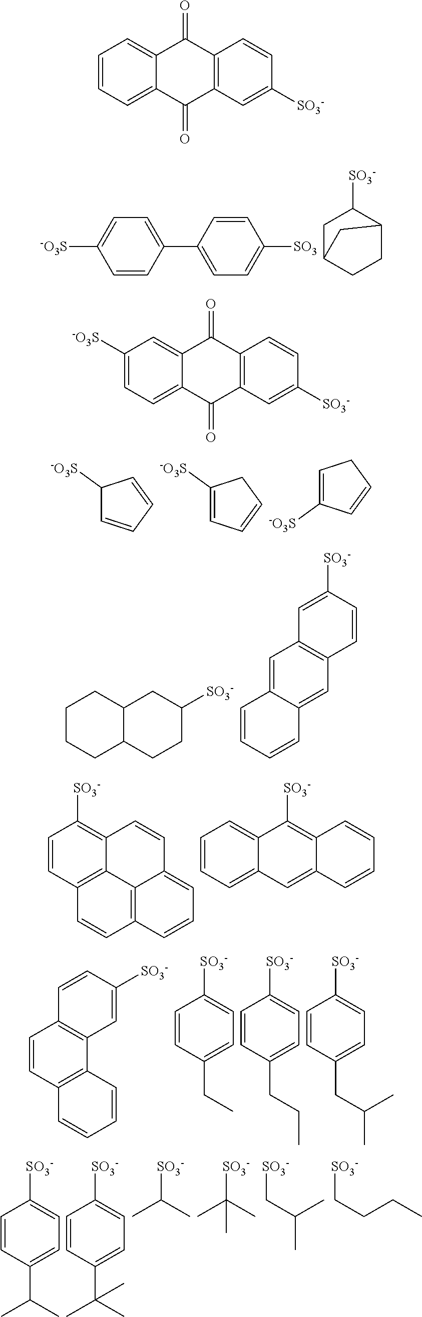

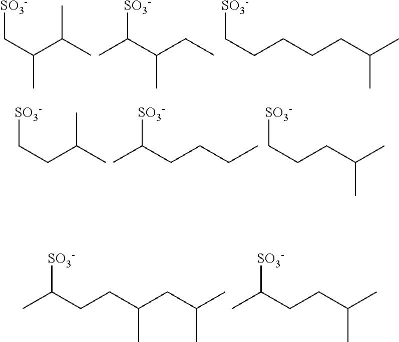

### (II-4-3)

More specific examples of the thermal acid generators include, but are not limited to, the following combinations of a counter base cation and a sulfonate anion.

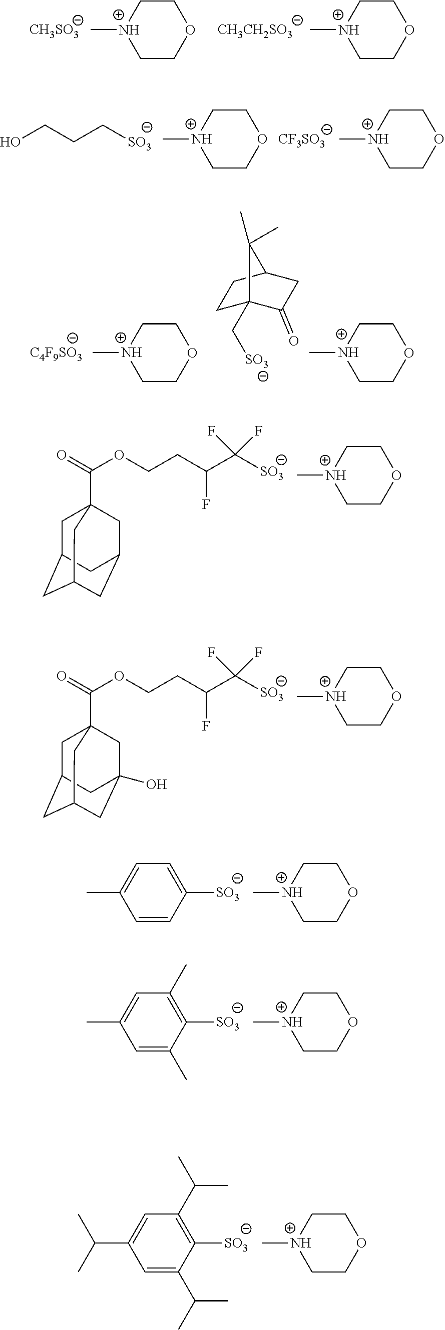

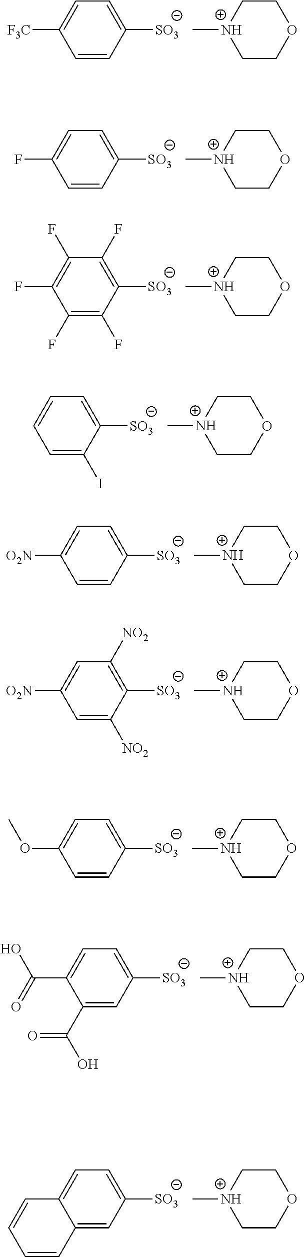

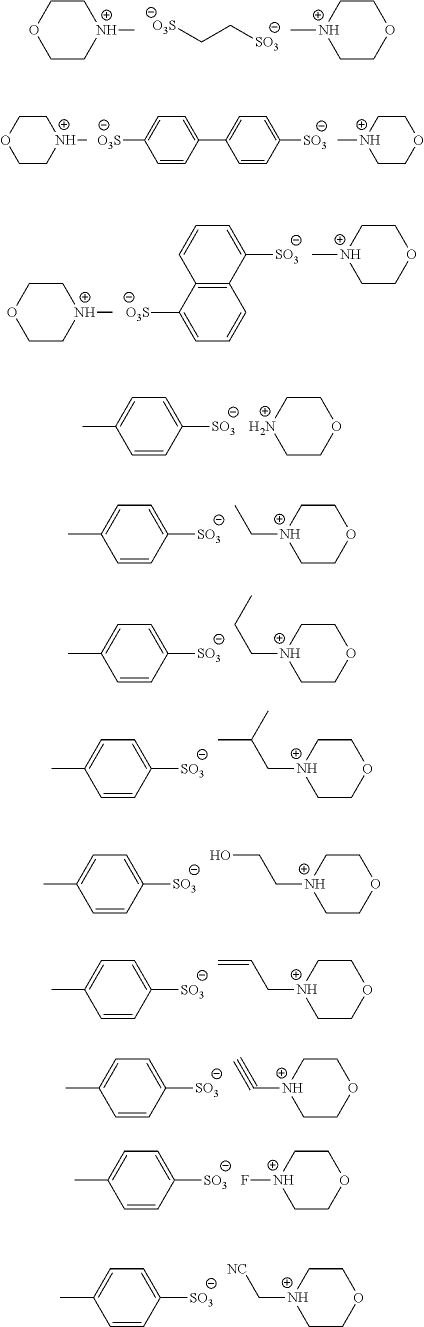

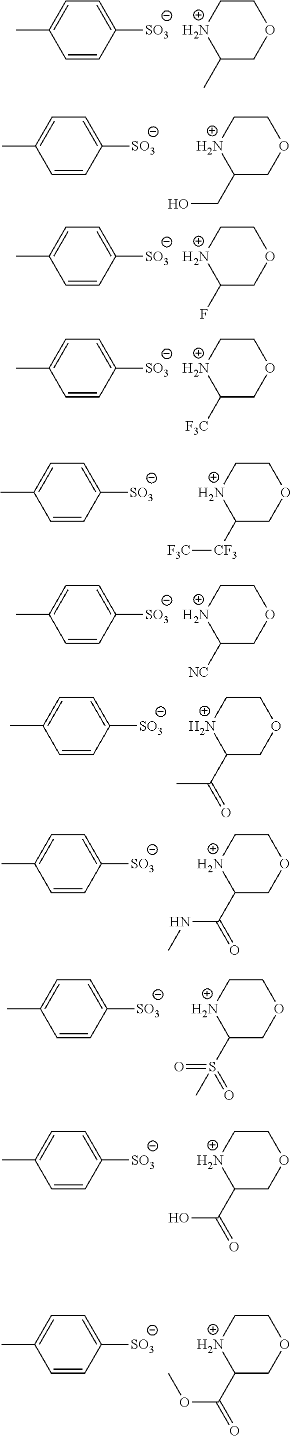

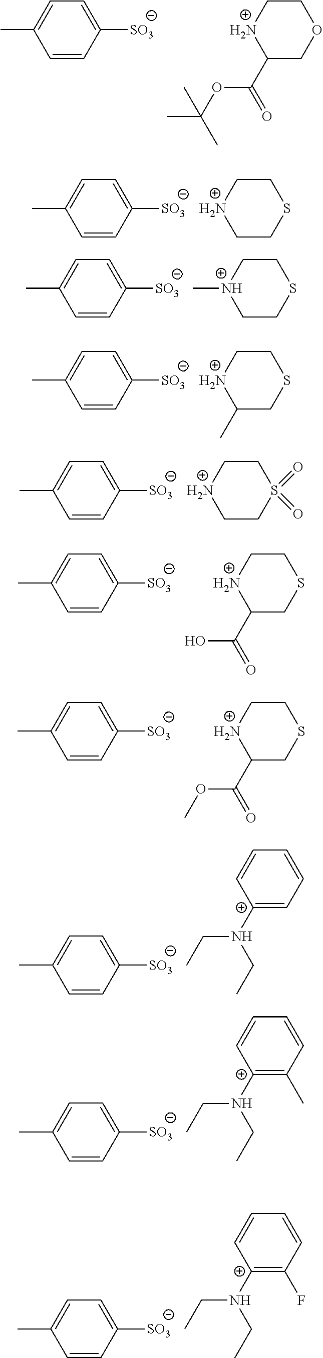

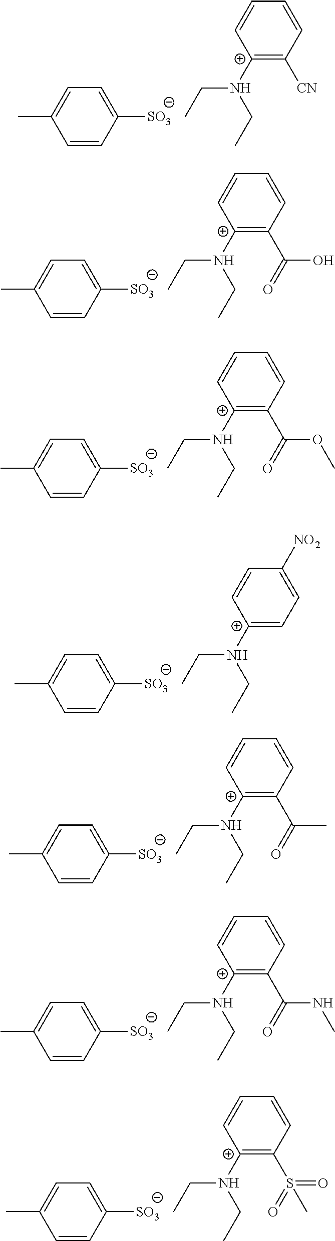

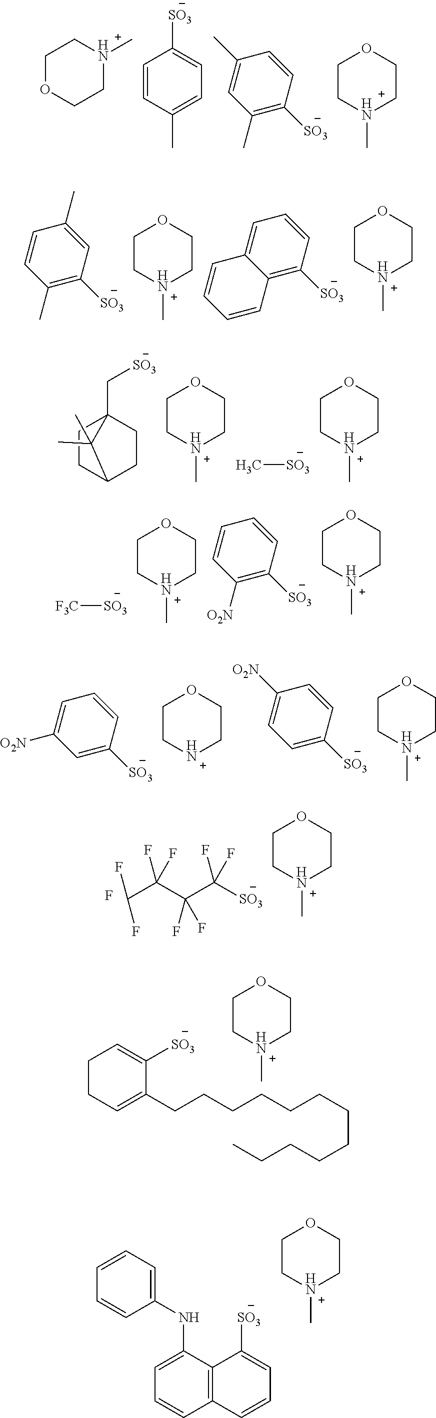

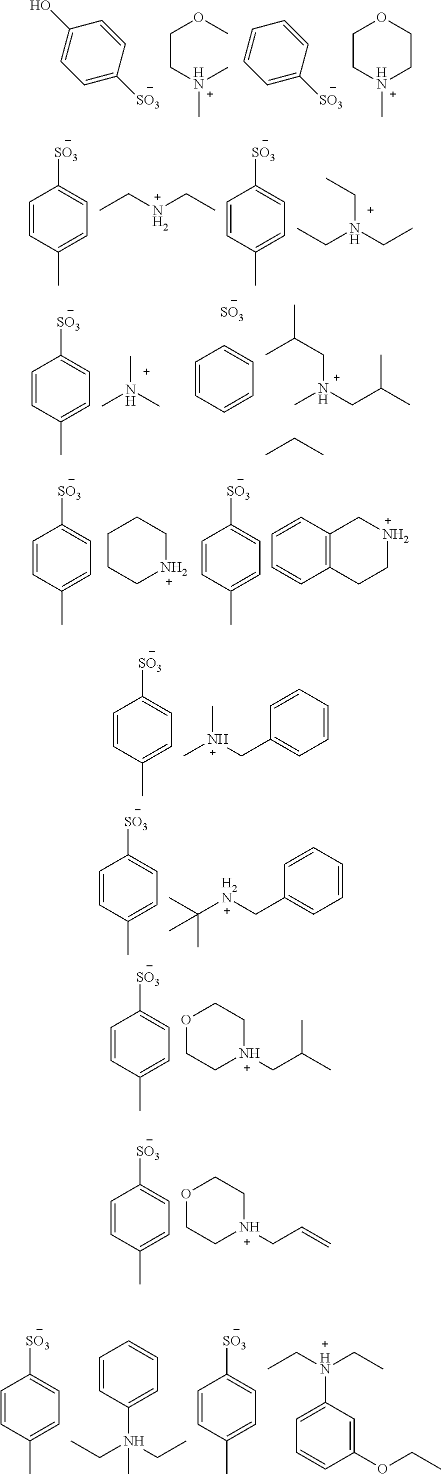

### (II-5)

The amount of the thermal acid generator is 0.0001 to 20 mass %, preferably 0.0005 to 10 mass %, and more preferably 0.01 to 3 mass % based on the total solid content in the resist underlayer film forming composition.

In an embodiment of the thermal acid generator according to the present invention, the thermal decomposition onset temperature, that is, the thermal acid generation temperature is preferably 50° C. or above, more preferably 100° C. or above, and still more preferably 150° C. or above, and is preferably 400° C. or below.

### [III. Aromatic Ring-Containing Polymers]

### (III-1)

The aromatic ring-containing polymer is not particularly limited. For example, the polymer may be at least one selected from the group consisting of polyvinyl alcohols, polyacrylamides, (meth)acrylic resins, polyamide acids, polyhydroxystyrenes, polyhydroxystyrene derivatives, polymethacrylate-maleic anhydride copolymers, epoxy resins, phenolic resins, novolac resins, resol resins, maleimide resins, polyether ether ketone resins, polyether ketone resins, polyether sulfone resins, polyketone resins, polyester resins, polyether resins, urea resins, polyamides, polyimides, celluloses, cellulose derivatives, starches, chitins, chitosans, gelatins, zeins, sugar-skeleton polymer compounds, polyethylene terephthalates, polycarbonates, polyurethanes, and polysiloxanes, each of these having an aromatic ring. These resins are used singly, or two or more are used in combination.

### (III-2)

### (III-2-1)

The aromatic ring-containing polymer is preferably a novolac resin.

The “novolac resin” in the present specification has already been described in (I-1) of [I. Definition of terms].

### (III-2-2)

More preferably, the aromatic ring-containing polymer is a novolac resin containing a unit structure having an optionally substituted aromatic ring, and

(i)
the aromatic ring contains a heteroatom in a substituent on the aromatic ring,
   (ii)
the unit structure contains a plurality of aromatic rings, at least two of the aromatic rings are connected to one another via a linking group, and the linking group contains a heteroatom, or
   (iii)
the aromatic ring is an aromatic heterocyclic ring or an aromatic ring forming a condensed ring with one or more heterocyclic rings.

These aromatic rings (i) to (iii) correspond to the unit structures A in the novolac resin described in (I-1).

The aromatic rings are as described in (I-3) hereinabove, and the heterocyclic rings are as described in (I-4) hereinabove.

More preferably, the unit structure of (i) or (ii) has at least one, more preferably two aromatic rings each having an oxygen-containing substituent, or has a plurality of aromatic rings connected to one another by at least one-NH—, respectively.

Examples of the oxygen-containing substituents include hydroxyl groups; hydroxyl groups substituted with a saturated or unsaturated, linear, branched, or cyclic hydrocarbon group in place of a hydrogen atom (namely, alkoxy groups); and saturated or unsaturated, linear, branched, or cyclic hydrocarbon groups and aromatic ring residues each interrupted with an oxygen atom one or more times.

### (III-2-3)

More preferably, the aromatic ring-containing polymer has:
(i) one, or two or more kinds of unit structures having an optionally substituted aromatic ring, and
(ii) a unit structure that includes an optionally substituted 4- to 12-membered monocyclic, bicyclic, tricyclic, or tetracyclic organic group in which:
   the monocyclic ring is a non-aromatic monocyclic ring, and
   at least one of the monocyclic rings constituting the bicyclic, tricyclic, or tetracyclic ring is a non-aromatic monocyclic ring, and the remaining monocyclic ring or rings are optionally aromatic monocyclic rings or non-aromatic monocyclic rings. For example, the unit structures may be in the form of dimer or trimer in which two or three identical or differing organic groups are connected to one another via a divalent or trivalent linking group.

The monocyclic, bicyclic, tricyclic, or tetracyclic organic group may be further condensed with one or more aromatic rings to form a pentacyclic or higher cyclic ring.

In the novolac resin, the unit structures (i) and (ii) are bonded to one another at least by a covalent bond of a carbon atom (a linking carbon atom) on any of the non-aromatic monocyclic rings in (ii) with a carbon atom on the aromatic ring in (i). That is, the unit structure (i) corresponds to the unit structure A of the novolac resin described in (I-1), and the monocyclic, bicyclic, tricyclic, or tetracyclic organic group in (ii) corresponds to the unit structure B of the novolac resin described in (I-1).

Here, typical examples of (ii) include unit structures in which a keto group in a cyclic ketone is substituted with two valence bonds; and unit structures in which an organic group is added to a keto group in a cyclic ketone to convert the ketone into a tertiary alcohol, and the tertiary hydroxyl group is substituted with one valence bond.

When the unit structure (ii) contains an aromatic ring, the aromatic ring may be bonded to each of the linking carbon atoms in the other two unit structures (ii). The unit structure resulting from this manner of bonding may be used as a type of the unit structure (i), specifically, as the unit structure A.

When the unit structure (ii) contains an aromatic ring X, the linking carbon atom in the unit structure (ii) may be bonded to an aromatic ring Y in the unit structure (i), and further the aromatic ring X in the unit structure (ii) may be bonded to the linking carbon atom in the other unit structure (ii). The unit structure resulting from this manner of bonding is equivalent to a composite unit structure consisting of one unit structure (i) and one unit structure (ii) and may be used in place of at least part of the composite unit structures. Such a unit structure corresponds to the unit structure C of the novolac resin described in (I-1).

### (III-3) Novolac Resins Containing Composite Unit Structures A-B

The novolac resin preferably includes composite unit structures A-B represented by formula (AB) below:

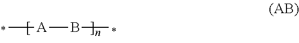

In the formula (AB), n indicates the number of composite unit structures A-B.

The unit structures A are one, or two or more kinds of unit structures having an optionally substituted aromatic ring, and are optionally such that the aromatic ring is substituted with a substituent containing a heteroatom; the unit structure includes a plurality of aromatic rings, the aromatic rings are connected to one another via a linking group, and the linking group contains a heteroatom; or the aromatic ring is an aromatic heterocyclic ring or is an aromatic ring forming a condensed ring with one or more heterocyclic rings.

The unit structures B are one, or two or more kinds of unit structures containing a linking carbon atom capable of bonding to the aromatic ring in the unit structure A [see (I-1) “Novolac resins”] and include a structure represented by formula (B1), (B2), or (B3) described later in (III-3-B10) to (III-3-B14), in (III-3-B20) to (III-3-B23), and in (III-3-B30) to (III-3-B35), respectively. For example, the unit structure may be such that two or three identical or differing structures represented by the above formulas are connected to one another via a divalent or trivalent linking group. The unit structure B may connect two unit structures A by covalently bonding to a carbon atom on the aromatic ring of the unit structure A.

At least one composite unit structure A-B may be replaced with a single equivalent unit structure, that is, one, or two or more kinds of unit structures C including structures represented by formulas (C1), (C2), and (C3) and (C4) described later in (III-3-B13), (III-3-B22), and (III-3-B34), respectively.

### (III-3-A0) Unit Structures A

As already described in (I-3), the concept of the “aromatic rings” in the unit structures A comprehends not only aromatic hydrocarbon rings but also aromatic heterocyclic rings and includes not only monocyclic rings but also polycyclic rings. In the case of polycyclic rings, at least one monocyclic ring is an aromatic monocyclic ring, but the remaining monocyclic ring or rings may be heteromonocyclic rings or alicyclic monocyclic rings. Furthermore, reference may be made to the description of the aromatic rings in (I-3) hereinabove and the description of the heterocyclic rings in (I-4) hereinabove.

The aromatic rings may be organic groups that have a structure in which two or more aromatic rings are connected to one another by a linking group, such as an alkylene group.

The “aromatic ring” in the unit structure A preferably has 6 to 30 or 6 to 24 carbon atoms.

Preferably, the “aromatic ring” in the unit structure A is one or more benzene, naphthalene, anthracene, or pyrene rings; or is a condensed ring formed between a benzene ring, a naphthalene ring, an anthracene ring, or a pyrene ring and a heterocyclic ring or an aliphatic ring.

The aromatic ring in the unit structure A may be optionally substituted, and the substituent preferably contains a heteroatom.

The aromatic ring in the unit structure A may include two or more aromatic rings connected to one another by a linking group, and the linking group preferably contains a heteroatom.

Examples of the heteroatoms include oxygen atom, nitrogen atom, and sulfur atom.

Preferably, the “aromatic ring” in the unit structure A is a C6-C30 or C6-C24 organic group that contains at least one heteroatom selected from N, S, and O on the ring, within the ring, or between the rings.

Examples of the heteroatoms contained on the ring include nitrogen atom contained in amino groups (for example, propargylamino group) and in the cyano group; oxygen atom contained in oxygen-containing substituents, such as formyl group, hydroxyl group, carboxyl group, and alkoxy groups (for example, propargyloxy group); and nitrogen atom and oxygen atom contained in the nitro group that is an oxygen-containing and nitrogen-containing substituent.

Examples of the heteroatoms contained within the ring include oxygen atom contained in xanthene and nitrogen atom contained in carbazole.

Examples of the heteroatoms contained in the linking group between two or more aromatic rings include nitrogen atom, oxygen atom, and sulfur atom contained in —NH— bond, —NHCO— bond, —O— bond, —COO— bond, —CO— bond, —S— bond, —SS— bond, and —SO₂— bond.

Preferably, the unit structure A is a unit structure that has an aromatic ring having an oxygen-containing substituent described above, a unit structure that has two or more aromatic rings connected to one another by —NH—, or a unit structure that has a condensed ring formed between one or more aromatic hydrocarbon rings and one or more heterocyclic rings.

### (III-3-A1)

Preferably, the unit structures A are at least one kind of unit structures selected from the following:

### (Examples of Amine Skeletons)

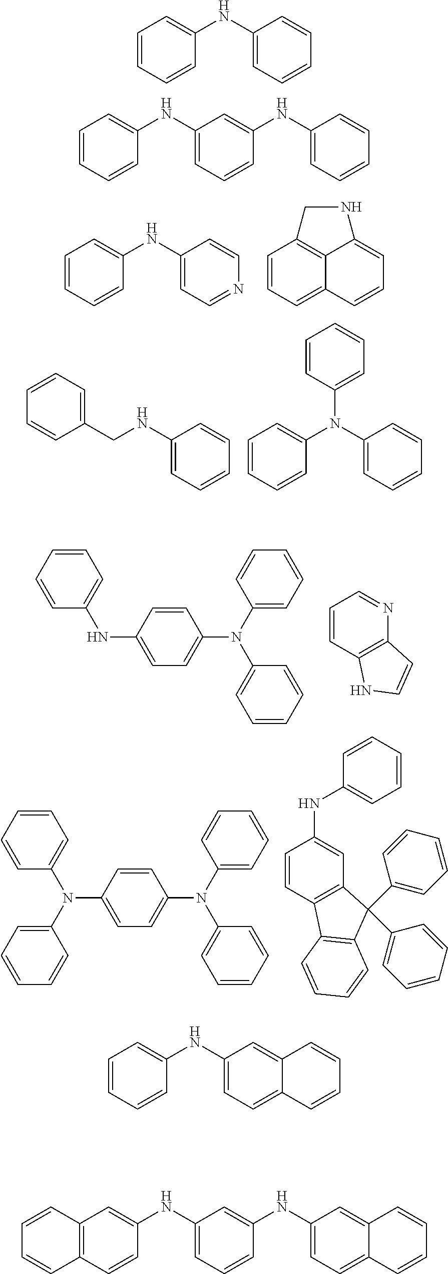

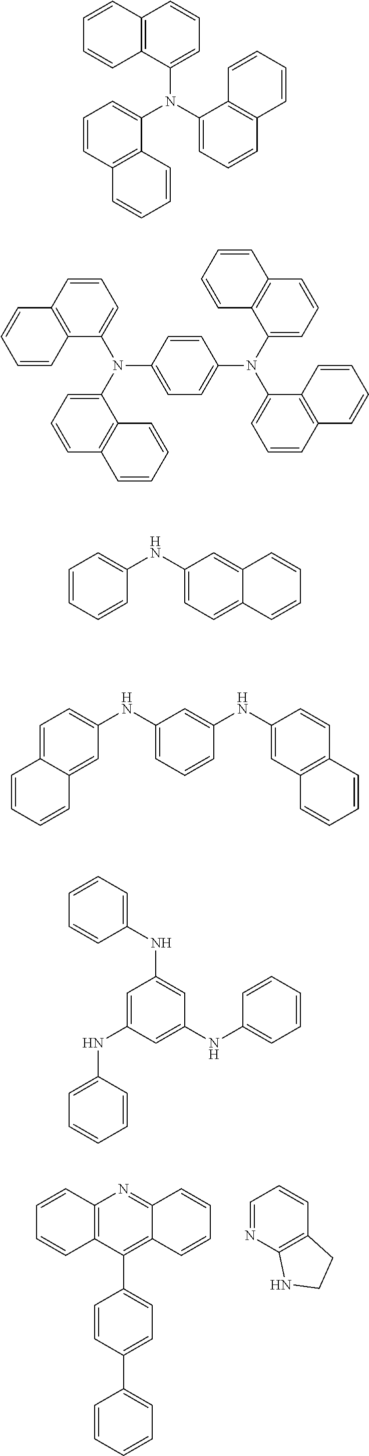

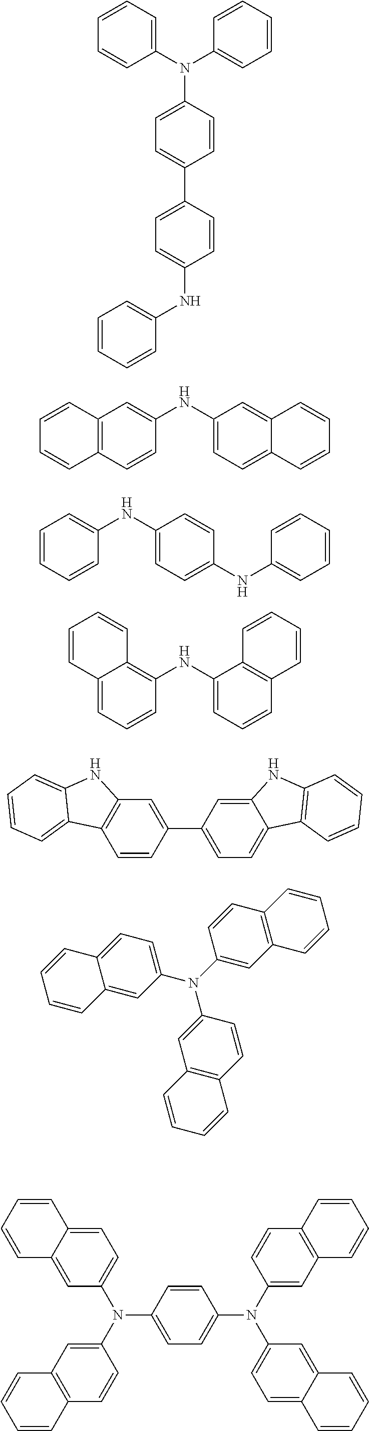

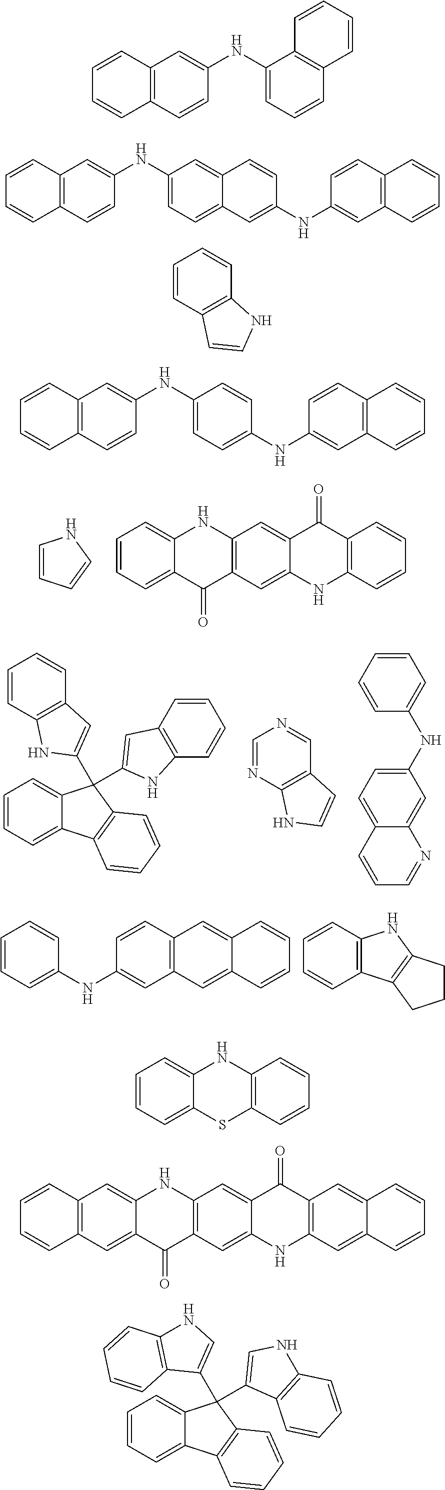

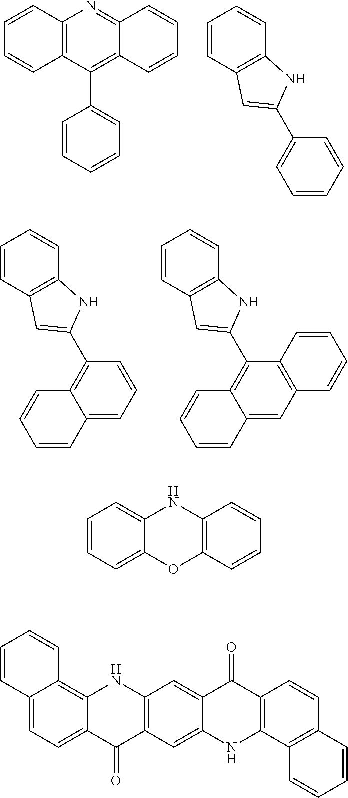

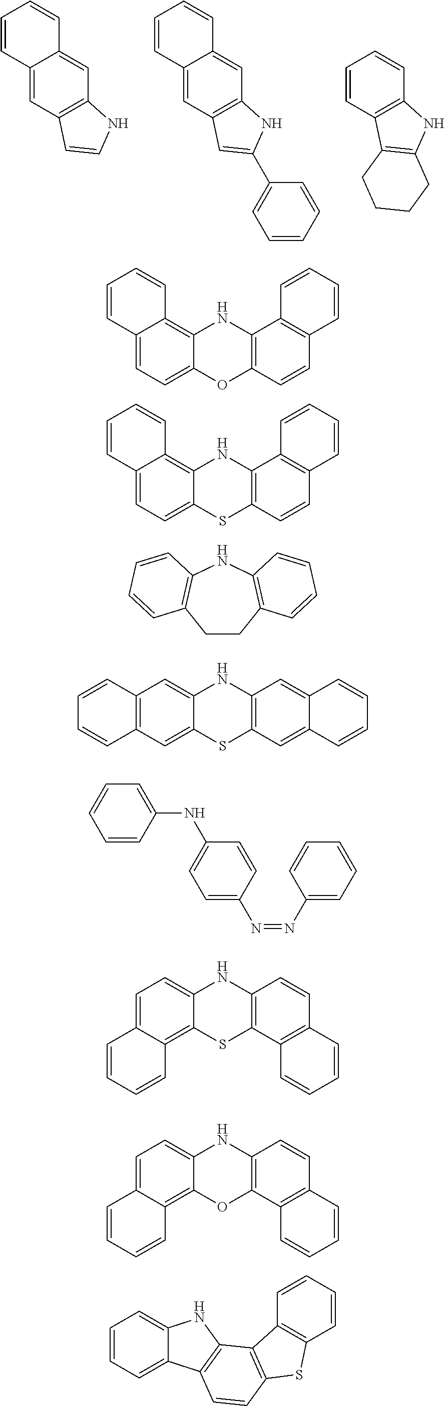

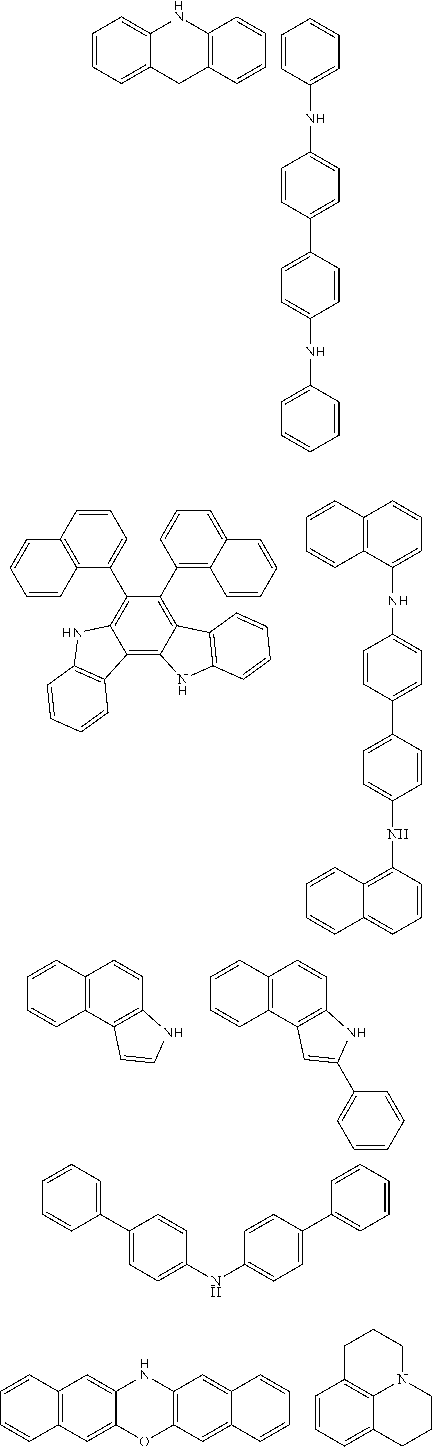

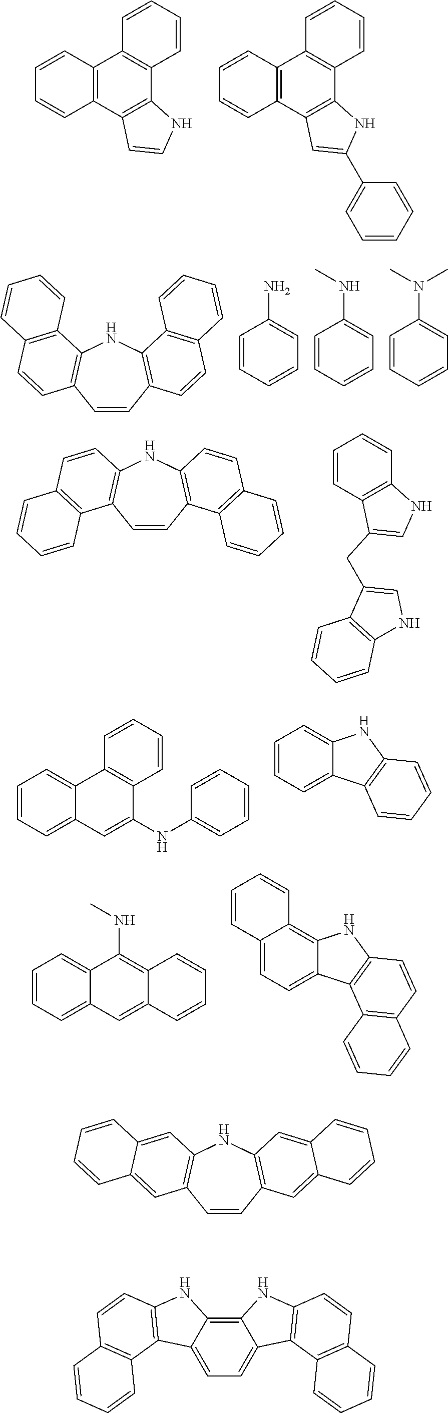

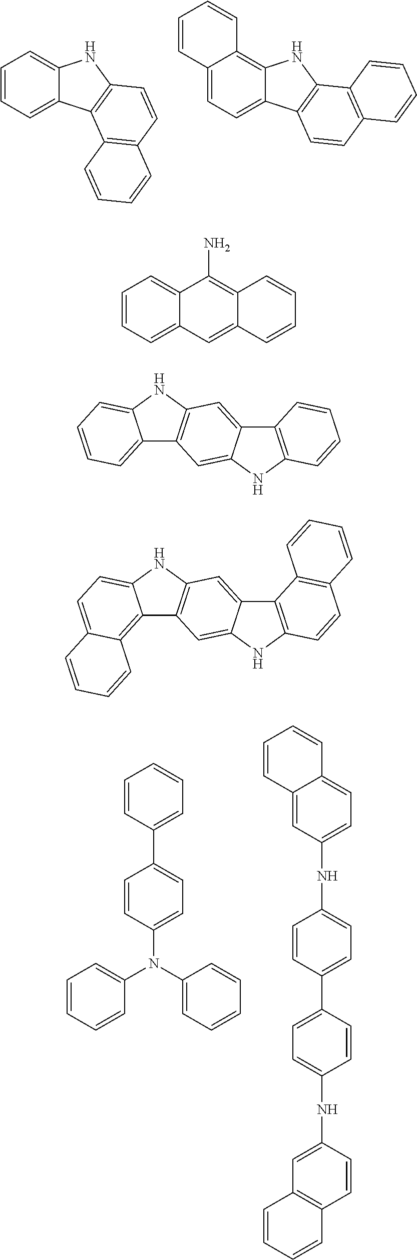

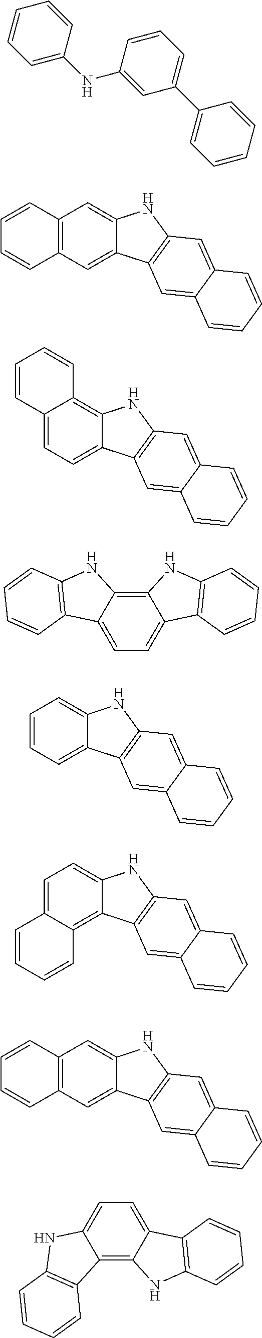

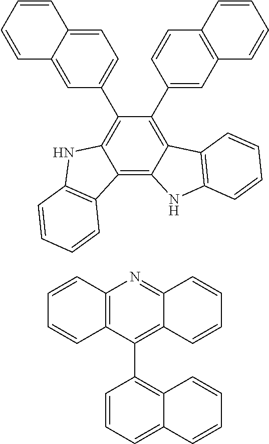

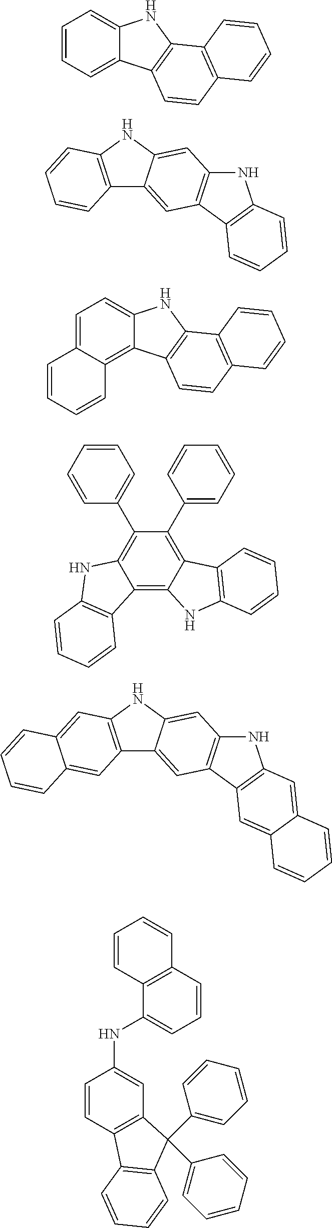

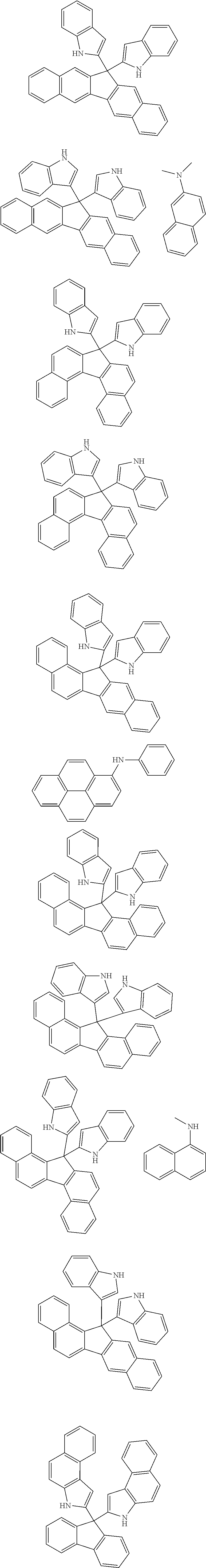

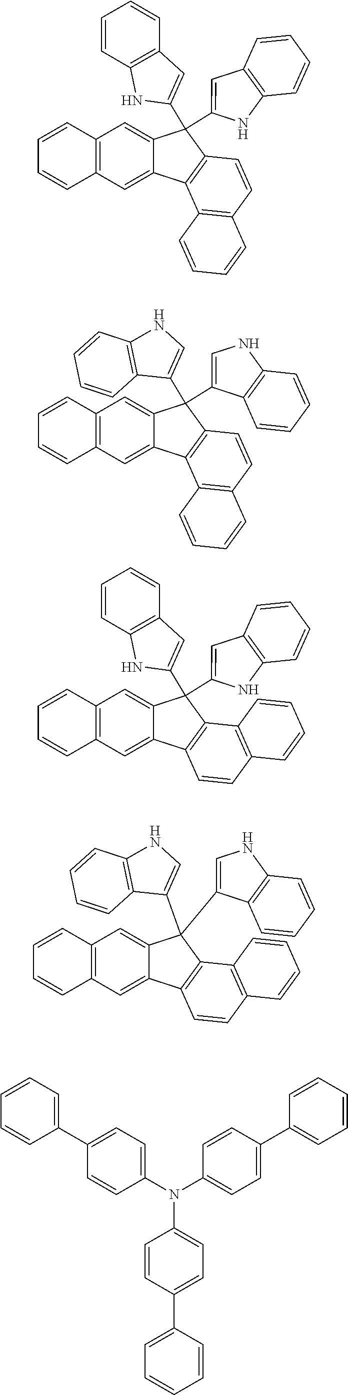 [SMILES: c1ccc2cc3c(cc2c1)-c1c(ccc2ccccc12)C3(c1cc2ccccc2[nH]1)c1cc2ccccc2[nH]1 ; c1ccc2cc3c(cc2c1)-c1c(ccc2ccccc12)C3(c1c[nH]c2ccccc12)c1c[nH]c2ccccc12 ; c1ccc2cc3c(cc2c1)-c1ccc2ccccc2c1C3(c1cc2ccccc2[nH]1)c1cc2ccccc2[nH]1 ; c1ccc2cc3c(cc2c1)-c1ccc2ccccc2c1C3(c1c[nH]c2ccccc12)c1c[nH]c2ccccc12 ; c1ccc(-c2ccc(N(c3ccc(-c4ccccc4)cc3)c3ccc(-c4ccccc4)cc3)cc2)cc1]

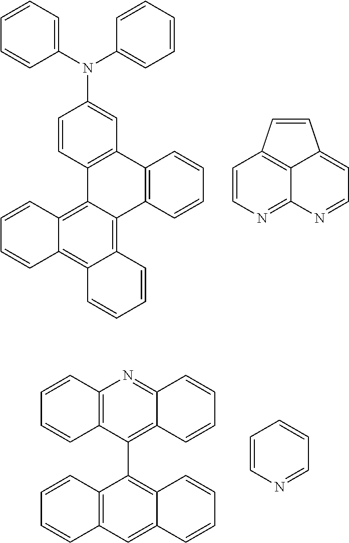

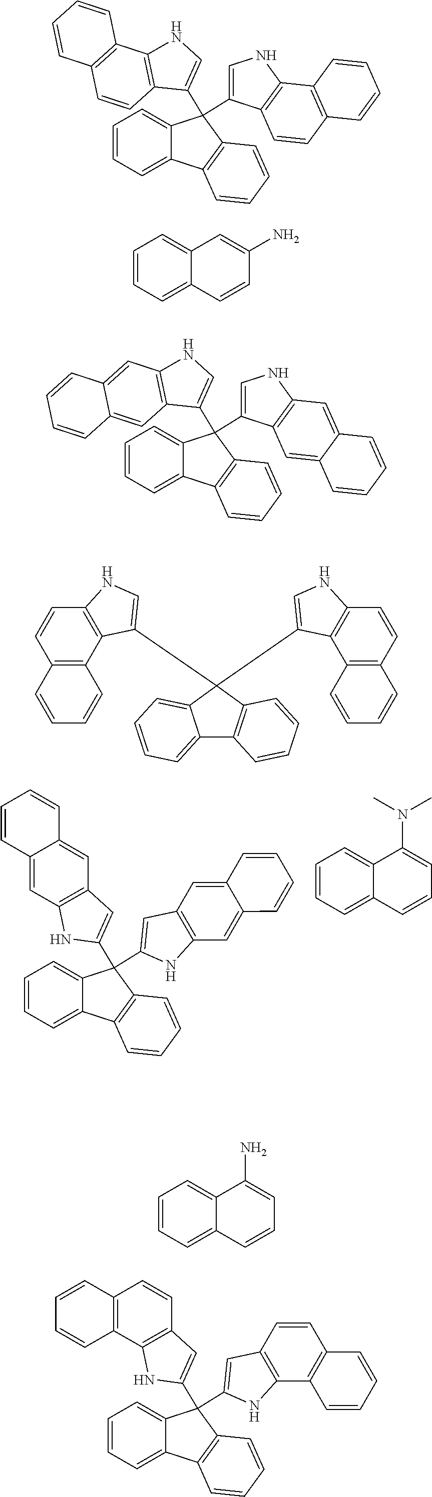

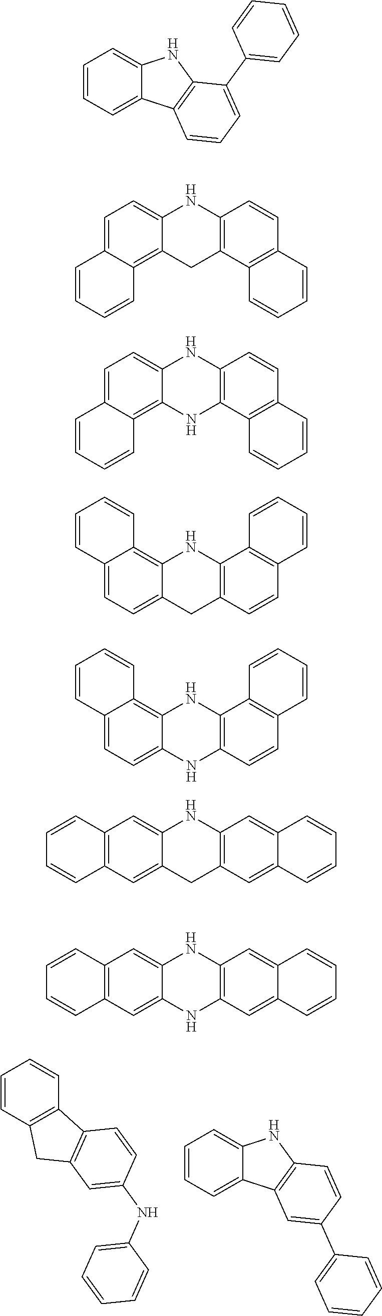

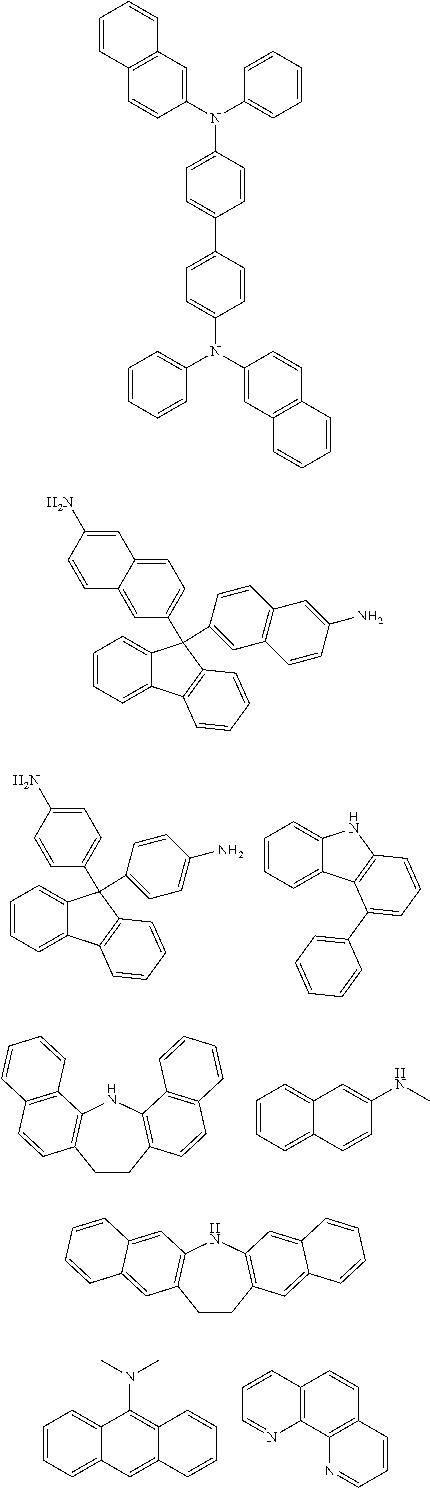

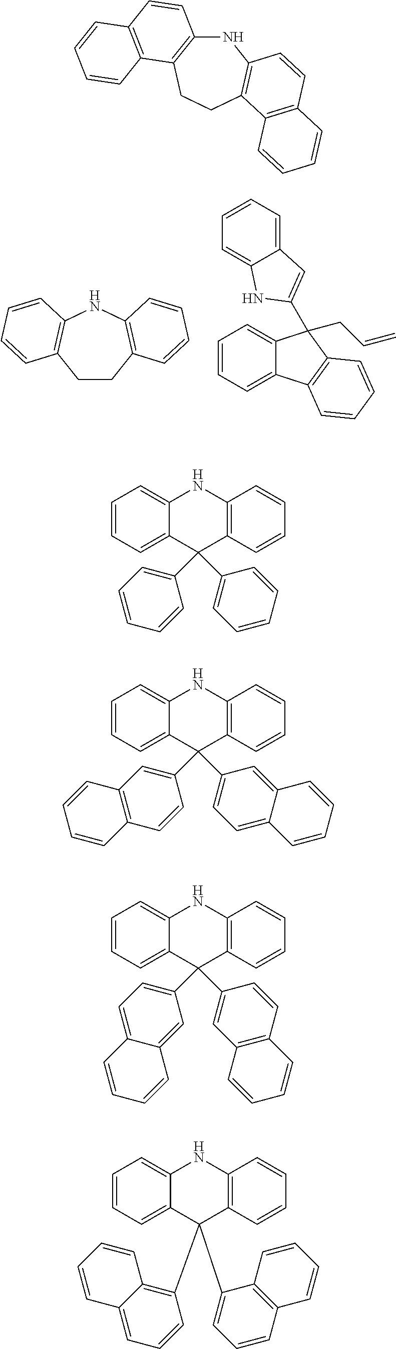

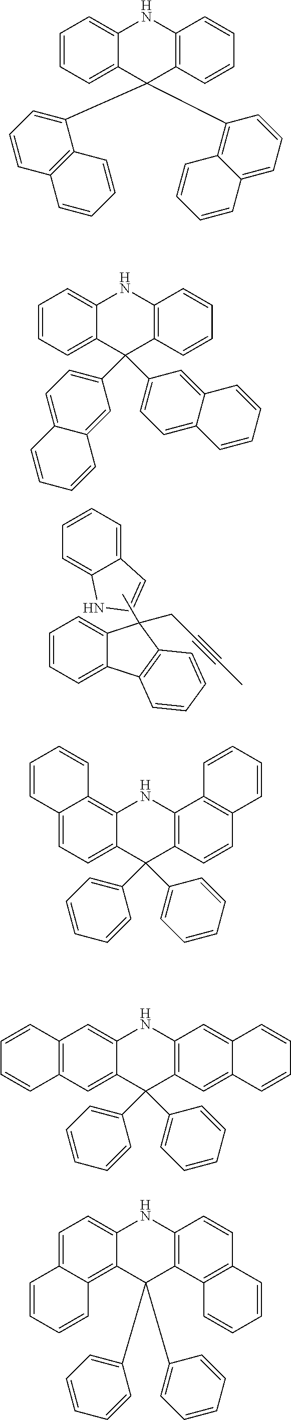

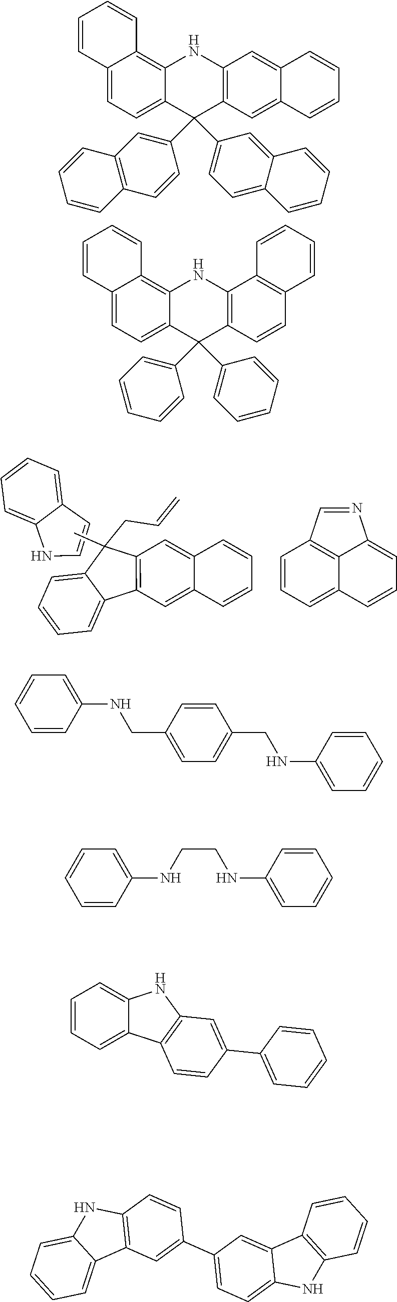

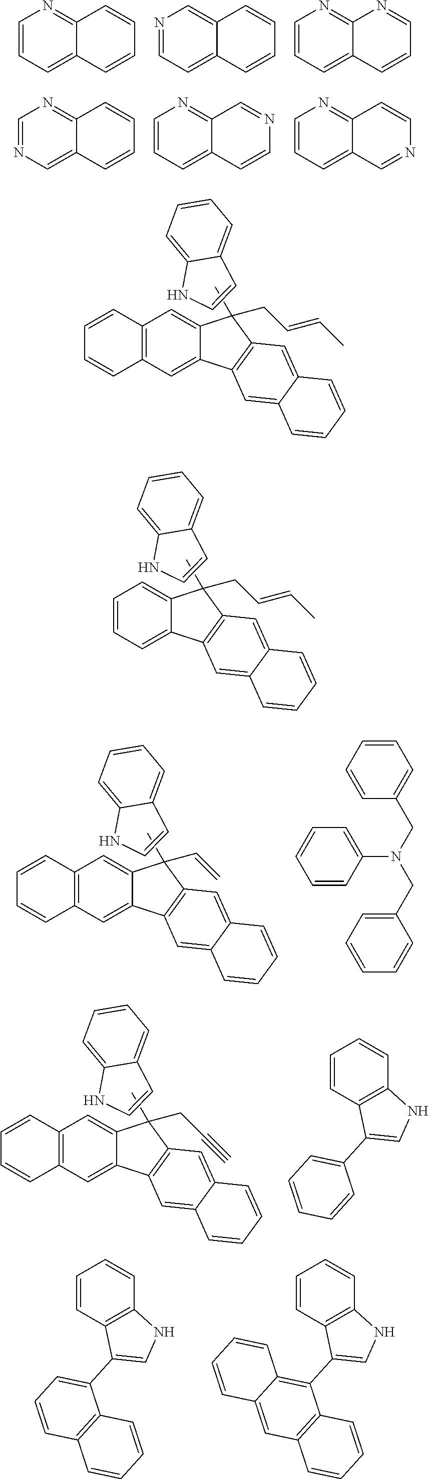

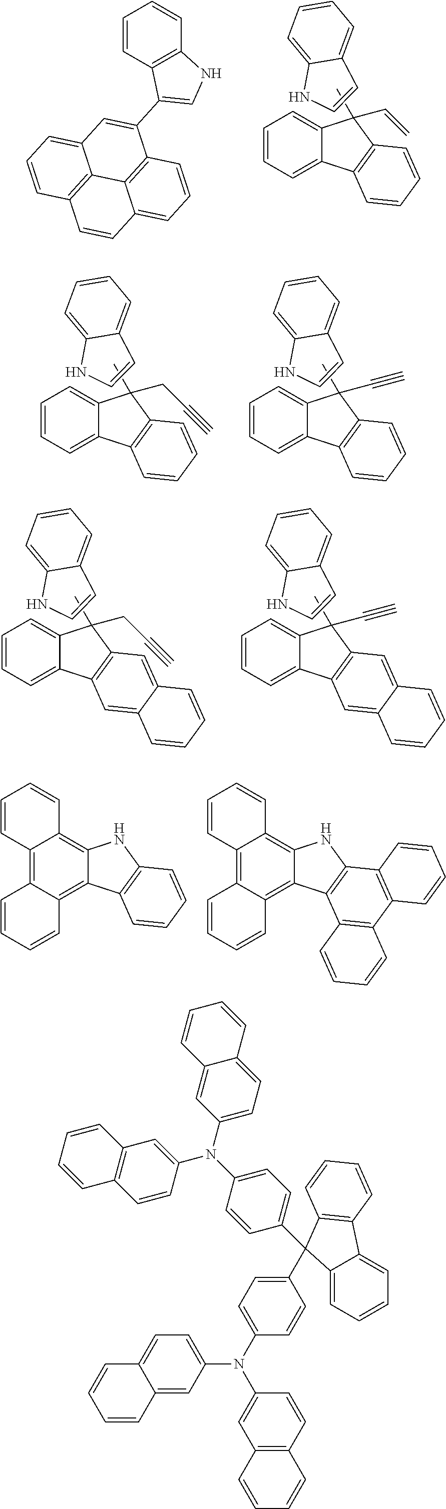

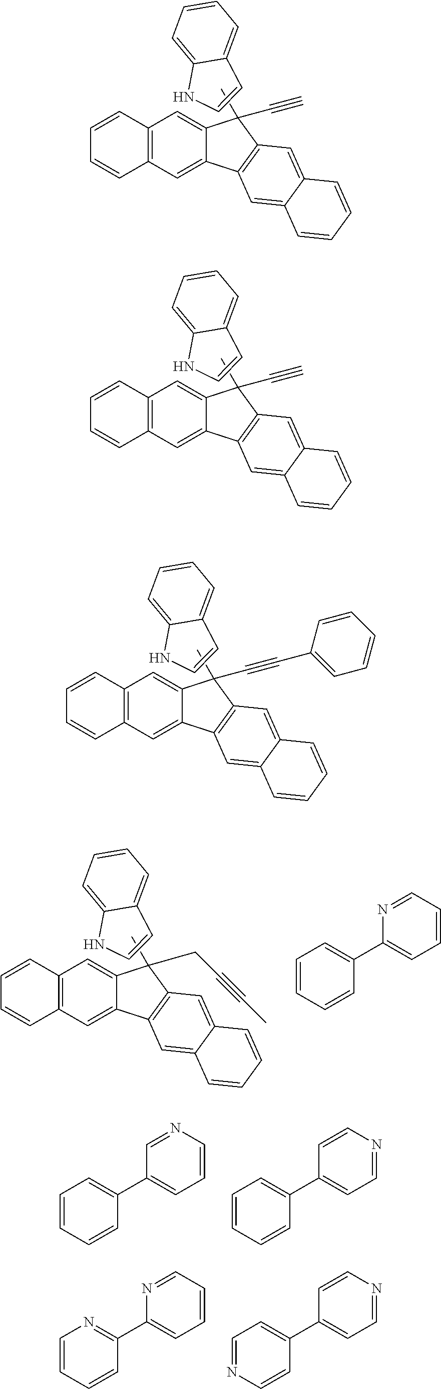

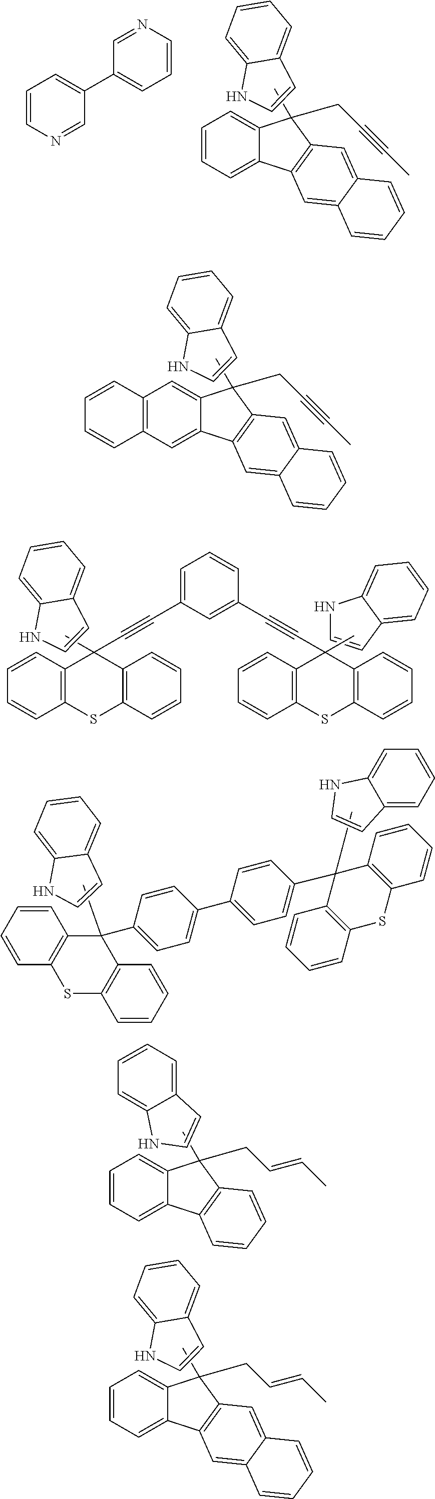

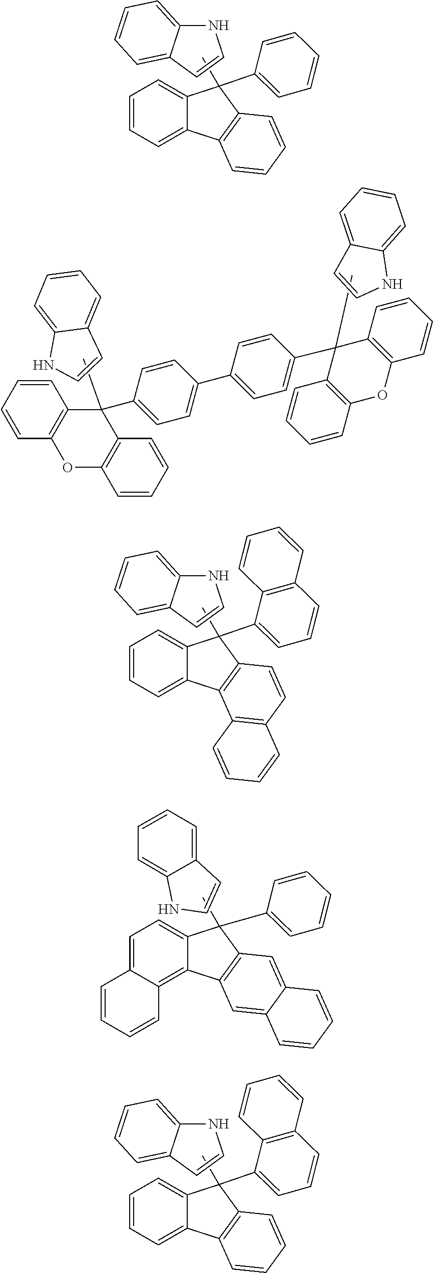

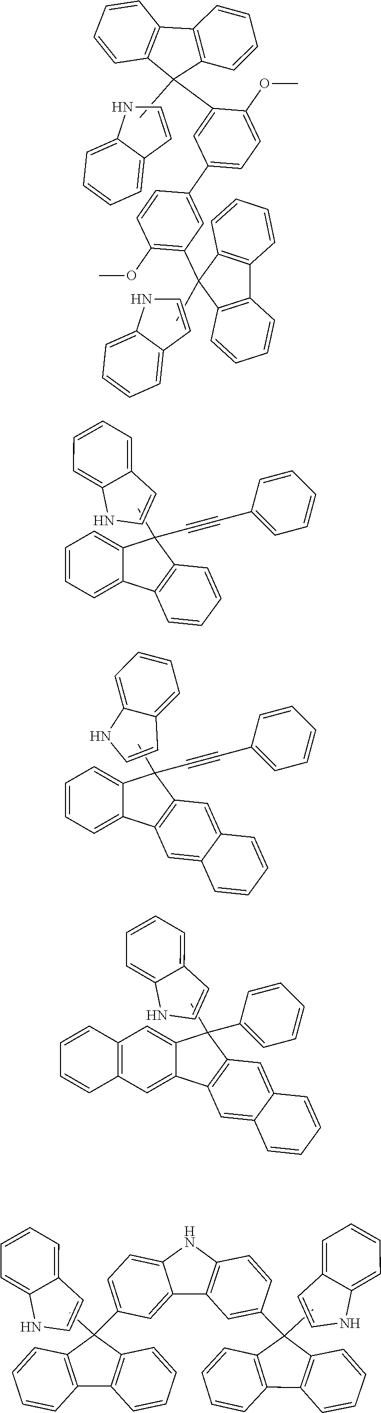

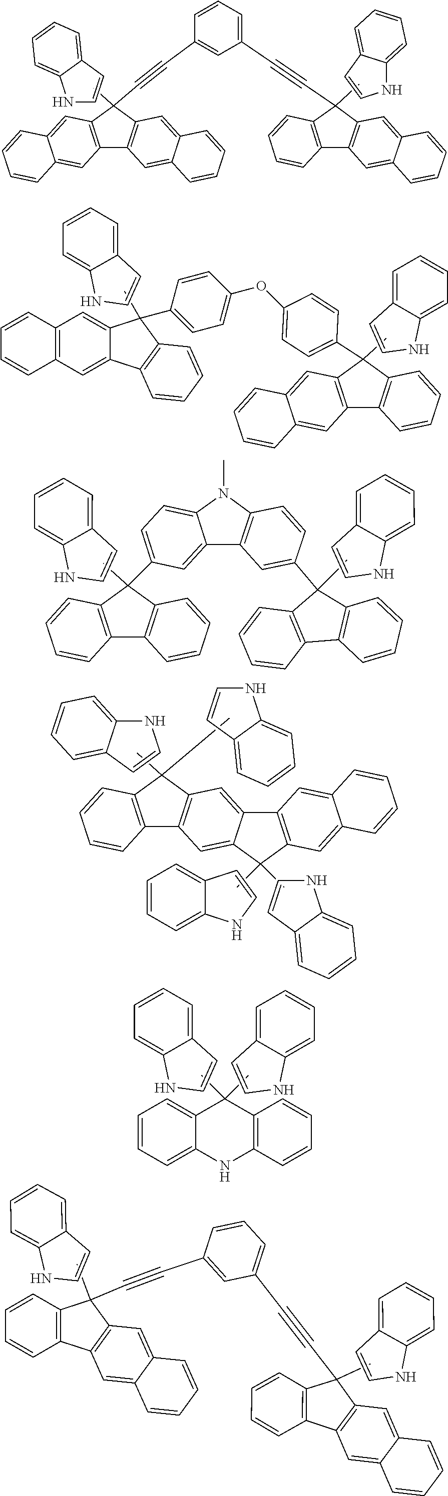

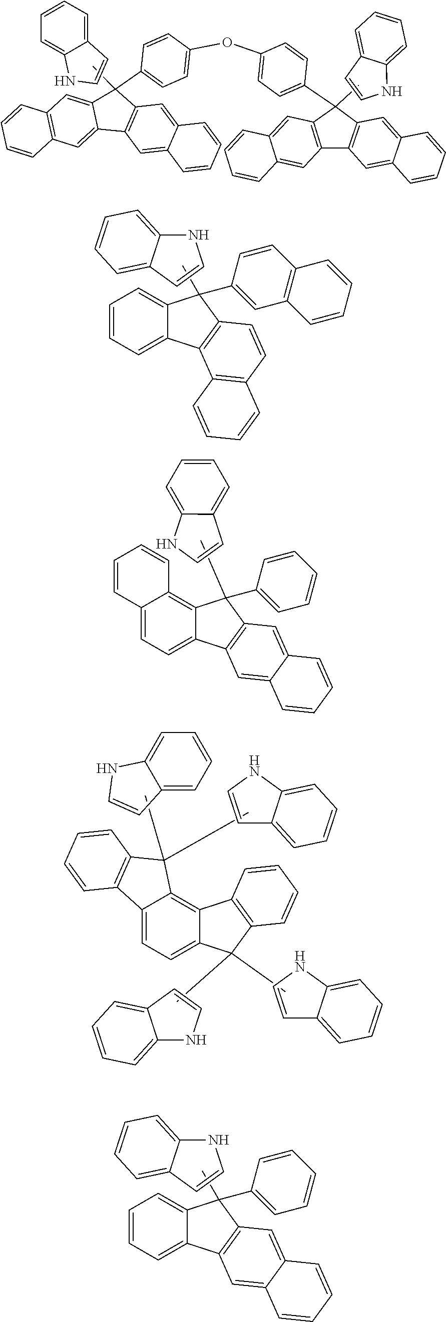

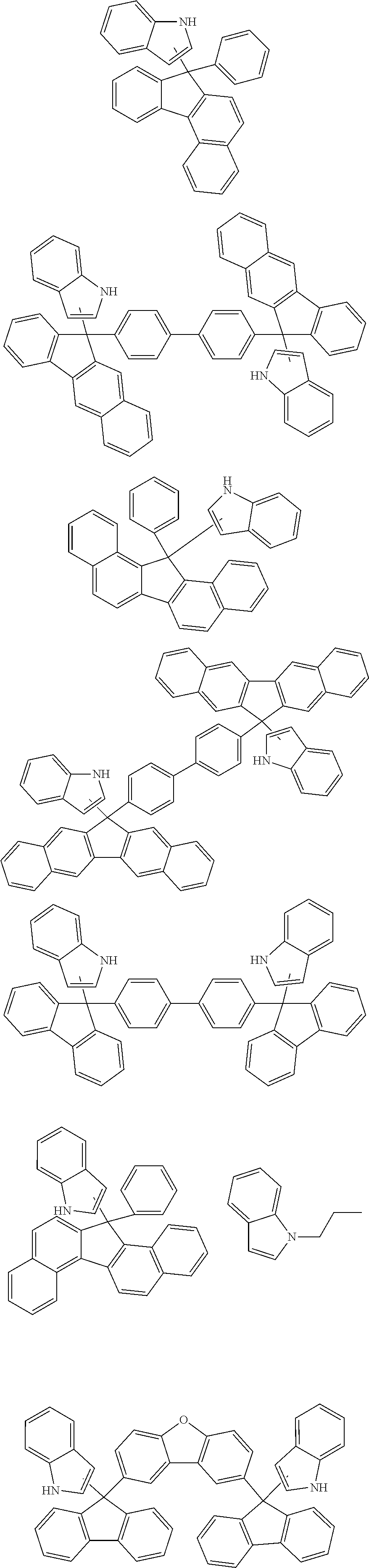

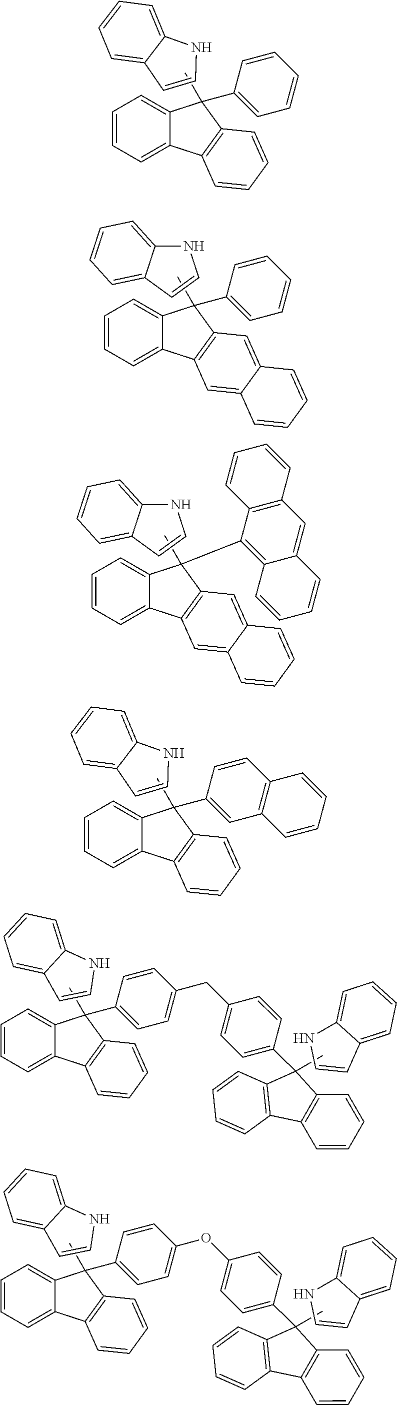

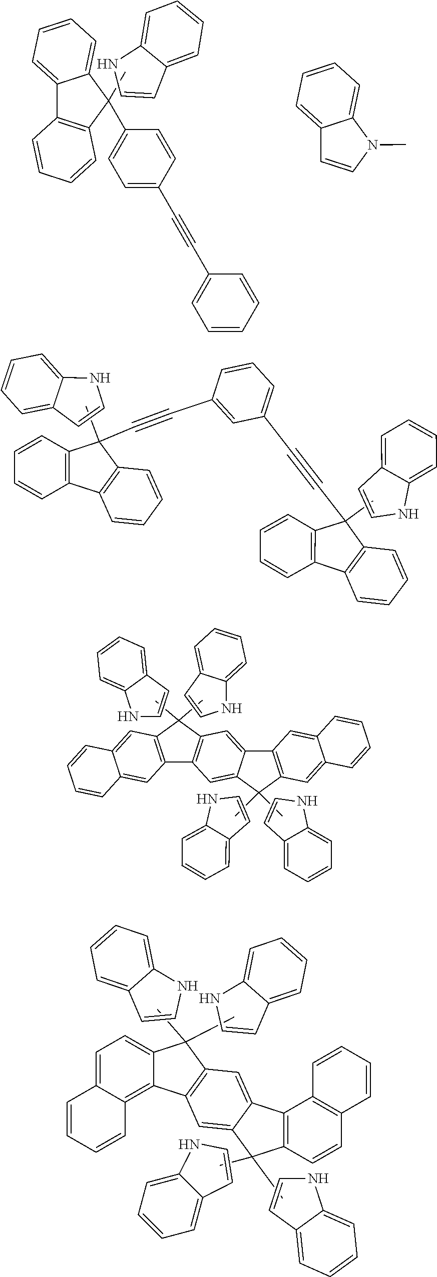

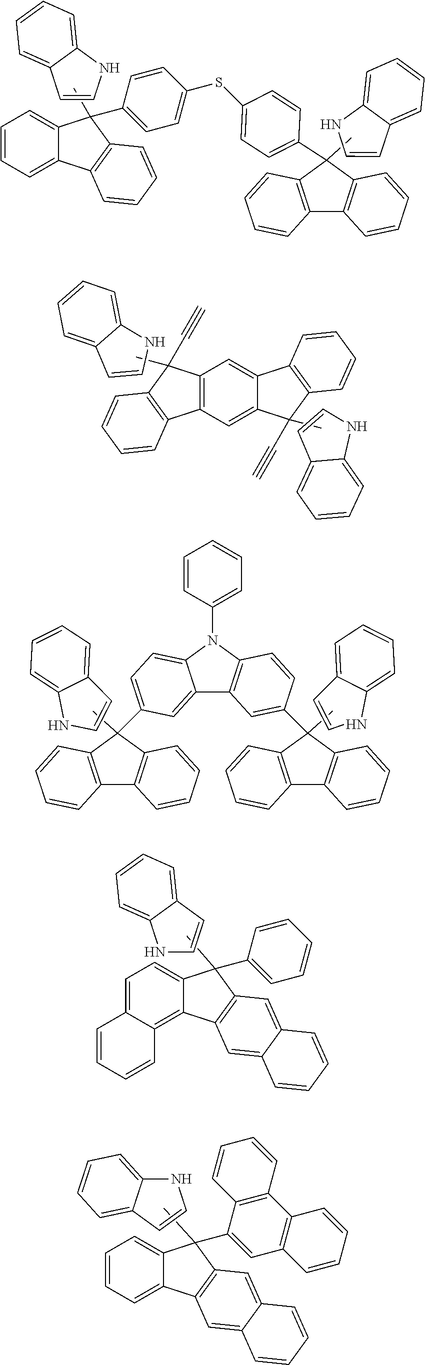

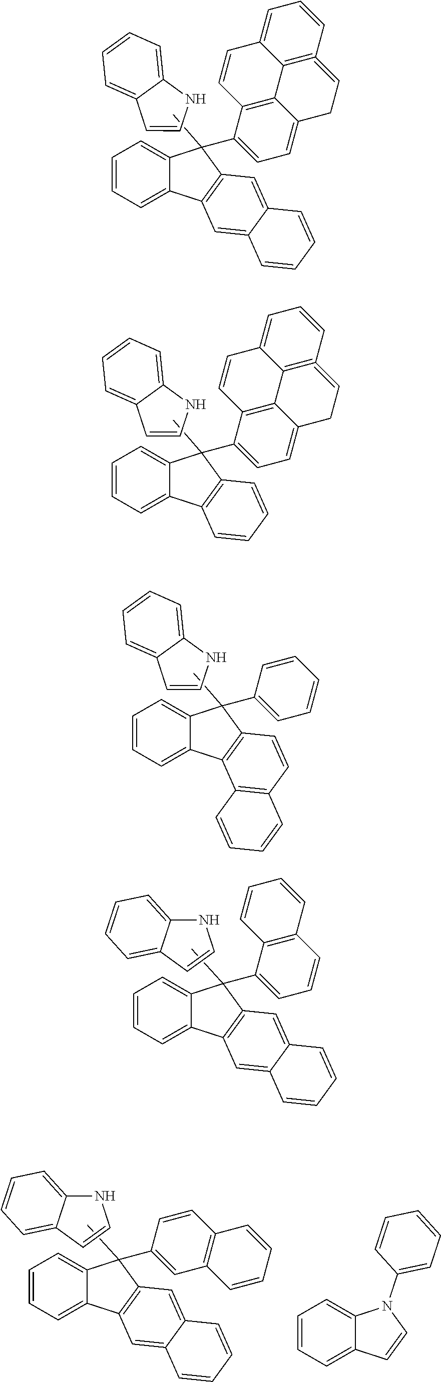

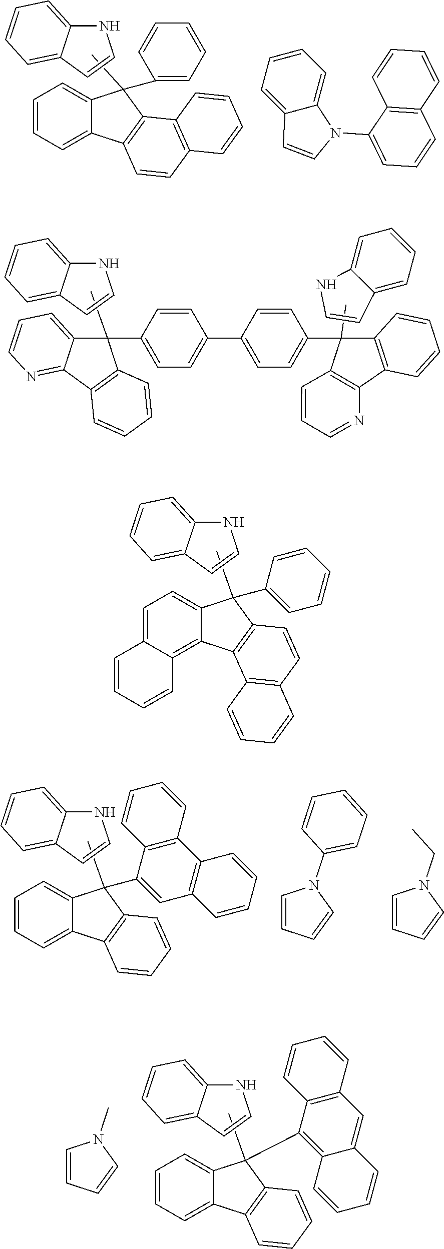

### (Examples of Phenol Skeletons)

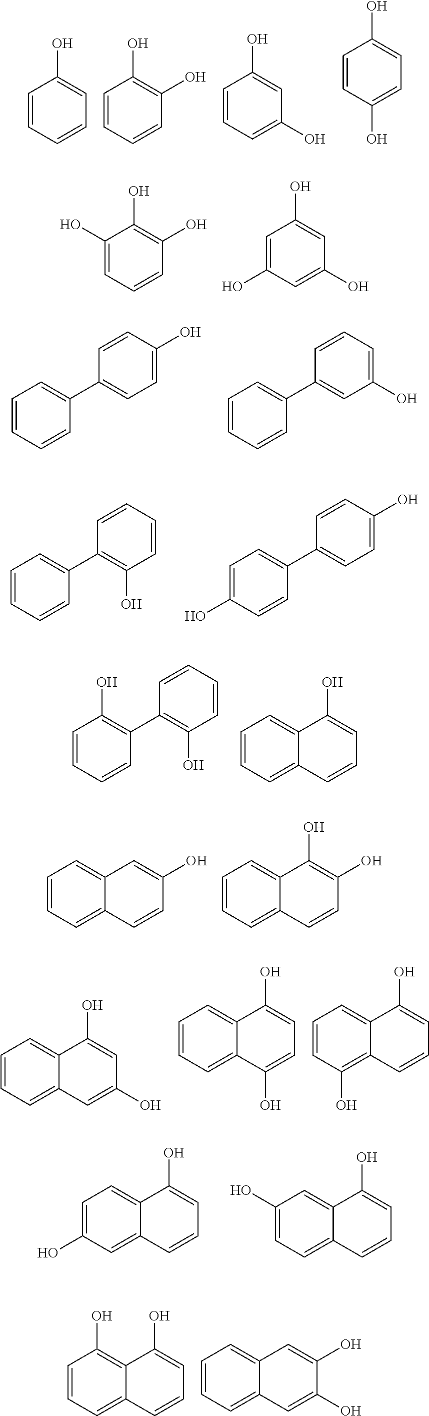

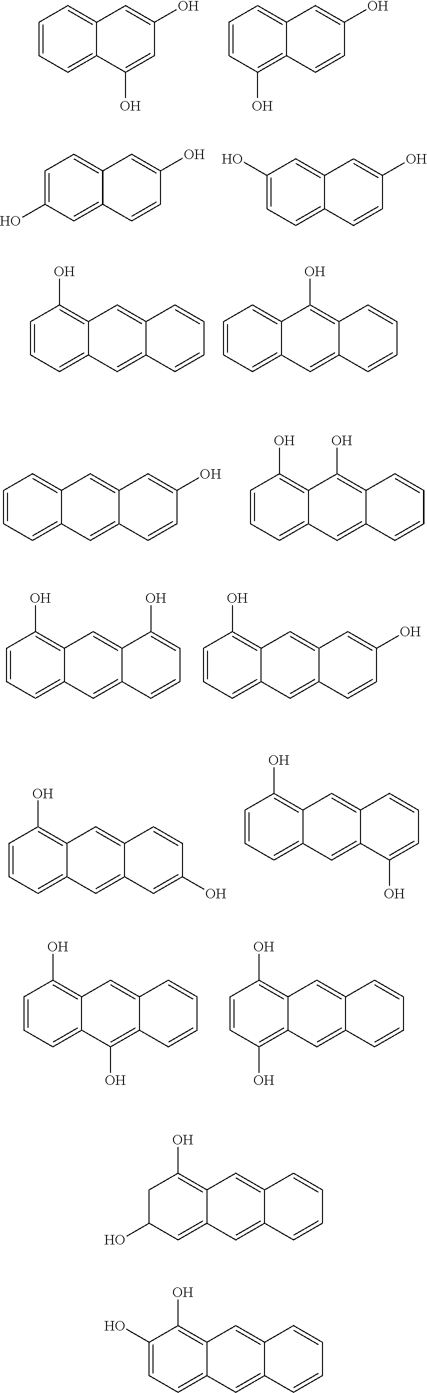

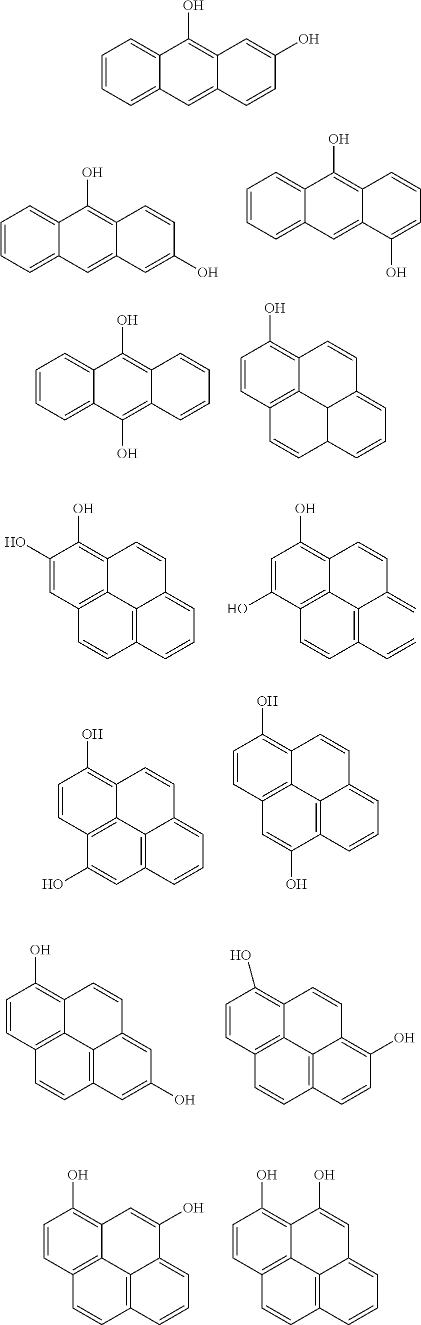

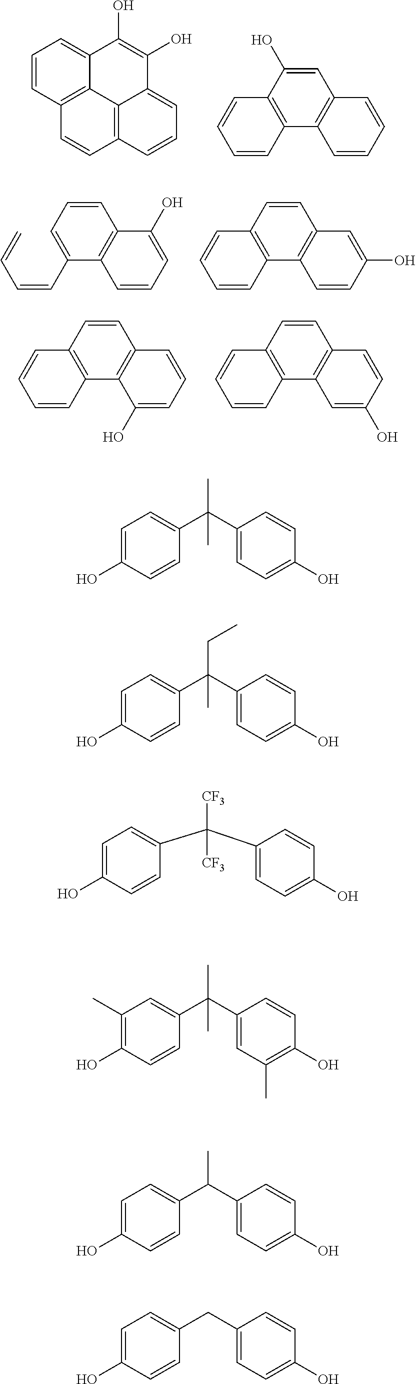

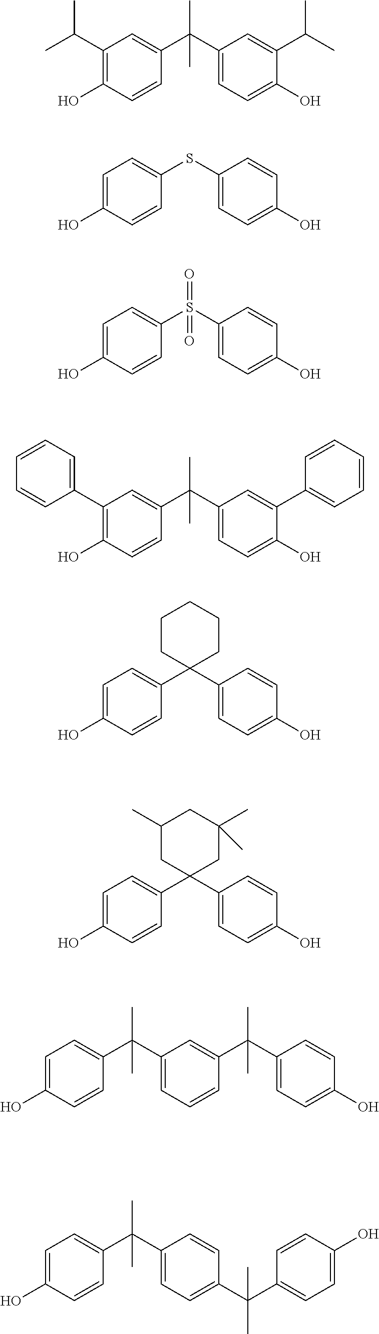

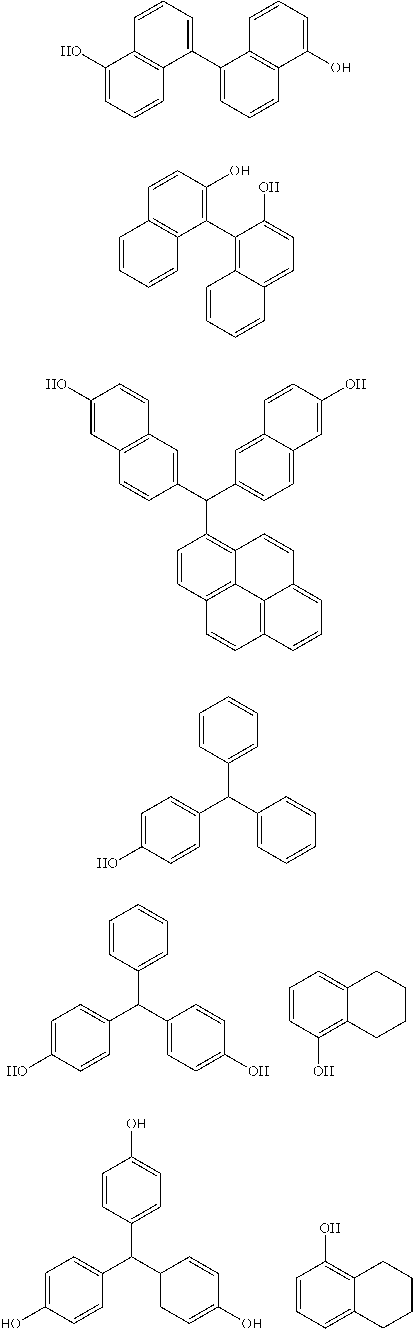

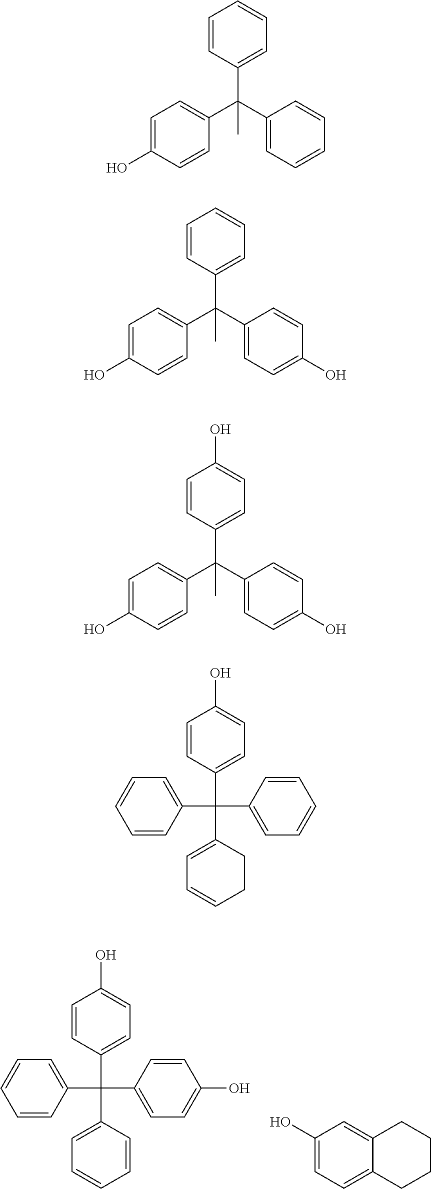 [SMILES: CC(c1ccccc1)(c1ccccc1)c1ccc(O)cc1 ; CC(c1ccccc1)(c1ccc(O)cc1)c1ccc(O)cc1 ; CC(c1ccc(O)cc1)(c1ccc(O)cc1)c1ccc(O)cc1 ; Oc1ccc(C(C2=CC=CCC2)(c2ccccc2)c2ccccc2)cc1 ; Oc1ccc(C(c2ccccc2)(c2ccccc2)c2ccc(O)cc2)cc1 ; Oc1ccc2c(c1)CCCC2]

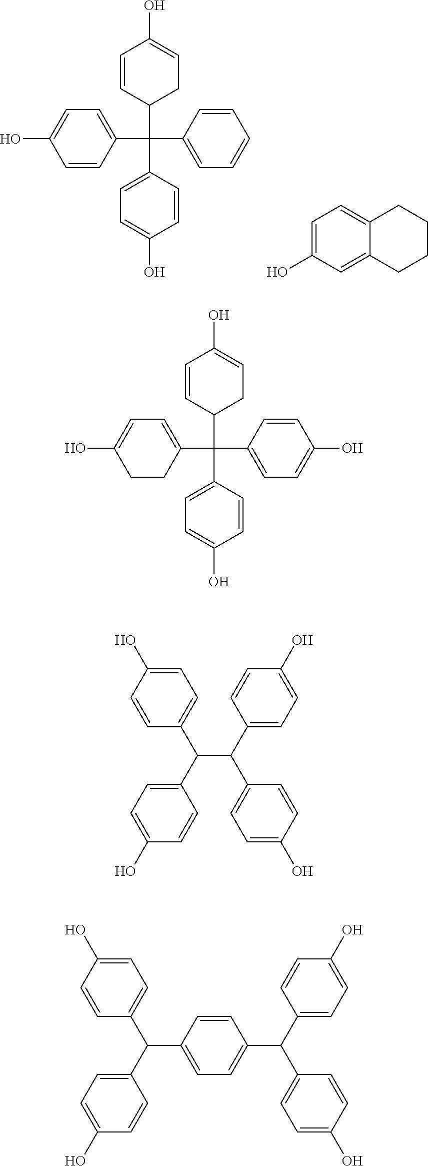 [SMILES: OC1=CCC(C(c2ccccc2)(c2ccc(O)cc2)c2ccc(O)cc2)C=C1 ; Oc1ccc2c(c1)CCCC2 ; OC1=CCC(C(C2=CC=C(O)CC2)(c2ccc(O)cc2)c2ccc(O)cc2)C=C1 ; Oc1ccc(C(c2ccc(O)cc2)C(c2ccc(O)cc2)c2ccc(O)cc2)cc1 ; Oc1ccc(C(c2ccc(O)cc2)c2ccc(C(c3ccc(O)cc3)c3ccc(O)cc3)cc2)cc1]

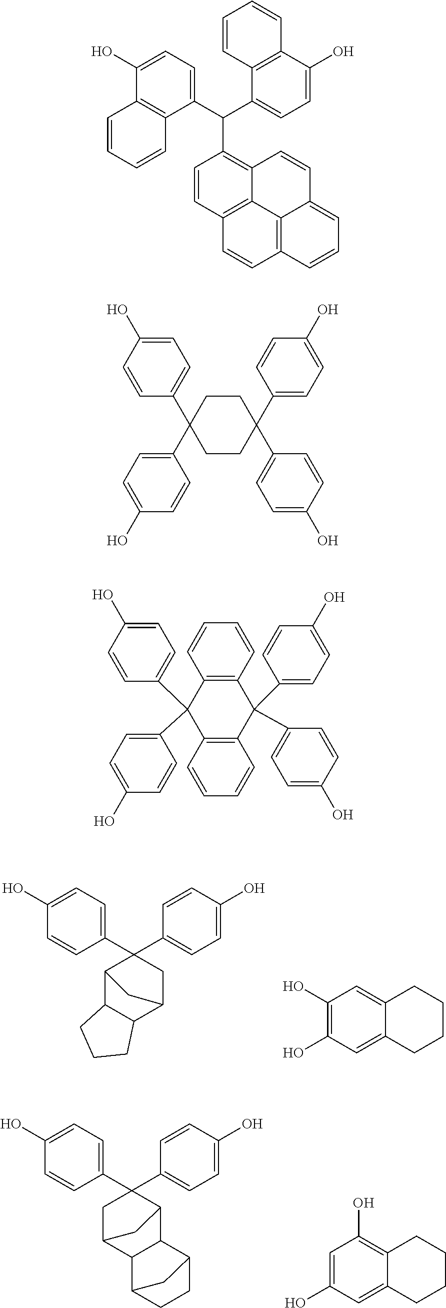

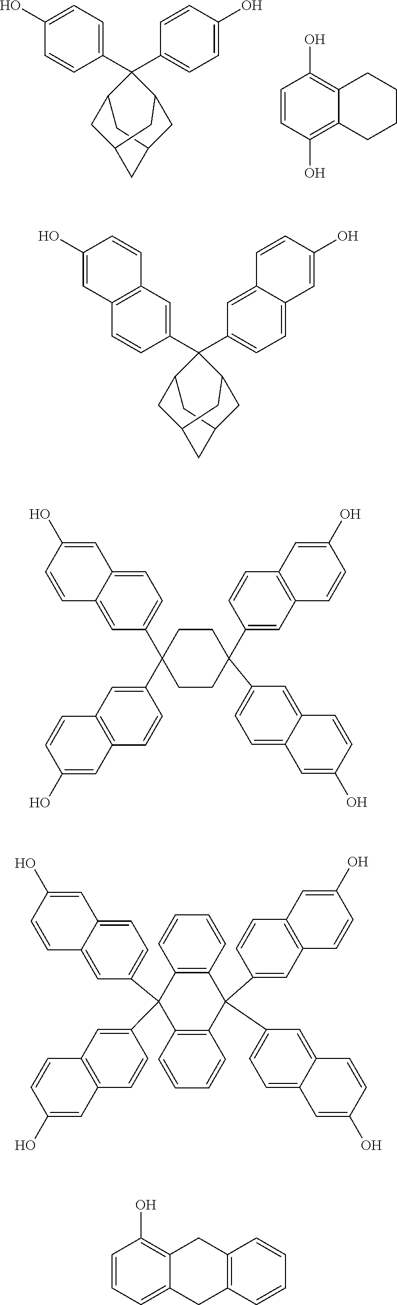 [SMILES: Oc1ccc(C2(c3ccc(O)cc3)C3CC4CC(C3)CC2C4)cc1 ; Oc1ccc(O)c2c1CCCC2 ; Oc1ccc2cc(C3(c4ccc5cc(O)ccc5c4)C4CC5CC(C4)CC3C5)ccc2c1 ; Oc1ccc2cc(C3(c4ccc5cc(O)ccc5c4)CCC(c4ccc5cc(O)ccc5c4)(c4ccc5cc(O)ccc5c4)CC3)ccc2c1 ; Oc1ccc2cc(C3(c4ccc5cc(O)ccc5c4)c4ccccc4C(c4ccc5cc(O)ccc5c4)(c4ccc5cc(O)ccc5c4)c4ccccc43)ccc2c1 ; Oc1cccc2c1Cc1ccccc1C2]

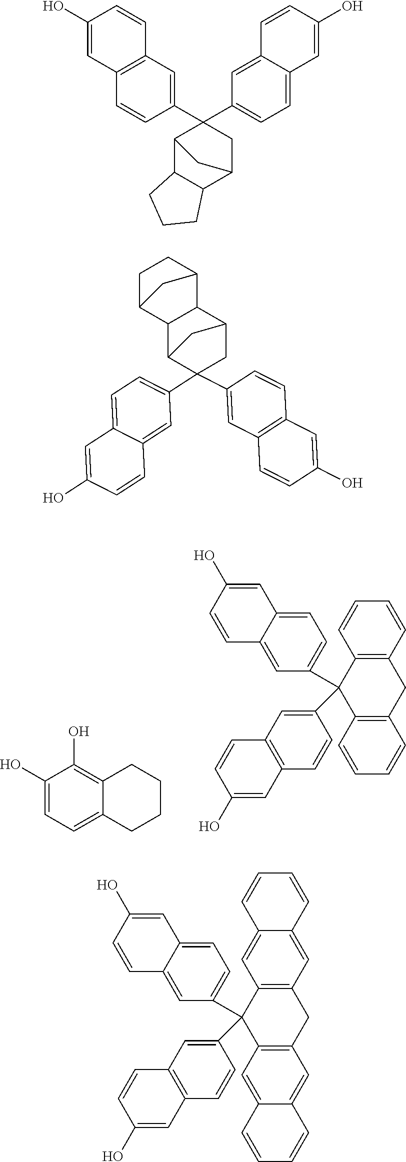

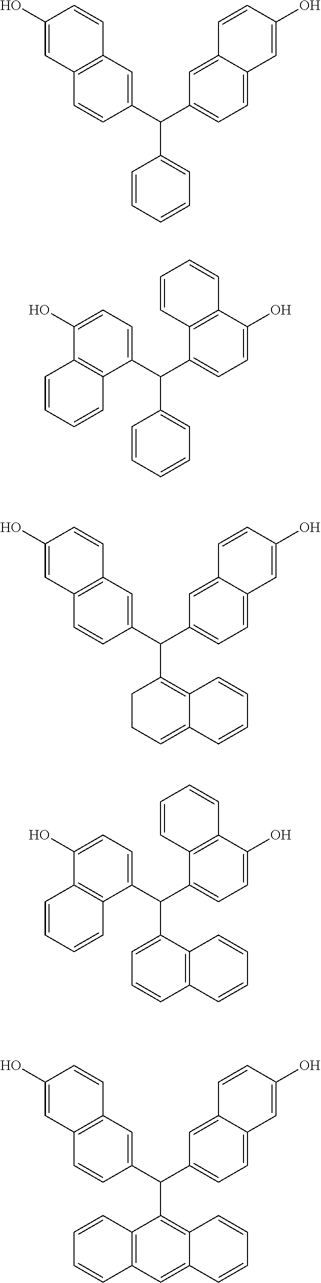 [SMILES: Oc1ccc2cc(C(c3ccccc3)c3ccc4cc(O)ccc4c3)ccc2c1 ; Oc1ccc(C(c2ccccc2)c2ccc(O)c3ccccc23)c2ccccc12 ; Oc1ccc2cc(C(C3=c4ccccc4=CCC3)c3ccc4cc(O)ccc4c3)ccc2c1 ; Oc1ccc(C(c2cccc3ccccc23)c2ccc(O)c3ccccc23)c2ccccc12 ; Oc1ccc2cc(C(c3ccc4cc(O)ccc4c3)c3c4ccccc4cc4ccccc34)ccc2c1]

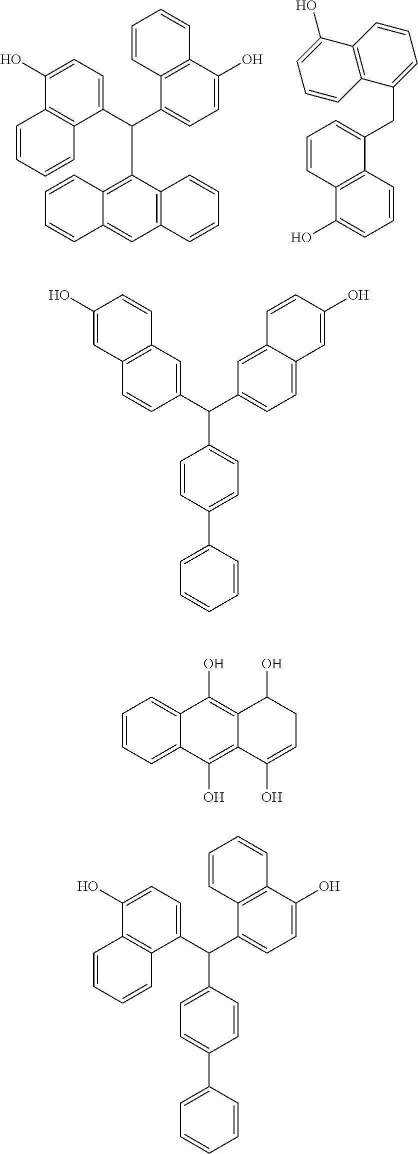 [SMILES: Oc1ccc(C(c2c3ccccc3cc3ccccc23)c2ccc(O)c3ccccc23)c2ccccc12 ; Oc1cccc2c(Cc3cccc4c(O)cccc34)cccc12 ; Oc1ccc2cc(C(c3ccc(-c4ccccc4)cc3)c3ccc4cc(O)ccc4c3)ccc2c1 ; OC1=CCC(O)c2c1c(O)c1ccccc1c2O ; Oc1ccc(C(c2ccc(-c3ccccc3)cc2)c2ccc(O)c3ccccc23)c2ccccc12]

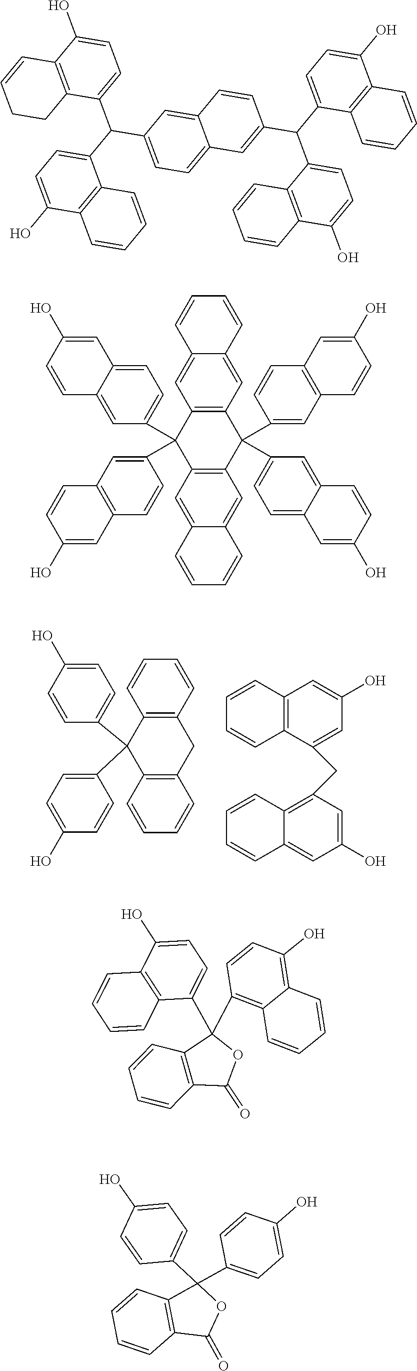

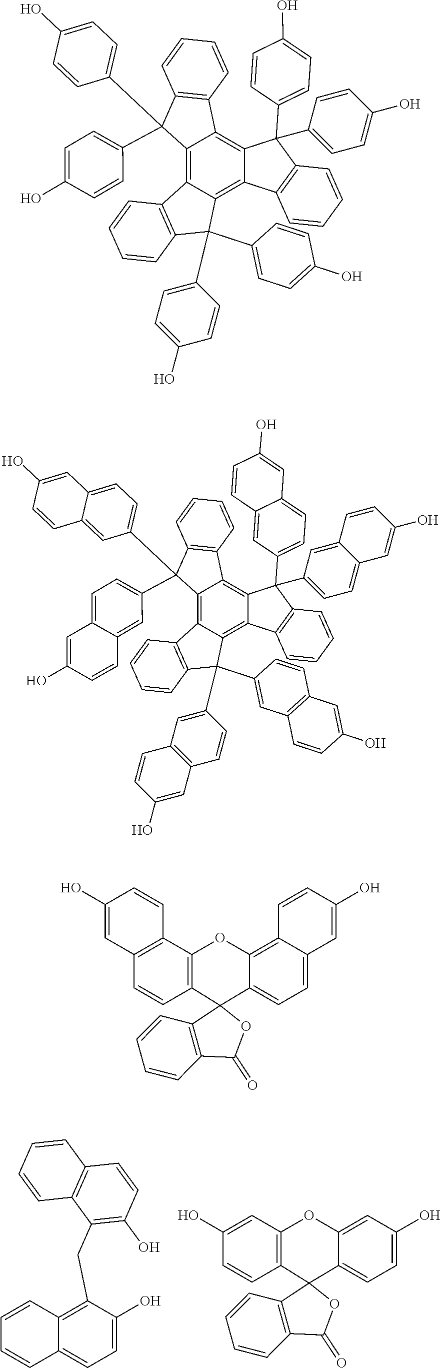 [SMILES: Oc1ccc(C2(c3ccc(O)cc3)c3ccccc3-c3c2c2c(c4c3C(c3ccc(O)cc3)(c3ccc(O)cc3)c3ccccc3-4)C(c3ccc(O)cc3)(c3ccc(O)cc3)c3ccccc3-2)cc1 ; Oc1ccc2cc(C3(c4ccc5cc(O)ccc5c4)c4ccccc4-c4c3c3c(c5c4C(c4ccc6cc(O)ccc6c4)(c4ccc6cc(O)ccc6c4)c4ccccc4-5)C(c4ccc5cc(O)ccc5c4)(c4ccc5cc(O)ccc5c4)c4ccccc4-3)ccc2c1 ; O=C1OC2(c3ccccc31)c1ccc3cc(O)ccc3c1Oc1c2ccc2cc(O)ccc12 ; Oc1ccc2ccccc2c1Cc1c(O)ccc2ccccc12 ; O=C1OC2(c3ccc(O)cc3Oc3cc(O)ccc32)c2ccccc21]

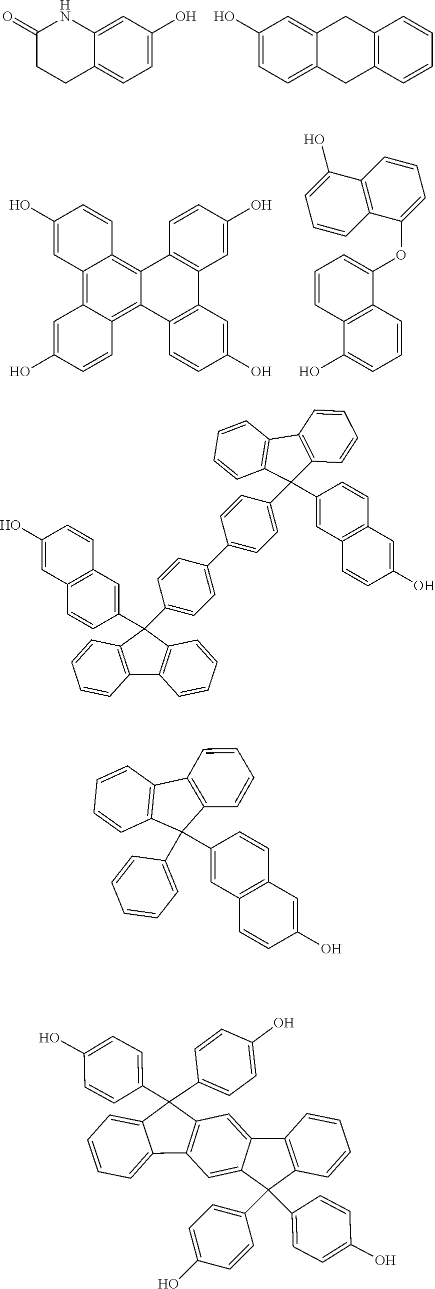

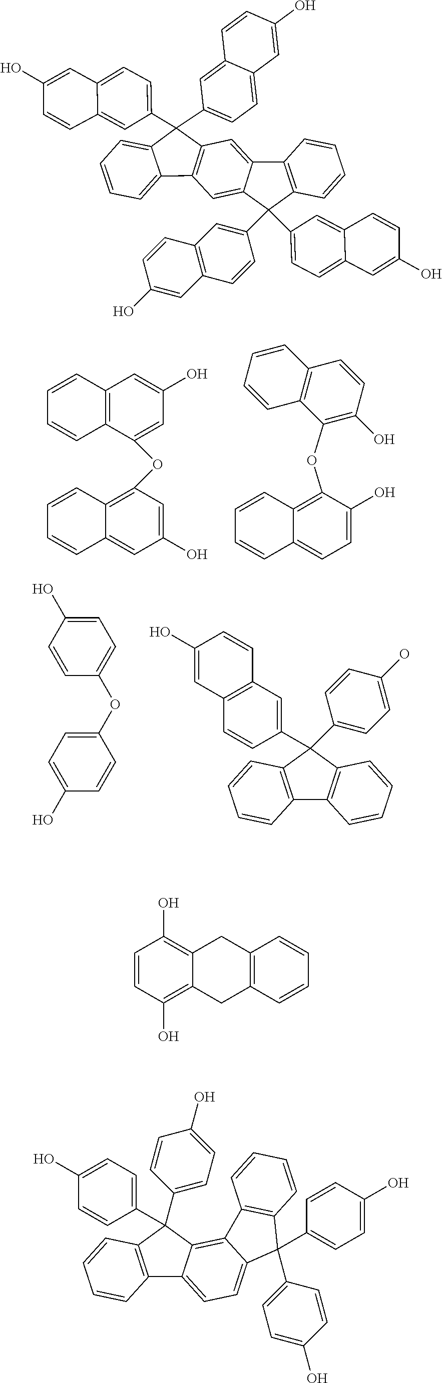

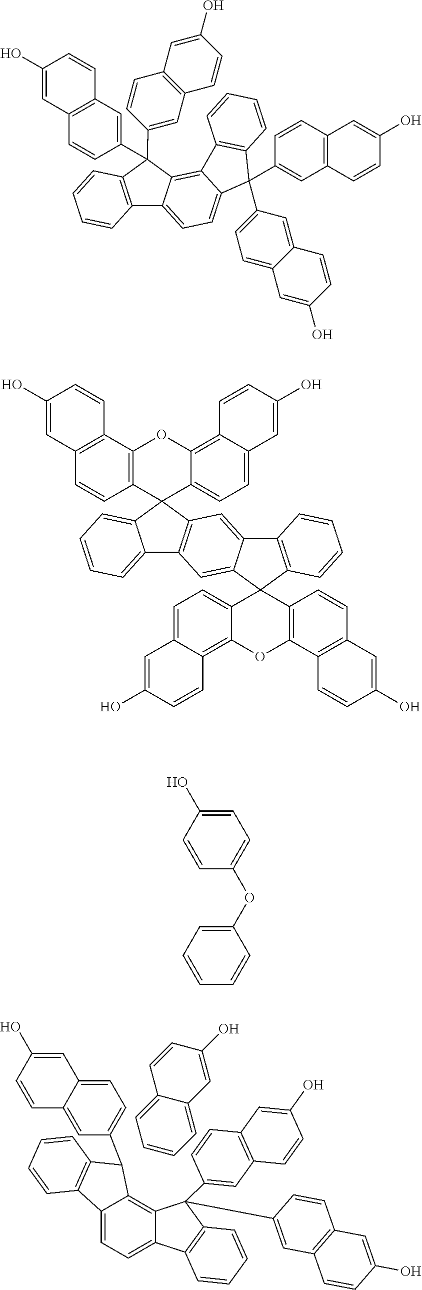

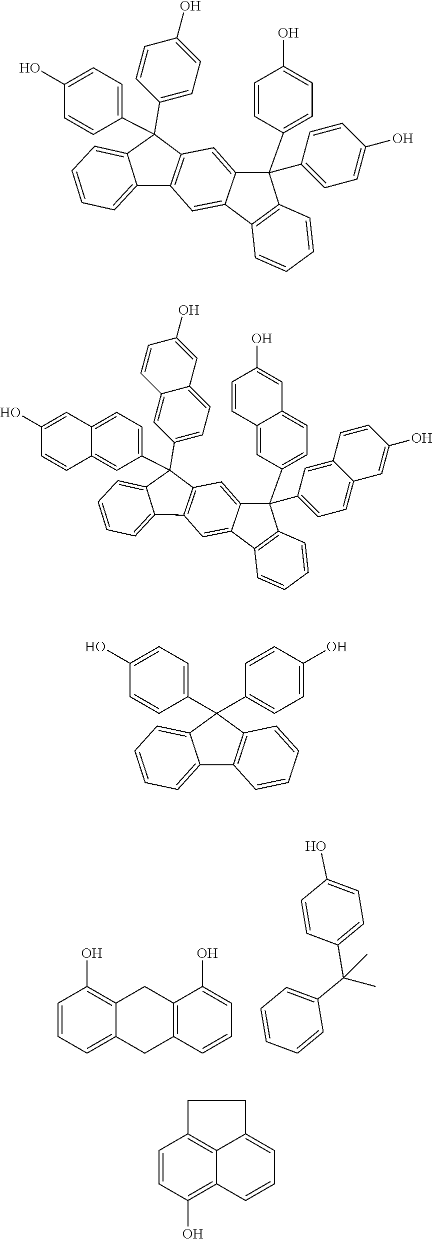

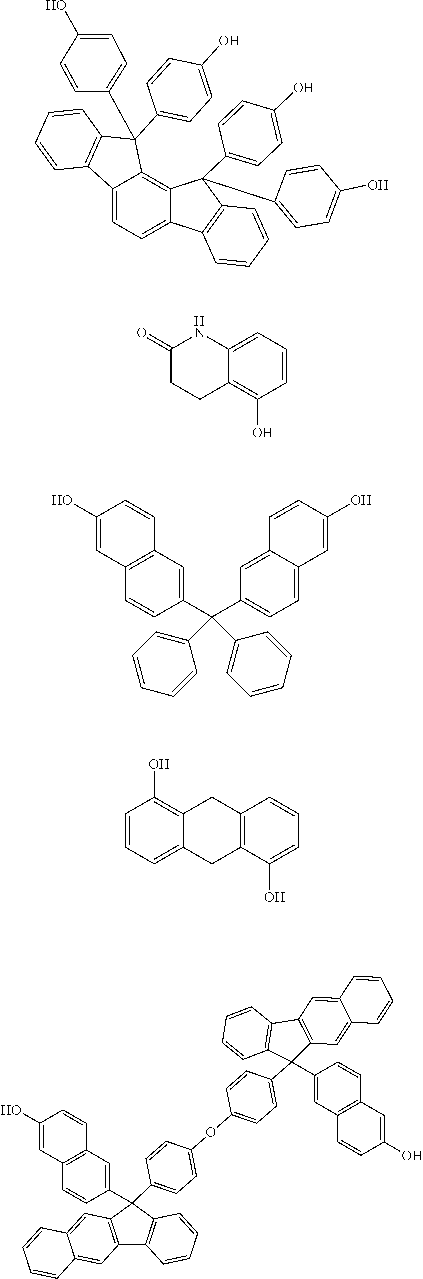 [SMILES: Oc1ccc(C2(c3ccc(O)cc3)c3ccccc3-c3ccc4c(c32)C(c2ccc(O)cc2)(c2ccc(O)cc2)c2ccccc2-4)cc1 ; O=C1CCc2c(O)cccc2N1 ; Oc1ccc2cc(C(c3ccccc3)(c3ccccc3)c3ccc4cc(O)ccc4c3)ccc2c1 ; Oc1cccc2c1Cc1cccc(O)c1C2 ; Oc1ccc2cc(C3(c4ccc(Oc5ccc(C6(c7ccc8cc(O)ccc8c7)c7ccccc7-c7cc8ccccc8cc76)cc5)cc4)c4ccccc4-c4cc5ccccc5cc43)ccc2c1]

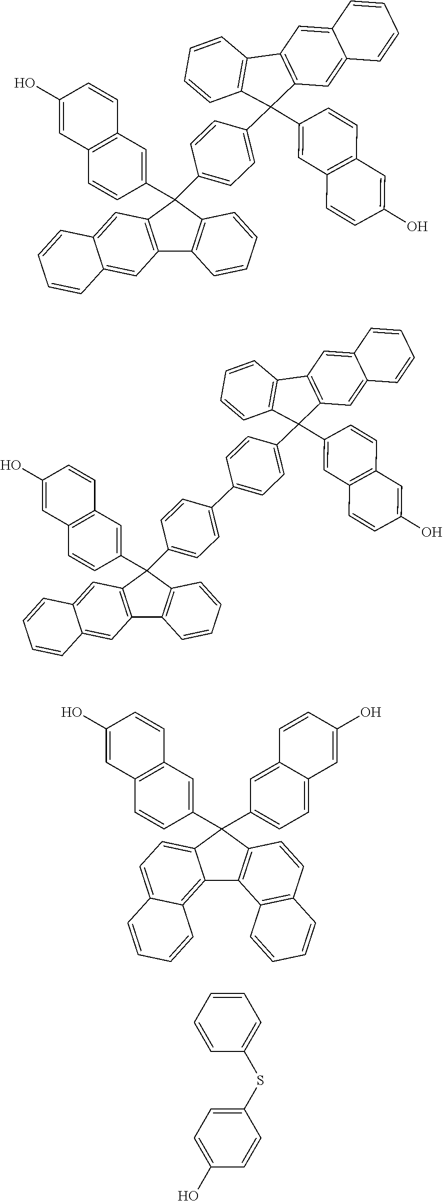

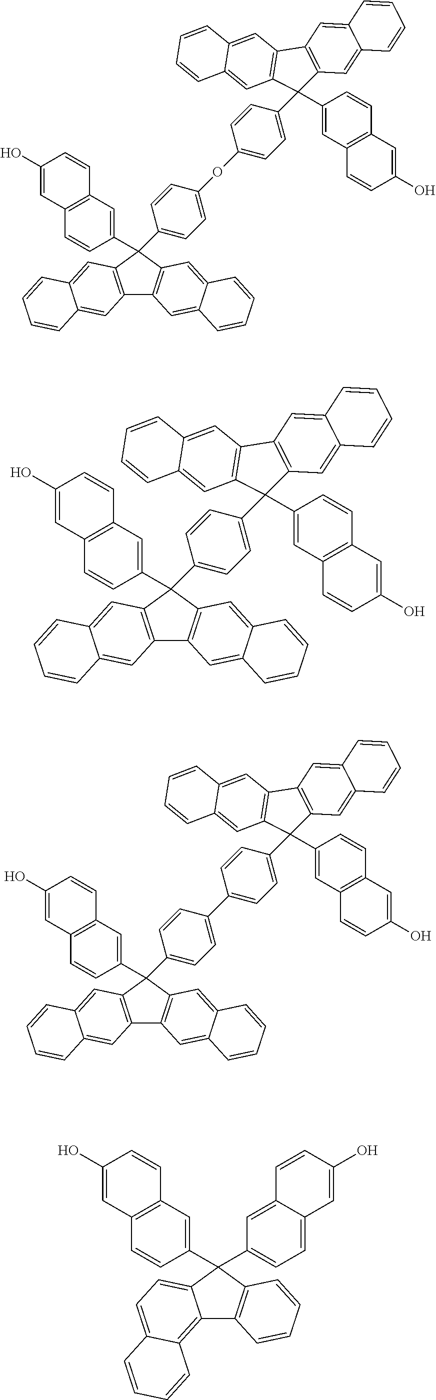 [SMILES: Oc1ccc2cc(C3(c4ccc(Oc5ccc(C6(c7ccc8cc(O)ccc8c7)c7cc8ccccc8cc7-c7cc8ccccc8cc76)cc5)cc4)c4cc5ccccc5cc4-c4cc5ccccc5cc43)ccc2c1 ; Oc1ccc2cc(C3(c4ccc(C5(c6ccc7cc(O)ccc7c6)c6cc7ccccc7cc6-c6cc7ccccc7cc65)cc4)c4cc5ccccc5cc4-c4cc5ccccc5cc43)ccc2c1 ; Oc1ccc2cc(C3(c4ccc(-c5ccc(C6(c7ccc8cc(O)ccc8c7)c7cc8ccccc8cc7-c7cc8ccccc8cc76)cc5)cc4)c4cc5ccccc5cc4-c4cc5ccccc5cc43)ccc2c1 ; Oc1ccc2cc(C3(c4ccc5cc(O)ccc5c4)c4ccccc4-c4c3ccc3ccccc43)ccc2c1]

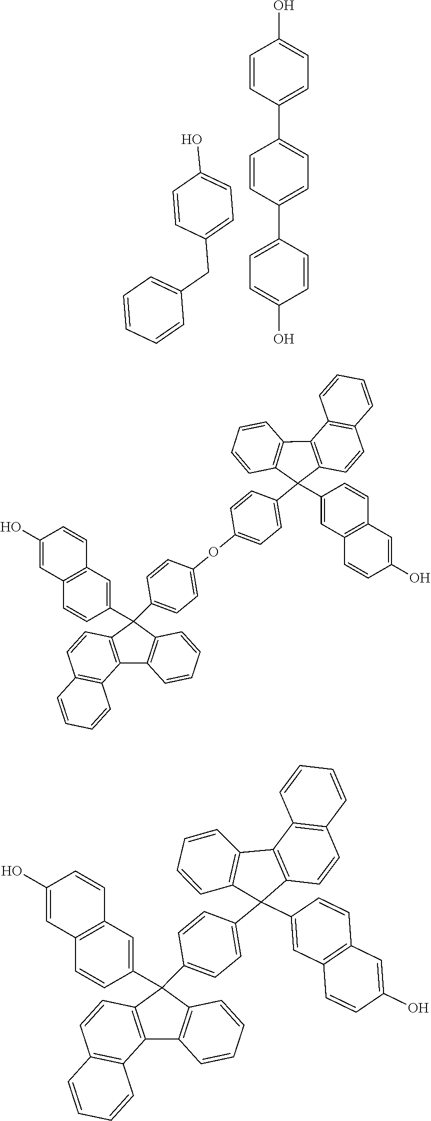

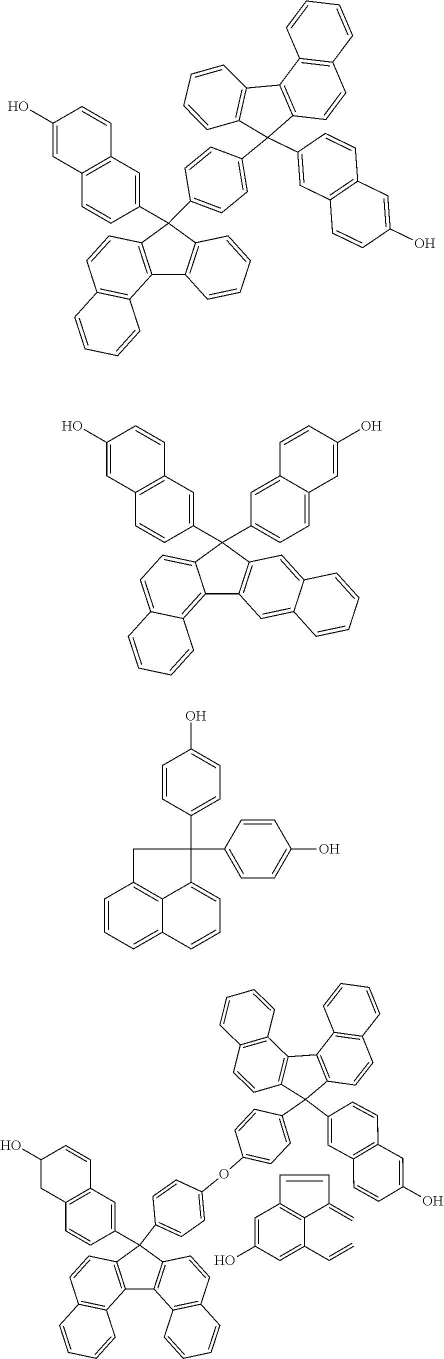

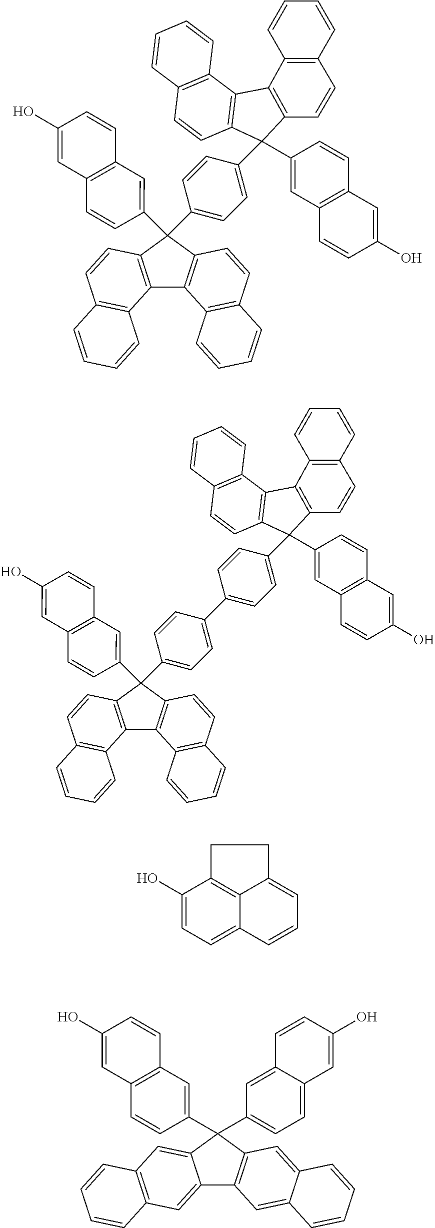 [SMILES: Oc1ccc2cc(C3(c4ccc(C5(c6ccc7cc(O)ccc7c6)c6ccc7ccccc7c6-c6c5ccc5ccccc65)cc4)c4ccc5ccccc5c4-c4c3ccc3ccccc43)ccc2c1 ; Oc1ccc2cc(C3(c4ccc(-c5ccc(C6(c7ccc8cc(O)ccc8c7)c7ccc8ccccc8c7-c7c6ccc6ccccc76)cc5)cc4)c4ccc5ccccc5c4-c4c3ccc3ccccc43)ccc2c1 ; Oc1ccc2cccc3c2c1CC3 ; Oc1ccc2cc(C3(c4ccc5cc(O)ccc5c4)c4cc5ccccc5cc4-c4cc5ccccc5cc43)ccc2c1]

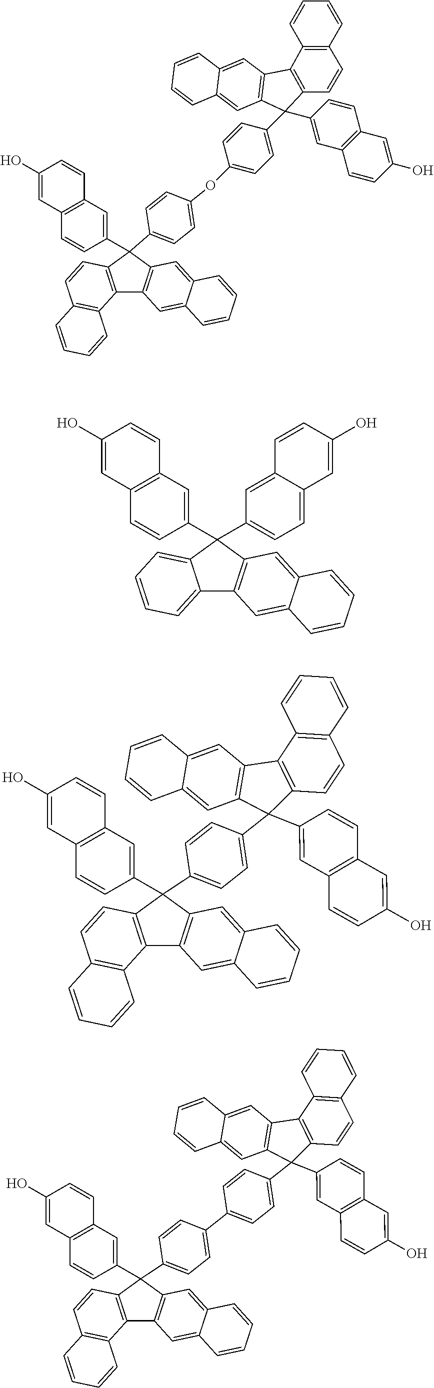 [SMILES: Oc1ccc2cc(C3(c4ccc(Oc5ccc(C6(c7ccc8cc(O)ccc8c7)c7cc8ccccc8cc7-c7c6ccc6ccccc76)cc5)cc4)c4cc5ccccc5cc4-c4c3ccc3ccccc43)ccc2c1 ; Oc1ccc2cc(C3(c4ccc5cc(O)ccc5c4)c4ccccc4-c4cc5ccccc5cc43)ccc2c1 ; Oc1ccc2cc(C3(c4ccc(C5(c6ccc7cc(O)ccc7c6)c6cc7ccccc7cc6-c6c5ccc5ccccc65)cc4)c4cc5ccccc5cc4-c4c3ccc3ccccc43)ccc2c1 ; Oc1ccc2cc(C3(c4ccc(-c5ccc(C6(c7ccc8cc(O)ccc8c7)c7cc8ccccc8cc7-c7c6ccc6ccccc76)cc5)cc4)c4cc5ccccc5cc4-c4c3ccc3ccccc43)ccc2c1]

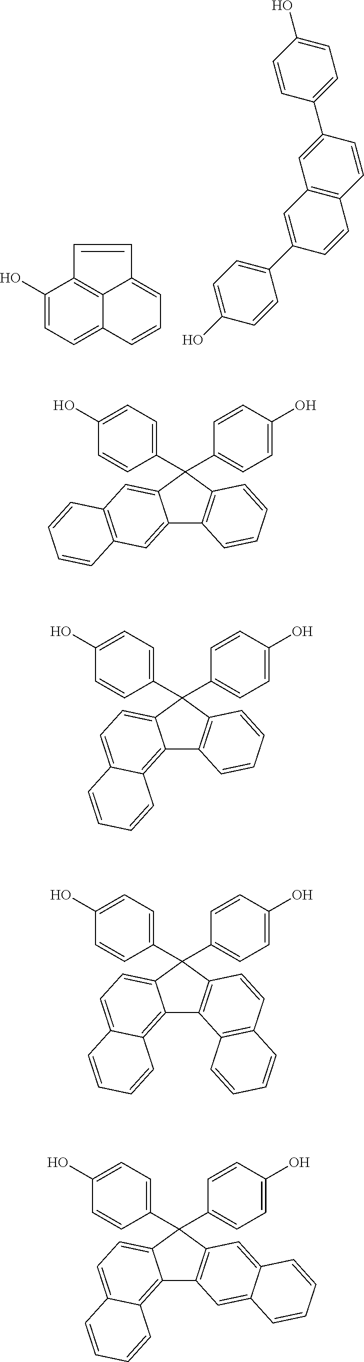

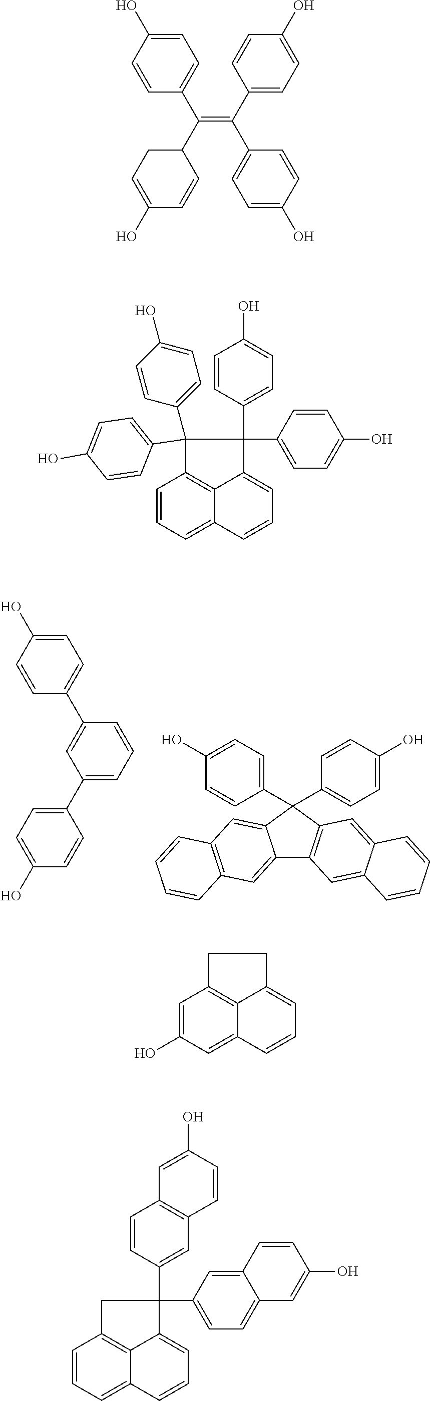

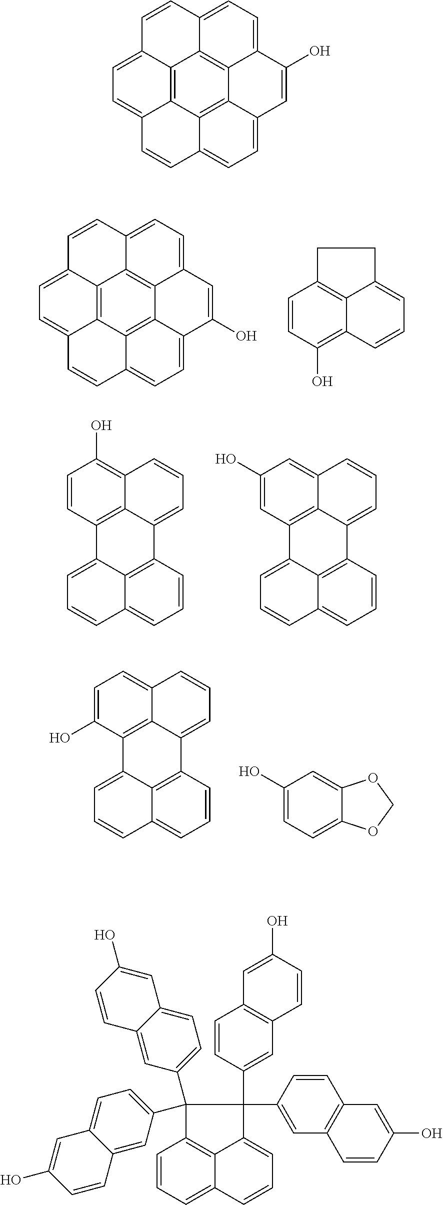

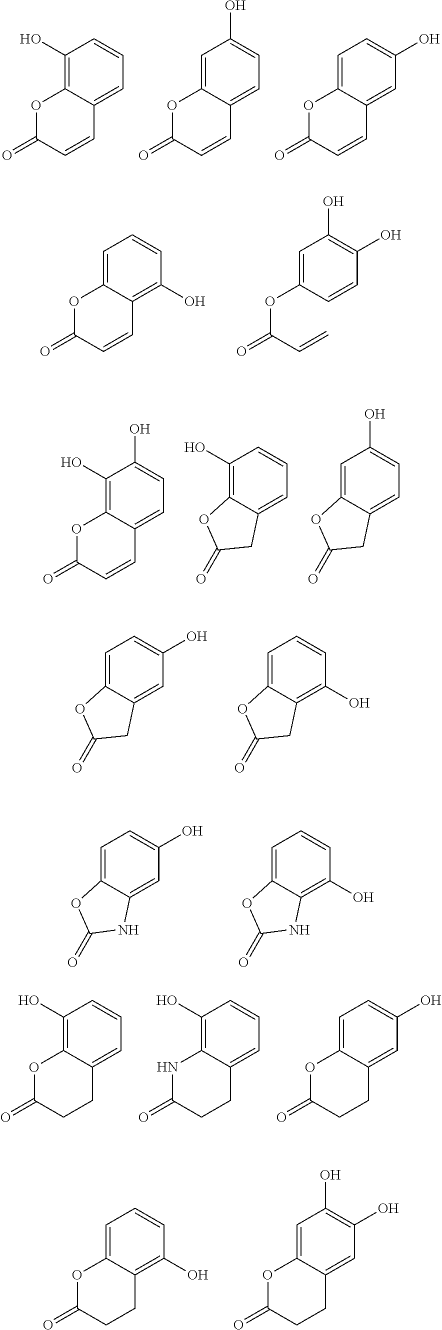

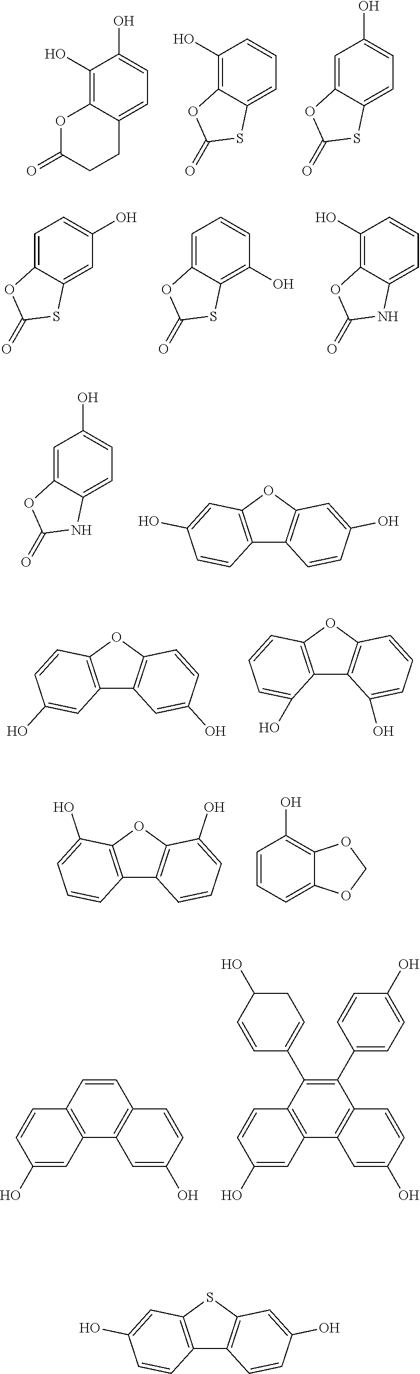

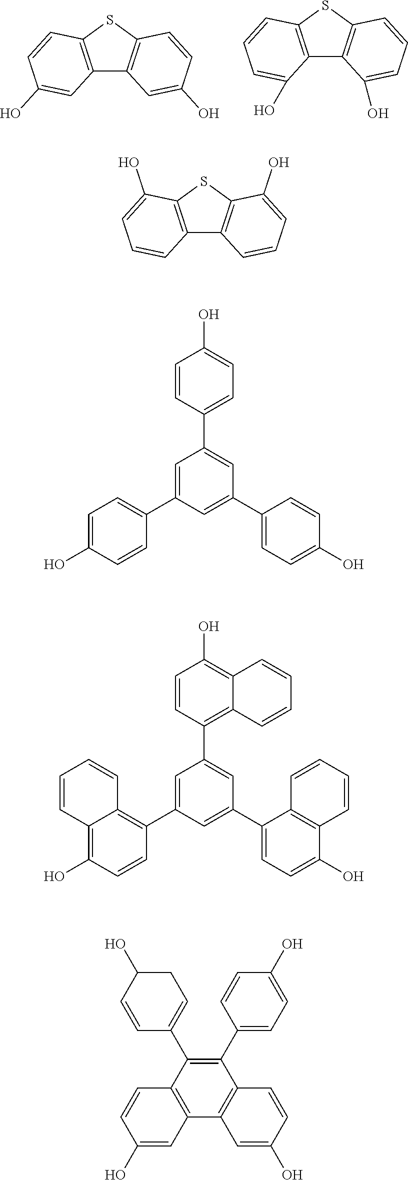 [SMILES: Oc1ccc2sc3ccc(O)cc3c2c1 ; Oc1cccc2sc3cccc(O)c3c12 ; Oc1cccc2c1sc1c(O)cccc12 ; Oc1ccc(-c2cc(-c3ccc(O)cc3)cc(-c3ccc(O)cc3)c2)cc1 ; Oc1ccc(-c2cc(-c3ccc(O)c4ccccc34)cc(-c3ccc(O)c4ccccc34)c2)c2ccccc12 ; Oc1ccc(-c2c(C3=CCC(O)C=C3)c3ccc(O)cc3c3cc(O)ccc23)cc1]

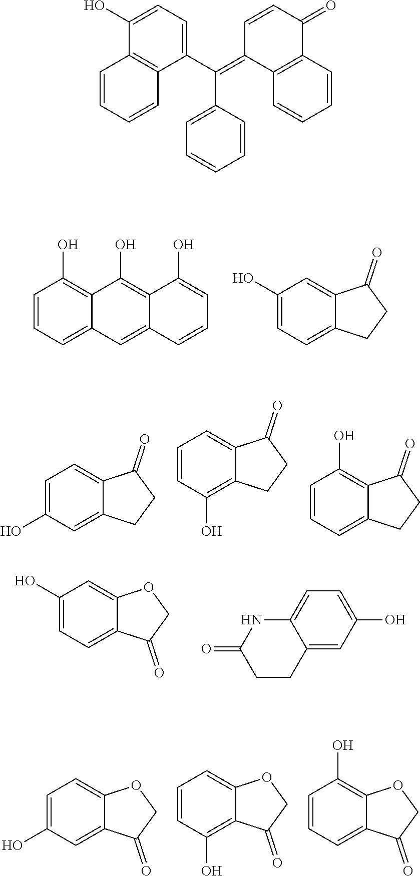

H of NH in the above amine skeletons and H of OH in the above phenol skeletons may be substituted with substituents illustrated below:

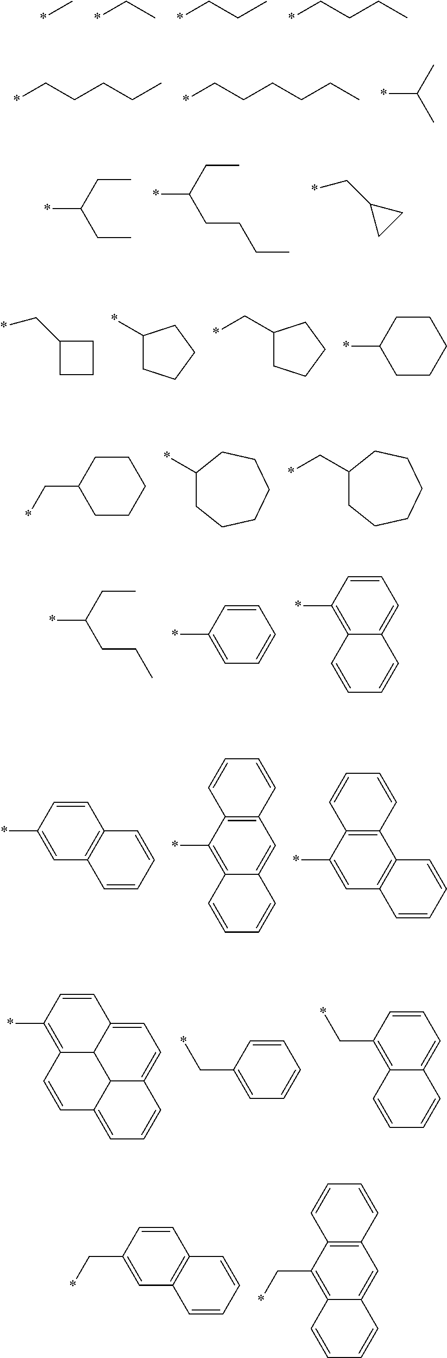

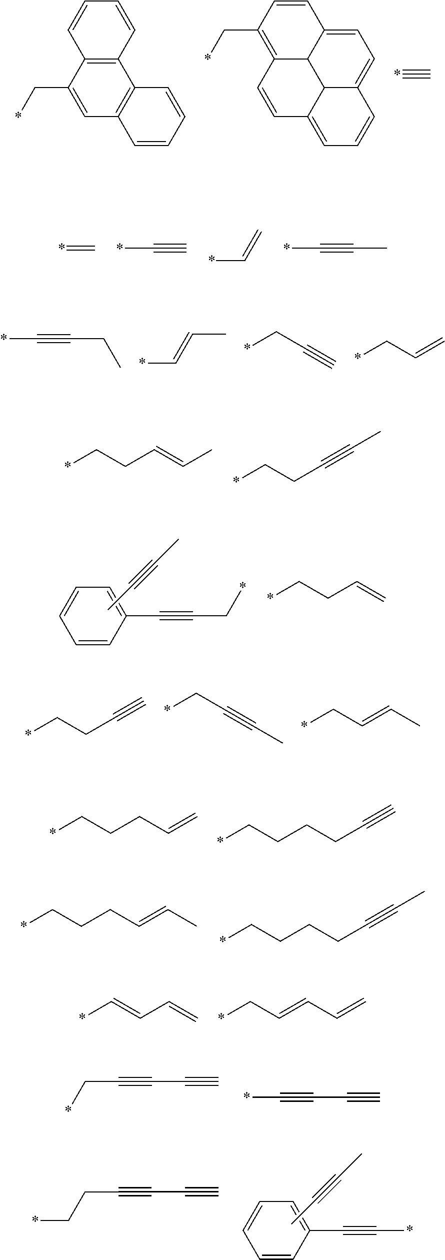

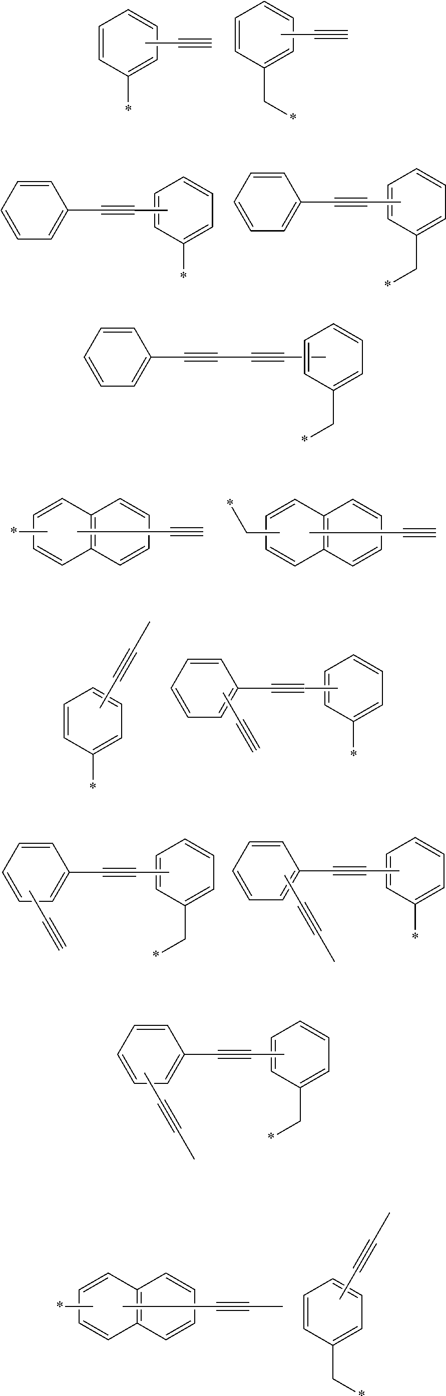

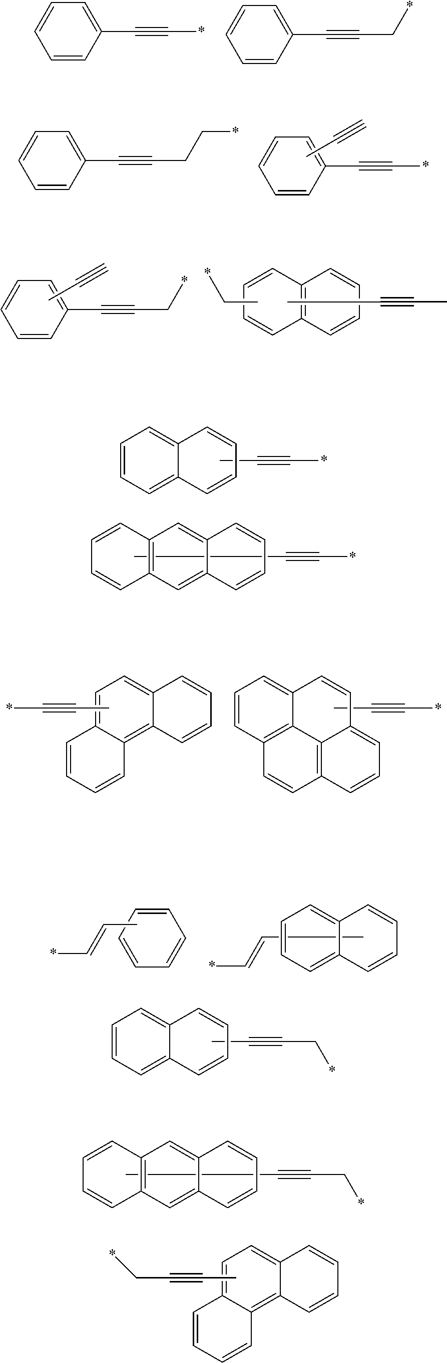

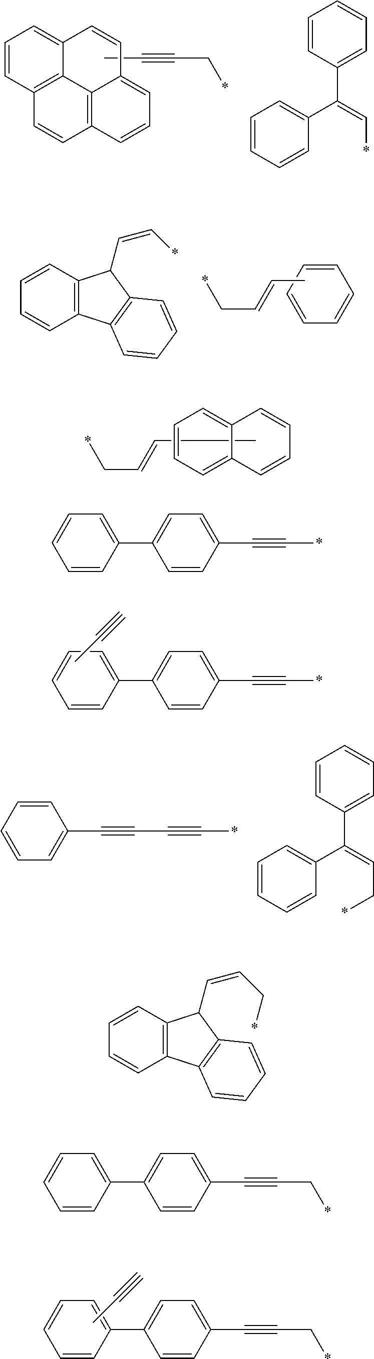

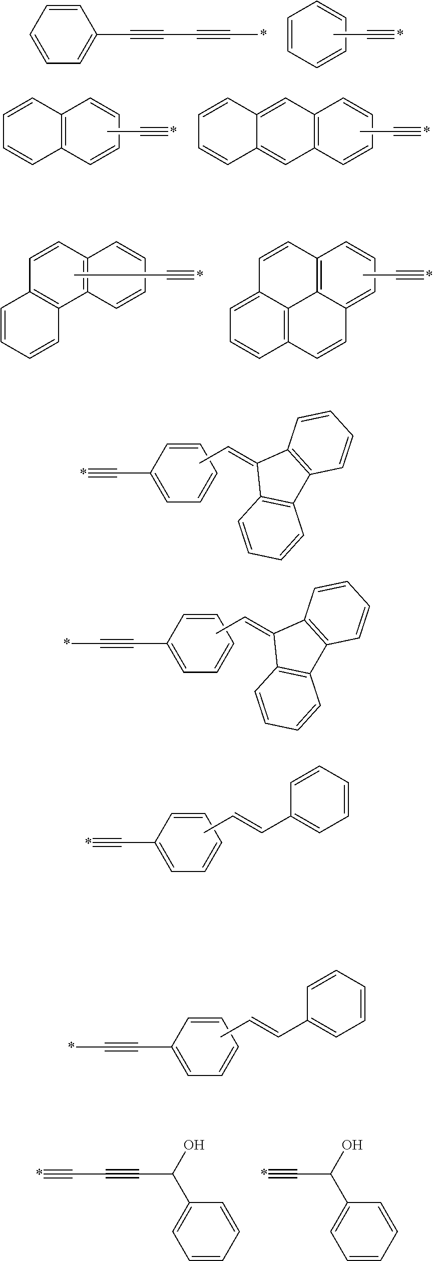

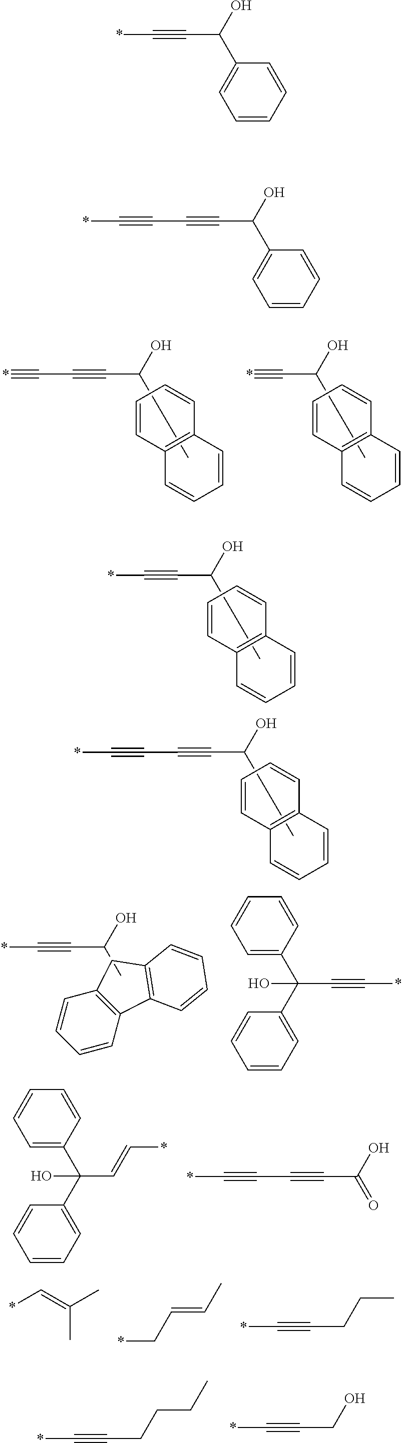

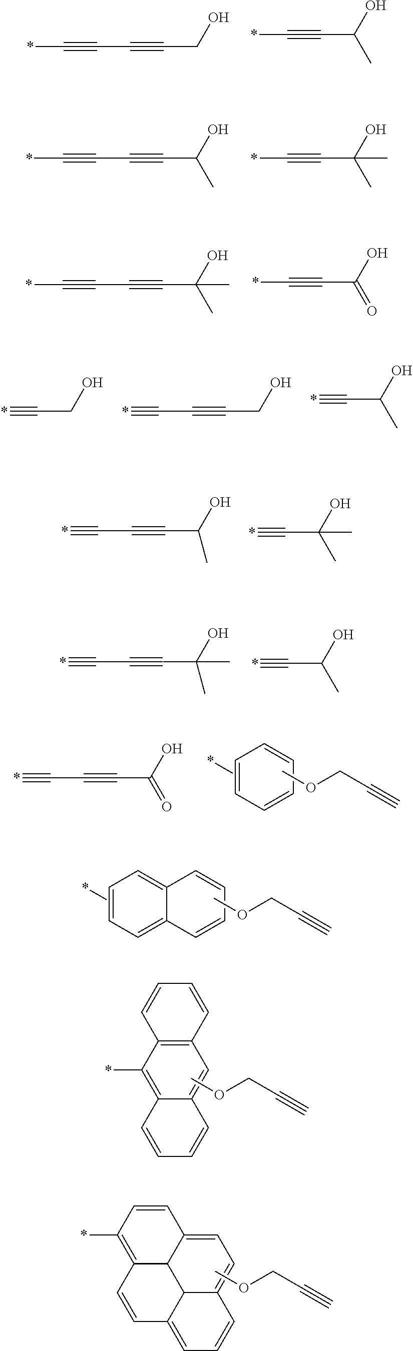

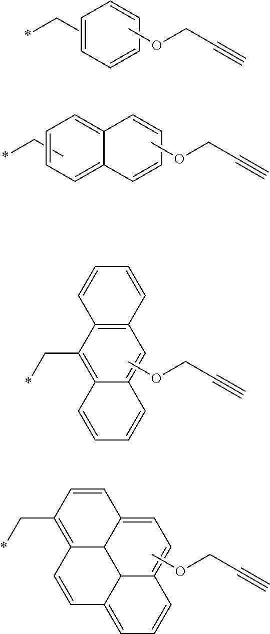

### (III-3-A2)

Preferably, the unit structures A are at least one type of unit structures selected from the following:

(Examples of the Unit Structures Derived from a Heterocyclic Ring)

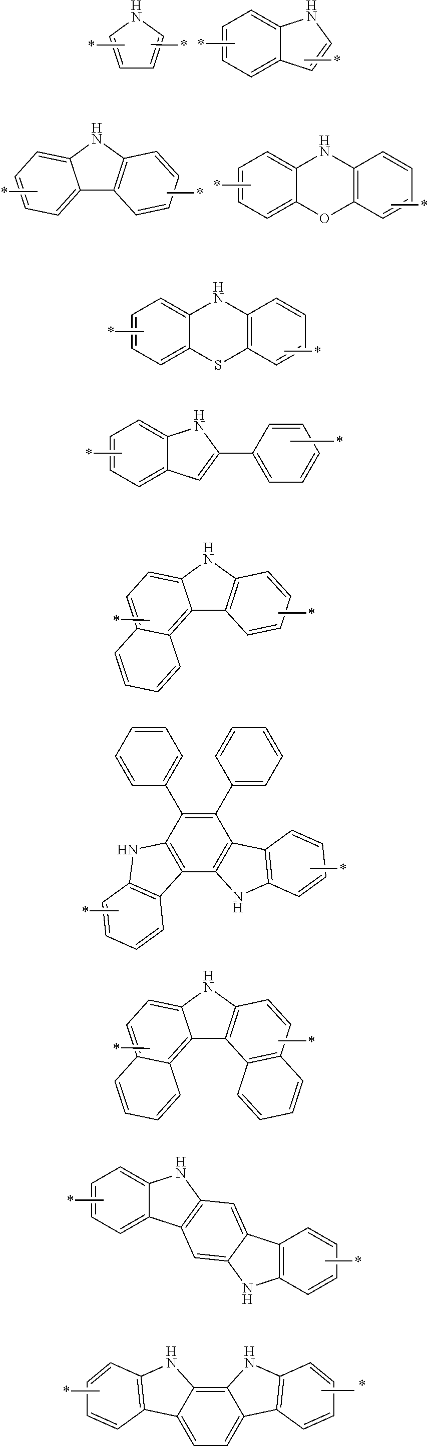

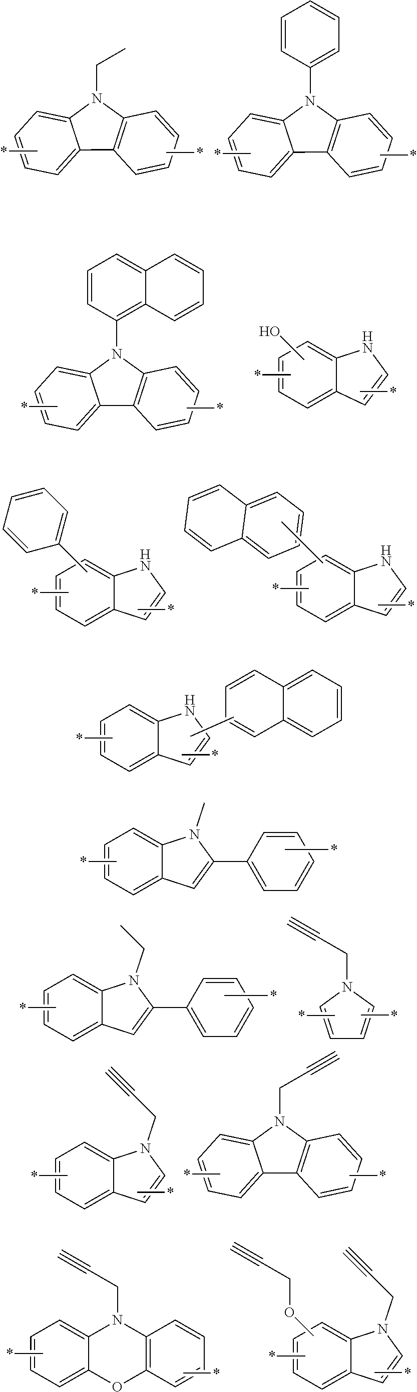

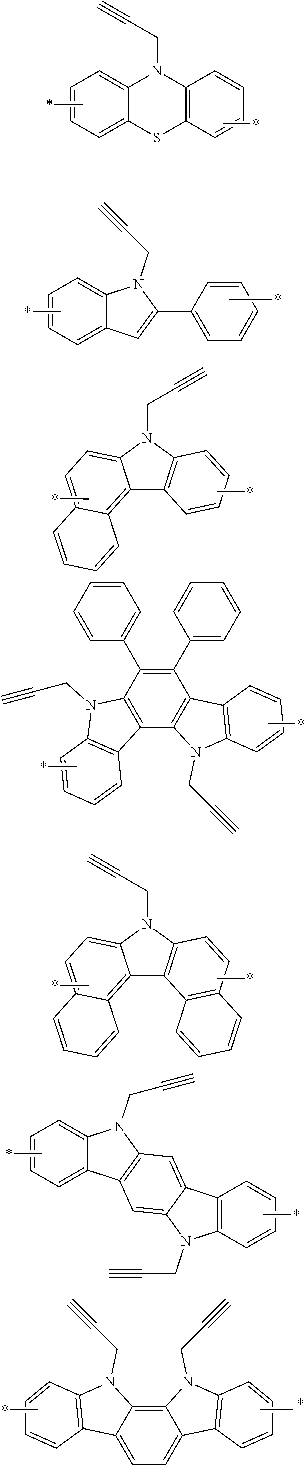

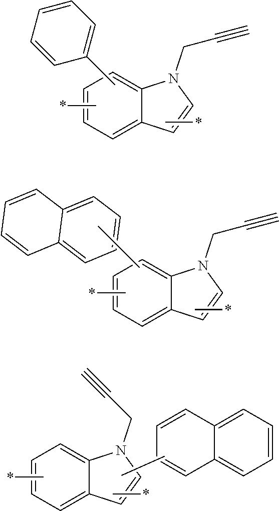

(Examples of the Unit Structures Derived from an Aromatic Hydrocarbon Having an Oxygen-Containing Substituent)

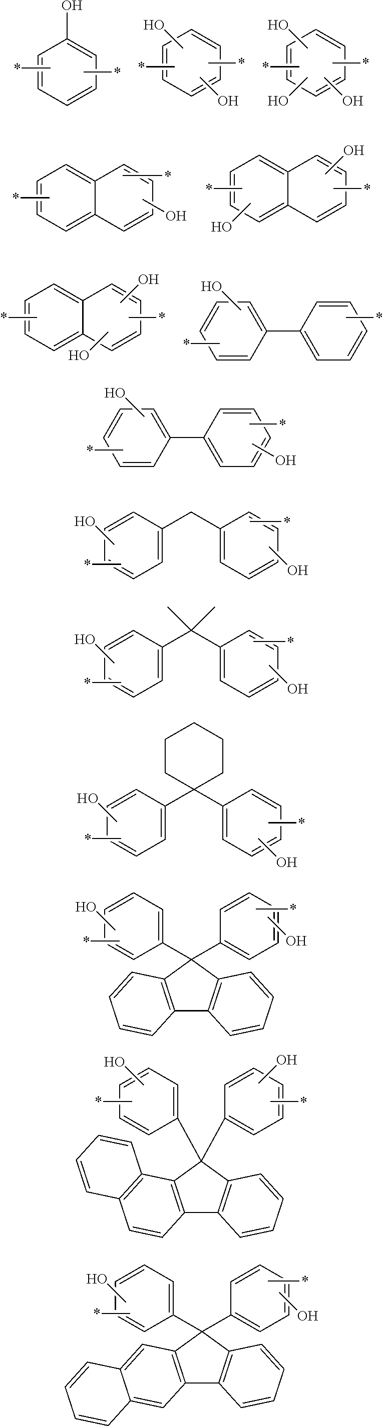

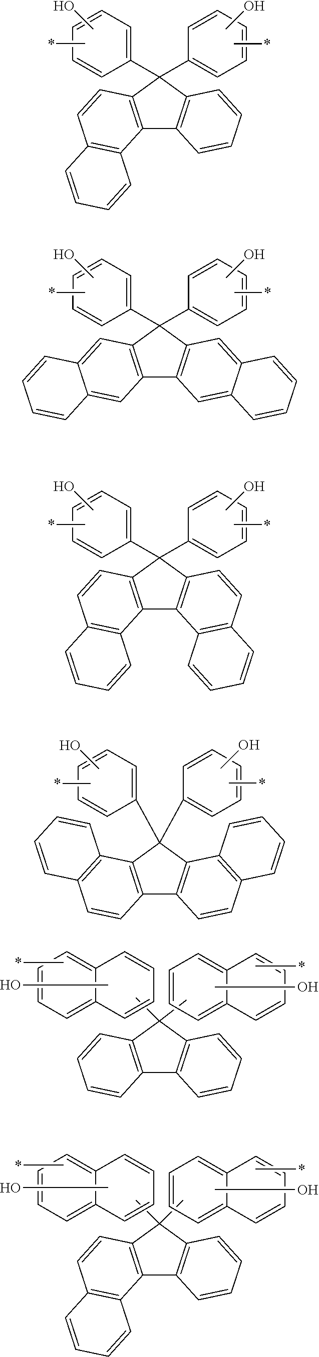

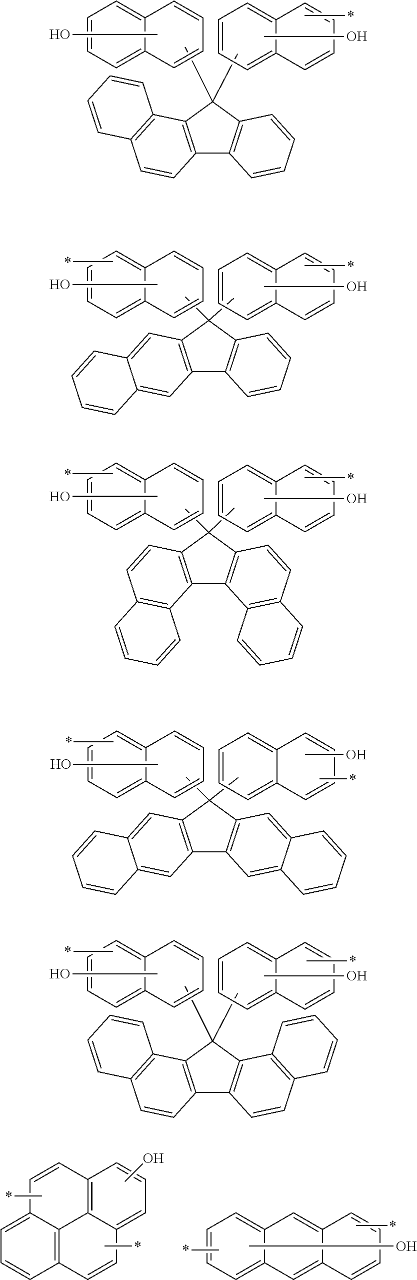

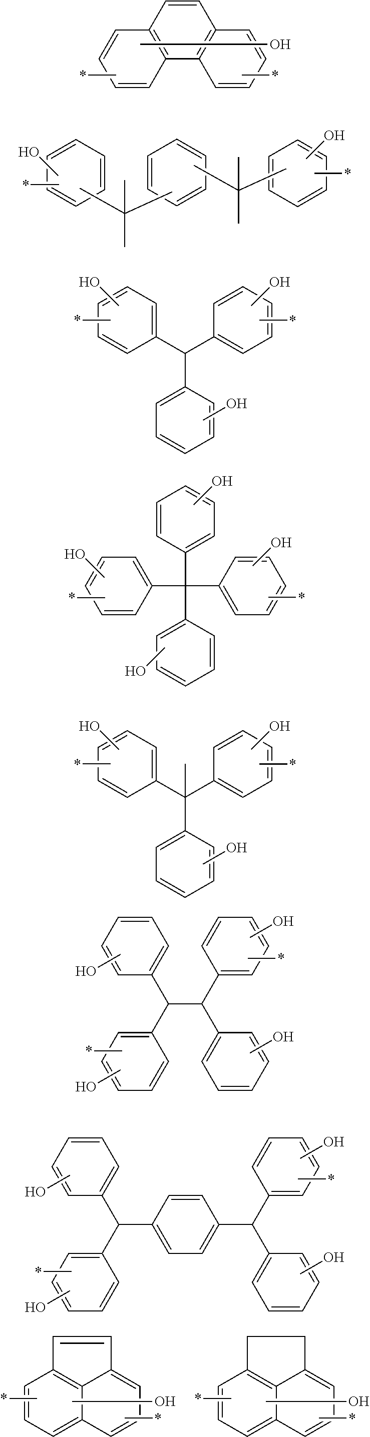

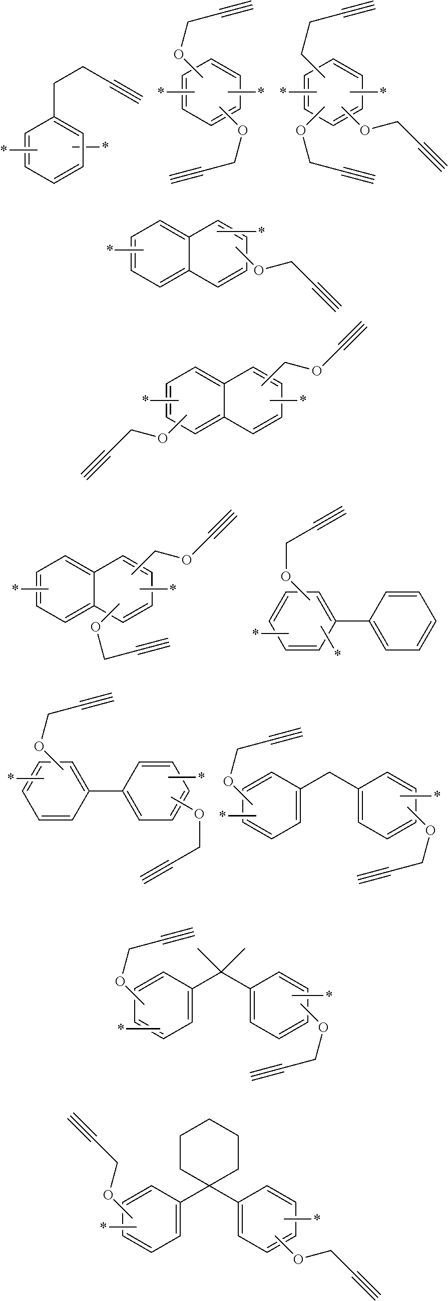

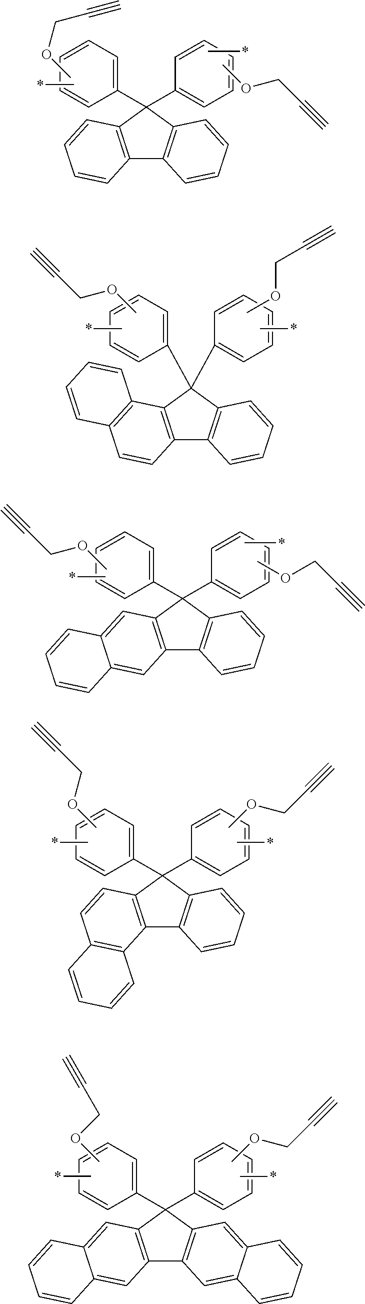

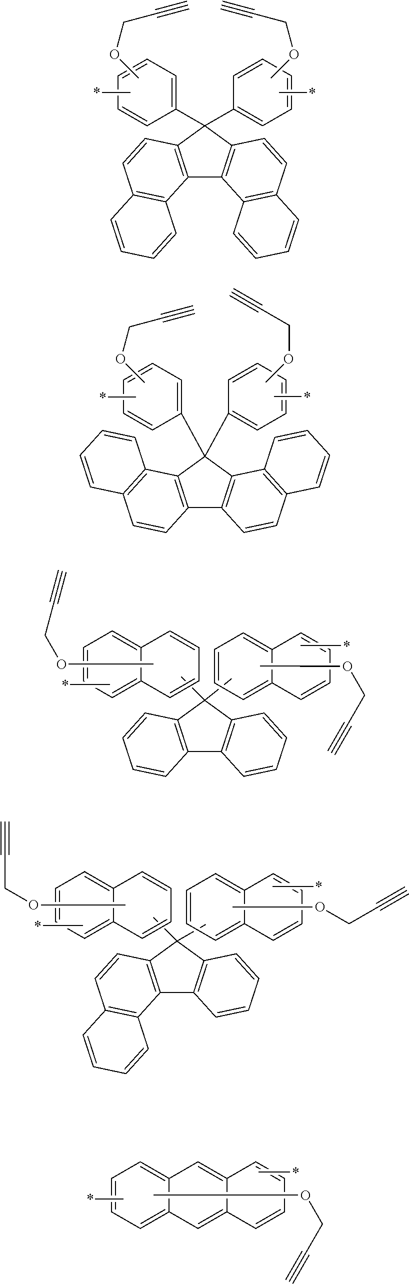

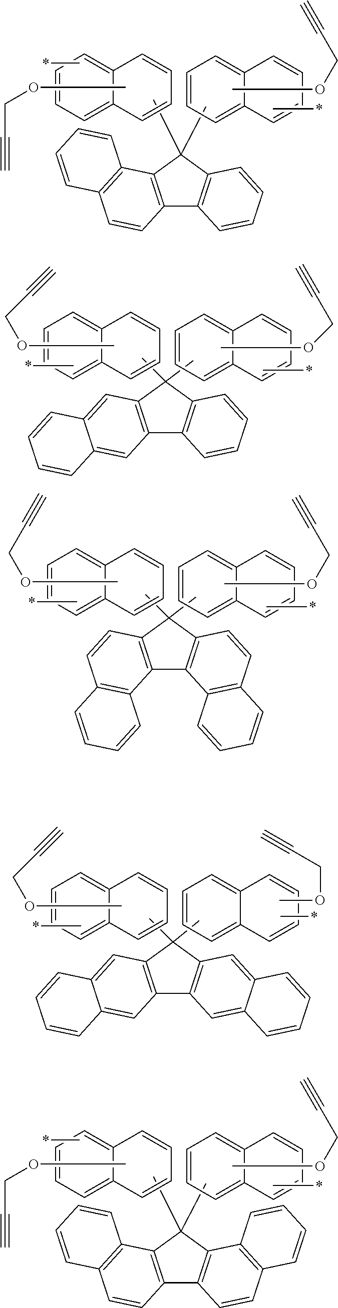

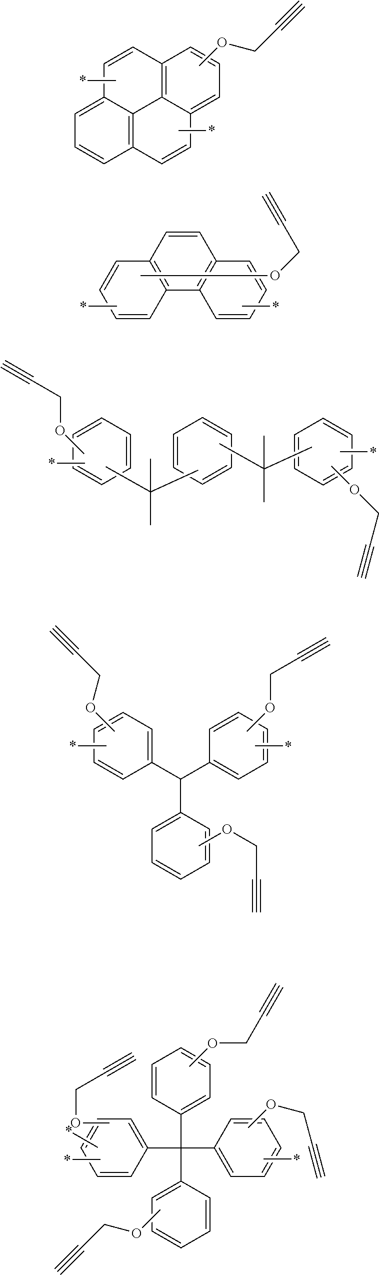

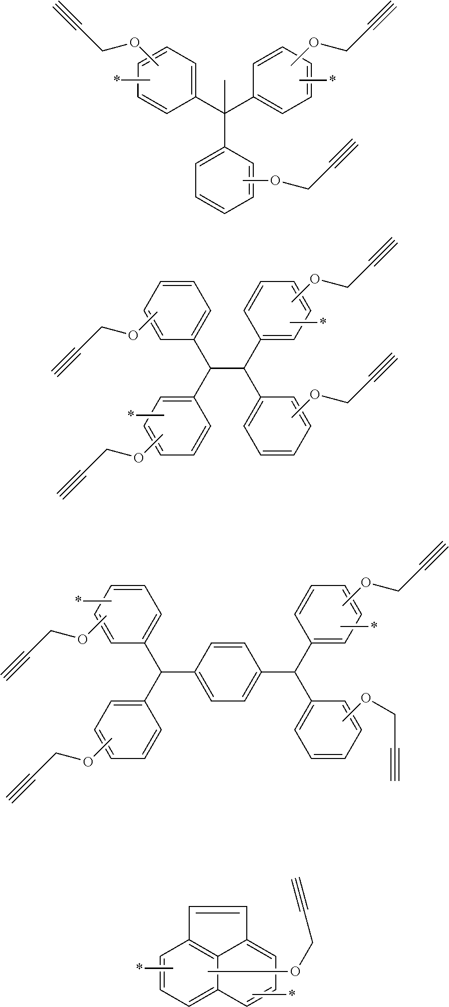

(Examples of the Unit Structures Derived from Aromatic Hydrocarbons Connected by —NH—)

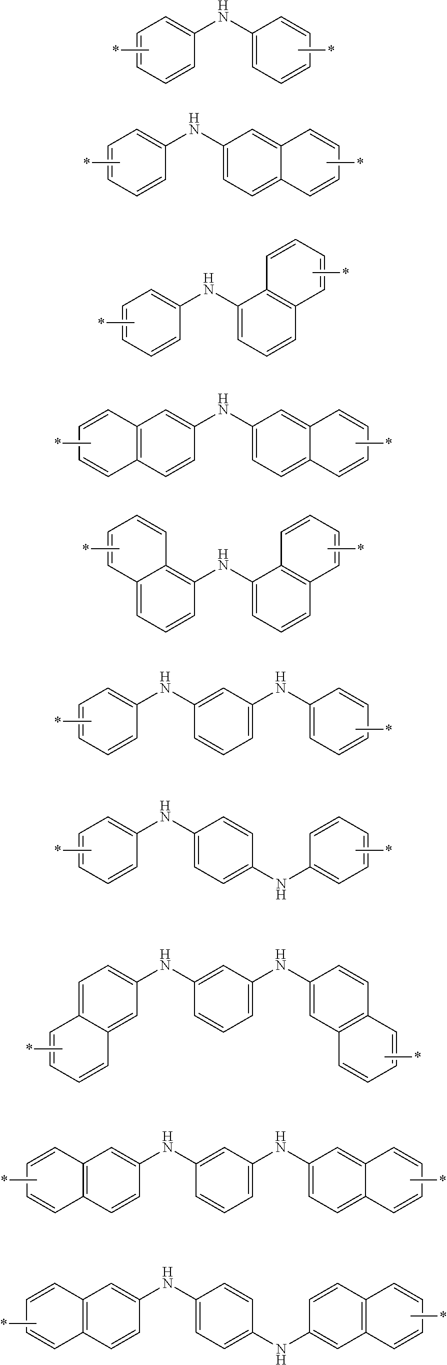

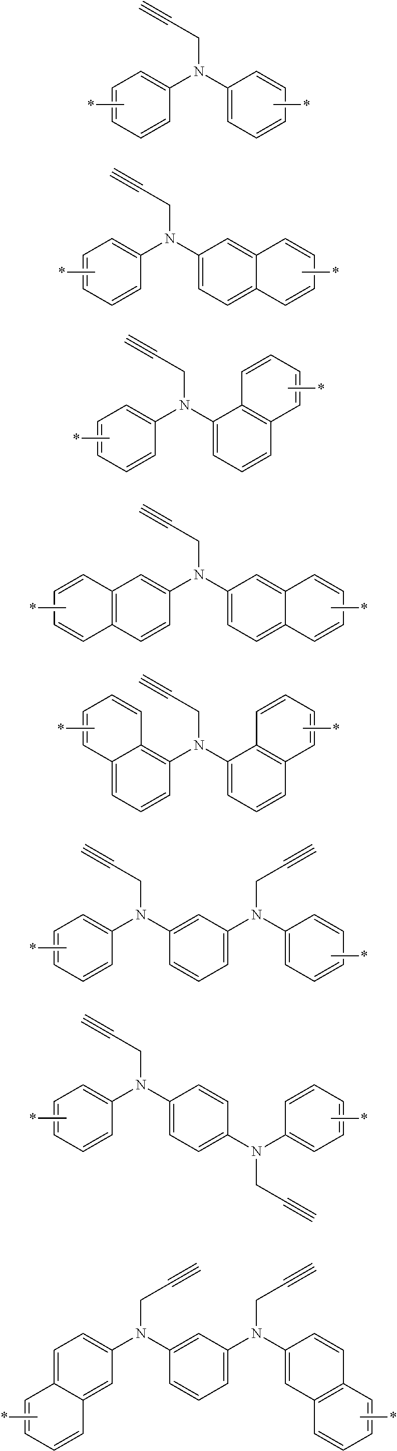

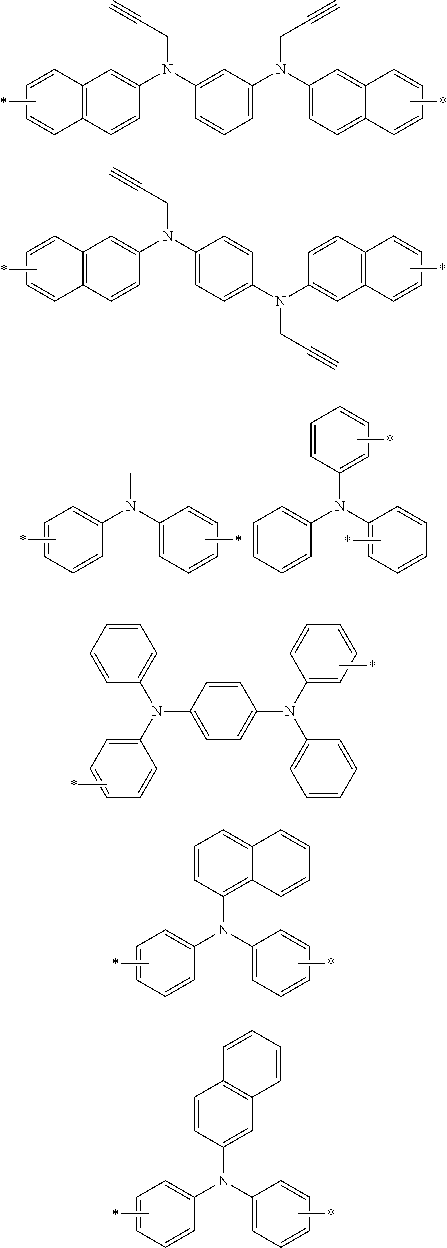

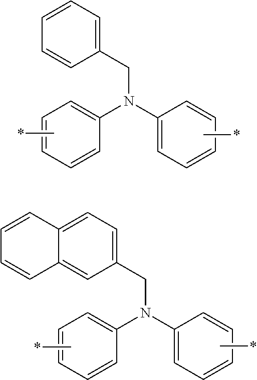

### (III-3-B0) Unit Structures B

The unit structures B are one, or two or more kinds of unit structures that contain a linking carbon atom capable of bonding to the aromatic ring in the unit structure A [see (I-1) “Novolac resins”] and include a structure represented by formula (B1), (B2), or (B3) described later in (III-3-B10) to (III-3-B14), in (III-3-B20) to (III-3-B23), and in (III-3-B30) to (III-3-B35), respectively.

### (III-3-B10) Formula (B1)

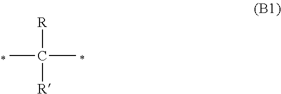

In the formula (B¹),

R and R′ each independently denote a hydrogen atom, an optionally substituted C6-C30 aromatic ring, an optionally substituted C3-C30 heterocyclic ring, or an optionally substituted C10 or lower, linear, branched, or cyclic alkyl group.

In the definitions of R and R′ in the formula (B1), the term “substituted”, the “aromatic ring”, and the “heterocyclic ring” are as described in (I-3), (I-4), and other sections hereinabove.

The two valence bonds in the formula (B1) can be covalently bonded to the aromatic rings in the unit structures A.

### (III-3-B11)

Examples of the “alkyl group” in the definitions of R and R′ in the formula (B1) include methyl group, ethyl group, n-propyl group, i-propyl group, cyclopropyl group, n-butyl group, i-butyl group, s-butyl group, t-butyl group, cyclobutyl group, 1-methyl-cyclopropyl group, 2-methyl-cyclopropyl group, n-pentyl group, 1-methyl-n-butyl group, 2-methyl-n-butyl group, 3-methyl-n-butyl group, 1,1-dimethyl-n-propyl group, 1,2-dimethyl-n-propyl group, 2,2-dimethyl-n-propyl group, 1-ethyl-n-propyl group, cyclopentyl group, 1-methyl-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, n-hexyl group, 1-methyl-n-pentyl group, 2-methyl-n-pentyl group, 3-methyl-n-pentyl group, 4-methyl-n-pentyl group, 1,1-dimethyl-n-butyl group, 1,2-dimethyl-n-butyl group, 1,3-dimethyl-n-butyl group, 2,2-dimethyl-n-butyl group, 2,3-dimethyl-n-butyl group, 3,3-dimethyl-n-butyl group, 1-ethyl-n-butyl group, 2-ethyl-n-butyl group, 1,1,2-trimethyl-n-propyl group, 1,2,2-trimethyl-n-propyl group, 1-ethyl-1-methyl-n-propyl group, 1-ethyl-2-methyl-n-propyl group, cyclohexyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2,2-dimethyl-cyclobutyl group, 2,3-dimethyl-cyclobutyl group, 2,4-dimethyl-cyclobutyl group, 3,3-dimethyl-cyclobutyl group, 1-n-propyl-cyclopropyl group, 2-n-propyl-cyclopropyl group, 1-i-propyl-cyclopropyl group, 2-i-propyl-cyclopropyl group, 1,2,2-trimethyl-cyclopropyl group, 1,2,3-trimethyl-cyclopropyl group, 2,2,3-trimethyl-cyclopropyl group, 1-ethyl-2-methyl-cyclopropyl group, 2-ethyl-1-methyl-cyclopropyl group, 2-ethyl-2-methyl-cyclopropyl group, 2-ethyl-3-methyl-cyclopropyl group, n-heptyl group, n-octyl group, n-nonyl group, and n-decyl group.

Preferably, R and R′ are each independently phenyl, naphthalenyl, anthracenyl, phenanthrenyl, naphthacenyl, or pyrenyl.

### (III-3-B12)

In principle, the two valence bonds in the formula (B1) are bonded to aromatic rings in dissimilar structures having an aromatic ring (corresponding to the unit structures A). At a polymer terminal, however, the valence bond is bonded to a polymer terminal group [see (III-3-B4) described later].

For example, the unit structure including a structure represented by the formula (B1) may include the form of dimer or trimer structure in which two or three identical or differing structures of the formula (B1) are bonded via a divalent or trivalent linking group. In this case, as illustrated in formula (B11) below, one of the two valence bonds in each of the structures of the formula (B1) is bonded to the linking group.

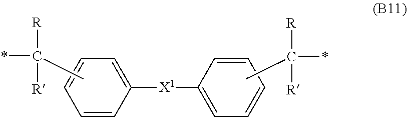

Examples of such linking groups include linking groups having two or three aromatic rings (corresponding to the unit structures A). Specific examples of the divalent or trivalent linking groups include the divalent linking groups (L1) below that are illustrated in the formula (B11) above.

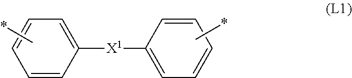

[X¹ denotes a single bond, a methylene group, an oxygen atom, a sulfur atom, or —N(R⁵)—, and R⁵ denotes a hydrogen atom or a C1-C20 hydrocarbon group (that may be a chain hydrocarbon or a cyclic hydrocarbon (that may be aromatic or non-aromatic))]. Examples further include divalent or trivalent linking groups of formulas (L2) and (L3) below.

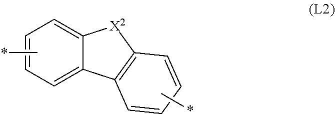

[X² denotes a methylene group, an oxygen atom, or —N(R⁶)—, and R⁶ denotes a hydrogen atom, a C1-C10 aliphatic hydrocarbon group, or a C5-C20 aromatic hydrocarbon group].

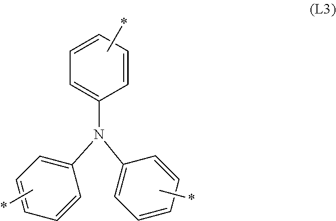

Examples further include a divalent linking group of formula (L4) below that can undergo an addition reaction of an acetylide with a ketone to form a covalent bond with the linking carbon atom.

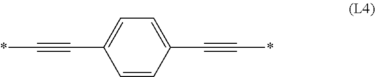 [SMILES: *C#Cc1ccc(C#C*)cc1]

### (III-3-B13)

When at least one of R or R′ in the formula (B1) is an aromatic ring, the aromatic ring [see for example, Ar in formula (B12) below] may be additionally bonded to the other unit structure B. Specifically, when at least one of R or R′ in the formula (B1) is an aromatic ring, and when the aromatic ring is bonded to the other unit structure B while one of the valence bonds in the formula (B1) is bonded to the aromatic ring in the unit structure A, the unit structure of the formula (B1) may be regarded as a single unit structure C equivalent to a composite unit structure A-B.

That is, the structure represented by the formula (B1) may be included in a composite unit structure A-B as such a unit structure C. In this case, the remaining valence bond in the formula (B1) will be bonded, for example, to a polymer terminal group or to an aromatic ring in other polymer chain to form a crosslink.

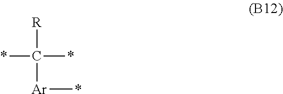

When, for example, one valence bond of the linking carbon atom is bonded to a polymer terminal T (such as a hydrogen atom; a functional group, such as a hydroxyl group or an unsaturated aliphatic hydrocarbon group; a terminal unit structure A; or a unit structure A in other polymer chain) as illustrated in formula (C1) below, the unit structure may be regarded as a single unit structure C equivalent to a composite unit structure A-B and may replace at least one composite unit structure A-B.

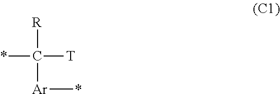

That is, the aromatic ring in the formula (C1) [Ar in the formula (C1)] may be bonded to the other unit structure B and the remaining valence bond of the linking carbon atom illustrated in the formula (C1) may be bonded to the aromatic ring in the unit structure A, thereby extending the polymer chain.

In the present specification, any reference to a bonding to the unit structure A may be interpreted as including a bonding to the aromatic ring in the unit structure C, even if not explicitly stated. Furthermore, in the present specification, any reference to a bonding to the unit structure B may be interpreted as including a bonding to the linking carbon atom in the unit structure C, even if not explicitly stated.

### (III-3-B14)

Some specific examples of the unit structures B including a structure represented by the formula (B1) are illustrated below. * basically indicates a bonding site to the unit structure A. It is needless to mention that the illustrated structures may be part of the whole unit structure.

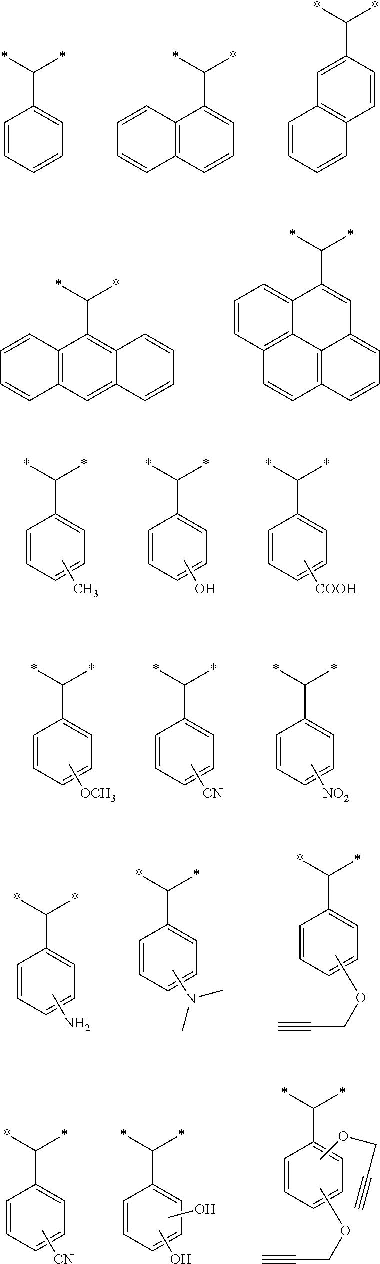

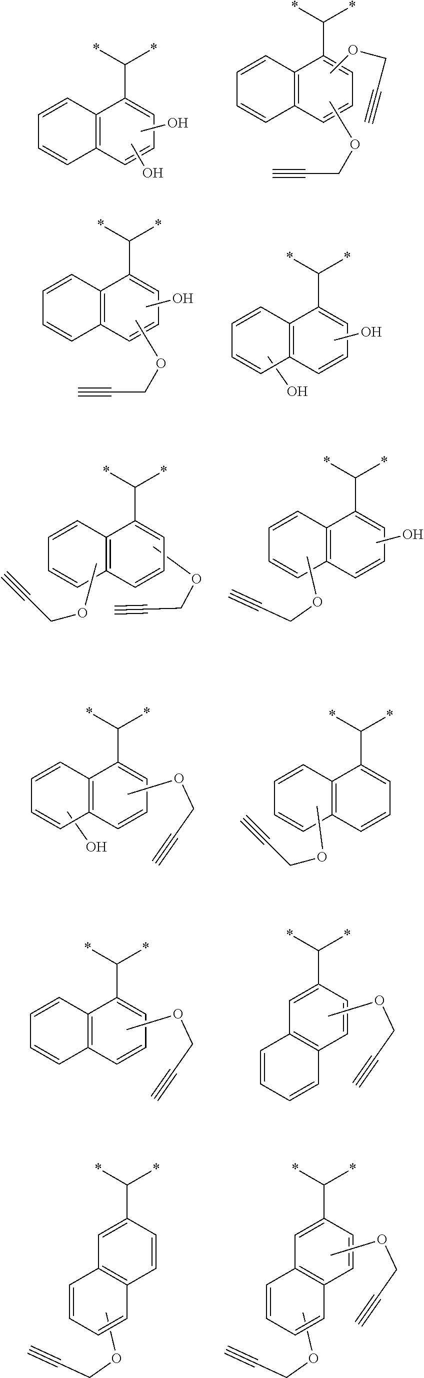

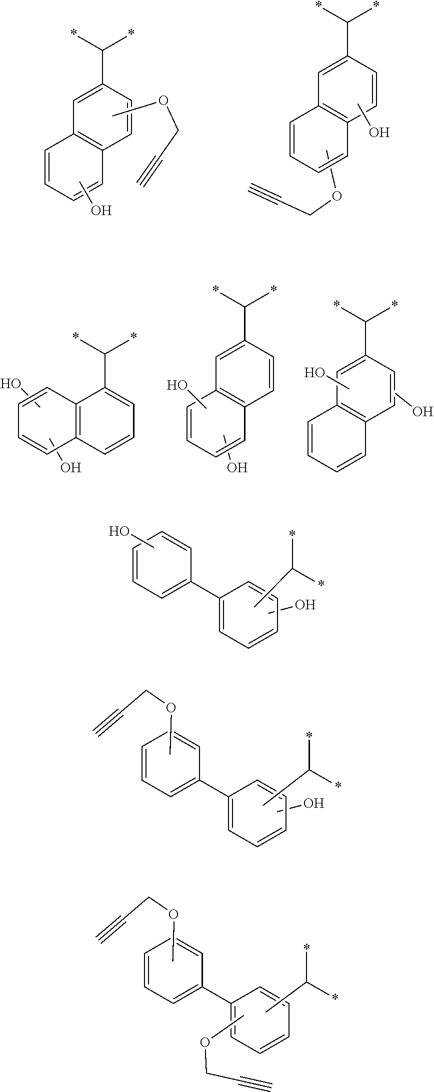

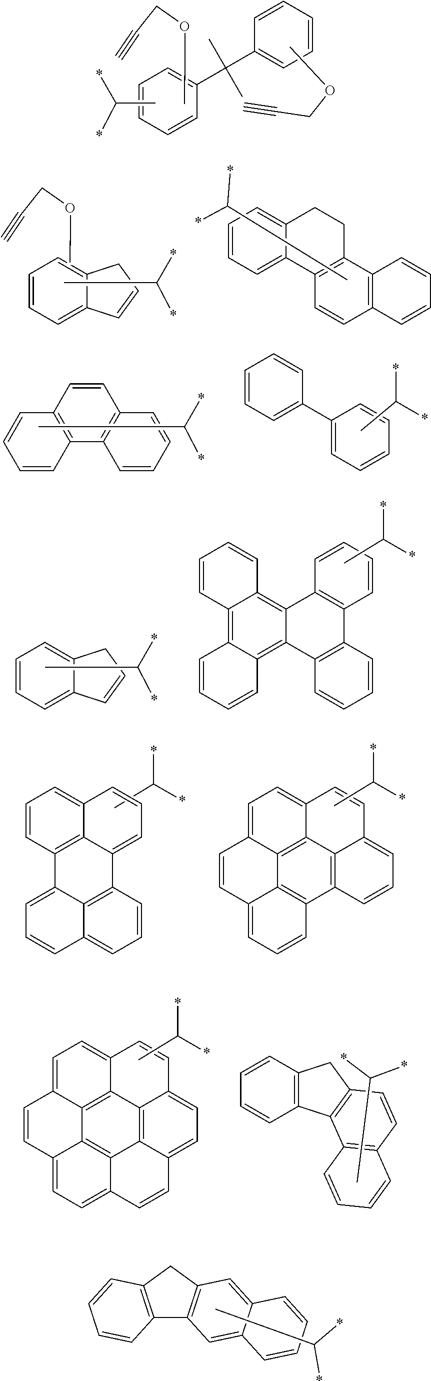

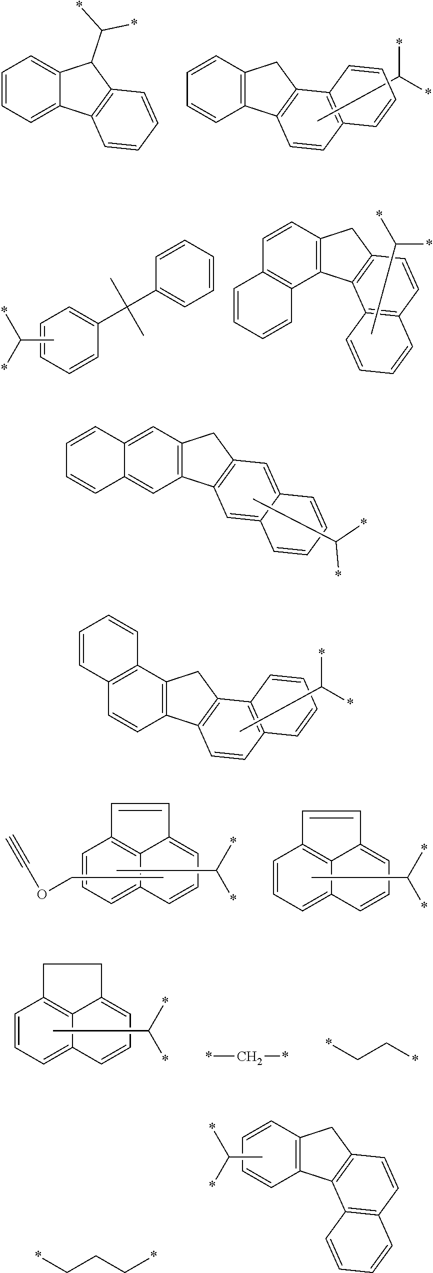

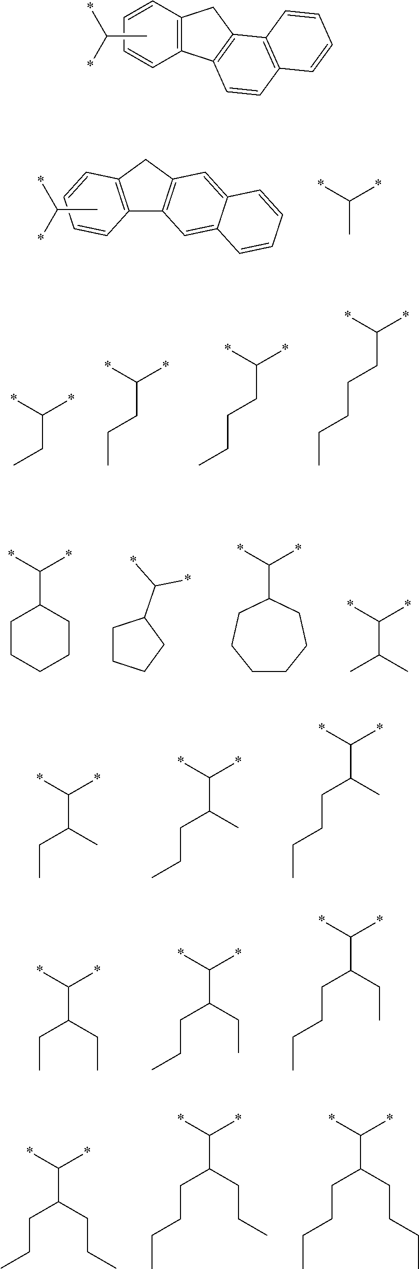

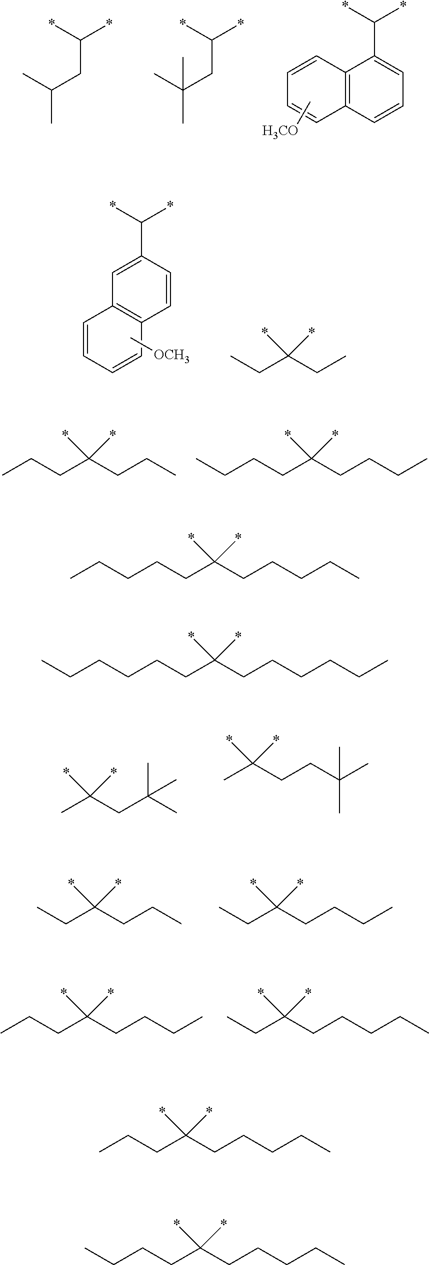

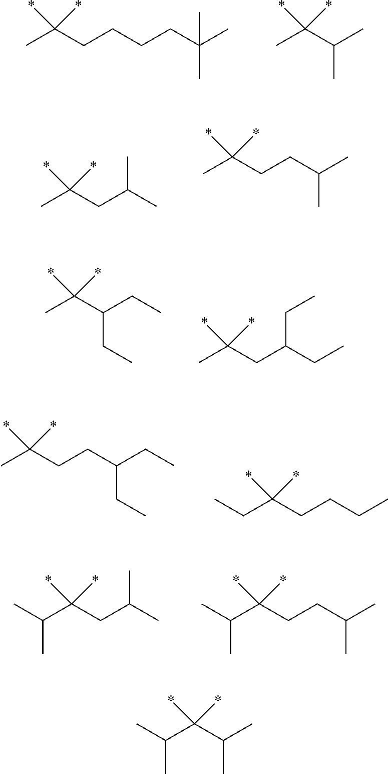

### (III-3-B20) Formula (B2)

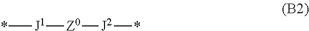

In the formula (B2),

Z⁰ denotes an optionally substituted C6-C30 aromatic ring residue, aliphatic ring residue, or organic group including two aromatic or aliphatic rings connected to each other via a single bond. Examples of the organic groups including two aromatic or aliphatic rings connected to each other via a single bond include divalent residues, such as biphenyl, cyclohexylphenyl, and bicyclohexyl.

In the definition of Z⁰ in the formula (B2), the “aromatic ring”, the term “substituted”, the “aliphatic ring”, and the “residue” are the same as described in (I-2), (I-3), and (I-5).

J¹ and J² each independently denote a direct bond or an optionally substituted divalent organic group. The divalent organic group is preferably a C1-C6 linear or branched alkylene group optionally substituted with a substituent, such as a hydroxyl group, an aryl group (such as a phenyl group or a substituted phenyl group), or a halo group (for example, fluorine). Examples of the linear alkylene groups include methylene group, ethylene group, propylene group, butylene group, pentylene group, and hexylene group.

### (III-3-B21)

Similarly to (III-3-B12) for the formula (B1), the unit structure including a structure represented by the formula (B2) may include the form of dimer or trimer structure in which two or three identical or differing structures of the formula (B2) are bonded to a divalent or trivalent linking group.

### (III-3-B22)

Embodiments of the formula (B2) include those in which the unit structure contains an aromatic ring [Z⁰ in the formula (B2)]. Thus, similarly to (III-3-B13) for the formula (B1), the aromatic ring [for example, an aromatic ring in Z⁰_{Ar} in formula (B21) below] may be additionally bonded to the other unit structure B [via the vertical valence bond in the formula (B21)].

Specifically, in an embodiment in which the formula (B2) contains an aromatic ring, the aromatic ring in the formula (B2) may be bonded to the other unit structure B while one of the valence bonds in the formula (B2) may be bonded to the aromatic ring in the unit structure A. In this case, the unit structure represented by the formula (B2) may be regarded as a single unit structure C equivalent to a composite unit structure A-B.

That is, the structure represented by the formula (B2) may be included in a composite unit structure A-B as such a unit structure C. In this case, the remaining valence bond in the formula (B2) will be bonded, for example, to a polymer terminal group or to an aromatic ring in other polymer chain to form a crosslink.

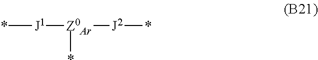

[In the formula (B21),
Z⁰_{Ar} is an optionally substituted C6-C30 aromatic ring residue or organic group including two aromatic rings or aliphatic rings connected to each other via a single bond and having at least one aromatic ring; the valence bond extending downward from Z⁰_{Ar} belongs to the aromatic ring in Z⁰_{Ar}; and
J¹ and J² are the same as defined in the formula (B2).]

When one valence bond of the linking carbon atom in the above case is bonded to a polymer terminal T (such as a hydrogen atom; a functional group, such as a hydroxyl group or an unsaturated aliphatic hydrocarbon group; a terminal unit structure A; or a unit structure A in other polymer chain) as illustrated in the formula (C2) below, the unit structure may be regarded as a single unit structure C equivalent to a composite unit structure A-B and may replace at least one composite unit structure A-B.

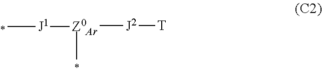

[In the formula (C2),
Z⁰_{Ar}, J¹, and J² are the same as defined in the formula (B21), and
T denotes the polymer terminal.]
   That is, the aromatic ring in the formula (C2) [the aromatic ring in Z⁰_{Ar} in the formula (C2)] may be bonded to the other unit structure B and the remaining valence bond of the linking carbon atom illustrated in the formula (C2) may be bonded to the aromatic ring in the unit structure A, thereby extending the polymer chain.

### (III-3-B23)

Some specific examples of the unit structures including a structure represented by the formula (B²) are illustrated below. * indicates a bonding site to the unit structure A. It is needless to mention that the illustrated structures may be part of the whole unit structure.

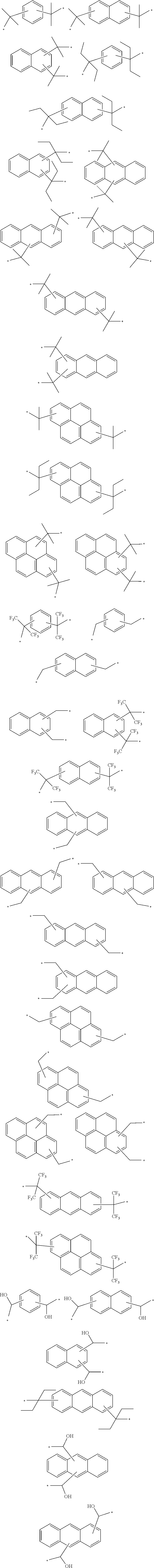

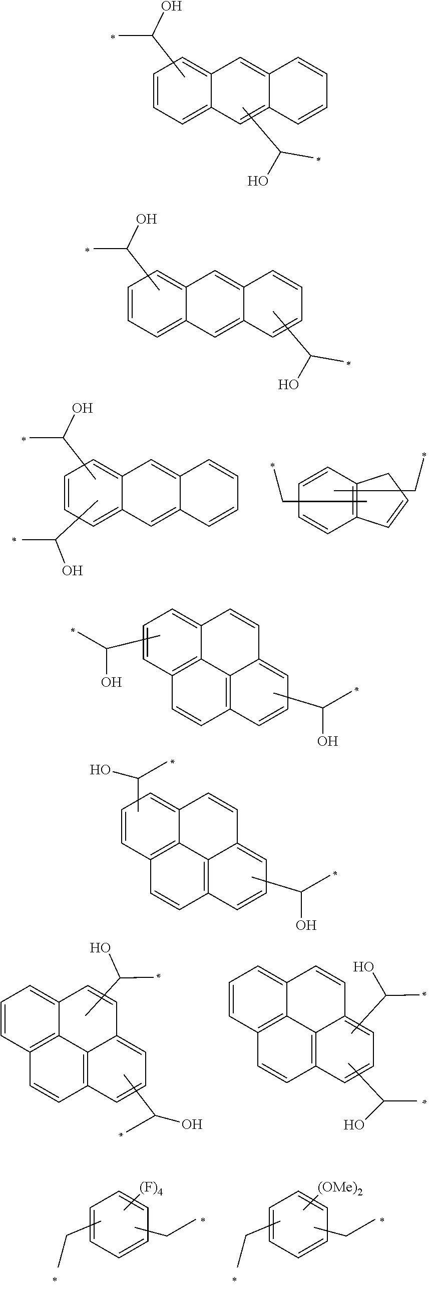

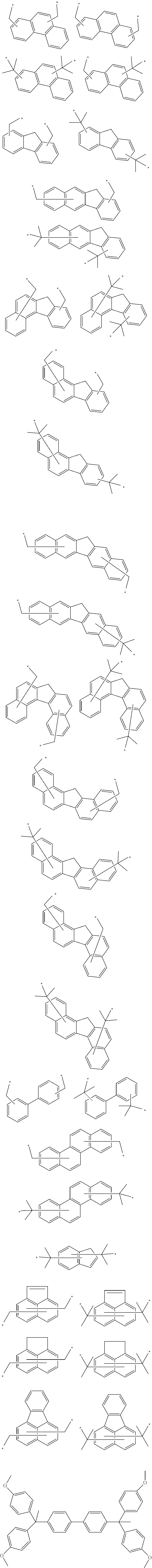

### (III-3-B30) Formula (B3)

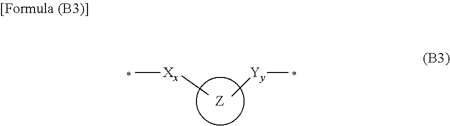

In the formula (B3),
Z is an optionally substituted C4-C25 monocyclic ring or bicyclic, tricyclic, or tetracyclic condensed ring. Here, the number of carbon atoms indicates the number of carbon atoms constituting the ring skeleton of the monocyclic ring or the bicyclic, tricyclic, or tetracyclic condensed ring except substituents. When the monocyclic ring or the condensed ring is a heterocyclic ring, the number of carbon atoms does not include the number of heteroatoms constituting the heterocyclic ring.

The monocyclic ring is a non-aromatic monocyclic ring; and at least one of the monocyclic rings constituting the bicyclic, tricyclic, or tetracyclic ring is a non-aromatic monocyclic ring, and the remaining monocyclic ring or rings may be aromatic monocyclic rings or non-aromatic monocyclic rings.

The monocyclic ring or the bicyclic, tricyclic, or tetracyclic condensed ring may be further condensed with one or more aromatic rings to form a pentacyclic or higher condensed ring. The number of carbon atoms in the pentacyclic or higher condensed ring is preferably 40 or less. The number of carbon atoms here indicates the number of carbon atoms constituting the ring skeleton of the pentacyclic or higher condensed ring except substituents. When the pentacyclic or higher condensed ring is a heterocyclic ring, the number of carbon atoms does not include the number of heteroatoms constituting the heterocyclic ring.

X and Y denote identical or different —CR³¹R³²— groups, and R³¹ and R³² are the same as or different from each other and each denote a hydrogen atom or a C1-C6 hydrocarbon group.

The letters x and y indicate the numbers of X and Y, respectively, and are each independently 0 or 1.

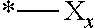

is bonded to any carbon atom (referred to as “carbon atom 1”) constituting any of the non-aromatic monocyclic rings in Z (when x=1) or extends from the carbon atom 1 (when x=0).

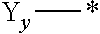

is bonded to any carbon atom (referred to as “carbon atom 2”) constituting any of the non-aromatic monocyclic rings in Z (when y=1) or extends from the carbon atom 2 (when y=0). The carbon atom 1 and the carbon atom 2 may be the same as or different from each other. The carbon atom 1 and the carbon atom 2 different from each other may belong to the same non-aromatic monocyclic ring or may belong to different non-aromatic monocyclic rings.

Furthermore, the formula (B3) may optionally contain a linking carbon atom other than the carbon atom 1 and the carbon atom 2 [see (III-3-B33) described later].

When Z is a tricyclic or higher condensed ring, the one or two non-aromatic monocyclic rings having the carbon atoms 1 and 2 in the formula (B3) may have any permutational positional relationship with the other monocyclic ring or rings in the condensed ring. When the carbon atom 1 and the carbon atom 2 belong to different non-aromatic monocyclic rings (referred to as the “non-aromatic monocyclic ring 1” and the “non-aromatic monocyclic ring 2”, respectively), the permutational positional relationship between the non-aromatic monocyclic ring 1 and the non-aromatic monocyclic ring 2 in the condensed ring is not limited.

### (III-3-B31)

Embodiments of the unit structures of the formula (B3) include formula (B31) illustrated below.

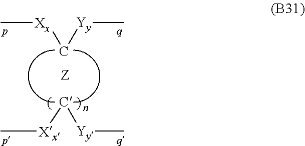

Z is an optionally substituted 4- to 17-membered monocyclic, bicyclic, tricyclic, or tetracyclic organic group, wherein the monocyclic ring or at least one of the monocyclic rings constituting the organic group is a non-aromatic monocyclic ring and the organic group has a maximum of four non-aromatic monocyclic rings. The remaining monocyclic ring or rings are aromatic rings. The rings may be further condensed with an additional aromatic monocyclic ring or rings to form a pentacyclic or higher polycyclic organic group.

Here, the non-aromatic monocyclic ring, the non-aromatic bicyclic ring, the non-aromatic tricyclic ring, and the non-aromatic tetracyclic ring are as described in (I-5) hereinabove.

Examples of the aromatic monocyclic rings and the aromatic rings include those illustrated in (I-3) hereinabove. For example, optionally substituted benzene rings, naphthalene rings, anthracene rings, and pyrene rings are preferable.

The formula (B31) illustrates individual carbon atoms C and C′ [linking carbon atoms described in (I-1)] among the atoms constituting the ring moiety of the non-aromatic monocyclic ring. Of these carbon atoms, the linking carbon atom C is always present but the linking carbon atom C′ is optional. The letter n in the formula (B31) indicating the number of C′ is 0 to 2. Preferably, n is 0.

X, Y, X′, and Y′ denote identical or different —CR¹R²— groups. R¹ and R² are the same as or different from each other and each denote a hydrogen atom or a C1-C3 hydrocarbon group. These linking groups are optional. That is, x, y, x′, and y′ indicating the numbers (0 or 1) of X, Y, X′, and Y′, respectively, may be all 0.

The letters p, q, p′, and q′ indicate the numbers of a valence bond and each independently denote 0 or 1. When the number is 0, the valence bond is meant to be replaced with a hydrogen atom.

In principle, these valence bonds are bonded to aromatic rings in dissimilar structures having an aromatic ring (corresponding to the unit structures A). At a polymer terminal, however, the valence bond is bonded to a polymer terminal group [see (III-3-B4) described later].

To form a polymer chain, at least two valence bonds are necessary. When n is 0, p and q are 1. When n is 1, assuming that at least one valence bond extends from each of C and C′ (the linking carbon atoms), at least one of p or q, and at least one of p′ or q′ are each 1. When n is 2, similarly, at least one of p or q, and at least one of p′ or q′ in each C′ are each 1.

When the unit structure has two or more valence bonds, the extra valence bond(s) will be bonded, for example, to a polymer terminal group or to an aromatic ring in other polymer chain to form a crosslink.

### (III-3-B32)

Similarly to (III-3-B12) for the formula (B1), the unit structure may be in the form of dimer or trimer structure in which two or three identical or differing structures of the formula (B3) are bonded to a divalent or trivalent linking group.

In the case of the formula (B31), either of the valence bonds p and q in each structure of the formula (B31) is bonded to the linking group. Furthermore, n is not 0, and one valence bond is provided from the linking carbon atom C and at least one valence bond is provided from the linking carbon atom C′.

### (III-3-B33)

Some specific examples of the organic groups including a structure represented by formula (B3) are illustrated below. The bonding sites to the unit structures A are not particularly limited. It is needless to mention that the illustrated structures may be part of the whole unit structure.

In some of the following examples, the number of valence bonds (*) exceeds 2. The extra valence bonds may be used to, for example, form bonds to aromatic rings in other polymer chains to establish crosslinking.

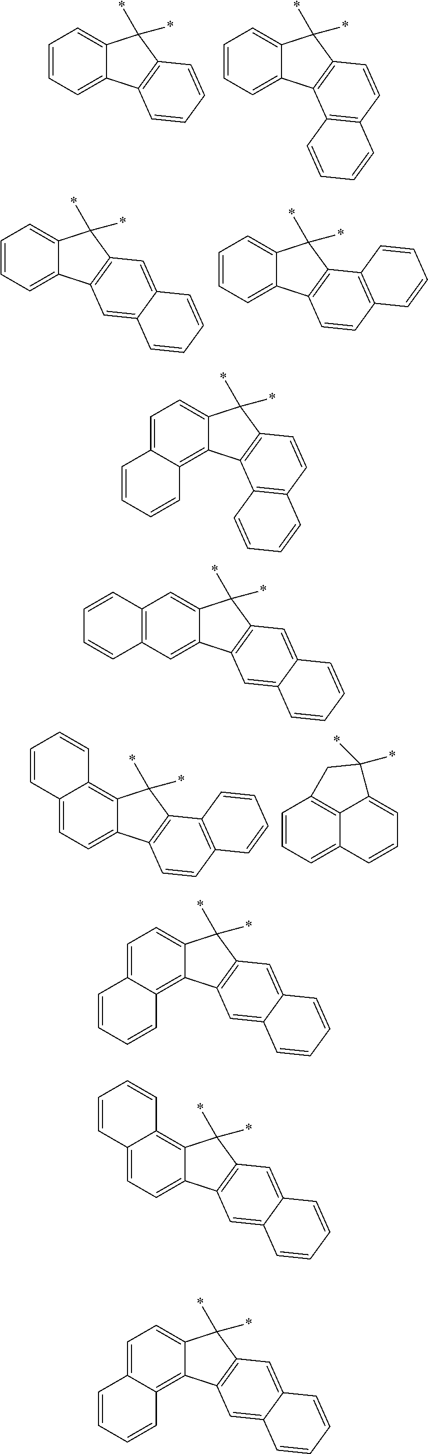

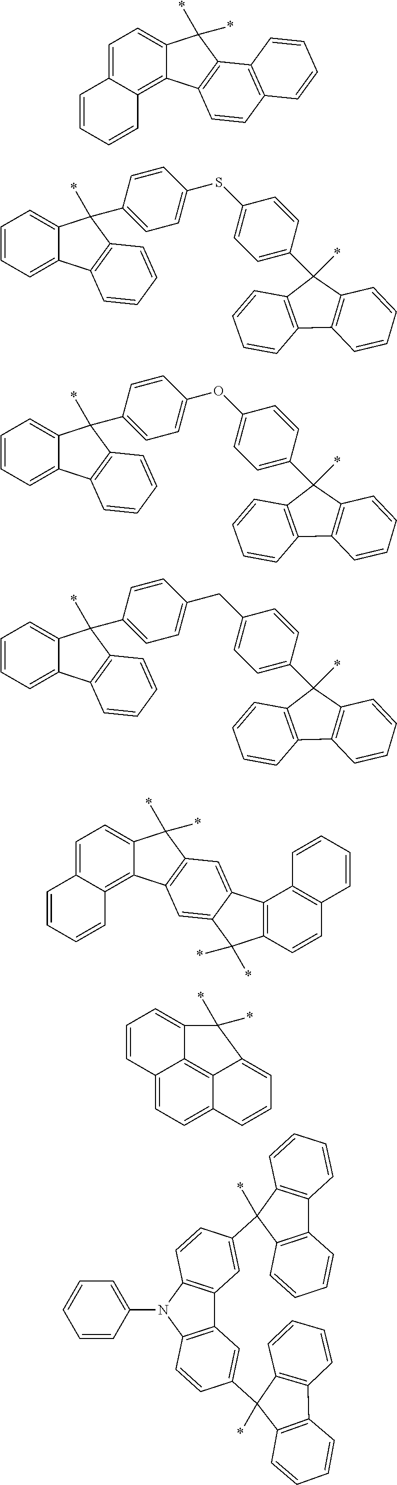

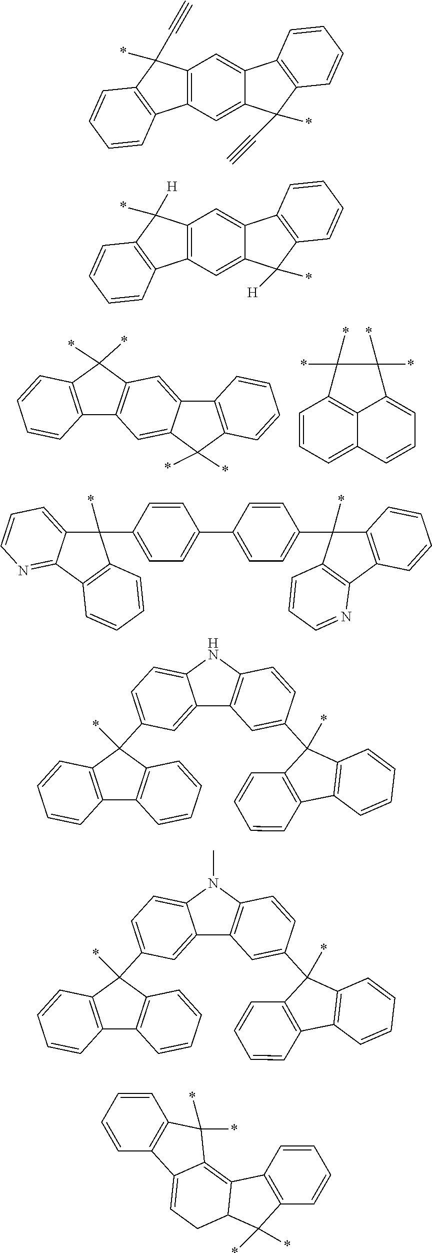

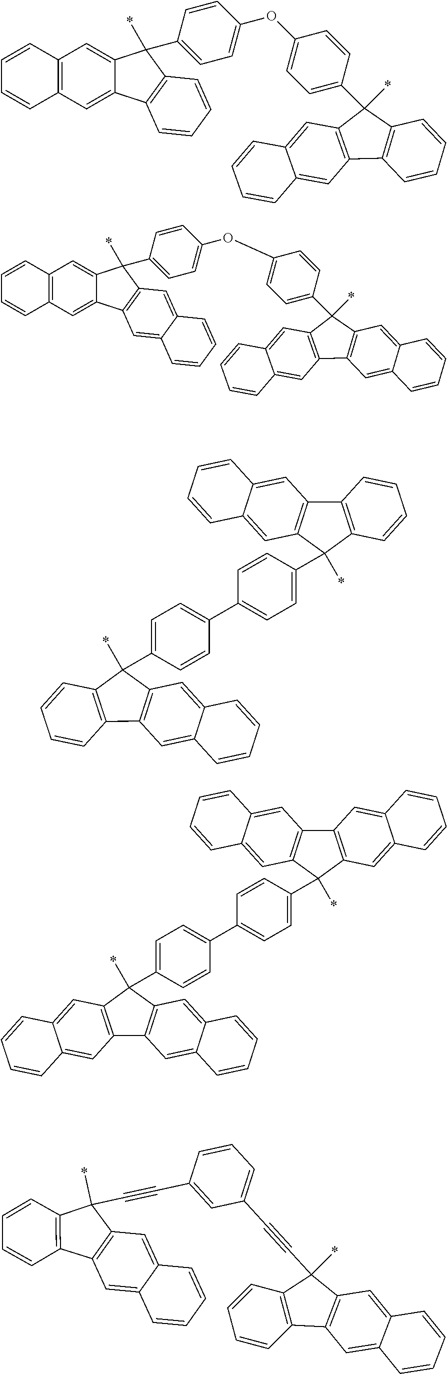

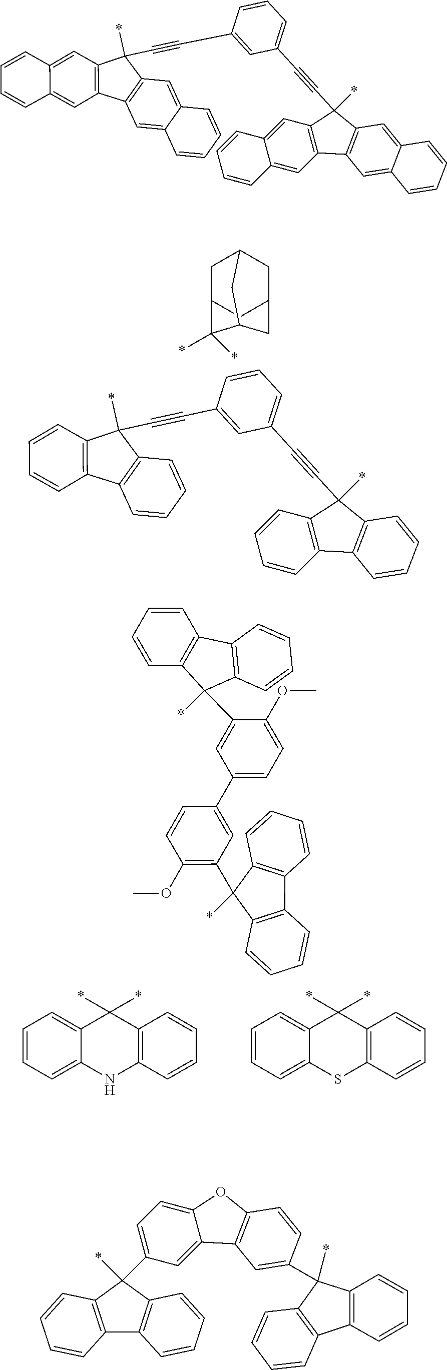

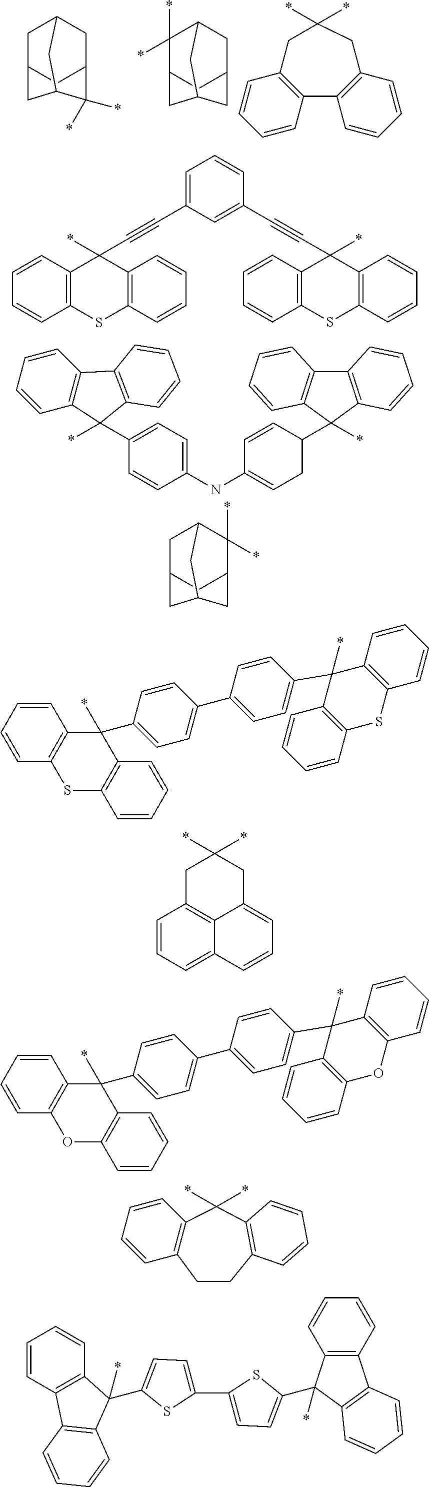

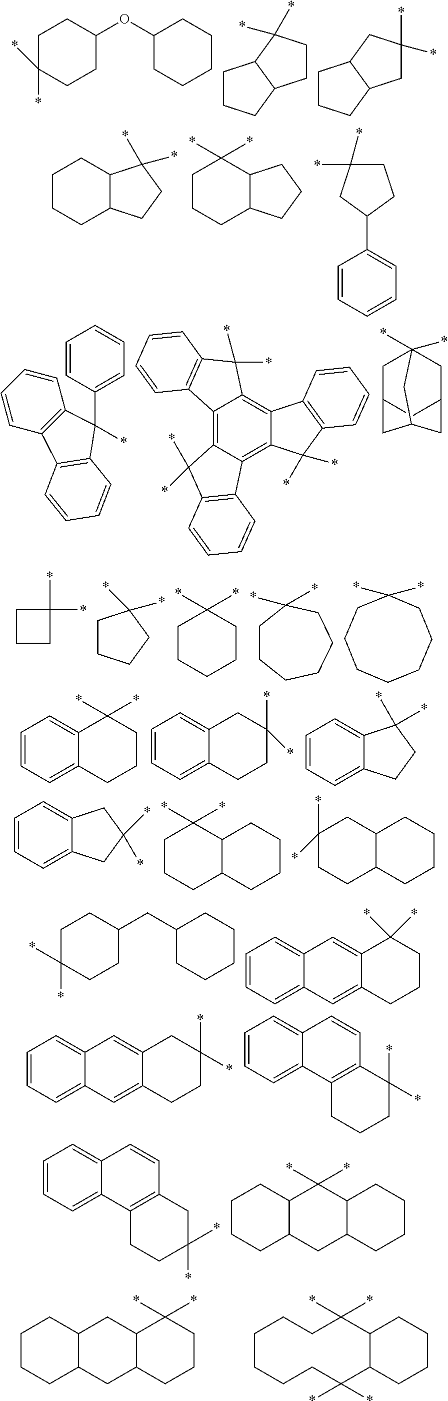

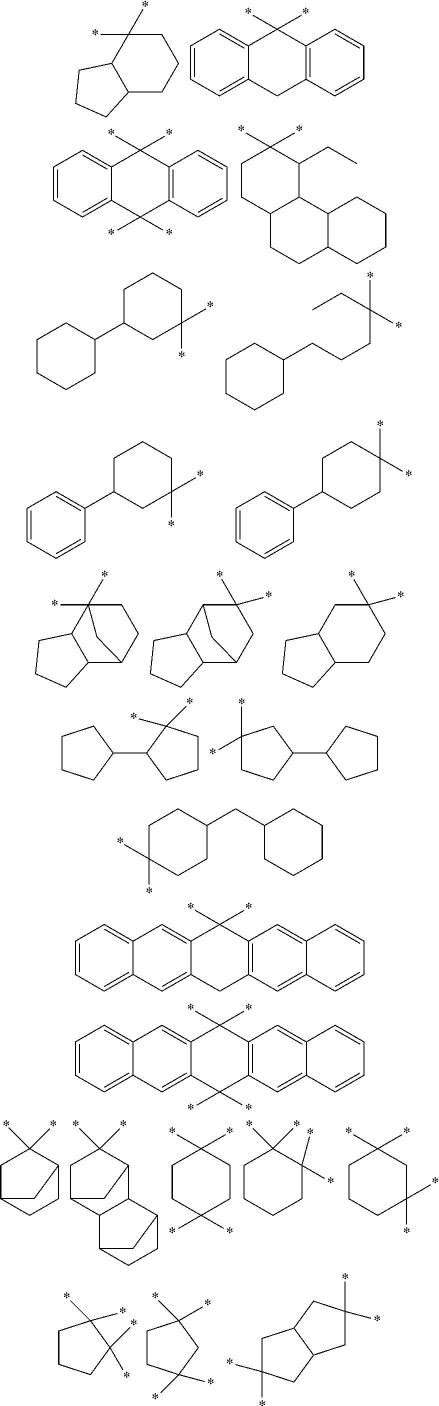

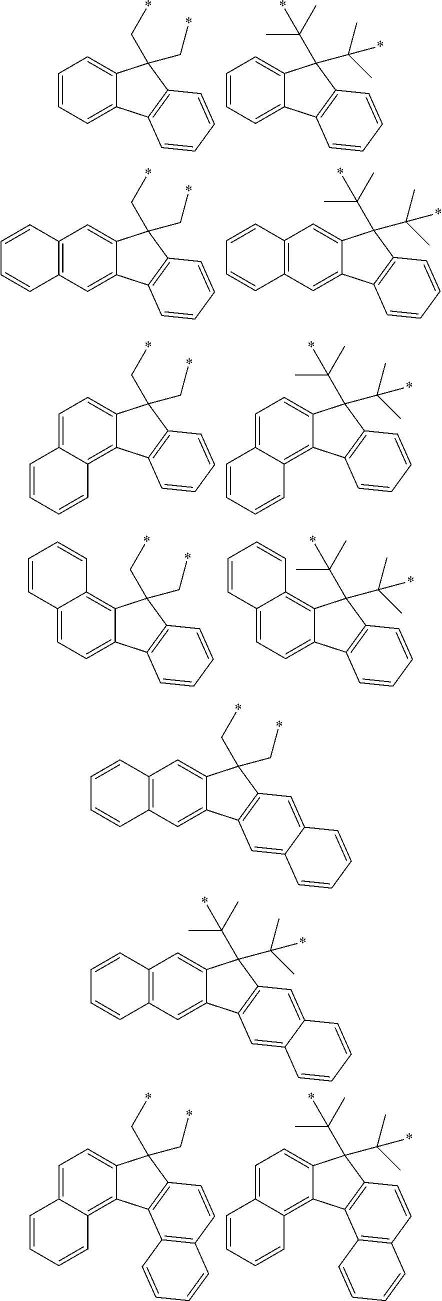

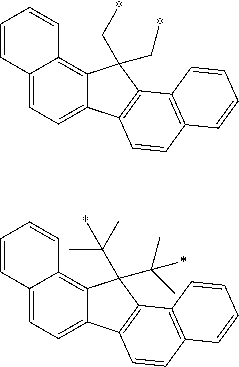 [SMILES: *CC1(C*)c2c(ccc3ccccc23)-c2ccc3ccccc3c21 ; *C(C)(C)C1(C(*)(C)C)c2c(ccc3ccccc23)-c2ccc3ccccc3c21]

### (III-3-B34)

When Z in the formula (B3) contains an aromatic ring, the aromatic ring [see for example, Ar¹ in formula (B32) below] may be additionally bonded to the other unit structure B.

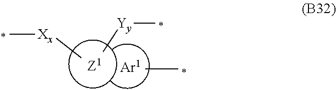

In the formula (B32),
Z¹ denotes at least one non-aromatic monocyclic ring; Ar¹ denotes at least one aromatic monocyclic ring forming a condensed ring with the non-aromatic monocyclic ring in Z¹; and the whole of Z¹ and Ar¹ is an optionally substituted C8-C25 bicyclic, tricyclic, tetracyclic, or pentacyclic condensed ring. The number of carbon atoms here indicates the number of carbon atoms constituting the ring skeleton of the bicyclic, tricyclic, or tetracyclic condensed ring except substituents. When the bicyclic, tricyclic, or tetracyclic condensed ring is a heterocyclic ring, the number of carbon atoms does not include the number of heteroatoms constituting the heterocyclic ring.

The bicyclic, tricyclic, tetracyclic, or pentacyclic organic group may be further condensed with one or more aromatic rings to form a hexacyclic or higher ring. The number of carbon atoms in the hexacyclic or higher condensed ring is preferably 40 or less. The number of carbon atoms here indicates the number of carbon atoms constituting the ring skeleton of the pentacyclic or higher condensed ring except substituents. When the hexacyclic or higher condensed ring is a heterocyclic ring, the number of carbon atoms does not include the number of heteroatoms constituting the heterocyclic ring.

In the cyclic organic group, the one, or two or more non-aromatic monocyclic rings in Z¹ may have any permutational positional relationship with the one, or two or more aromatic monocyclic rings in Ar¹. When, for example, Z¹ contains two or more non-aromatic monocyclic rings and Ar¹ contains two or more aromatic monocyclic rings, the non-aromatic monocyclic rings in Z¹ and the aromatic monocyclic rings in Ar¹ may be condensed alternately.

X, Y, x, and y are the same as defined in the formula (B3).

When one valence bond of the linking carbon atom in the above case is bonded to a polymer terminal T (such as a hydrogen atom; a functional group, such as a hydroxyl group or an unsaturated aliphatic hydrocarbon group; a terminal unit structure A; or a unit structure A in other polymer chain) as illustrated in formula (C3) below, the unit structure may be regarded as a single unit structure C equivalent to a composite unit structure A-B and may replace at least one composite unit structure A-B.

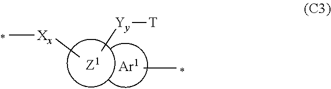

[In the formula (C3),
Z¹, Ar¹, X, Y, x, and y are the same as defined in the formula (B32), and
T denotes the polymer terminal.]
   That is, the aromatic ring in the formula (C3) [Ar¹ in the formula (C3)] may be bonded to the other unit structure B and the remaining valence bond of the linking carbon atom illustrated in the formula (C3) may be bonded to the aromatic ring in the unit structure A, thereby extending the polymer chain.

The unit structures C equivalent to composite unit structures A-B may further include unit structures including a structure of formula (C4) below.

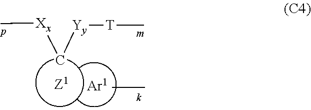

In the formula (C4),
Z¹ denotes at least one non-aromatic monocyclic ring; Ar¹ denotes at least one aromatic monocyclic ring; and the whole of Z¹ and Ar¹ is a cyclic organic group that is an optionally substituted 8- to 17-membered bicyclic or higher condensed ring. In the cyclic organic group, the aromatic monocyclic rings and the non-aromatic monocyclic rings may be arranged in any manner and in any order. Any of the non-aromatic monocyclic ring or rings in Z¹ contains the carbon atom C illustrated in the formula (C4) [the linking carbon atom described in (I-1)] among the atoms constituting the ring moiety.

X, Y, x, and y are the same as defined in the formula (B31).

T denotes a polymer terminal group or an aromatic ring residue Ar².

The letter p denotes one valence bond for forming a covalent bond with the aromatic ring in the unit structure A (or an aromatic ring in the second unit structure C).

On the other hand, k and m denote the numbers of valence bonds for forming a covalent bond with the unit structure B (or the third unit structure C). The letter k is 0 to 2, m is 0 or 1, and at least one of k or m is not 0 (when k and m are 0, the valence bonds are meant to be replaced with hydrogen atoms).

When k is 2, the two valence bonds indicated by k may extend from the same aromatic monocyclic ring or may extend from different aromatic monocyclic rings. When k is 2 or when k is 1 and m is 1, the extra valence bond will be bonded to a polymer terminal group or will form a crosslink with other polymer chain.

### (III-3-B35)

More specific examples of the structures of the formula (C3) or (C4) include formula (C31) below in which T in the formula (C3) is a terminal hydrogen atom. Depending on the valence bonds indicated by p, k₁, and k₂, specifically, when the valence bonds are indicated by p and k₁ or by p and k₂, the unit structure may serve as a single unit structure C equivalent to a composite unit structure A-B.

Incidentally, the unit structure may also function as a unit structure A when the valence bonds are indicated by k₁ and k₂.

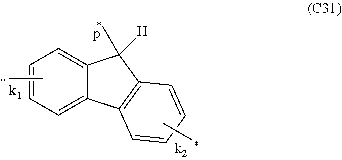

Furthermore, formula (C32) below illustrates a structure of the formula (C3) in which T is a phenyl group. Depending on the valence bonds indicated by p, k₁, k₂, and m, specifically, when the valence bonds are indicated by p and k₁, by p and k₂, or by p and m, this illustrative structure may serve as a single unit structure C equivalent to a composite unit structure A-B.

Incidentally, the unit structure may also function as a unit structure A when the valence bonds are indicated by k₁ and k₂, by k₁ and m, or by k₂ and m.

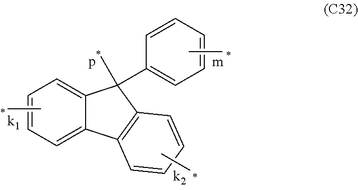

Some specific examples of the unit structures C of the formula (C3) (unit structures equivalent to composite unit structures A-B) are illustrated below. * indicates a bonding site to the unit structure A.

While the unit structures C have, on any of the aromatic rings in the structure, a valence bond that bonds to the unit structure B, the specific examples below omit such a valence bond. It is needless to mention that the illustrated structures may be part of the whole unit structure.

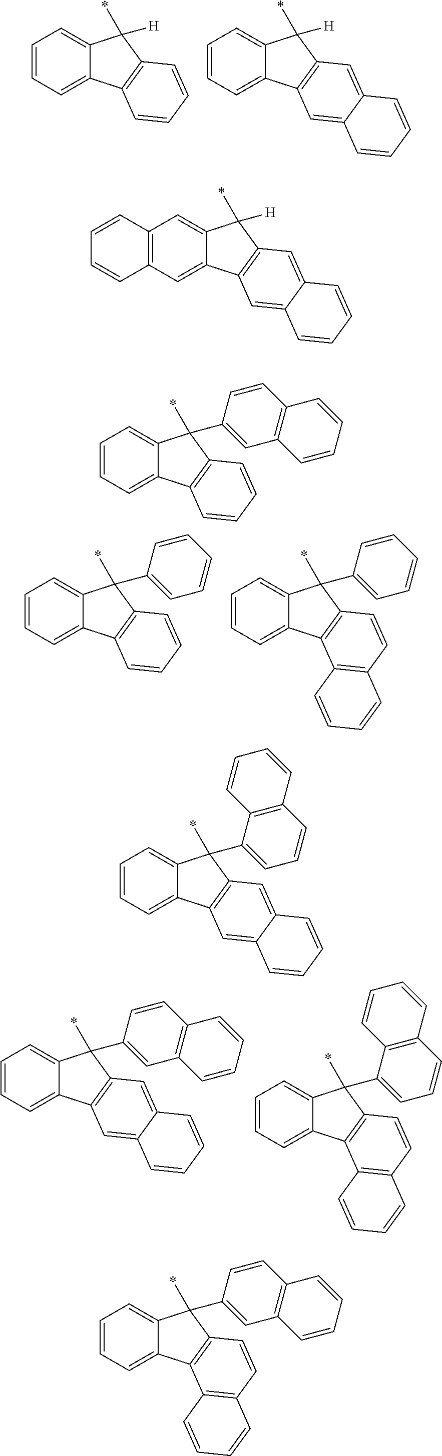

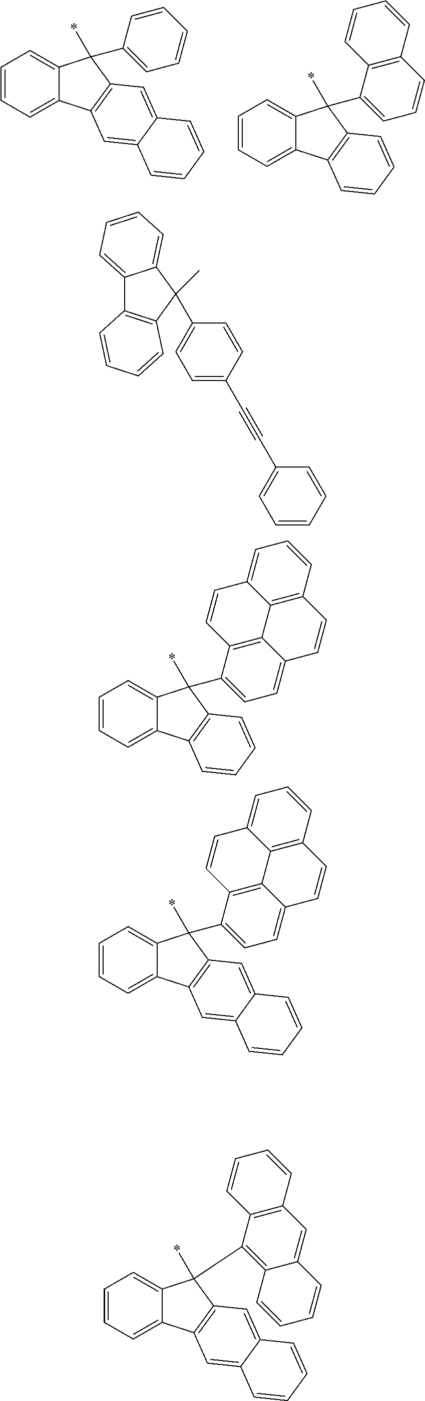

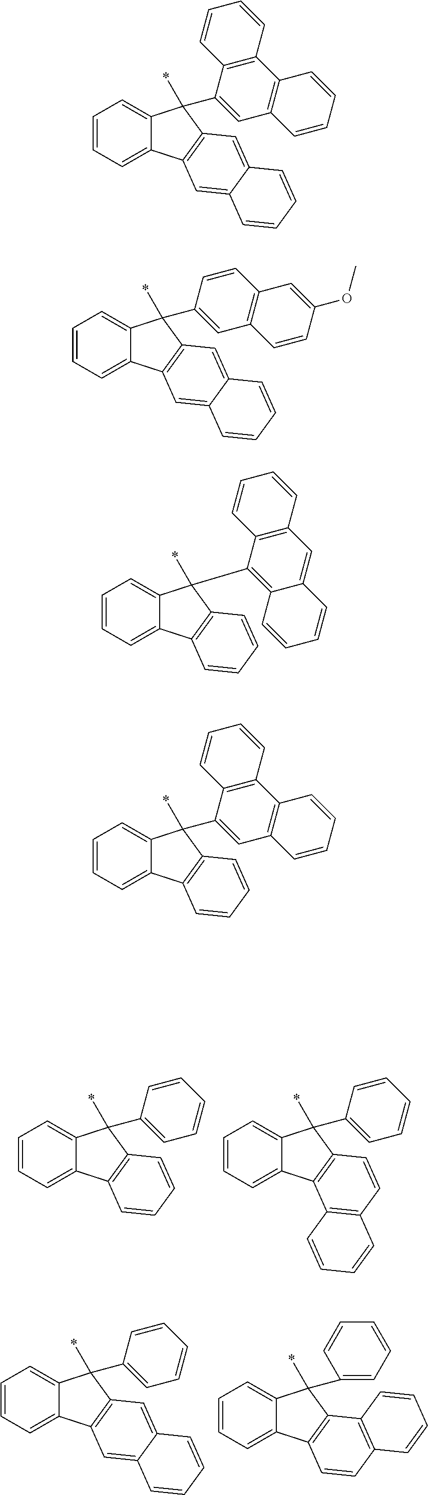

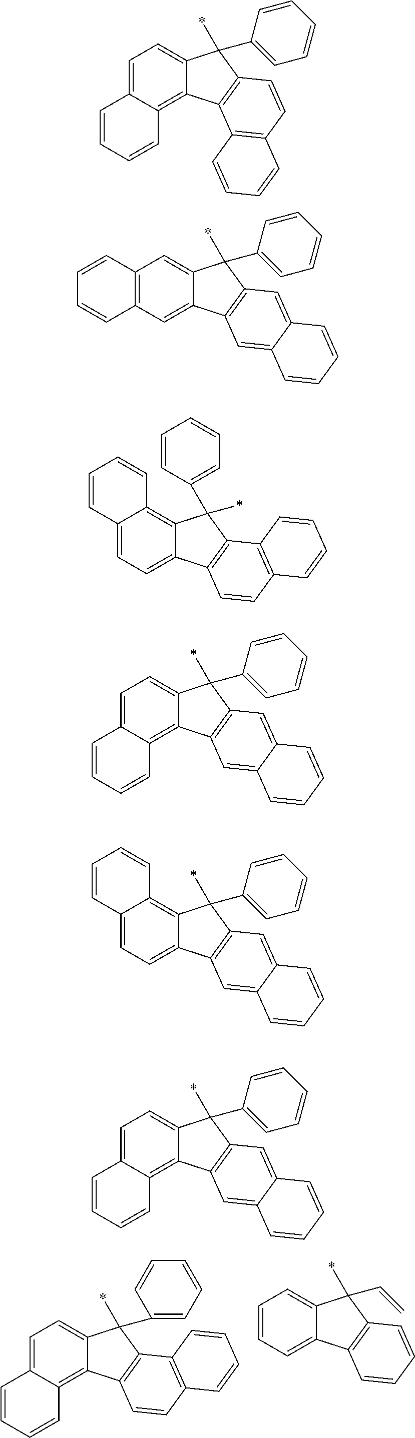

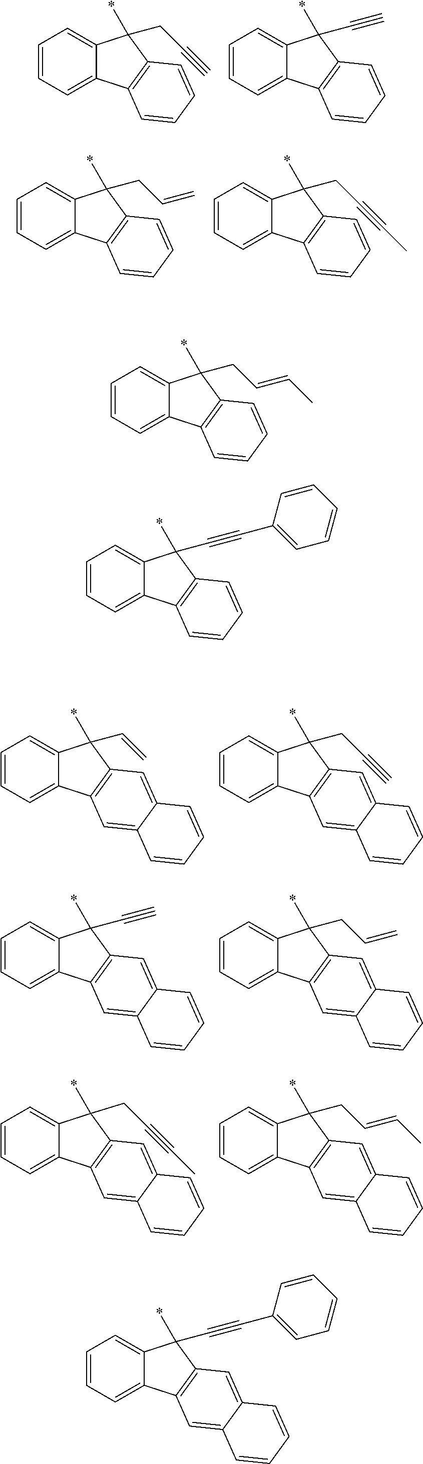

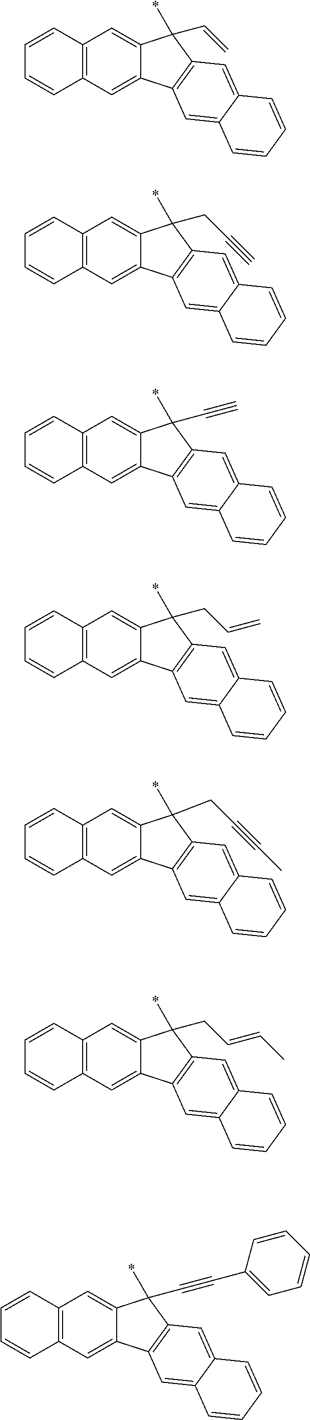

The above specific illustrations without the valence bond on the aromatic ring can serve as specific examples of the polymer terminals.

### (III-3-B4)

At a polymer terminal, the unit structure B forms a covalent bond with a terminal group (a polymer terminal group). The polymer terminal group may or may not be an aromatic ring derived from the unit structure A.

Examples of the polymer terminal groups include hydrogen atom and organic groups including optionally substituted aromatic ring residues and optionally substituted unsaturated aliphatic hydrocarbon residues [see the substituents corresponding to T in the formula (C3) or (C4) in the specific examples illustrated in (III-3-B35)].

### (III-3-S) [Synthesis Methods]

The novolac resin having a structure represented by the formula (AB) may be prepared by a known method. For example, such a novolac resin may be prepared by condensing a ring-containing compound represented by H-A-H with an oxygen-containing compound represented by, for example, OHC—B, O═C—B, HO—B—OH, or RO—B—OR. In the above formulas, A and B are the same as defined hereinabove, and R denotes a halogen or an alkyl group having about 1 to 3 carbon atoms.

The ring-containing compound and the oxygen-containing compound may be each a single compound or a combination of two or more compounds. In the condensation reaction, the oxygen-containing compound may be used in an amount of 0.1 to 10 mol, preferably 0.1 to 2 mol, per mol of the ring-containing compound.

A catalyst may be used in the condensation reaction, with examples including mineral acids, such as sulfuric acid, phosphoric acid, and perchloric acid, organic sulfonic acids, such as p-toluenesulfonic acid, p-toluenesulfonic acid monohydrate, methanesulfonic acid, and trifluoromethanesulfonic acid, and carboxylic acids, such as formic acid and oxalic acid. The amount in which the catalyst is used varies depending on the type of the catalyst used, but is usually 0.001 to 10,000 parts by mass, preferably 0.01 to 1,000 parts by mass, and more preferably 0.05 to 100 parts by mass with respect to 100 parts by mass of the ring-containing compound (when plural, the total of the ring-containing compounds).

The condensation reaction may be carried out without a solvent but is usually performed using a solvent. The solvent is not particularly limited as long as it can dissolve the reaction substrates and does not inhibit the reaction. Examples include 1,2-dimethoxyethane, diethylene glycol dimethyl ether, propylene glycol monomethyl ether, propylene glycol monomethyl ether acetate, tetrahydrofuran, tetrahydropyran, 4-methyltetrahydropyran, dioxane, 1,2-dichloromethane, 1,2-dichloroethane, toluene, N-methylpyrrolidone, and dimethylformamide. The condensation reaction temperature is usually 40° C. to 200° C., and preferably 100° C. to 180° C. The reaction time varies depending on the reaction temperature but is usually 5 minutes to 50 hours, and preferably 5 minutes to 24 hours.

The weight average molecular weight of the novolac resin according to an aspect of the present invention is usually 500 to 100,000, preferably 600 to 50,000, 700 to 10,000, or 800 to 8,000.

### [IV. One, or Two or More Kinds of Bases B²]

### (IV-1)

One, or two or more kinds of bases B² as additional base components are separately added to the underlayer film forming composition according to the present invention. The bases trap the acid generated at the time of baking and thereby slow down the curing rate. As a result, the composition can form cured films on various kinds of films, such as SiO₂, TiN, and SiN, while exhibiting high flattening properties and high gap-filling properties. Furthermore, the bases eliminate influences of the acid generator on the polymer that is a main component of the resist underlayer film and the storage stability of the polymer can be ensured. Thus, the composition is free from coloration and can form films that are not dissolved by photoresist solvents.

### (IV-2)

In order to trap more effectively the acid generated at the time of baking, it is preferable that when the amount of a base required to neutralize the same number of moles of sulfonic acid (a monobasic acid) as the sulfonate anion groups (SO₃⁻) contained in the thermal acid generator (a) is 1 equivalent, the amount added of the base or bases B² be 0.05 to 3.0, more preferably 0.1 to 2.5, and still more preferably 0.2 to 2.0.

Similarly, when the amount of a base required to neutralize the same number of moles of sulfonic acid (a monobasic acid) as the sulfonate anion groups (SO₃⁻) contained in the thermal acid generator (a) is 1 equivalent, it is preferable that the base or bases B¹ and the base or bases B² include 1.05 equivalents or more, more preferably 1.1 equivalents or more, and still more preferably 1.2 equivalents or more of a base having a higher pKa than pyridine, more preferably a base having a pKa of 6.5 or more.

On the other hand, from the point of view of the cost relative to the effect, it is preferable that when the amount of a base required to neutralize the same number of moles of sulfonic acid (a monobasic acid) as the sulfonate anion groups (SO₃⁻) contained in the thermal acid generator (a) is 1 equivalent, the base or bases B¹ and the base or bases B² include 2 equivalents or less, more preferably 1.8 equivalents or less, and still more preferably 1.5 equivalents or less of a base having a higher pKa than pyridine, more preferably a base having a pKa of 6.5 or more.

### (IV-3)

Specific examples of the bases having a higher pKa than pyridine, preferably a pKa of 6.5 or more, in the present invention include N-methylmorpholine, N,N-diethylaniline, N-isobutylmorpholine, and N-allylmorpholine.

For example, pKa may be measured by potentiometric titration [see, for example, S. Xu et al., “Dissociation constants of alkanolamines”, Can. J. Chem. 71, 1048 (1993)] in water, preferably in water at 25° C. The values of pKa thus measured are compared. Reference may be made to other literature, such as R. Linnell, J. Org. Chem. 1960, 25, 2, 290-290; “Dai Yuukikagaku Bekkan 2 (Great Organic Chemistry, Special Volume 2), Yuukikagaku Teisuu Binran (Handbook of constants in organic chemistry)”, supervised by Munio Kotake, p. 584 (1963), (Asakura Publishing Co., Ltd.); H. K. Hall Jr. et al., Tetrahedron Letters 53 (2012) 1830-1832.

### [V. Solvents]

### (V-1)

The resist underlayer film forming composition according to the present invention includes a solvent.

The solvent is not particularly limited as long as it can dissolve the thermal acid generator (a), the aromatic ring-containing polymer (b), the base or bases (c), and optional components that are added as required. When, in particular, the composition is used as a uniform nanoimprinting solution, it is recommended to use a solvent commonly used in lithographic processes in consideration of the coating performance of the composition.

Examples of such solvents include methyl cellosolve acetate, ethyl cellosolve acetate, propylene glycol, propylene glycol monomethyl ether, propylene glycol monoethyl ether, propylene glycol monopropyl ether, methyl isobutyl carbinol, propylene glycol monobutyl ether, propylene glycol monomethyl ether acetate, propylene glycol monoethyl ether acetate, propylene glycol monopropyl ether acetate, propylene glycol monobutyl ether acetate, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethylene glycol monomethyl ether, ethylene glycol monoethyl ether, ethylene glycol monopropyl ether, ethylene glycol monobutyl ether, ethylene glycol monomethyl ether acetate, ethylene glycol monoethyl ether acetate, ethylene glycol monopropyl ether acetate, ethylene glycol monobutyl ether acetate, diethylene glycol monomethyl ether, diethylene glycol monoethyl ether, diethylene glycol dimethyl ether, diethylene glycol diethyl ether, diethylene glycol dipropyl ether, diethylene glycol dibutyl ether, propylene glycol dimethyl ether, propylene glycol diethyl ether, propylene glycol dipropyl ether, propylene glycol dibutyl ether, ethyl lactate, propyl lactate, isopropyl lactate, butyl lactate, isobutyl lactate, methyl formate, ethyl formate, propyl formate, isopropyl formate, butyl formate, isobutyl formate, amyl formate, isoamyl formate, methyl acetate, ethyl acetate, amyl acetate, isoamyl acetate, hexyl acetate, methyl propionate, ethyl propionate, propyl propionate, isopropyl propionate, butyl propionate, isobutyl propionate, methyl butyrate, ethyl butyrate, propyl butyrate, isopropyl butyrate, butyl butyrate, isobutyl butyrate, ethyl hydroxyacetate, methyl 2-hydroxy-2-methylpropionate, ethyl 2-hydroxy-2-methylpropionate, methyl 3-methoxy-2-methylpropionate, methyl 2-hydroxy-3-methylbutyrate, ethyl methoxyacetate, ethyl ethoxyacetate, methyl 3-methoxypropionate, ethyl 3-ethoxypropionate, ethyl 3-methoxypropionate, 3-methoxybutyl acetate, 3-methoxypropyl acetate, 3-methyl-3-methoxybutyl acetate, 3-methyl-3-methoxybutyl propionate, 3-methyl-3-methoxybutyl butyrate, methyl acetoacetate, toluene, xylene, methyl ethyl ketone, methyl propyl ketone, methyl butyl ketone, 2-heptanone, 3-heptanone, 4-heptanone, cyclopentanone, cyclohexanone, N,N-dimethylformamide, N-methylacetamide, N,N-dimethylacetamide, N-methylpyrrolidone, 4-methyl-2-pentanol, and γ-butyrolactone. These solvents may be used singly, or two or more may be used in combination.

### (V-2)

In order to dissolve uniformly the thermal acid generator (a), the aromatic ring-containing polymer (b), the base or bases (c), and optional components (such as an aminoplast crosslinking agent or a phenoplast crosslinking agent), it is preferable that the solvent include a compound having an alcoholic hydroxyl group or a compound having a group capable of forming an alcoholic hydroxyl group. Preferred examples of such solvents include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monopropyl ether, propylene glycol monomethyl ether acetate, propylene glycol monoethyl ether, propylene glycol monoethyl ether acetate, propylene glycol propyl ether acetate, cyclopentanone, cyclohexanone, ethyl 2-hydroxypropionate, methyl 2-hydroxy-2-methylpropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, and butyl lactate. Among these, propylene glycol monomethyl ether, propylene glycol monoethyl ether, propylene glycol monopropyl ether, propylene glycol monomethyl ether acetate, propylene glycol monoethyl ether acetate, propylene glycol monopropyl ether acetate, methyl 2-hydroxy-2-methylpropionate, ethyl lactate, and cyclohexanone are more preferable, and propylene glycol monomethyl ether, propylene glycol monomethyl ether acetate, methyl 2-hydroxy-2-methylpropionate, ethyl lactate, and cyclohexanone are the most preferable.

### (V-3)

Furthermore, the composition may include a solvent having a boiling point of 160° C. or above. For example, use may be made of the compound illustrated below that is described in WO 2018/131562 (A1).

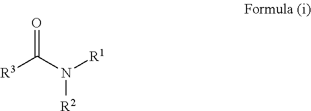

(R¹, R², and R³ in the formula (i) each denote a hydrogen atom or a C1-C20 alkyl group optionally interrupted with an oxygen atom, a sulfur atom, or an amide bond, and are the same as or different from one another and are optionally bonded to one another to form a ring structure.)

Alternatively, 1,6-diacetoxyhexane (boiling point: 260° C.) and tripropylene glycol monomethyl ether (boiling point: 242° C.) described in JP 2021-84974 A, and various high boiling point solvents described in paragraph 0082 of the same publication may be suitably used.

Alternatively, dipropylene glycol monomethyl ether acetate (boiling point: 213° C.), diethylene glycol monoethyl ether acetate (boiling point: 217° C.), diethylene glycol monobutyl ether acetate (boiling point: 247° C.), dipropylene glycol dimethyl ether (boiling point: 171° C.), dipropylene glycol monomethyl ether (boiling point: 187° C.), dipropylene glycol monobutyl ether (boiling point: 231° C.), tripropylene glycol monomethyl ether (boiling point: 242° C.), γ-butyrolactone (boiling point: 204° C.), benzyl alcohol (boiling point: 205° C.), propylene carbonate (boiling point: 242° C.), tetraethylene glycol dimethyl ether (boiling point: 275° C.), 1,6-diacetoxyhexane (boiling point: 260° C.), dipropylene glycol (boiling point: 230° C.), and 1,3-butylene glycol diacetate (boiling point: 232° C.) described in JP 2019-20701 A, and various high boiling point solvents described in paragraphs 0023 to 0031 of the same publication may be suitably used.

### [VI. Optional Components]

Where necessary, the resist underlayer film forming composition according to the present invention may include additives, such as crosslinking agents, surfactants, light absorbers, rheology modifiers, and adhesion aids, in addition to the above components.

### (VI-1: Aminoplast Crosslinking Agents)

Exemplary aminoplast crosslinking agents include highly alkylated, alkoxylated, or alkoxyalkylated melamines, benzoguanamines, glycolurils, ureas, and polymers thereof. Preferably, the crosslinking agents have at least two crosslinking substituents, with examples including methoxymethylated glycoluril, butoxymethylated glycoluril, methoxymethylated melamine, butoxymethylated melamine, methoxymethylated benzoguanamine, butoxymethylated benzoguanamine, methoxymethylated urea, butoxymethylated urea, methoxymethylated thiourea, and methoxymethylated thiourea. Condensates of these compounds may also be used.

Furthermore, highly heat-resistant crosslinking agents may be used as the crosslinking agents. Compounds that contain a crosslinking substituent having an aromatic ring (for example, a benzene ring or a naphthalene ring) in the molecule may be preferably used as the highly heat-resistant crosslinking agents.

Preferably, the crosslinking agent is at least one selected from the group consisting of tetramethoxymethylglycoluril and hexamethoxymethylmelamine.

The aminoplast crosslinking agents may be used singly, or two or more may be used in combination. The aminoplast crosslinking agent may be produced by a method known per se or deemed as known or may be purchased from the market.

The amount in which the aminoplast crosslinking agent is used varies depending on factors, such as the coating solvent that is used, the base substrate that is used, the solution viscosity that is required, and the film shape that is required, but is 0.001 mass % or more, 0.01 mass % or more, 0.05 mass % or more, 0.5 mass % or more, or 1.0 mass % or more, and is 80 mass % or less, 50 mass % or less, 40 mass % or less, 20 mass % or less, or 10 mass % or less, based on the total solid content in the resist underlayer film forming composition according to the present invention.

Some specific examples are illustrated below:

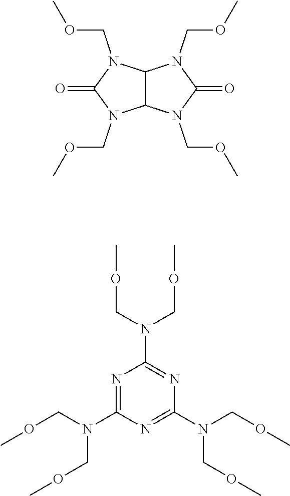

### (VI-2: Phenoplast Crosslinking Agents)

Exemplary phenoplast crosslinking agents include highly alkylated, alkoxylated, or alkoxyalkylated aromatics, and polymers thereof. Preferably, the crosslinking agents have at least two crosslinking substituents in the molecule, with examples including 2,6-dihydroxymethyl-4-methylphenol, 2,4-dihydroxymethyl-6-methylphenol, bis(2-hydroxy-3-hydroxymethyl-5-methylphenyl)methane, bis(4-hydroxy-3-hydroxymethyl-5-methylphenyl)methane, 2,2-bis(4-hydroxy-3,5-dihydroxymethylphenyl)propane, bis(3-formyl-4-hydroxyphenyl)methane, bis(4-hydroxy-2,5-dimethylphenyl)formylmethane, and α,α-bis(4-hydroxy-2,5-dimethylphenyl)-4-formyltoluene. Condensates of these compounds may also be used.

Furthermore, highly heat-resistant crosslinking agents may be used as the crosslinking agents. Compounds that contain a crosslinking substituent having an aromatic ring (for example, a benzene ring or a naphthalene ring) in the molecule may be preferably used as the highly heat-resistant crosslinking agents.

The phenoplast crosslinking agents may be used singly, or two or more may be used in combination. The phenoplast crosslinking agent may be produced by a method known per se or deemed as known or may be purchased from the market.

The amount in which the phenoplast crosslinking agent is used varies depending on factors, such as the coating solvent that is used, the base substrate that is used, the solution viscosity that is required, and the film shape that is required, but is 0.001 mass % or more, 0.01 mass % or more, 0.05 mass % or more, 0.5 mass % or more, or 1.0 mass % or more, and is 80 mass % or less, 50 mass % or less, 40 mass % or less, 20 mass % or less, or 10 mass % or less, based on the total solid content in the resist underlayer film forming composition according to the present invention.

Examples of such compounds, in addition to those described above, include compounds that have a partial structure of formula (4) below, and polymers or oligomers that have a repeating unit of formula (5) below.

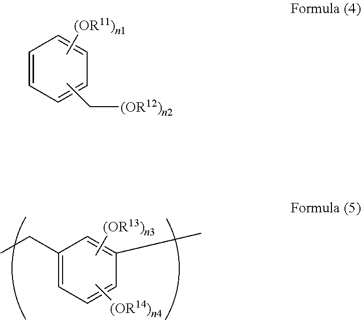

R¹¹, R¹², R¹³, and R¹⁴ are each a hydrogen atom or a C1-C10 alkyl group. Examples of the alkyl groups include those described hereinabove. n1 is an integer of 1 to 4, n2 is an integer of 1 to (5−n1), and (n1+n2) is an integer of 2 to 5. n3 is an integer of 1 to 4, n4 is 0 to (4−n3), and (n3+n4) is an integer of 1 to 4. The number of the repeating unit structures in the oligomers and the polymers may be in the range of 2 to 100, or 2 to 50.

Some specific examples are illustrated below:

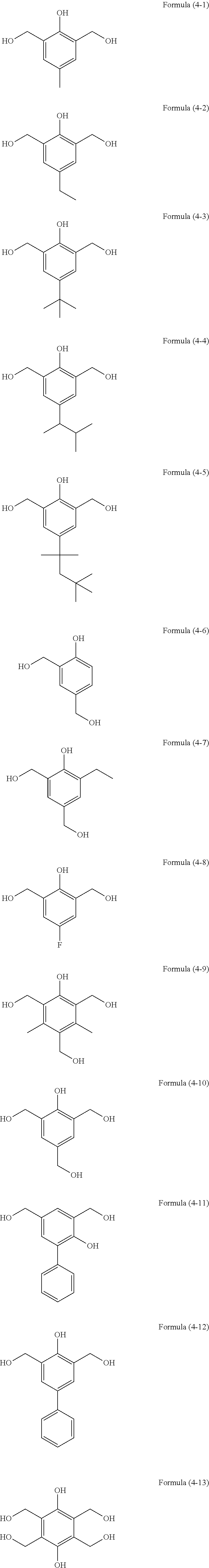

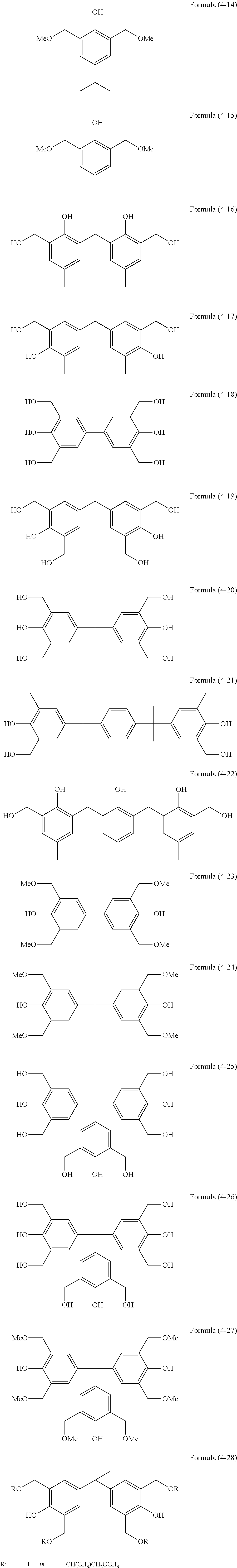

### (VI-3: Surfactants)

To reduce the occurrence of defects, such as pinholes or striation, and to further enhance the applicability to surface unevenness, the resist underlayer film forming composition according to the present invention may include a surfactant.

Examples of the surfactants include nonionic surfactants, for example, polyoxyethylene alkyl ethers, such as polyoxyethylene lauryl ether, polyoxyethylene stearyl ether, polyoxyethylene cetyl ether, and polyoxyethylene oleyl ether, polyoxyethylene alkyl aryl ethers, such as polyoxyethylene octyl phenol ether and polyoxyethylene nonyl phenol ether, polyoxyethylene/polyoxypropylene block copolymers, sorbitan fatty acid esters, such as sorbitan monolaurate, sorbitan monopalmitate, sorbitan monostearate, sorbitan monooleate, sorbitan trioleate, and sorbitan tristearate, and polyoxyethylene sorbitan fatty acid esters, such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorine surfactants, such as EFTOP series EF301, EF303, and EF352 (product names, manufactured by Tohkem Products Corp.), MEGAFACE series F171, F173, R-30, and R-40 (product names, manufactured by DIC CORPORATION), FLUORAD series FC430 and FC431 (product names, manufactured by Sumitomo 3M Ltd.), ASAHI GUARD AG710, and SURFLON series S-382, SC101, SC102, SC103, SC104, SC105, and SC106 (product names, manufactured by AGC Inc.); and organosiloxane polymer KP341 (manufactured by Shin-Etsu Chemical Co., Ltd.). The amount in which the surfactant is added is usually 2.0 mass % or less, and preferably 1.0 mass % or less relative to the total solid content in the resist underlayer film forming composition according to the present invention. The surfactants may be added singly, or two or more may be added in combination.

### (VI-4: Other Additives)

In order to promote the crosslinking reaction, the resist underlayer film forming composition according to the present invention may contain a catalyst in addition to the crosslinking catalyst of formula (I). Examples of such additional catalysts include acidic compounds, such as citric acid; thermal acid generators, such as 2,4,4,6-tetrabromocyclohexadienone, benzoin tosylate, 2-nitrobenzyl tosylate, and organic sulfonic acid alkyl esters; onium salt photoacid generators, such as bis(4-t-butylphenyl)iodonium trifluoromethanesulfonate and triphenylsulfonium trifluoromethanesulfonate; halogen-containing compound-based photoacid generators, such as phenyl-bis(trichloromethyl)-s-triazine; and sulfonic acid-based photoacid generators, such as benzoin tosylate and N-hydroxysuccinimide trifluoromethanesulfonate.

Some example light absorbers that may be suitably used include commercially available light absorbers described in “Kougyouyou Shikiso no Gijutsu to Shijou (Technology and Market of Industrial Dyes)” (CMC Publishing Co., Ltd.) and “Senryou Binran (Dye Handbook)” (edited by The Society of Synthetic Organic Chemistry, Japan), such as, for example, C. I. Disperse Yellow 1, 3, 4, 5, 7, 8, 13, 23, 31, 49, 50, 51, 54, 60, 64, 66, 68, 79, 82, 88, 90, 93, 102, 114, and 124; C. I. Disperse Orange 1, 5, 13, 25, 29, 30, 31, 44, 57, 72, and 73; C. I. Disperse Red 1, 5, 7, 13, 17, 19, 43, 50, 54, 58, 65, 72, 73, 88, 117, 137, 143, 199, and 210; C. I. Disperse Violet 43; C. I. Disperse Blue 96; C. I. Fluorescent Brightening Agent 112, 135, and 163; C. I. Solvent Orange 2 and 45; C. I. Solvent Red 1, 3, 8, 23, 24, 25, 27, and 49; C. I. Pigment Green 10; and C. I. Pigment Brown 2. The light absorber is usually added in a proportion of 10 mass % or less, preferably 5 mass % or less relative to the total solid content in the resist underlayer film forming composition according to the present invention.

A rheology modifier may be added mainly to enhance the fluidity of the resist underlayer film forming composition and thereby, particularly in the baking step, to enhance the uniformity in thickness of a resist underlayer film and to increase the filling performance of the resist underlayer film forming composition with respect to the inside of holes. Specific examples thereof include phthalic acid derivatives, such as dimethyl phthalate, diethyl phthalate, diisobutyl phthalate, dihexyl phthalate, and butyl isodecyl phthalate; adipic acid derivatives, such as di-n-butyl adipate, diisobutyl adipate, diisooctyl adipate, and octyl decyl adipate; maleic acid derivatives, such as di-n-butyl maleate, diethyl maleate, and dinonyl maleate; oleic acid derivatives, such as methyl oleate, butyl oleate, and tetrahydrofurfuryl oleate; and stearic acid derivatives, such as n-butyl stearate and glyceryl stearate. The rheology modifier is usually added in a proportion of less than 30 mass % relative to the total solid content in the resist underlayer film forming composition according to the present invention.

An adhesion aid may be added mainly to enhance the adhesion between the resist underlayer film forming composition and a substrate or a resist and thereby to prevent the detachment of the resist particularly during development. Specific examples thereof include chlorosilanes, such as trimethylchlorosilane, dimethylvinylchlorosilane, methyldiphenylchlorosilane, and chloromethyldimethylchlorosilane; alkoxysilanes, such as trimethylmethoxysilane, dimethyldiethoxysilane, methyldimethoxysilane, dimethylvinylethoxysilane, diphenyldimethoxysilane, and phenyltriethoxysilane; silazanes, such as hexamethyldisilazane, N,N′-bis(trimethylsilyl)urea, dimethyltrimethylsilylamine, and trimethylsilylimidazole; silanes, such as vinyltrichlorosilane, γ-chloropropyltrimethoxysilane, γ-aminopropyltriethoxysilane, and γ-glycidoxypropyltrimethoxysilane; heterocyclic compounds, such as benzotriazole, benzimidazole, indazole, imidazole, 2-mercaptobenzimidazole, 2-mercaptobenzothiazole, 2-mercaptobenzoxazole, urazole, thiouracil, mercaptoimidazole, and mercaptopyrimidine; and urea or thiourea compounds, such as 1,1-dimethylurea and 1,3-dimethylurea. The adhesion aid is usually added in a proportion of less than 5 mass %, preferably less than 2 mass % relative to the total solid content in the resist underlayer film forming composition according to the present invention.

The solid content in the resist underlayer film forming composition according to the present invention is 0.1 to 70 mass % or 0.1 to 60 mass %. The solid content is the content of all the components except the solvent in the resist underlayer film forming composition. The proportion of the crosslinkable resin in the solid content may be 1 to 99.9 mass %, or 50 to 99.9 mass %, or 50 to 95 mass %, or 50 to 90 mass %.

### [VII: Resist Underlayer Films]

A resist underlayer film may be formed as described below using the resist underlayer film forming composition according to the present invention.

The resist underlayer film forming composition according to an aspect of the present invention is applied with an appropriate technique, such as a spinner or a coater, onto a semiconductor device substrate (such as, for example, a silicon wafer substrate, a silicon dioxide-coated substrate (a SiO₂ substrate), a silicon nitride substrate (a SiN substrate), a silicon oxynitride substrate (a SiON substrate), a titanium nitride substrate (a TiN substrate), a tungsten substrate (a W substrate), a glass substrate, an ITO substrate, a polyimide substrate, or a low-dielectric constant material (low-k material)-coated substrate), and the coating is baked using a heating device, such as a hot plate, to form a resist underlayer film. The baking conditions are appropriately selected from baking temperatures of 80° C. to 600° C. and amounts of baking time of 0.3 to 60 minutes. The baking temperature is preferably 150° C. to 400° C., more preferably 150° C. to 350° C., and the baking time is preferably 0.5 to 2 minutes. The atmosphere gas at the time of baking may be air or an inert gas, such as nitrogen or argon. In an embodiment, in particular, the oxygen concentration is preferably 1% or less. Here, the film thickness of the underlayer film that is formed is, for example, 10 to 1000 nm, or 20 to 500 nm, or 30 to 400 nm, or 50 to 300 nm. Furthermore, replicas (mold replicas) of a quartz imprinting mold may be produced by using quartz substrates as the substrates.

Furthermore, an adhesion layer and/or a silicone layer containing 99 mass % or less, or 50 mass % or less of Si may be formed on the resist underlayer film according to an aspect of the present invention by application or deposition. For example, an adhesion layer described in JP 2013-202982 A or JP 5827180 B2 may be formed, or a silicon-containing resist underlayer film (inorganic resist underlayer film) forming composition described in WO 2009/104552 (A1) may be applied by spin coating. Furthermore, a Si-based inorganic material film may be formed by such a method as a CVD method.

The resist underlayer film forming composition according to an aspect of the present invention may be applied onto a semiconductor substrate having a stepped region and a stepless region (a so-called non-planar substrate) and may be baked to reduce the difference in height between the stepped region and the stepless region.

### [VIII: Methods for Manufacturing Semiconductor Devices]

### (VIII-1)

(i)

A method for manufacturing a semiconductor device according to an aspect of the present invention includes:
a step of forming on a semiconductor substrate a resist underlayer film from the resist underlayer film forming composition according to an aspect of the present invention;
a step of forming a resist film on the resist underlayer film;
a step of forming a resist pattern by irradiation of the resist film with light or electron beam followed by development;
a step of etching the resist underlayer film through the resist pattern; and
a step of processing the semiconductor substrate through the resist underlayer film having been patterned.
   (ii)

A method for manufacturing a semiconductor device according to another aspect of the present invention includes:
a step of forming on a semiconductor substrate a resist underlayer film from the resist underlayer film forming composition according to an aspect of the present invention;
a step of forming a hard mask on the resist underlayer film;
a step of forming a resist film on the hard mask;
a step of forming a resist pattern by irradiation of the resist film with light or electron beam followed by development;
a step of etching the hard mask through the resist pattern;
a step of etching the resist underlayer film through the hard mask having been patterned; and
a step of processing the semiconductor substrate through the resist underlayer film having been patterned.
   (iii)

A method for manufacturing a semiconductor device according to another aspect of the present invention includes:
a step of forming on a semiconductor substrate a resist underlayer film from the resist underlayer film forming composition according to an aspect of the present invention;
a step of forming a hard mask on the resist underlayer film;
a step of forming a resist film on the hard mask;
a step of forming a resist pattern by irradiation of the resist film with light or electron beam followed by development;
a step of etching the hard mask through the resist pattern;
a step of etching the resist underlayer film through the hard mask having been patterned;
a step of removing the hard mask; and
a step of processing the semiconductor substrate through the resist underlayer film having been patterned.
   (iv)

A method for manufacturing a semiconductor device according to another aspect of the present invention includes:
a step of forming on a semiconductor substrate a resist underlayer film from the resist underlayer film forming composition according to an aspect of the present invention;
a step of forming a hard mask on the resist underlayer film;
a step of forming a resist film on the hard mask;
a step of forming a resist pattern by irradiation of the resist film with light or electron beam followed by development;
a step of etching the hard mask through the resist pattern;
a step of etching the resist underlayer film through the hard mask having been patterned;
a step of removing the hard mask;
a step of forming a deposited film (a spacer) on the resist underlayer film cleaned of the hard mask;
a step of processing the deposited film (the spacer) by etching;
a step of removing the resist underlayer film having been patterned while leaving the deposited film (the spacer) having been patterned; and
a step of processing the semiconductor substrate through the deposited film (the spacer) having been patterned.

### (VIII-2)

The step of forming a resist underlayer film from the resist underlayer film forming composition according to an aspect of the present invention is as described in

### [VII. Resist Underlayer Films].

A hard mask, such as a silicon-containing film, may be formed as a second resist underlayer film on the resist underlayer film resulting from the above step, and a resist pattern may be formed thereon. The second resist underlayer film may be a coating film or may be a SiON film, a SiN film, or a SiO₂ film formed by a deposition method, such as CVD or PVD. Furthermore, a bottom anti-reflective coating (BARC) as a third resist underlayer film may be formed on the second resist underlayer film. The third resist underlayer film may be a resist shape correction film having no antireflection function.

In the step of forming a resist pattern, the exposure is performed through a mask (a reticle) for forming a predetermined pattern or is carried out by direct drawing. For example, g-line, i-line, KrF excimer laser, ArF excimer laser, EUV, or electron beam may be used as the exposure source. After the exposure, post exposure baking is performed as required. Subsequently, the latent image is developed with a developing solution (for example, a 2.38 mass % aqueous tetramethylammonium hydroxide solution, or butyl acetate), and the pattern is further rinsed with a rinsing solution or pure water to remove the developing solution used. Subsequently, post-baking is performed to dry the resist pattern and to enhance the adhesion with respect to the substrate.

The etching steps after the resist pattern formation are performed by dry etching.

The processing of the hard mask (the silicon-containing film), the resist underlayer film, and the substrate may be performed using a gas, specifically, CF₄, CHF₃, CH₂F₂, CH₃F, C₄F₆, C₄F₈, O₂, NO₀, NO₂, H₂, or He. These gases may be used singly, or two or more gases may be mixed. Furthermore, argon, nitrogen, carbon dioxide, carbonyl sulfide, sulfur dioxide, neon, or nitrogen trifluoride may be mixed with the above gases.

### (VIII-3)

The resist film may be patterned by a nanoimprinting method or a self-assembled film method.

In a nanoimprinting method, a resist composition is molded with a patterned mold that is transparent to the irradiation light. In a self-assembled film method, a pattern is formed using a self-assembled film that naturally forms a regular structure on the order of nanometers, for example, a diblock polymer (such as polystyrene-polymethyl methacrylate).

In a nanoimprinting method, a silicon layer (a hard mask layer) may be optionally formed by application or deposition on the resist underlayer film before the application of a curable composition for forming a resist film. An adhesion layer may be formed on the resist underlayer film or the silicon layer (the hard mask layer) by application or deposition, and a curable composition for forming a resist film may be applied onto the adhesion layer.

### (VIII-4)

Wet etching is sometimes performed for the purposes of simplifying the process step and reducing the damage to the workpiece substrate. This leads to smaller variations in processing dimensions and smaller pattern roughness, and enables processing of substrates with a high yield. Thus, the removal of the hard mask in (VIII-1) (iii) and (iv) may be performed by either etching or using an alkaline chemical solution. When, in particular, an alkaline chemical solution is used, the components are not particularly limited but the solution preferably includes any of the following alkaline components.

Examples of the alkaline components include tetramethylammonium hydroxide, tetraethylammonium hydroxide, tetrapropylammonium hydroxide, tetrabutylammonium hydroxide, methyltripropylammonium hydroxide, methyltributylammonium hydroxide, ethyltrimethylammonium hydroxide, dimethyldiethylammonium hydroxide, benzyltrimethylammonium hydroxide, hexadecyltrimethylammonium hydroxide, and (2-hydroxyethyl)trimethylammonium hydroxide, monoethanolamine, diethanolamine, triethanolamine, 2-(2-aminoethoxy) ethanol, N,N-dimethylethanolamine, N,N-diethylethanolamine, N,N-dibutylethanolamine, N-methylethanolamine, N-ethylethanolamine, N-butylethanolamine, N-methyldiethanolamine, monoisopropanolamine, diisopropanolamine, triisopropanolamine, tetrahydrofurfurylamine, N-(2-aminoethyl)piperazine, 1,8-diazabicyclo[5.4.0]undecene-7, 1,4-diazabicyclo[2.2.2]octane, hydroxyethylpiperazine, piperazine, 2-methylpiperazine, trans-2,5-dimethylpiperazine, cis-2,6-dimethylpiperazine, 2-piperidinemethanol, cyclohexylamine, and 1,5-diazabicyclo[4,3,0]nonene-5. From the point of view of handling in particular, tetramethylammonium hydroxide and tetraethylammonium hydroxide are particularly preferable, and an inorganic base may be used in combination with the quaternary ammonium hydroxide. Preferred inorganic bases are alkali metal hydroxides, such as potassium hydroxide, sodium hydroxide, and rubidium hydroxide, with potassium hydroxide being more preferable.

### [IX]

The resist underlayer film forming composition according to the present invention is characterized in that one, or two or more kinds of bases B² are separately added as additional base components.

Without wishing to be bound by theory, the bases that are added trap the acid generated at the time of baking and thereby slow down the curing rate. As a result, the composition can form cured films on various kinds of films, such as SiO₂, TiN, and SiN, while exhibiting high flattening properties and high gap-filling properties. Furthermore, the bases eliminate influences of the acid generator on the polymer that is a main component of the resist underlayer film and the storage stability of the polymer can be ensured. Thus, the composition is free from coloration and can form films that are not dissolved by photoresist solvents.

### EXAMPLES

### [Synthesis 1 of Polymers]

Compounds A, compounds B, compounds C, catalysts D, solvents E, and reprecipitation solvent F described below were used for the synthesis of structural formulas (S1) to (S15) as polymers for use in resist underlayer films.

### Compounds A to C

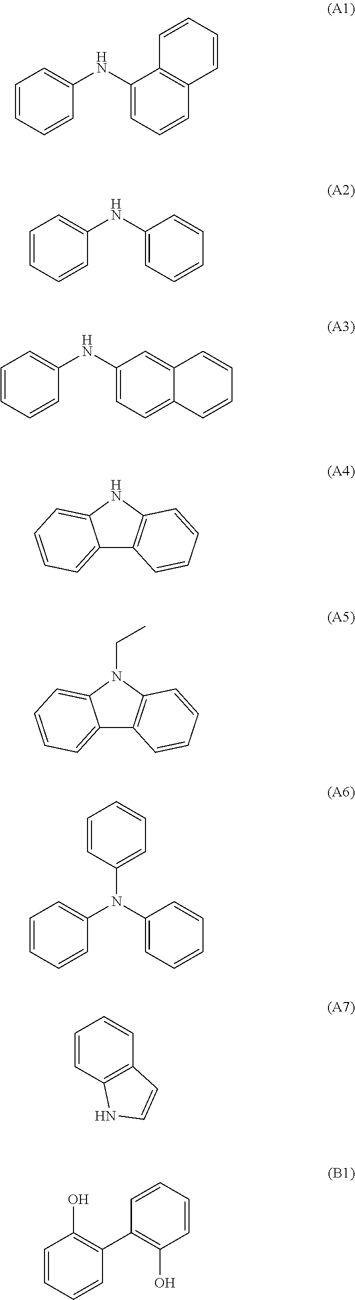

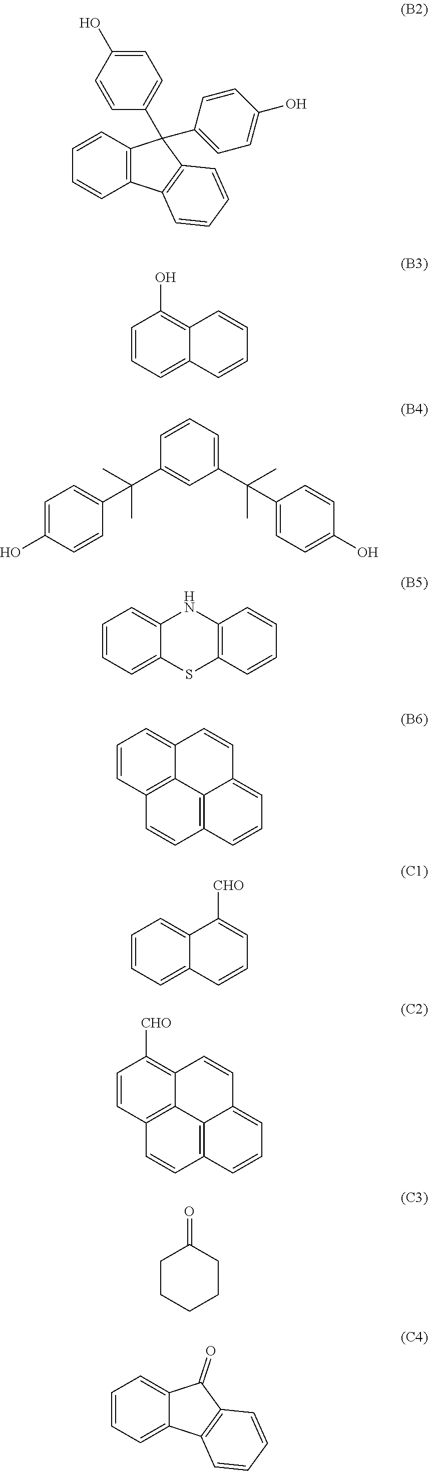

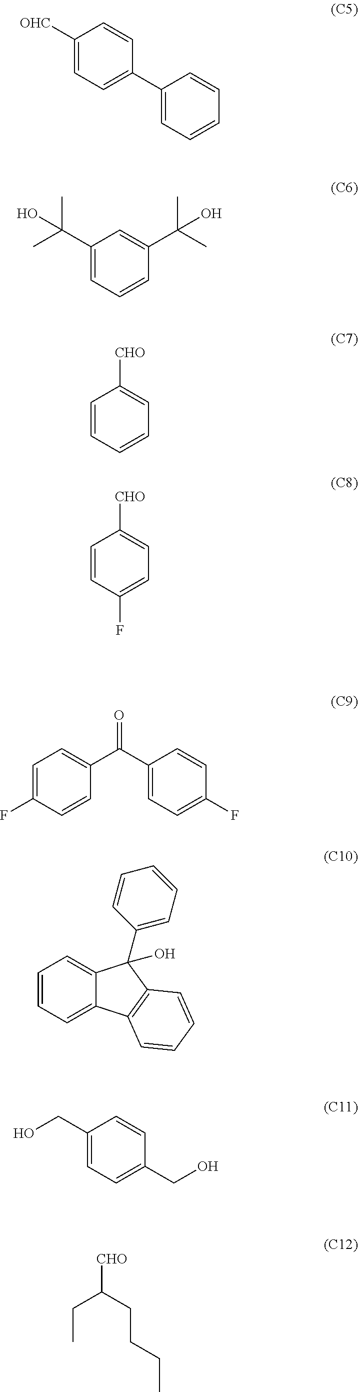

### Catalysts D, Solvents E, and Reprecipitation Solvent F

p-Toluenesulfonic acid monohydrate: D1
Methanesulfonic acid: D2
1,4-Dioxane: E1
Toluene: E2
Propylene glycol monomethyl ether acetate (=PGMEA): E3
Methanol: F1

### Synthesis Example 1

A flask was charged with 10.0 g of phenylnaphthylamine, 7.1 g of 1-naphthaldehyde, 0.9 g of p-toluenesulfonic acid monohydrate, and 21.0 g of 1,4-dioxane. Subsequently, the mixture was heated to 110° C. under nitrogen and reacted for about 12 hours. After the reaction was discontinued, the product was reprecipitated from methanol and was dried to give a resin (S1). The polystyrene-equivalent weight average molecular weight Mw measured by GPC was about 1,400. The resin obtained was dissolved into PGMEA, and ion exchange was performed for 4 hours using a cation exchange resin and an anion exchange resin. A target compound solution was thus obtained.

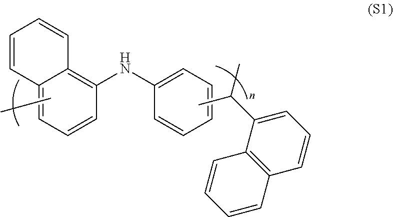

### Synthesis Examples 2 to 15

Polymers for use in resist underlayer films were synthesized while changing the types of the compounds A, the compounds B, the compounds C, the catalysts D, the solvents E, and the reprecipitation solvent F. The experimental procedures were the same as in Synthesis Example 1. The conditions adapted in the synthesis of polymers (S1) to (S15) are described below.

TABLE 1-1

| Syn. | Structural | | | | | Reprecip- |
|---|---|---|---|---|---|---|
| Ex. | formula | Compounds | Catalysts | Solvents | Temp./time | itation |
| 1 | S1 | A1/C1 | D1 | E1 | 110° C./ | F1 |
| | | 10.0 g/7.1 g | 0.9 g | 21.0 g | 12 hr | |
| 2 | S2 | A1/C2 | D1 | E1/E2 | Reflux/ | F1 |
| | | 8.0 g/8.5 g | 1.0 g | 16.3 g/16.3 g | 20 hr | |
| 3 | S3 | A2/C3/C4 | D2 | — | Reflux/ | F1 |
| | | 10.0 g/10.7 g/ | 2.8 g | | 2.5 hr | |
| | | 23.5 g | | | | |
| 4 | S4 | A2/C5 | D2 | E3 | 115° C./ | F1 |
| | | 10.0 g/10.8 g | 0.3 g | 63.2 g | 4 hr | |
| 5 | S5 | A3/C6 | D2 | E3 | Reflux/ | F1 |
| | | 65.0 g/55.3 g | 8.2 g | 192.7 g | 5 hr | |
| 6 | S6 | A4/C1 | D2 | E3 | 120° C./ | F1 |
| | | 35.0 g/32.7 g | 2.0 g | 162.7 g | 7 hr | |
| 7 | S7 | A3/C4 | D2 | E3 | Reflux/ | F1 |
| | | 8.0 g/8.6 g | 2.3 g | 18.9 g | 1.5 hr | |
| 8 | S8 | A5/C7 | D2 | E3 | Reflux/ | F1 |
| | | 8.0 g/4.4 g | 0.6 g | 30.2 g | 3 hr | |
| 9 | S9 | A6/C5 | D2 | E3 | 100° C./ | F1 |
| | | 10.0 g/7.4 g | 0.4 g | 53.5 g | 15 hr | |
| 10 | S10 | A2/B3/B4/C8 | D2 | E3 | Reflux/ | F1 |
| | | 15.0 g/1.8 g/8.8 g/ | 0.6 g | 168.0 g | 4 hr | |
| | | 15.7 g | | | | |
| 11 | S11 | A2/B1/B2/C8 | D2 | E3 | Reflux/ | F1 |
| | | 15.0 g/2.4 g/8.9 g/ | 0.6 g | 170.3 g | 4 hr | |
| | | 15.7 g | | | | |
| 12 | S12 | A2/B5/C8/C9 | D2 | E3 | Reflux/ | F1 |
| | | 60.0 g/10.1 g/ | 2.4 g | 630.2 g | 4 hr | |
| | | 62.9 g/22.1 g | | | | |
| 13 | S13 | A2/A7/B6/C8 | D2 | E3 | Reflux/ | F1 |
| | | 70.0 g/13.9 g/ | 2.8 g | 53.5 g | 4 hr | |
| | | 112.0 g/73.4 g | | | | |

TABLE 1-2

| | | | | | | |
|---|---|---|---|---|---|---|
| 14 | S14 | A2/C8/C10/C11 | D2 | E3 | Reflux/ | F1 |
| | | 70.0 g/41.1 g/ | 1.7 g | 688.4 g | 5 hr | |
| | | 5.3 g/8.6 g | | | | |
| 15 | S15 | A2/C1/C8/C12 | D2 | E3 | Reflux/ | F1 |
| | | 100.0 g/9.2 g/ | 2.8 g | 675.6 g | 4 hr | |
| | | 66.1 g/7.6 g | | | | |

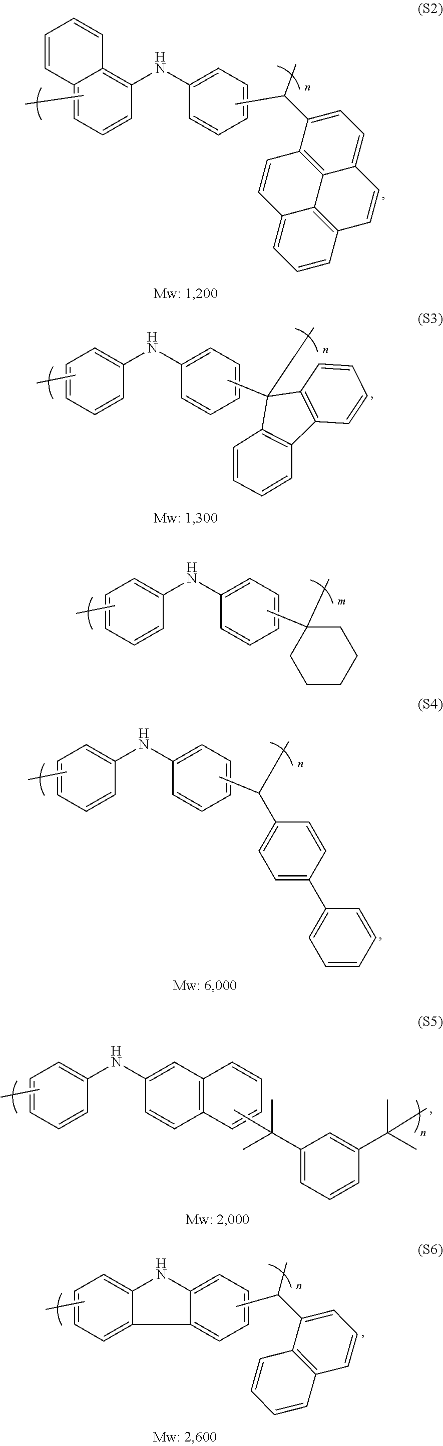

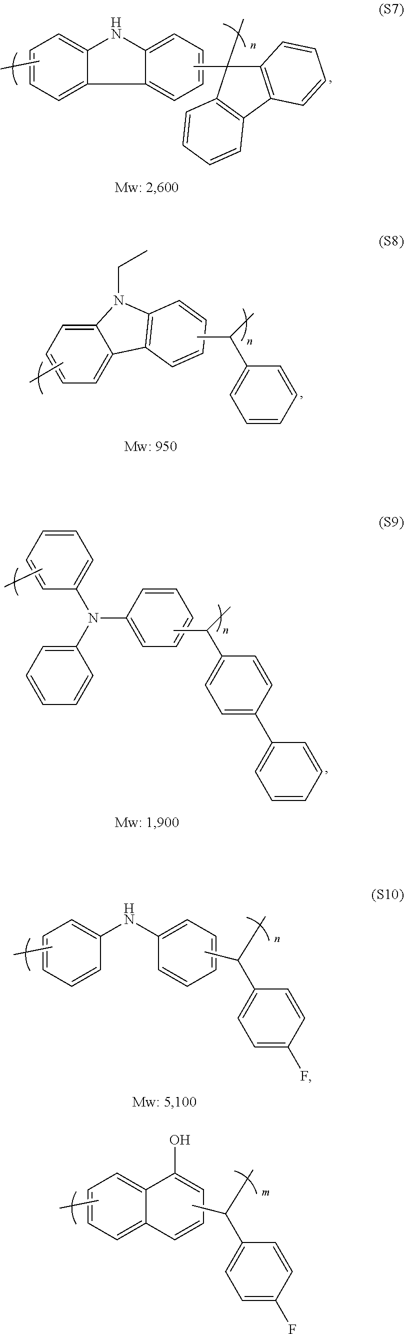

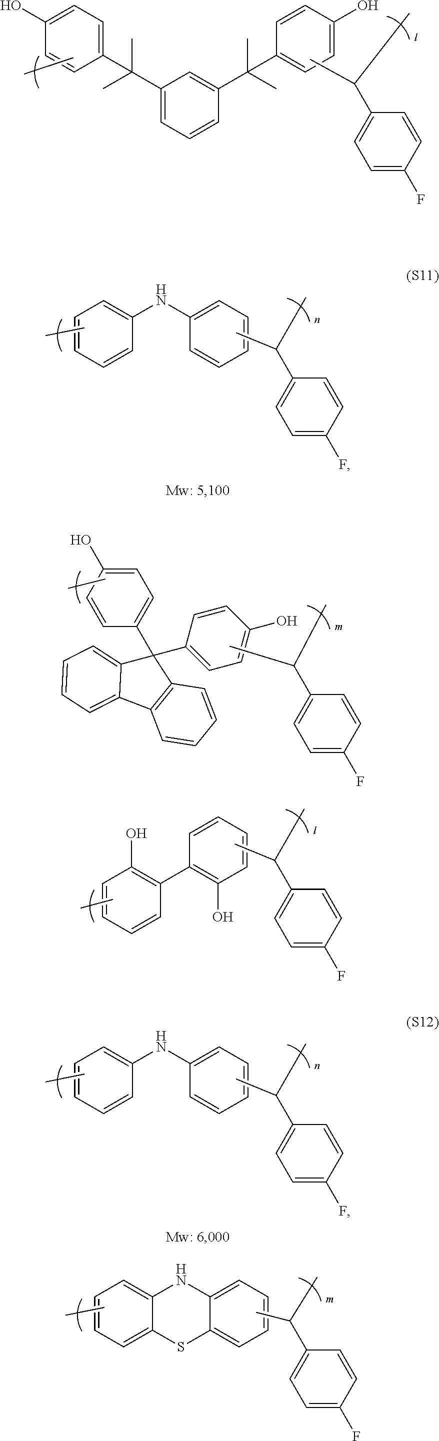

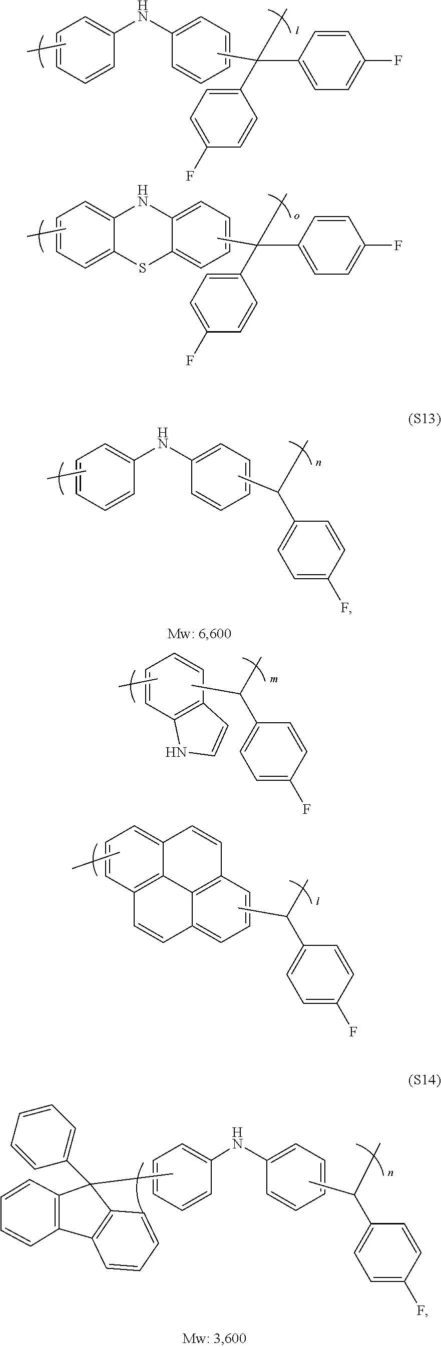

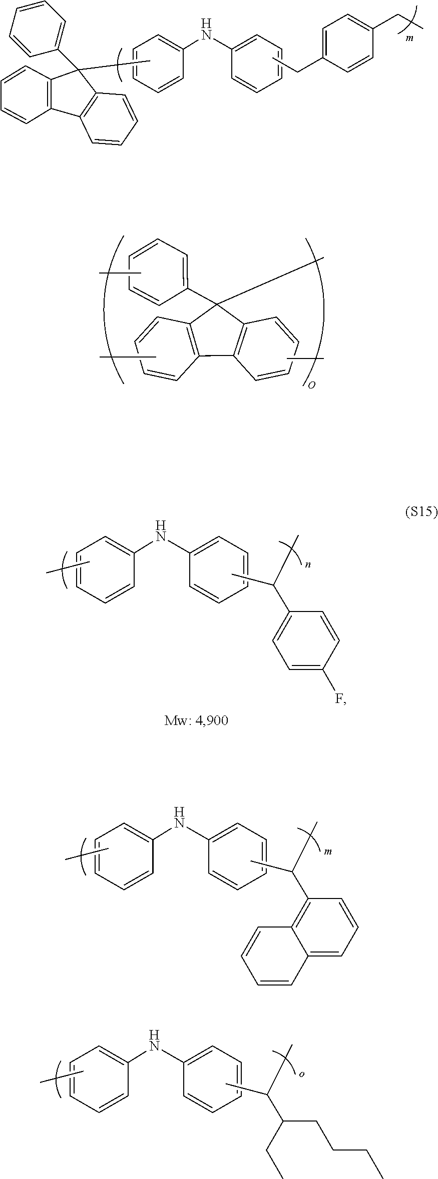

### [Preparation 1 of Resist Underlayer Films]

The polymers (S1) to (S15), crosslinking agents (CR1 and CR2), acid generators (Ad1 to Ad3), bases (Base 1 to Base 12) (the amount is described in parentheses as a molar ratio relative to the number of moles of the acid generator), solvents (propylene glycol monomethyl ether acetate (PGMEA), propylene glycol monomethyl ether (PGME), cyclohexanone (CYH)), and MEGAFACE R-40 (manufactured by DIC CORPORATION, G1) as a surfactant were mixed in proportions described in the tables below. The mixtures were filtered through a 0.1 μm polytetrafluoroethylene microfilter. Resist underlayer film materials (M1 to M29 and Comparative M1 to Comparative M18) were thus prepared.

In the tables, the numerical values for the crosslinking agents, the acid generators, and the surfactant indicate the numbers of grams of the crosslinking agents, the acid generators, and the surfactant used per 100 g of the polymer. As mentioned above, the numerical values for the bases are described in parentheses because the values are molar ratios relative to the number of moles of the acid generator and are based on a different standard from the other numerical values. Furthermore, the numerical values for the respective solvents indicate the numbers of grams of the solvents used in 100 g of the whole solvent.

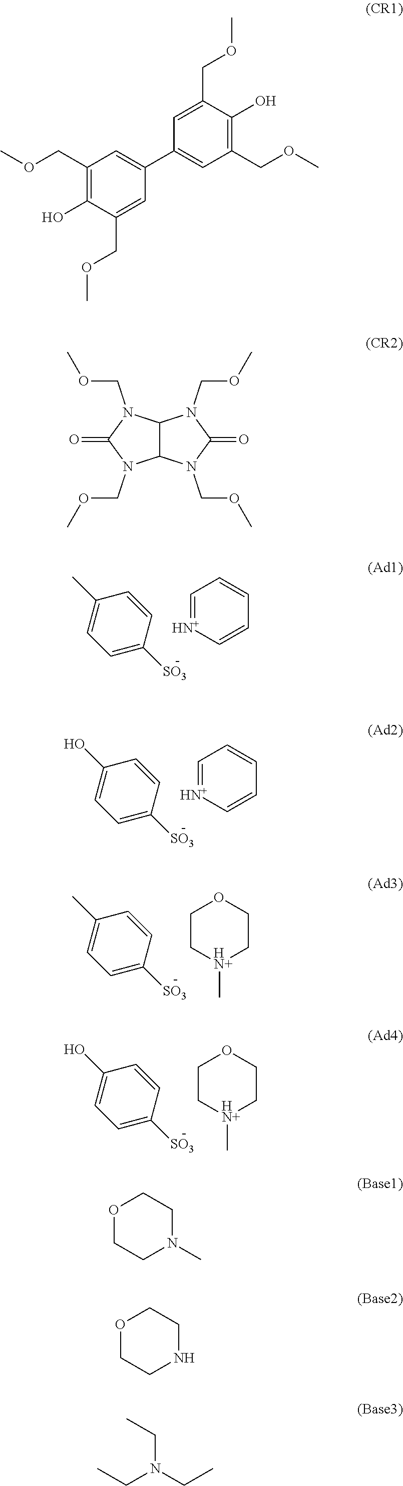

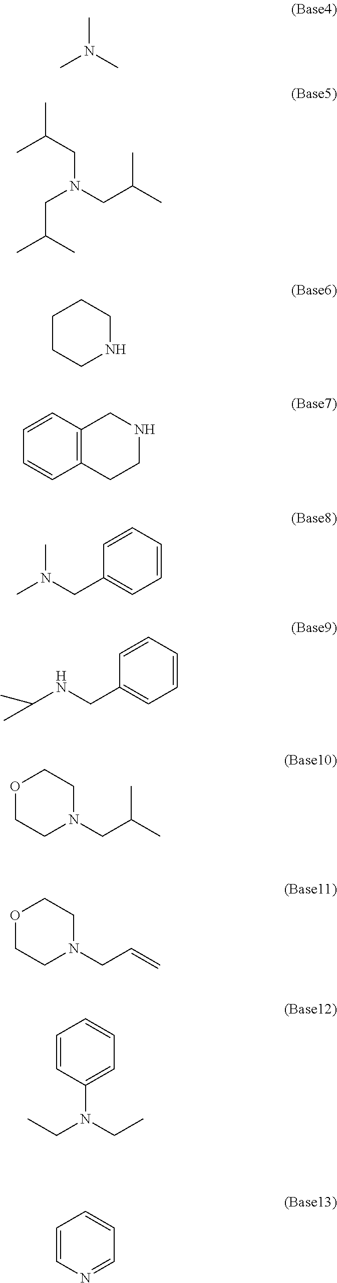

TABLE 2-1

| | | Crosslinking | Acid | | | Solvents | | |
|---|---|---|---|---|---|---|---|---|
| Composition | Polymer | agent | generator | Base | Surfactant | (100 in total) | | |
| M1 | Syn. | CR1 | Ad2 | Base1 | G1 | PGMEA | PGME | CYH |
| | Ex.1 | | | | | | | |
| | 100 | 35 | 3.75 | (2.0) | 0.1 | 40 | 30 | 30 |
| M2 | Syn. | CR1 | Ad2 | Base2 | G1 | PGMEA | PGME | CYH |
| | Ex.1 | | | | | | | |
| | 100 | 35 | 3.75 | (2.0) | 0.1 | 40 | 30 | 30 |
| M3 | Syn. | CR1 | Ad2 | Base3 | G1 | PGMEA | PGME | CYH |
| | Ex.1 | | | | | | | |
| | 100 | 35 | 3.75 | (2.0) | 0.1 | 40 | 30 | 30 |
| M4 | Syn. | CR1 | Ad2 | Base4 | G1 | PGMEA | PGME | CYH |
| | Ex.1 | | | | | | | |
| | 100 | 35 | 3.75 | (2.0) | 0.1 | 40 | 30 | 30 |
| M5 | Syn. | CR1 | Ad2 | Base5 | G1 | PGMEA | PGME | CYH |
| | Ex.1 | | | | | | | |
| | 100 | 35 | 3.75 | (2.0) | 0.1 | 40 | 30 | 30 |
| M6 | Syn. | CR1 | Ad2 | Base6 | G1 | PGMEA | PGME | CYH |
| | Ex.1 | | | | | | | |
| | 100 | 35 | 3.75 | (2.0) | 0.1 | 40 | 30 | 30 |
| M7 | Syn. | CR1 | Ad2 | Base7 | G1 | PGMEA | PGME | CYH |
| | Ex.1 | | | | | | | |
| | 100 | 35 | 3.75 | (2.0) | 0.1 | 40 | 30 | 30 |
| M8 | Syn. | CR1 | Ad2 | Base8 | G1 | PGMEA | PGME | CYH |
| | Ex.1 | | | | | | | |
| | 100 | 35 | 3.75 | (2.0) | 0.1 | 40 | 30 | 30 |
| M9 | Syn. | CR1 | Ad2 | Base9 | G1 | PGMEA | PGME | CYH |
| | Ex.1 | | | | | | | |
| | 100 | 35 | 3.75 | (2.0) | 0.1 | 40 | 30 | 30 |
| M10 | Syn. | CR1 | Ad2 | Base10 | G1 | PGMEA | PGME | CYH |
| | Ex.1 | | | | | | | |
| | 100 | 35 | 3.75 | (2.0) | 0.1 | 40 | 30 | 30 |

TABLE 2-2

| M11 | Syn. | CR1 | Ad2 | Base11 | G1 | PGMEA | PGME | CYH |
|---|---|---|---|---|---|---|---|---|
| | Ex.1 | | | | | | | |
| | 100 | 35 | 3.75 | (2.0) | 0.1 | 40 | 30 | 30 |
| M12 | Syn. | CR1 | Ad2 | Base12 | G1 | PGMEA | PGME | CYH |
| | Ex.1 | | | | | | | |
| | 100 | 35 | 3.75 | (2.0) | 0.1 | 40 | 30 | 30 |
| M13 | Syn. | CR2 | Ad1 | Base1 | G1 | PGMEA | PGME | CYH |
| | Ex.2 | | | | | | | |
| | 100 | 20 | 3.0 | (1.5) | 0.1 | 40 | 10 | 50 |
| M14 | Syn. | CR1 | Ad2 | Base1 | G1 | PGMEA | PGME | CYH |
| | Ex.3 | | | | | | | |
| | 100 | 20 | 3.0 | (2.0) | 0.1 | 40 | 30 | 30 |
| M15 | Syn. | CR2 | Ad1 | Base1 | G1 | PGMEA | PGME | CYH |
| | Ex.4 | | | | | | | |
| | 100 | 25 | 3.75 | (0.5) | 0.1 | 40 | 30 | 30 |
| M16 | Syn. | CR2 | Ad1 | Base1 | G1 | PGMEA | PGME | CYH |
| | Ex.4 | | | | | | | |
| | 100 | 25 | 3.75 | (1.0) | 0.1 | 40 | 30 | 30 |
| M17 | Syn. | CR2 | Ad1 | Base1 | G1 | PGMEA | PGME | CYH |
| | Ex.4 | | | | | | | |
| | 100 | 25 | 3.75 | (1.5) | 0.1 | 40 | 30 | 30 |
| M18 | Syn. | CR2 | Ad1 | Base1 | G1 | PGMEA | PGME | CYH |
| | Ex.4 | | | | | | | |
| | 100 | 25 | 3.75 | (2.0) | 0.1 | 40 | 30 | 30 |
| M19 | Syn. | CR2 | Ad1 | Base1 | G1 | PGMEA | PGME | CYH |
| | Ex.5 | | | | | | | |
| | 100 | 25 | 3.75 | (2.0) | 0.1 | 70 | 30 | 0 |
| M20 | Syn. | CR2 | Ad1 | Base1 | G1 | PGMEA | PGME | CYH |
| | Ex.6 | | | | | | | |
| | 100 | 25 | 3.75 | (2.0) | 0.1 | 40 | 30 | 30 |
| M21 | Syn. | CR2 | Ad1 | Base1 | G1 | PGMEA | PGME | CYH |
| | Ex.7 | | | | | | | |
| | 100 | 25 | 3.75 | (2.0) | 0.1 | 40 | 30 | 30 |

TABLE 2-3

| M22 | Syn. | CR2 | Ad1 | Base1 | G1 | PGMEA | PGME | CYH |
|---|---|---|---|---|---|---|---|---|
| | Ex. 8 | | | | | | | |
| | 100 | 35 | 3.0 | (2.0) | 0.1 | 40 | 30 | 30 |
| M23 | Syn. | CR2 | Ad1 | Base1 | G1 | PGMEA | PGME | CYH |
| | Ex. 9 | | | | | | | |
| | 100 | 35 | 3.0 | (2.0) | 0.1 | 40 | 30 | 30 |
| M24 | Syn. | CR1 | Ad1 | Base1 | G1 | PGMEA | PGME | CYH |
| | Ex. 10 | | | | | | | |
| | 100 | 35 | 3.75 | (2.0) | 0.1 | 70 | 30 | 0 |
| M25 | Syn. | CR1 | Ad1 | Base1 | G1 | PGMEA | PGME | CYH |
| | Ex. 11 | | | | | | | |
| | 100 | 35 | 3.75 | (2.0) | 0.1 | 70 | 30 | 0 |
| M26 | Syn. | CR1 | Ad1 | Base1 | G1 | PGMEA | PGME | CYH |
| | Ex. 12 | | | | | | | |
| | 100 | 35 | 3.75 | (2.0) | 0.1 | 70 | 30 | 0 |
| M27 | Syn. | CR1 | Ad1 | Base1 | G1 | PGMEA | PGME | CYH |
| | Ex. 13 | | | | | | | |
| | 100 | 35 | 3.75 | (2.0) | 0.1 | 70 | 30 | 0 |
| M28 | Syn. | CR1 | Ad1 | Base1 | G1 | PGMEA | PGME | CYH |
| | Ex. 14 | | | | | | | |
| | 100 | 35 | 3.75 | (2.0) | 0.1 | 70 | 30 | 0 |
| M29 | Syn. | CR1 | Ad1 | Base1 | G1 | PGMEA | PGME | CYH |
| | Ex. 15 | | | | | | | |
| | 100 | 35 | 3.75 | (2.0) | 0.1 | 70 | 30 | 0 |

TABLE 2-4

| | | Crosslinking | Acid | | | Solvents | | |
|---|---|---|---|---|---|---|---|---|
| Composition | Polymer | agent | generator | Base | Surfactant | (100 in total) | | |
| Comp. M1 | Syn. | CR1 | Ad2 | — | G1 | PGMEA | PGME | CYH |
| | Ex. 1 | | | | | | | |
| | 100 | 35 | 3.75 | — | 0.1 | 40 | 30 | 30 |
| Comp. M2 | Syn. | CR1 | Ad4 | — | G1 | PGMEA | PGME | CYH |
| | Ex. 1 | | | | | | | |
| | 100 | 35 | 3.75 | — | 0.1 | 40 | 30 | 30 |
| Comp. M3 | Syn. | CR2 | Ad1 | — | G1 | PGMEA | PGME | CYH |
| | Ex. 2 | | | | | | | |
| | 100 | 20 | 3.0 | — | 0.1 | 40 | 10 | 50 |
| Comp. M4 | Syn. | CR1 | Ad2 | — | G1 | PGMEA | PGME | CYH |
| | Ex. 3 | | | | | | | |
| | 100 | 20 | 3.0 | — | 0.1 | 40 | 30 | 30 |
| Comp. M5 | Syn. | CR2 | Ad1 | — | G1 | PGMEA | PGME | CYH |
| | Ex. 4 | | | | | | | |
| | 100 | 25 | 3.75 | — | 0.1 | 40 | 30 | 30 |
| Comp. M6 | Syn. | CR2 | Ad3 | — | G1 | PGMEA | PGME | CYH |
| | Ex. 4 | | | | | | | |
| | 100 | 25 | 3.75 | — | 0.1 | 40 | 30 | 30 |
| Comp. M7 | Syn. | CR2 | Ad1 | — | G1 | PGMEA | PGME | CYH |
| | Ex. 5 | | | | | | | |
| | 100 | 25 | 3.75 | — | 0.1 | 70 | 30 | 0 |
| Comp. M8 | Syn. | CR2 | Ad1 | — | G1 | PGMEA | PGME | CYH |
| | Ex. 6 | | | | | | | |
| | 100 | 25 | 3.75 | — | 0.1 | 40 | 30 | 30 |
| Comp. M9 | Syn. | CR2 | Ad1 | — | G1 | PGMEA | PGME | CYH |
| | Ex. 7 | | | | | | | |
| | 100 | 25 | 3.75 | — | 0.1 | 40 | 30 | 30 |
| Comp. M10 | Syn. | CR2 | Ad1 | — | G1 | PGMEA | PGME | CYH |
| | Ex. 8 | | | | | | | |
| | 100 | 35 | 3.0 | — | 0.1 | 40 | 30 | 30 |

TABLE 2-5

| Comp. M11 | Syn. | CR2 | Ad1 | — | G1 | PGMEA | PGME | CYH |
|---|---|---|---|---|---|---|---|---|
| | Ex. 9 | | | | | | | |
| | 100 | 35 | 3.0 | — | 0.1 | 40 | 30 | 30 |
| Comp. M12 | Syn. | CR1 | Ad1 | — | G1 | PGMEA | PGME | CYH |
| | Ex. 10 | | | | | | | |
| | 100 | 35 | 3.75 | — | 0.1 | 70 | 30 | 0 |
| Comp. M13 | Syn. | CR1 | Ad1 | — | G1 | PGMEA | PGME | CYH |
| | Ex. 11 | | | | | | | |
| | 100 | 35 | 3.75 | — | 0.1 | 70 | 30 | 0 |
| Comp. M14 | Syn. | CR1 | Ad1 | — | G1 | PGMEA | PGME | CYH |
| | Ex. 12 | | | | | | | |
| | 100 | 35 | 3.75 | — | 0.1 | 70 | 30 | 0 |
| Comp. M15 | Syn. | CR1 | Ad1 | — | G1 | PGMEA | PGME | CYH |
| | Ex. 13 | | | | | | | |
| | 100 | 35 | 3.75 | — | 0.1 | 70 | 30 | 0 |
| Comp. M16 | Syn. | CR1 | Ad1 | — | G1 | PGMEA | PGME | CYH |
| | Ex. 14 | | | | | | | |
| | 100 | 35 | 3.75 | — | 0.1 | 70 | 30 | 0 |
| Comp. M17 | Syn. | CR1 | Ad1 | — | G1 | PGMEA | PGME | CYH |
| | Ex. 15 | | | | | | | |
| | 100 | 35 | 3.75 | — | 0.1 | 70 | 30 | 0 |
| Comp. M18 | Syn. | CR2 | Ad1 | Base13 | G1 | PGMEA | PGME | CYH |
| | Ex. 4 | | | | | | | |
| | 100 | 25 | 3.75 | (2.0) | 0.1 | 40 | 30 | 30 |

The evaluations in Examples described later show the results of characteristics compared to Comparative Examples involving the polymer from the same Synthesis Example.
[Test 1 of Dissolution into Resist Solvent]

The resist underlayer film materials were each applied onto a silicon wafer using a spin coater, and the coatings were baked on a hot plate at 240° C. for 60 seconds to form a resist underlayer film with a film thickness of about 120 nm (Comparative Examples 1 to 18 and Examples 1 to 29). The resist underlayer films formed were soaked in a general-purpose thinner, specifically, PGME/PGMEA=7/3 for 60 seconds and were spin dried and baked at 100° C. for 30 seconds. The film thicknesses before and after the thinner immersion were compared to examine the resistance to the solvent. The resistance was evaluated as ∘ when the loss in film thickness after the thinner immersion was less than 1%, and as x when the loss in film thickness was 1% or more.

### [Test 1 of Storage Stability of Resist Underlayer Film Materials]

The resist underlayer film materials were adjusted so that the total solid content in the material would be 3% (Comparative Examples 1 to 18 and Examples 1 to 29). The samples were placed in screw tubes and were stored in a thermostatic chamber at 35° C. under dark conditions for one week. After one week, the color of the samples was visually compared to that before the storage. The storage stability was evaluated as x when the color had changed, and as ∘ when the color remained unchanged.

TABLE 3-1
(Table 1)

| Ex./ | | | Solvent | Change in |
|---|---|---|---|---|
| Comp. Ex. | Composition | Baking temp. | resistance | solution color |
| Ex. 1 | M1 | 240° C./60 sec | ∘ | ∘ |
| Ex. 2 | M2 | 240° C./60 sec | ∘ | ∘ |
| Ex. 3 | M3 | 240° C./60 sec | ∘ | ∘ |
| Ex. 4 | M4 | 240° C./60 sec | ∘ | ∘ |
| Ex. 5 | M5 | 240° C./60 sec | ∘ | ∘ |
| Ex. 6 | M6 | 240° C./60 sec | ∘ | ∘ |
| Ex. 7 | M7 | 240° C./60 sec | ∘ | ∘ |
| Ex. 8 | M8 | 240° C./60 sec | ∘ | ∘ |
| Ex. 9 | M9 | 240° C./60 sec | ∘ | ∘ |
| Ex. 10 | M10 | 240° C./60 sec | ∘ | ∘ |
| Ex. 11 | M11 | 240° C./60 sec | ∘ | ∘ |
| Ex. 12 | M12 | 240° C./60 sec | ∘ | ∘ |
| Ex. 13 | M13 | 240° C./60 sec | ∘ | ∘ |
| Ex. 14 | M14 | 240° C./60 sec | ∘ | ∘ |
| Ex. 15 | M15 | 240° C./60 sec | ∘ | ∘ |
| Ex. 16 | M16 | 240° C./60 sec | ∘ | ∘ |
| Ex. 17 | M17 | 240° C./60 sec | ∘ | ∘ |
| Ex. 18 | M18 | 240° C./60 sec | ∘ | ∘ |
| Ex. 19 | M19 | 240° C./60 sec | ∘ | ∘ |
| Ex. 20 | M20 | 240° C./60 sec | ∘ | ∘ |
| Ex. 21 | M21 | 240° C./60 sec | ∘ | ∘ |
| Ex. 22 | M22 | 240° C./60 sec | ∘ | ∘ |
| Ex. 23 | M23 | 240° C./60 sec | ∘ | ∘ |
| Ex. 24 | M24 | 240° C./60 sec | ∘ | ∘ |
| Ex. 25 | M25 | 240° C./60 sec | ∘ | ∘ |
| Ex. 26 | M26 | 240° C./60 sec | ∘ | ∘ |
| Ex. 27 | M27 | 240° C./60 sec | ∘ | ∘ |
| Ex. 28 | M28 | 240° C./60 sec | ∘ | ∘ |
| Ex. 29 | M29 | 240° C./60 sec | ∘ | ∘ |

TABLE 3-2

| | | | | |
|---|---|---|---|---|
| Comp. Ex. 1 | Comp. M1 | 240° C./60 sec | ∘ | x |
| Comp. Ex. 2 | Comp. M2 | 240° C./60 sec | ∘ | x |
| Comp. Ex. 3 | Comp. M3 | 240° C./60 sec | ∘ | x |
| Comp. Ex. 4 | Comp. M4 | 240° C./60 sec | ∘ | x |
| Comp. Ex. 5 | Comp. M5 | 240° C./60 sec | ∘ | x |
| Comp. Ex. 6 | Comp. M6 | 240° C./60 sec | ∘ | x |
| Comp. Ex. 7 | Comp. M7 | 240° C./60 sec | ∘ | x |
| Comp. Ex. 8 | Comp. M8 | 240° C./60 sec | ∘ | x |
| Comp. Ex. 9 | Comp. M9 | 240° C./60 sec | ∘ | x |
| Comp. Ex. 10 | Comp. M10 | 240° C./60 sec | ∘ | x |
| Comp. Ex. 11 | Comp. M11 | 240° C./60 sec | ∘ | x |
| Comp. Ex. 12 | Comp. M12 | 240° C./60 sec | ∘ | x |
| Comp. Ex. 13 | Comp. M13 | 240° C./60 sec | ∘ | x |
| Comp. Ex. 14 | Comp. M14 | 240° C./60 sec | ∘ | x |
| Comp. Ex. 15 | Comp. M15 | 240° C./60 sec | ∘ | x |
| Comp. Ex. 16 | Comp. M16 | 240° C./60 sec | ∘ | x |
| Comp. Ex. 17 | Comp. M17 | 240° C./60 sec | ∘ | x |
| Comp. Ex. 18 | Comp. M18 | 240° C./60 sec | ∘ | x |

### [Evaluation 1 of Gap-Filling Properties]

Gap-filling properties were evaluated using 200 nm thick SiO₂ substrate, SiN substrate, and TiN substrate that had a dense pattern area consisting of 50 nm wide trenches at 100 nm pitches. The resist underlayer film materials were each applied onto the substrate, and the coatings were baked at 240° C. for 60 seconds to form a resist underlayer film having a thickness of about 120 nm (Comparative Examples 1 to 20 and Examples 1 to 31). The flatness of the substrates was evaluated using a scanning electron microscope (S-4800) manufactured by Hitachi High-Tech Corporation, and whether the resist underlayer film forming composition had filled the inside of the pattern was determined. The gap-filling properties were rated as ∘ when the resist underlayer film forming composition had filled the inside of the pattern, and as x when the resist underlayer film forming composition had failed to fill the inside of the pattern.

### [Test 1 of Covering Performance on Non-Planar Substrates]

To test the covering performance on a non-planar substrate, the resist underlayer film forming compositions were each applied to 200 nm thick SiO₂ substrate, SiN substrate, and TiN substrate, and the coatings were baked at 240° C. for 60 seconds to form a resist underlayer film having a thickness of about 120 nm (Comparative Examples 1 to 20 and Examples 1 to 31). The coating film thickness was compared between at an 800 nm trenched area (TRENCH) and at an open area (OPEN) free from patterns. The flatness of the substrates was evaluated using a scanning electron microscope (S-4800) manufactured by Hitachi High-Tech Corporation by measuring the difference in film thickness between on the trenched area (the patterned area) and on the open area (the pattern-free area) of the non-planar substrate (the step height created on the coating film between the trenched area and the open area, called a bias). Here, the flatness means how small the difference (an iso-dense bias) is in the film thickness of the coating film between on the region with the pattern (the trenched area (the patterned area)) and on the region without patterns (the open area (the pattern-free area)). Flattening properties were rated as o when the bias was improved compared to Comparative Examples.

TABLE 4-1
(Table 2)

| Ex./ | | | | | |
|---|---|---|---|---|---|
| Comp. | | Film | | Gap-filling | Flattening |
| Ex. | Composition | thickness | Substrate | properties | properties |
| Ex. 1 | M1 | 120 nm | TiN | ∘ | ∘ |
| Ex. 2 | M2 | 120 nm | TiN | ∘ | ∘ |
| Ex. 3 | M3 | 120 nm | TiN | ∘ | ∘ |
| Ex. 4 | M4 | 120 nm | TiN | ∘ | ∘ |
| Ex. 5 | M5 | 120 nm | TiN | ∘ | ∘ |
| Ex. 6 | M6 | 120 nm | TiN | ∘ | ∘ |
| Ex. 7 | M7 | 120 nm | TiN | ∘ | ∘ |
| Ex. 8 | M8 | 120 nm | TiN | ∘ | ∘ |
| Ex. 9 | M9 | 120 nm | TiN | ∘ | ∘ |
| Ex. 10 | M10 | 120 nm | TiN | ∘ | ∘ |
| Ex. 11 | M11 | 120 nm | TiN | ∘ | ∘ |
| Ex. 12 | M12 | 120 nm | TiN | ∘ | ∘ |
| Ex. 13 | M13 | 120 nm | SiO₂ | ∘ | ∘ |
| Ex. 14 | M14 | 120 nm | SiN | ∘ | ∘ |
| Ex. 15 | M15 | 120 nm | SiO₂ | ∘ | ∘ |
| Ex. 16 | M16 | 120 nm | SiO₂ | ∘ | ∘ |
| Ex. 17 | M17 | 120 nm | SiO₂ | ∘ | ∘ |
| Ex. 18 | M18 | 120 nm | SiO₂ | ∘ | ∘ |
| Ex. 19 | M19 | 120 nm | SiO₂ | ∘ | ∘ |
| Ex. 20 | M20 | 120 nm | SiO₂ | ∘ | ∘ |
| Ex. 21 | M21 | 120 nm | SiO₂ | ∘ | ∘ |
| Ex. 22 | M22 | 120 nm | SiO₂ | ∘ | ∘ |
| Ex. 23 | M23 | 120 nm | SiO₂ | ∘ | ∘ |
| Ex. 24 | M24 | 120 nm | SiO₂ | ∘ | ∘ |
| Ex. 25 | M25 | 120 nm | SiN | ∘ | ∘ |
| Ex. 26 | M26 | 120 nm | SiO₂ | ∘ | ∘ |
| Ex. 27 | M27 | 120 nm | SiN | ∘ | ∘ |
| Ex. 28 | M28 | 120 nm | SiN | ∘ | ∘ |
| Ex. 29 | M29 | 120 nm | SiN | ∘ | ∘ |
| Ex. 30 | M1 | 120 nm | SiN | ∘ | ∘ |
| Ex. 31 | M1 | 120 nm | SiO₂ | ∘ | ∘ |

TABLE 4-2

| | | | | | |
|---|---|---|---|---|---|
| Comp. Ex. 1 | Comp. M1 | 120 nm | TiN | ∘ | x |
| Comp. Ex. 2 | Comp. M2 | 120 nm | TiN | ∘ | x |
| Comp. Ex. 3 | Comp. M3 | 120 nm | SiO₂ | ∘ | x |
| Comp. Ex. 4 | Comp. M4 | 120 nm | SiN | ∘ | x |
| Comp. Ex. 5 | Comp. M5 | 120 nm | SiO₂ | ∘ | x |
| Comp. Ex. 6 | Comp. M6 | 120 nm | SiO₂ | ∘ | x |
| Comp. Ex. 7 | Comp. M7 | 120 nm | SiO₂ | ∘ | x |
| Comp. Ex. 8 | Comp. M8 | 120 nm | SiO₂ | x | x |
| Comp. Ex. 9 | Comp. M9 | 120 nm | SiO₂ | x | x |
| Comp. Ex. 10 | Comp. M10 | 120 nm | SiO₂ | ∘ | x |
| Comp. Ex. 11 | Comp. M11 | 120 nm | SiO₂ | ∘ | x |
| Comp. Ex. 12 | Comp. M12 | 120 nm | SiO₂ | ∘ | x |
| Comp. Ex. 13 | Comp. M13 | 120 nm | SiN | ∘ | x |
| Comp. Ex. 14 | Comp. M14 | 120 nm | SiO₂ | ∘ | x |
| Comp. Ex. 15 | Comp. M15 | 120 nm | SiO₂ | ∘ | x |
| Comp. Ex. 16 | Comp. M16 | 120 nm | SiO₂ | ∘ | x |
| Comp. Ex. 17 | Comp. M17 | 120 nm | SiN | ∘ | x |
| Comp. Ex. 18 | Comp. M18 | 120 nm | SiO₂ | ∘ | x |
| Comp. Ex. 19 | Comp. M1 | 120 nm | SiN | ∘ | x |
| Comp. Ex. 20 | Comp. M1 | 120 nm | SiO₂ | ∘ | x |

As described in Tables 1 and 2, the materials exhibit sufficient curability as resist underlayer films even when the base component has been added. Free sulfonic acid is captured by adding the amine component having a higher basicity than pyridine as the base. As a result, coloration stemming from the action of sulfonic acid on the polymer containing the amine component is suppressed, and consequently storage stability can be significantly improved. Furthermore, as a result of the addition of the base component, it is possible to trap part of the acid component generated from the acid generator in the resist underlayer film composition during baking. This slows down the curing rate to ensure a time for the resin to flow. As a result, a flatter film can be formed on a patterned substrate, and the resin can attain improved gap-filling properties. The above behavior and effects are achieved equally on various kinds of patterned substrates, such as SiN, SiO₂, and TiN.

### [Synthesis 2 of Polymers]

Compounds A′, compounds B′, catalysts C′, solvents D′, and reprecipitation solvents E′ described below were used for the synthesis of structural formulas (S′1) to (S′11) as polymers for use in resist underlayer films.

### Compounds A′ and B′

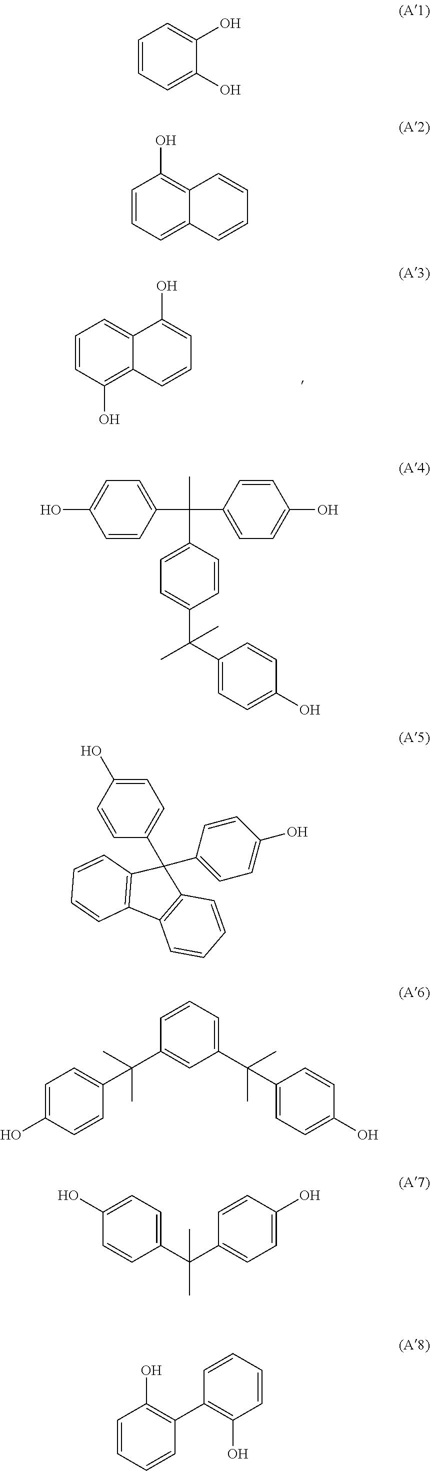

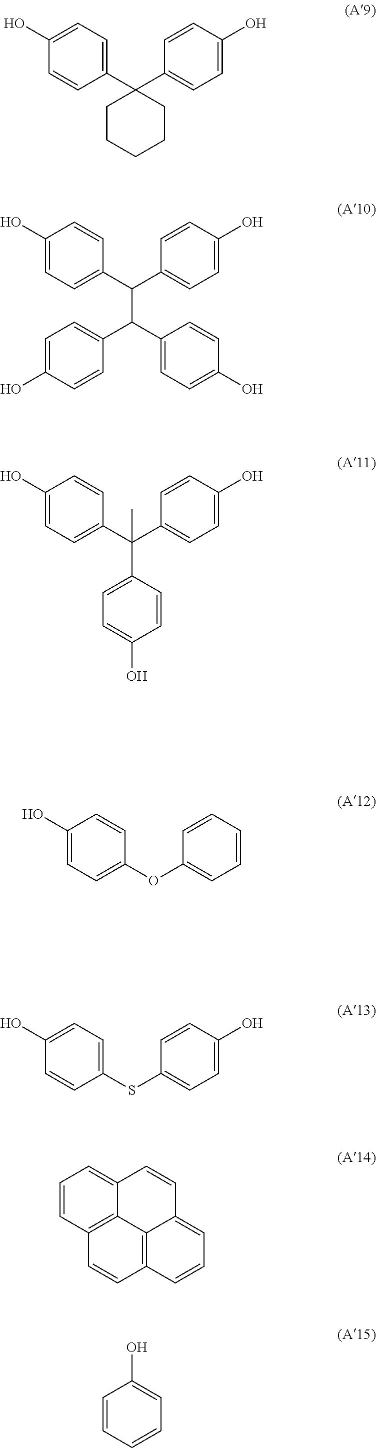

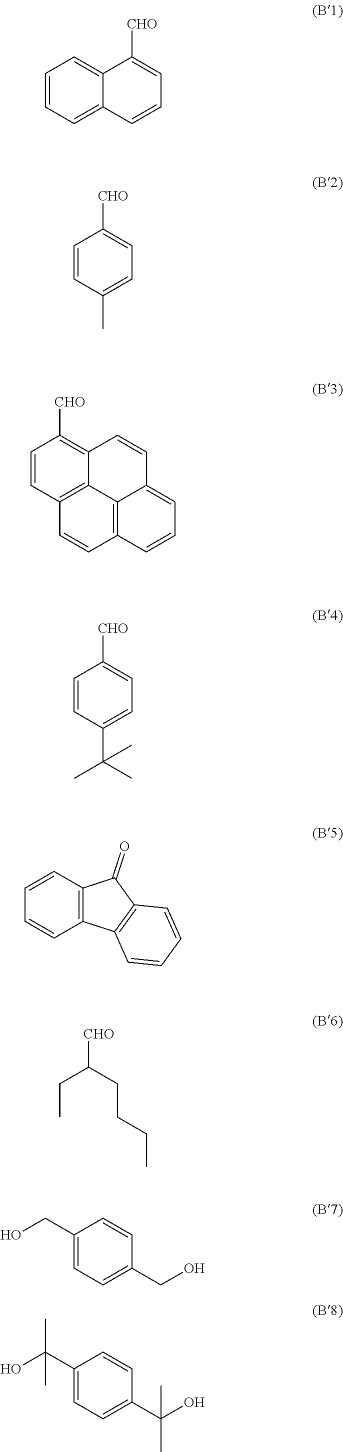

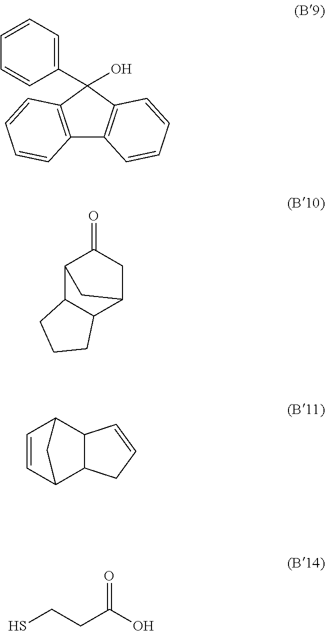 [SMILES: OC1(c2ccccc2)c2ccccc2-c2ccccc21 ; O=C1CC2CC1C1CCCC21 ; C1=CC2C3C=CC(C3)C2C1 ; O=C(O)CCS]

### Catalysts C′, Solvents D′, and Reprecipitation Solvents E′

Methanesulfonic acid: C′1
Trifluoromethanesulfonic acid: C′2
Propylene glycol monomethyl ether acetate: D′1
Propylene glycol monomethyl ether: D′2
Methanol/water: E′1
Methanol: E′2

### Synthesis Example 1′

A flask was charged with 13.0 g of catechol, 18.4 g of 1-naphthaldehyde, 3.4 g of methanesulfonic acid, 24.4 g of propylene glycol monomethyl ether acetate, and 10.5 g of propylene glycol monomethyl ether. Subsequently, the mixture was reacted under nitrogen for about 30 hours under reflux conditions. After the reaction was discontinued, the product was reprecipitated from methanol/water mixed solvent and was dried to give a resin (S′1). The polystyrene-equivalent weight average molecular weight Mw measured by GPC was about 1,650. The resin obtained was dissolved into PGMEA, and ion exchange was performed for 4 hours using a cation exchange resin and an anion exchange resin. A target compound solution was thus obtained.

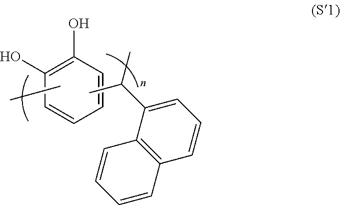

### Synthesis Examples 2′ to 11′

Polymers for use in resist underlayer films were synthesized while changing the types of the compounds A′, the compounds B′, the catalysts C′, the solvents D′, and the reprecipitation solvents E′. The experimental procedures were the same as in Synthesis Example 1′. The conditions adapted in the synthesis of polymers (S′1) to (S′11) are described below.

TABLE 5
(Table 3)

| Syn. | Structural | | | | Temp./ | Reprecip- |
|---|---|---|---|---|---|---|
| Ex. | formula | Compounds | Catalysts | Solvents | time | itation |
| 1′ | S′1 | A′1/B′1 | C′1 | D′1/D′2 | Reflux | E′1 |
| | | 13.0 g/18.4 g | 3.4 g | 24.4 g/10.5 g | 30 hr | |
| 2′ | S′2 | A′2/B′2 | C′1 | D′1 | Reflux | E′2 |
| | | 10.0 g/8.3 g | 1.3 g | 19.7 g | 7 hr | |
| 3′ | S′3 | A′3/B′2 | C′1 | D′1/D′2 | Reflux | E′2 |
| | | 10.0 g/7.5 g | 1.2 g | 21.8 g/21.8 g | 6 hr | |
| 4′ | S′4 | A′4/A′14/B′3 | C′1 | D′1/D′2 | Reflux | E′2 |
| | | 3.5 g/1.5 g/10.0 g | 0.8 g | 25.9 g/6.5 g | 4.75 hr | |
| 5′ | S′5 | A′5/B′4 | C′1 | D′1 | Reflux | E′2 |
| | | 10.0 g/4.7 g | 0.6 g | 22.8 g | 5.5 hr | |
| 6′ | S′6 | A′6/B′5 | C′1 | D′1 | Reflux | E′1 |
| | | 10.0 g/5.2 g | 0.7 g | 15.9 g | 13 hr | |
| 7′ | S′7 | A′11/A′13/B′3 | C′1 | D′1 | Reflux | E′2 |
| | | 5.6 g/12.0 g/25.5 g | 2.1 g | 180.1 g | 18 hr | |
| 8′ | S′8 | A′7/A′9/B′6/B′7 | C′1 | D′1 | Reflux | E′1 |
| | | 6.8 g/8.0 g/4.9 g/3.1 g | 1.2 g | 24.0 g | 4 hr | |
| 9′ | S′9 | A′10/A′12/B′8/B′9 | C′1 | D′1 | Reflux | E′1 |
| | | 6.4 g/7.0 g/9.4 g/1.4 g | 1.0 g | 25.2 g | 4 hr | |
| 10′ | S′10 | A′15/B′11 | C′2 | — | Reflux | E′1 |
| | | 18.8 g/8.0 g | 0.01 g | | 2 hr | |
| 11′ | S′11 | A′5/B′10/B′14 | C′1 | D′1 | Reflux | E′1 |
| | | 12.3 g/24.0 g/2.2 g | 2.0 g | 38.4 g | 16 hr | |

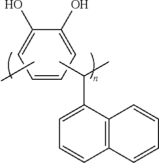

(S′1), Mw: 1,650 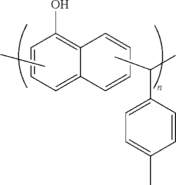
(S′2), Mw: 1,500 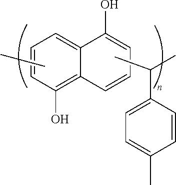
(S′3), Mw: 4,100 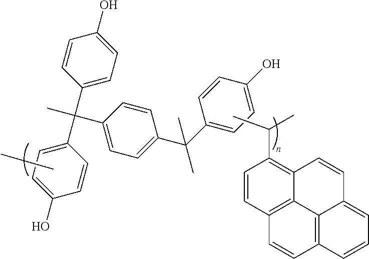 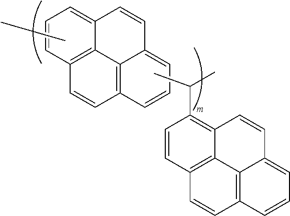
(S′4), Mw: 4,600 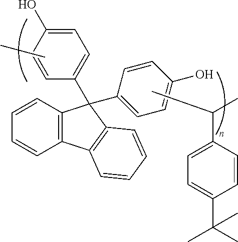
(S′5), Mw: 1,900 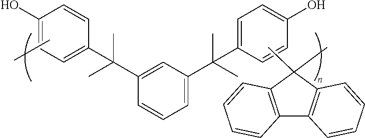
(S′6), Mw: 3,300 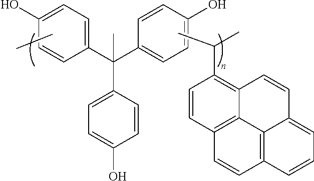 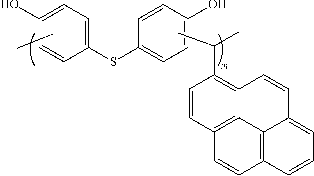
(S′7), Mw: 2,300 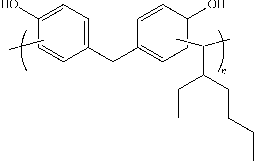 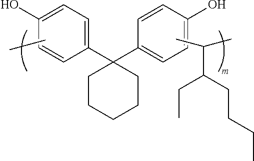 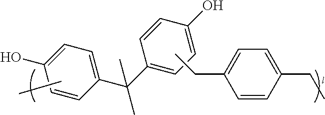
(S′8), Mw: 2,400 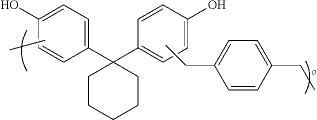 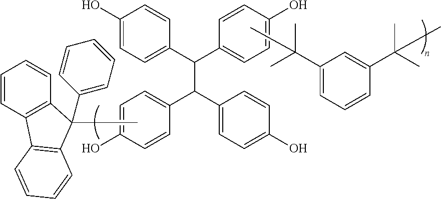 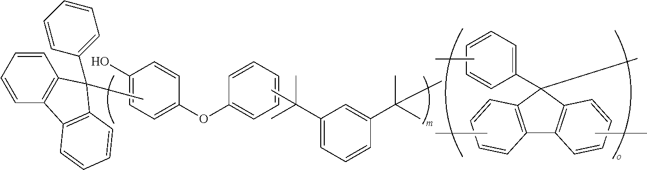
(S′9), Mw: 5,100 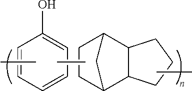
(S′10), Mw: 1,000 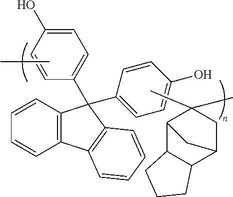
(S′11), Mw: 2,400

### [Preparation 2 of Resist Underlayer Films]

The polymers (S′1) to (S′11), crosslinking agents (CR′1 to CR′3), acid generators (Ad′1 to Ad′4), bases (Base′ 1 to Base′ 12) (the amount is described in parentheses as a molar ratio relative to the number of moles of the acid generator), solvents (propylene glycol monomethyl ether acetate (PGMEA), propylene glycol monomethyl ether (PGME), cyclohexanone (CYH)), and MEGAFACE R-40 (manufactured by DIC CORPORATION, G′1) as a surfactant were mixed in proportions described in the tables below. The mixtures were filtered through a 0.1 μm polytetrafluoroethylene microfilter. Resist underlayer film materials (M′1 to M′26 and Comparative M′1 to Comparative M′13) were thus prepared.

In Table 4, the numerical values for the crosslinking agents, the acid generators, and the surfactant indicate the numbers of grams of the crosslinking agents, the acid generators, and the surfactant used per 100 g of the polymer. As mentioned above, the numerical values for the bases are described in parentheses because the values are molar ratios relative to the number of moles of the acid generator and are based on a different standard from the other numerical values. Furthermore, the numerical values for the respective solvents indicate the numbers of grams of the solvents used in 100 g of the whole solvent.

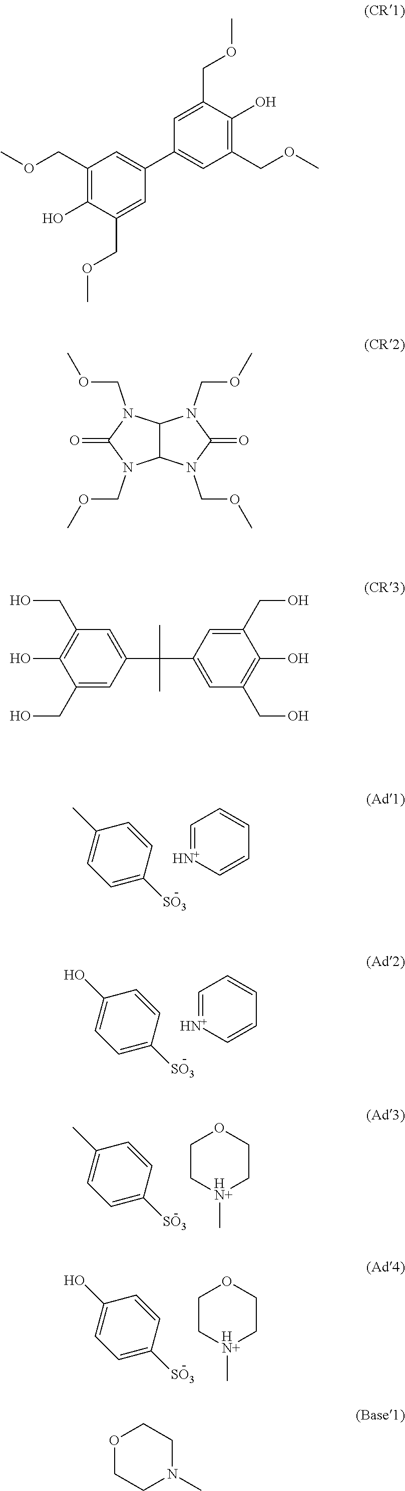

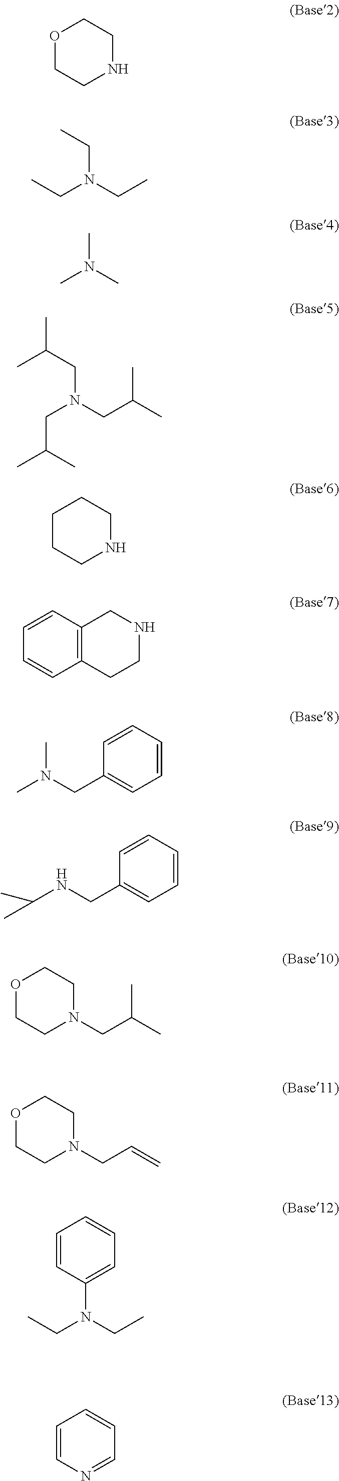

TABLE 6-1
(Table 4)

| | | Crosslinking | Acid | | | Solvents | | |
|---|---|---|---|---|---|---|---|---|
| Composition | Polymer | agent | generator | Base | Surfactant | (100 in total) | | |
| M′1 | Syn. Ex. | CR′1 | Ad′2 | Base′1 | G′1 | PGMEA | PGME | CYH |
| | 1′ | | | | | | | |
| | 100 | 30 | 3.0 | (2.0) | 0.1 | 70 | 30 | 0 |
| M′2 | Syn. Ex. | CR′1 | Ad′2 | Base′1 | G′1 | PGMEA | PGME | CYH |
| | 2′ | | | | | | | |
| | 100 | 30 | 3.0 | (2.0) | 0.1 | 70 | 30 | 0 |
| M′3 | Syn. Ex. | CR′3 | Ad′2 | Base′1 | G′1 | PGMEA | PGME | CYH |
| | 3′ | | | | | | | |
| | 100 | 30 | 3.0 | (2.0) | 0.1 | 30 | 70 | 0 |
| M′4 | Syn. Ex. | CR′1 | Ad′2 | Base′1 | G′1 | PGMEA | PGME | CYH |
| | 4′ | | | | | | | |
| | 100 | 30 | 3.0 | (2.0) | 0.1 | 40 | 30 | 30 |
| M′5 | Syn. Ex. | CR′1 | Ad′2 | Base′1 | G′1 | PGMEA | PGME | CYH |
| | 5′ | | | | | | | |
| | 100 | 30 | 3.0 | (2.0) | 0.1 | 70 | 30 | 0 |
| M′6 | Syn. Ex. | CR′1 | Ad′2 | Base′1 | G′1 | PGMEA | PGME | CYH |
| | 6′ | | | | | | | |
| | 100 | 30 | 3.0 | (2.0) | 0.1 | 70 | 30 | 0 |
| M′7 | Syn. Ex. | CR′2 | Ad′1 | Base′1 | G′1 | PGMEA | PGME | CYH |
| | 7′ | | | | | | | |
| | 100 | 30 | 3.0 | (2.0) | 0.1 | 40 | 30 | 30 |
| M′8 | Syn. Ex. | CR′2 | Ad′1 | Base′1 | G′1 | PGMEA | PGME | CYH |
| | 8′ | | | | | | | |
| | 100 | 30 | 3.0 | (2.0) | 0.1 | 70 | 30 | 0 |
| M′9 | Syn. Ex. | CR′2 | Ad′1 | Base′2 | G′1 | PGMEA | PGME | CYH |
| | 8′ | | | | | | | |
| | 100 | 30 | 3.0 | (2.0) | 0.1 | 70 | 30 | 0 |
| M′10 | Syn. Ex. | CR′2 | Ad′1 | Base′3 | G′1 | PGMEA | PGME | CYH |
| | 8′ | | | | | | | |
| | 100 | 30 | 3.0 | (2.0) | 0.1 | 70 | 30 | 0 |

TABLE 6-2

| M′11 | Syn. Ex. | CR′2 | Ad′1 | Base′4 | G′1 | PGMEA | PGME | CYH |
|---|---|---|---|---|---|---|---|---|
| | 8′ | | | | | | | |
| | 100 | 30 | 3.0 | (2.0) | 0.1 | 70 | 30 | 0 |
| M′12 | Syn. Ex. | CR′2 | Ad′1 | Base′5 | G′1 | PGMEA | PGME | CYH |
| | 8′ | | | | | | | |
| | 100 | 30 | 3.0 | (2.0) | 0.1 | 70 | 30 | 0 |
| M′13 | Syn. Ex. | CR′2 | Ad′1 | Base′6 | G′1 | PGMEA | PGME | CYH |
| | 8′ | | | | | | | |
| | 100 | 30 | 3.0 | (2.0) | 0.1 | 70 | 30 | 0 |
| M′14 | Syn. Ex. | CR′2 | Ad′1 | Base′7 | G′1 | PGMEA | PGME | CYH |
| | 8′ | | | | | | | |
| | 100 | 30 | 3.0 | (2.0) | 0.1 | 70 | 30 | 0 |
| M′15 | Syn. Ex. | CR′2 | Ad′1 | Base′8 | G′1 | PGMEA | PGME | CYH |
| | 8′ | | | | | | | |
| | 100 | 30 | 3.0 | (2.0) | 0.1 | 70 | 30 | 0 |
| M′16 | Syn. Ex. | CR′2 | Ad′1 | Base′9 | G′1 | PGMEA | PGME | CYH |
| | 8′ | | | | | | | |
| | 100 | 30 | 3.0 | (2.0) | 0.1 | 70 | 30 | 0 |
| M′17 | Syn. Ex. | CR′2 | Ad′1 | Base′10 | G′1 | PGMEA | PGME | CYH |
| | 8′ | | | | | | | |
| | 100 | 30 | 3.0 | (2.0) | 0.1 | 70 | 30 | 0 |
| M′18 | Syn. Ex. | CR′2 | Ad′1 | Base′11 | G′1 | PGMEA | PGME | CYH |
| | 8′ | | | | | | | |
| | 100 | 30 | 3.0 | (2.0) | 0.1 | 70 | 30 | 0 |
| M′19 | Syn. Ex. | CR′2 | Ad′1 | Base′12 | G′1 | PGMEA | PGME | CYH |
| | 8′ | | | | | | | |
| | 100 | 30 | 3.0 | (2.0) | 0.1 | 70 | 30 | 0 |
| M′20 | Syn. Ex. | CR′2 | Ad′1 | Base′13 | G′1 | PGMEA | PGME | CYH |
| | 8′ | | | | | | | |
| | 100 | 30 | 3.0 | (2.0) | 0.1 | 70 | 30 | 0 |
| M′21 | Syn. Ex. | CR′2 | Ad′1 | Base′1 | G′1 | PGMEA | PGME | CYH |
| | 8′ | | | | | | | |
| | 100 | 30 | 3.0 | (0.5) | 0.1 | 70 | 30 | 0 |

TABLE 6-3

| M′22 | Syn. Ex. | CR′2 | Ad′1 | Base′1 | G′1 | PGMEA | PGME | CYH |
|---|---|---|---|---|---|---|---|---|
| | 8′ | | | | | | | |
| | 100 | 30 | 3.0 | (1.0) | 0.1 | 70 | 30 | 0 |
| M′23 | Syn. Ex. | CR′2 | Ad′1 | Base′1 | G′1 | PGMEA | PGME | CYH |
| | 8′ | | | | | | | |
| | 100 | 30 | 3.0 | (1.5) | 0.1 | 70 | 30 | 0 |
| M′24 | Syn. Ex. | CR′1 | Ad′2 | Base′1 | G′1 | PGMEA | PGME | CYH |
| | 9′ | | | | | | | |
| | 100 | 30 | 3.0 | (2.0) | 0.1 | 70 | 30 | 0 |
| M′25 | Syn. Ex. | CR′1 | Ad′2 | Base′1 | G′1 | PGMEA | PGME | CYH |
| | 10′ | | | | | | | |
| | 100 | 30 | 3.0 | (2.0) | 0.1 | 70 | 30 | 0 |
| M′26 | Syn. Ex. | CR′1 | Ad′2 | Base′1 | G′1 | PGMEA | PGME | CYH |
| | 11′ | | | | | | | |
| | 100 | 30 | 3.0 | (2.0) | 0.1 | 70 | 30 | 0 |

| | | Crosslinking | Acid | | | Solvents | | |
|---|---|---|---|---|---|---|---|---|
| Composition | Polymer | agent | generator | Base | Surfactant | (100 in total) | | |
| Comp. M′1 | Syn. Ex. | CR′1 | Ad′2 | — | G′1 | PGMEA | PGME | CYH |
| | 1′ | | | | | | | |
| | 100 | 30 | 3.0 | — | 0.1 | 70 | 30 | 0 |
| Comp. M′2 | Syn. Ex. | CR′1 | Ad′2 | — | G′1 | PGMEA | PGME | CYH |
| | 2′ | | | | | | | |
| | 100 | 30 | 3.0 | — | 0.1 | 70 | 30 | 0 |
| Comp. M′3 | Syn. Ex. | CR′3 | Ad′2 | — | G′1 | PGMEA | PGME | CYH |
| | 3′ | | | | | | | |
| | 100 | 30 | 3.0 | — | 0.1 | 30 | 70 | 0 |
| Comp. M′4 | Syn. Ex. | CR′1 | Ad′2 | — | G′1 | PGMEA | PGME | CYH |
| | 4′ | | | | | | | |
| | 100 | 30 | 3.0 | — | 0.1 | 40 | 30 | 30 |
| Comp. M′5 | Syn. Ex. | CR′1 | Ad′2 | — | G′1 | PGMEA | PGME | CYH |
| | 5′ | | | | | | | |
| | 100 | 30 | 3.0 | — | 0.1 | 70 | 30 | 0 |

TABLE 6-4

| Comp. M′6 | Syn. Ex. | CR′1 | Ad′2 | — | G′1 | PGMEA | PGME | CYH |
|---|---|---|---|---|---|---|---|---|
| | 6′ | | | | | | | |
| | 100 | 30 | 3.0 | — | 0.1 | 70 | 30 | 0 |
| Comp. M′7 | Syn. Ex. | CR′2 | Ad′1 | — | G′1 | PGMEA | PGME | CYH |
| | 7′ | | | | | | | |
| | 100 | 30 | 3.0 | — | 0.1 | 40 | 30 | 30 |
| Comp. M′8 | Syn. Ex. | CR′2 | Ad′1 | — | G′1 | PGMEA | PGME | CYH |
| | 8′ | | | | | | | |
| | 100 | 30 | 3.0 | — | 0.1 | 70 | 30 | 0 |
| Comp. M′9 | Syn. Ex. | CR′1 | Ad′2 | — | G′1 | PGMEA | PGME | CYH |
| | 9′ | | | | | | | |
| | 100 | 30 | 3.0 | — | 0.1 | 70 | 30 | 0 |
| Comp. M′10 | Syn. Ex. | CR′1 | Ad′2 | — | G′1 | PGMEA | PGME | CYH |
| | 10′ | | | | | | | |
| | 100 | 30 | 3.0 | — | 0.1 | 70 | 30 | 0 |
| Comp. M′11 | Syn. Ex. | CR′1 | Ad′2 | — | G′1 | PGMEA | PGME | CYH |
| | 11′ | | | | | | | |
| | 100 | 30 | 3.0 | — | 0.1 | 70 | 30 | 0 |
| Comp. M′12 | Syn. Ex. | CR′2 | Ad′3 | — | G′1 | PGMEA | PGME | CYH |
| | 8′ | | | | | | | |
| | 100 | 30 | 3.0 | — | 0.1 | 70 | 30 | 0 |
| Comp. M′13 | Syn. Ex. | CR′1 | Ad′4 | — | G′1 | PGMEA | PGME | CYH |
| | 9′ | | | | | | | |
| | 100 | 30 | 3.0 | — | 0.1 | 70 | 30 | 0 |

The evaluations in Examples described later show the results of characteristics compared to Comparative Examples involving the polymer from the same Synthesis Example.
[Test 2 of Dissolution into Resist Solvent]

The resist underlayer film materials were each applied onto a silicon wafer using a spin coater, and the coatings were baked on a hot plate at 240° C. for 60 seconds to form a resist underlayer film with a film thickness of about 120 nm (Comparative Examples 1′ to 13′ and Examples 1′ to 26′). The resist underlayer films formed were soaked in a general-purpose thinner, specifically, PGME/PGMEA=7/3 for 60 seconds and were spin dried and baked at 100° C. for 30 seconds. The film thicknesses before and after the thinner immersion were compared to examine the resistance to the solvent. The resistance was evaluated as ∘ when the loss in film thickness after the thinner immersion was less than 1%, and as x when the loss in film thickness was 1% or more.

TABLE 7-1
(Table 1′)

| Ex./ | | | Solvent |
|---|---|---|---|
| Comp. Ex. | Composition | Baking temp. | resistance |
| Ex. 1′ | M′1 | 240° C./60 sec | ∘ |
| Ex. 2′ | M′2 | 240° C./60 sec | ∘ |
| Ex. 3′ | M′3 | 240° C./60 sec | ∘ |
| Ex. 4′ | M′4 | 240° C./60 sec | ∘ |
| Ex. 5′ | M′5 | 240° C./60 sec | ∘ |
| Ex. 6′ | M′6 | 240° C./60 sec | ∘ |
| Ex. 7′ | M′7 | 240° C./60 sec | ∘ |
| Ex. 8′ | M′8 | 240° C./60 sec | ∘ |
| Ex. 9′ | M′9 | 240° C./60 sec | ∘ |
| Ex. 10′ | M′10 | 240° C./60 sec | ∘ |
| Ex. 11′ | M′11 | 240° C./60 sec | ∘ |
| Ex. 12′ | M′12 | 240° C./60 sec | ∘ |
| Ex. 13′ | M′13 | 240° C./60 sec | ∘ |
| Ex. 14′ | M′14 | 240° C./60 sec | ∘ |
| Ex. 15′ | M′15 | 240° C./60 sec | ∘ |
| Ex. 16′ | M′16 | 240° C./60 sec | ∘ |
| Ex. 17′ | M′17 | 240° C./60 sec | ∘ |
| Ex. 18′ | M′18 | 240° C./60 sec | ∘ |
| Ex. 19′ | M′19 | 240° C./60 sec | ∘ |
| Ex. 20′ | M′20 | 240° C./60 sec | ∘ |
| Ex. 21′ | M′21 | 240° C./60 sec | ∘ |
| Ex. 22′ | M′22 | 240° C./60 sec | ∘ |
| Ex. 23′ | M′23 | 240° C./60 sec | ∘ |
| Ex. 24′ | M′24 | 240° C./60 sec | ∘ |
| Ex. 25′ | M′25 | 240° C./60 sec | ∘ |
| Ex. 26′ | M′26 | 240° C./60 sec | ∘ |
| Comp. Ex. 1′ | Comp. M′1 | 240° C./60 sec | ∘ |
| Comp. Ex. 2′ | Comp. M′2 | 240° C./60 sec | ∘ |
| Comp. Ex. 3′ | Comp. M′3 | 240° C./60 sec | ∘ |
| Comp. Ex. 4′ | Comp. M′4 | 240° C./60 sec | ∘ |
| Comp. Ex. 5′ | Comp. M′5 | 240° C./60 sec | ∘ |

TABLE 7-2

| | | | |
|---|---|---|---|
| Comp. Ex. 6′ | Comp. M′6 | 240° C./60 sec | ∘ |
| Comp. Ex. 7′ | Comp. M′7 | 240° C./60 sec | ∘ |
| Comp. Ex. 8′ | Comp. M′8 | 240° C./60 sec | ∘ |
| Comp. Ex. 9′ | Comp. M′9 | 240° C./60 sec | ∘ |
| Comp. Ex. 10′ | Comp. M′10 | 240° C./60 sec | ∘ |
| Comp. Ex. 11′ | Comp. M′11 | 240° C./60 sec | ∘ |
| Comp. Ex. 12′ | Comp. M′12 | 240° C./60 sec | ∘ |
| Comp. Ex. 13′ | Comp. M′13 | 240° C./60 sec | ∘ |

### [Evaluation 2 of Gap-Filling Properties]

Gap-filling properties were evaluated using 200 nm thick SiO₂ substrate, SiN substrate, and TiN substrate that had a dense pattern area consisting of 50 nm wide trenches at 100 nm pitches. The resist underlayer film materials were each applied onto the substrate, and the coatings were baked at 240° C. for 60 seconds to form a resist underlayer film having a thickness of about 120 nm (Comparative Examples 1′ to 15′ and Examples 1′ to 28′). The flatness of the substrates was evaluated using a scanning electron microscope (S-4800) manufactured by Hitachi High-Tech Corporation, and whether the resist underlayer film forming composition had filled the inside of the pattern was determined. The gap-filling properties were rated as o when the resist underlayer film forming composition had filled the inside of the pattern, and as x when the resist underlayer film forming composition had failed to fill the inside of the pattern.

### [Test 2 of Covering Performance on Non-Planar Substrates]

To test the covering performance on a non-planar substrate, the resist underlayer film forming compositions were each applied to 200 nm thick SiO₂ substrate, SiN substrate, and TiN substrate, and the coatings were baked at 240° C. for 60 seconds to form a resist underlayer film having a thickness of about 120 nm (Comparative Examples 1′ to 15′ and Examples 1′ to 28′). The coating film thickness was compared between at an 800 nm trenched area (TRENCH) and at an open area (OPEN) free from patterns. The flatness of the substrates was evaluated using a scanning electron microscope (S-4800) manufactured by Hitachi High-Tech Corporation by measuring the difference in film thickness between on the trenched area (the patterned area) and on the open area (the pattern-free area) of the non-planar substrate (the step height created on the coating film between the trenched area and the open area, called a bias). Here, the flatness means how small the difference (an iso-dense bias) is in the film thickness of the coating film between on the region with the pattern (the trenched area (the patterned area)) and on the region without patterns (the open area (the pattern-free area)). Flattening properties were rated as o when the bias was improved compared to Comparative Examples.

TABLE 8-1
(Table 2′)

| Ex./ | | Film | | Gap- | |
|---|---|---|---|---|---|
| Comp. | | thick- | | filling | Flattening |
| Ex. | Composition | ness | Substrate | properties | properties |
| Ex. 1′ | M′1 | 120 nm | SiO₂ | ∘ | ∘ |
| Ex. 2′ | M′2 | 120 nm | SiO₂ | ∘ | ∘ |
| Ex. 3′ | M′3 | 120 nm | SiO₂ | ∘ | ∘ |
| Ex. 4′ | M′4 | 120 nm | SiO₂ | ∘ | ∘ |
| Ex. 5′ | M′5 | 120 nm | SiO₂ | ∘ | ∘ |
| Ex. 6′ | M′6 | 120 nm | SiO₂ | ∘ | ∘ |
| Ex. 7′ | M′7 | 120 nm | SiO₂ | ∘ | ∘ |
| Ex. 8′ | M′8 | 120 nm | TiN | ∘ | ∘ |
| Ex. 9′ | M′9 | 120 nm | TiN | ∘ | ∘ |
| Ex. 10′ | M′10 | 120 nm | TiN | ∘ | ∘ |
| Ex. 11′ | M′11 | 120 nm | TiN | ∘ | ∘ |
| Ex. 12′ | M′12 | 120 nm | TiN | ∘ | ∘ |
| Ex. 13′ | M′13 | 120 nm | TiN | ∘ | ∘ |
| Ex. 14′ | M′14 | 120 nm | TiN | ∘ | ∘ |
| Ex. 15′ | M′15 | 120 nm | TiN | ∘ | ∘ |
| Ex. 16′ | M′16 | 120 nm | TiN | ∘ | ∘ |
| Ex. 17′ | M′17 | 120 nm | TiN | ∘ | ∘ |
| Ex. 18′ | M′18 | 120 nm | TiN | ∘ | ∘ |
| Ex. 19′ | M′19 | 120 nm | TiN | ∘ | ∘ |
| Ex. 20′ | M′20 | 120 nm | TiN | ∘ | ∘ |
| Ex. 21′ | M′21 | 120 nm | TiN | ∘ | ∘ |
| Ex. 22′ | M′22 | 120 nm | TiN | ∘ | ∘ |
| Ex. 23′ | M′23 | 120 nm | TiN | ∘ | ∘ |
| Ex. 24′ | M′24 | 120 nm | SiO₂ | ∘ | ∘ |
| Ex. 25′ | M′25 | 120 nm | SiN | ∘ | ∘ |
| Ex. 26′ | M′26 | 120 nm | SiO₂ | ∘ | ∘ |
| Ex. 27′ | M′8 | 120 nm | SiN | ∘ | ∘ |
| Ex. 28′ | M′8 | 120 nm | SiO₂ | ∘ | ∘ |
| Comp. Ex. 1′ | Comp. M′1 | 120 nm | SiO₂ | ∘ | x |
| Comp. Ex. 2′ | Comp. M′2 | 120 nm | SiO₂ | ∘ | x |
| Comp. Ex. 3′ | Comp. M′3 | 120 nm | SiO₂ | ∘ | x |

TABLE 8-2

| | | | | | |
|---|---|---|---|---|---|
| Comp. Ex. 4′ | Comp. M′4 | 120 nm | SiO₂ | ∘ | x |
| Comp. Ex. 5′ | Comp. M′5 | 120 nm | SiO₂ | ∘ | x |
| Comp. Ex. 6′ | Comp. M′6 | 120 nm | SiO₂ | ∘ | x |
| Comp. Ex. 7′ | Comp. M′7 | 120 nm | SiO₂ | ∘ | x |
| Comp. Ex. 8′ | Comp. M′8 | 120 nm | TiN | ∘ | x |
| Comp. Ex. 9′ | Comp. M′9 | 120 nm | SiN | ∘ | x |
| Comp. Ex. 10′ | Comp. M′10 | 120 nm | SiN | ∘ | x |
| Comp. Ex. 11′ | Comp. M′11 | 120 nm | SiO₂ | ∘ | x |
| Comp. Ex. 12′ | Comp. M′12 | 120 nm | TiN | ∘ | x |
| Comp. Ex. 13′ | Comp. M′13 | 120 nm | SiO₂ | ∘ | x |
| Comp. Ex. 14′ | Comp. M′8 | 120 nm | SiN | ∘ | x |
| Comp. Ex. 15′ | Comp. M′8 | 120 nm | SiO₂ | ∘ | x |

As described in Tables 1′ and 2′, the materials exhibit sufficient curability as resist underlayer films even when the base component has been added. Furthermore, as a result of the addition of the base component, it is possible to trap part of the acid component generated from the acid generator in the resist underlayer film composition during baking. This slows down the curing rate to ensure a time for the resin to flow. As a result, a flatter film can be formed on a patterned substrate while achieving good gap-filling properties. The above behavior and effects are achieved equally on various kinds of patterned substrates, such as SiN, SiO₂, and TiN.

1. A resist underlayer film forming composition comprising:
(a)
a thermal acid generator represented by formula (1) below: 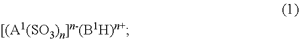
(b)
an aromatic ring-containing polymer;
(c)
one, or two or more kinds of bases B²; and
(d)
a solvent, wherein
A¹ in the formula (1) is an optionally substituted, linear, branched, or cyclic, saturated or unsaturated, aliphatic hydrocarbon group, or an optionally substituted aromatic ring residue,
n in the formula (1) indicates the number of the sulfonate anion groups and is 1 or 2,
B¹ in the formula (1) denotes one, or two or more kinds of counter bases and is a monoacidic base or a monoacidic base moiety of a diacidic base or a triacidic base,
A¹ and B¹ are optionally connected via a single bond or a linking group, and
at least one or more bases of B¹ and B² have a higher pKa than pyridine.

2. The resist underlayer film forming composition according to claim 1, wherein the aromatic ring-containing polymer is a novolac resin.

3. The resist underlayer film forming composition according to claim 2, wherein the aromatic ring-containing polymer is a novolac resin containing a unit structure having an optionally substituted aromatic ring, and
(i)
the aromatic ring contains a heteroatom in a substituent on the aromatic ring,
(ii)
the unit structure contains a plurality of aromatic rings, at least two of the aromatic rings are connected to one another via a linking group, and the linking group contains a heteroatom, or
(iii)
the aromatic ring is an aromatic heterocyclic ring or an aromatic ring forming a condensed ring with one or more heterocyclic rings.

4. The resist underlayer film forming composition according to claim 3, wherein the unit structure in (i) or (ii) is a unit structure having an aromatic ring with at least one oxygen-containing substituent or is a unit structure having aromatic rings connected via at least one —NH—.

5. The resist underlayer film forming composition according to claim 2, wherein the aromatic ring-containing polymer is a novolac resin comprising:
(i) one, or two or more kinds of unit structures having an optionally substituted aromatic ring; and
(ii) a unit structure including an optionally substituted 4- to 17-membered monocyclic, bicyclic, tricyclic, or tetracyclic organic group, wherein the monocyclic ring is a non-aromatic monocyclic ring; and at least one of the monocyclic rings constituting the bicyclic, tricyclic, or tetracyclic ring is a non-aromatic monocyclic ring, and the remaining monocyclic ring or rings are optionally aromatic monocyclic rings or non-aromatic monocyclic rings;
the monocyclic, bicyclic, tricyclic, or tetracyclic organic group is optionally further condensed with one or more aromatic rings to form a pentacyclic or higher condensed ring; and
the unit structures (i) and (ii) are bonded at least by a covalent bond of a carbon atom on any of the non-aromatic monocyclic rings in (ii) with a carbon atom on the aromatic ring in (i).

6. The resist underlayer film forming composition according to claim 2, wherein the aromatic ring-containing polymer comprises a structure represented by formula (AB) below: 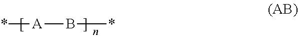
wherein in the formula (AB), n indicates the number of composite unit structures A-B,
the unit structures A comprise one, or two or more kinds of unit structures having an optionally substituted aromatic ring, and are optionally such that:
the aromatic ring is substituted with a substituent containing a heteroatom,
the unit structure includes a plurality of aromatic rings, the aromatic rings are connected to one another via a linking group, and the linking group contains a heteroatom, or
the aromatic ring is an aromatic heterocyclic ring or is an aromatic ring forming a condensed ring with one or more heterocyclic rings, and
the unit structures B comprise one, or two or more kinds of unit structures including a structure represented by formula (B1), (B2), or (B3) below: 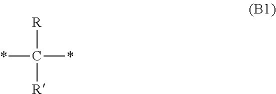
[in the formula (B1), R and R′each independently denote a hydrogen atom, an optionally substituted C6-C30 aromatic ring residue, an optionally substituted C3-C30 heterocyclic ring residue, or an optionally substituted C10 or lower, linear, branched, or cyclic alkyl group] 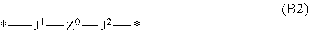
[in the formula (B2), Z⁰ denotes an optionally substituted C6-C30 aromatic ring residue, aliphatic ring residue, or organic group including two aromatic ring residues or aliphatic ring residues connected to each other via a single bond, and J¹ and J² each independently denote a direct bond or an optionally substituted divalent organic group] 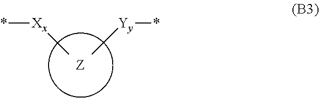
[in the formula (B3),
Z is an optionally substituted C4-C25 monocyclic ring or bicyclic, tricyclic, or tetracyclic condensed ring, wherein the monocyclic ring is a non-aromatic monocyclic ring; at least one of the monocyclic rings constituting the bicyclic, tricyclic, or tetracyclic ring is a non-aromatic monocyclic ring, and the remaining monocyclic ring or rings are optionally aromatic monocyclic rings or non-aromatic monocyclic rings; and the monocyclic ring or the bicyclic, tricyclic, or tetracyclic condensed ring is optionally further condensed with one or more aromatic rings to form a pentacyclic or higher condensed ring,
X and Y denote identical or different —CR³¹R³²— groups, R³¹ and R³² are the same as or different from each other and each denote a hydrogen atom or a C₁-C₆ hydrocarbon group,
x and y indicate the numbers of X and Y, respectively, and are each independently 0 or 1, 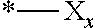
is bonded to any carbon atom (referred to as “carbon atom 1”) constituting any of the non-aromatic monocyclic rings in Z (when x=1) or extends from the carbon atom 1 (when x=0), 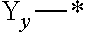
is bonded to any carbon atom (referred to as “carbon atom 2”) constituting any of the non-aromatic monocyclic rings in Z (when y=1) or extends from the carbon atom 2 (when y=0),
the carbon atom 1 and the carbon atom 2 are the same as or different from each other, and when the carbon atom 1 and the carbon atom 2 are different from each other, they belong to the same non-aromatic monocyclic ring or to different non-aromatic monocyclic rings, and
* indicates a valence bond].

7. The resist underlayer film forming composition according to claim 6, wherein
the formula (B3) is formula (B31) below: 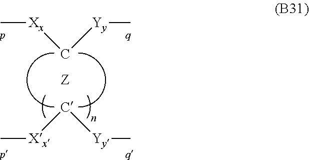
[in the formula (B31),
Z is an optionally substituted 4- to 17-membered monocyclic, bicyclic, tricyclic, or tetracyclic organic group, wherein the monocyclic ring is a non-aromatic monocyclic ring; and at least one of the monocyclic rings constituting the bicyclic, tricyclic, or tetracyclic ring is a non-aromatic monocyclic ring, and the remaining monocyclic ring or rings are optionally aromatic monocyclic rings or non-aromatic monocyclic rings,
the monocyclic, bicyclic, tricyclic, or tetracyclic organic group is optionally further condensed with one or more aromatic rings to form a pentacyclic or higher condensed ring,
C and C′ each denote a carbon atom among atoms constituting a ring moiety of any of the non-aromatic monocyclic rings in Z, and C and C′ belong to the same non-aromatic monocyclic ring or to different non-aromatic monocyclic rings,
n indicates the number of the carbon atoms C′ and denotes an integer of 0 to 2,
p, q, p′, and q′ indicate the number of a valence bond and each independently denote 0 or 1,
when n is 0, p and q are 1,
when n is 1 or 2, at least one of p or q, and at least one of p′ or q′ in each C′ are each 1,
when n is 2, the two C′ atoms belong to the same non-aromatic monocyclic ring while optionally bonding directly to each other, or the two C′ atoms belong to different non-aromatic monocyclic rings,
X, Y, X′, and Y′ denote identical or different —CR¹R²— groups; R¹ and R² are the same as or different from each other and each denote a hydrogen atom or a C1-C3 hydrocarbon group; and when n is 2, the two groups X′ are the same as or different from each other, and the two groups Y′ are the same as or different from each other, and
x, y, x′, and y′ indicate the numbers of X, Y, X′, and Y′, respectively, and each independently denote 0 or 1].

8. The resist underlayer film forming composition according to claim 1, wherein when the amount of a base required to neutralize the same number of moles of sulfonic acid (a monobasic acid) as the sulfonate anion groups (SO₃⁻) contained in the thermal acid generator (a) is 1 equivalent, the base or bases having a higher pKa than pyridine among the counter base or bases B¹ in the formula (1) of the component (a) and the base or bases B² in the component (c) represent 1.05 equivalents or more.

9. The resist underlayer film forming composition according to claim 1, wherein when the amount of a base required to neutralize the same number of moles of sulfonic acid (a monobasic acid) as the sulfonate anion groups (SO₃⁻) contained in the thermal acid generator (a) is 1 equivalent, the amount added of the base or bases B² is 0.05 to 3.0 equivalents.

10. The resist underlayer film forming composition according to claim 1, wherein
the counter base or bases B¹ in the formula (1) of the component (a) and/or the base or bases B² in the component (c) are R^{I}R^{II}R^{III}N,
R^{I} and R^{II} each independently denote a hydrogen atom, an optionally substituted, linear or branched, saturated or unsaturated, aliphatic hydrocarbon group,
R^{I} and R^{II} optionally form a ring together via a heteroatom or without a heteroatom, or optionally form a ring together via an aromatic ring,
R^{III} denotes a hydrogen atom, an optionally substituted aromatic ring residue, or an optionally substituted, linear or branched, saturated or unsaturated, aliphatic hydrocarbon group, and
when R^{I} and R^{II} do not form a ring together, R^{III} is a hydrogen atom or an optionally substituted aromatic ring residue.

11. The resist underlayer film forming composition according to claim 1, wherein
the counter base or bases B¹ in the formula (1) of the component (a) and/or the base or bases B² in the component (c) are each:
a base represented by: 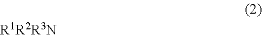
[wherein
R¹ and R² each independently denote an optionally substituted, linear or branched, saturated or unsaturated, aliphatic hydrocarbon group, and
R³ denotes a hydrogen atom or an optionally substituted aromatic hydrocarbon group] or
a cyclic amine compound represented by formula (3) below: 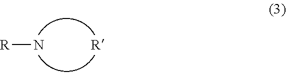
[in the formula (3),
R is:
a hydrogen atom;
a C1-C10 alkyl group, a C2-C10 alkenyl group, a C2-C10 alkynyl group, a C1-C10 hydroxyalkyl group, a C6-C40 aryl group, an ether bond-containing organic group, a ketone bond-containing organic group, or an ester bond-containing organic group, each of which is optionally substituted with a nitro group, a cyano group, an amino group, a carboxyl group, a hydroxyl group, an amide group, an aldehyde group, a (meth)acryloyl group, a halogen atom, or a C1-C10 alkoxy group; or
a group including a combination of the above groups, and
R′ is an aromatic ring forming a condensed ring together with a ring in the cyclic amine in the formula (3) or is: 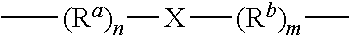
wherein R^{a} and R^{b} each independently denote an optionally substituted alkylene group,
X is O, S, SO₂, CO, CONH, COO, or NH, and
n and m are each independently 2, 3, 4, 5, or 6].

12. The resist underlayer film forming composition according to claim 11, wherein the base or bases are such that:
R³ in the formula (2) denotes an optionally substituted phenyl, naphthyl, anthracenyl, pyrenyl, or phenanthrenyl group, or
R in the formula (3) is a hydrogen atom, a methyl group, an ethyl group, an isobutyl group, an allyl group, or a cyanomethyl group, and
R′ in the formula (3) is represented by: 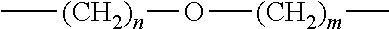
wherein n and m are each independently 2, 3, 4, 5, or 6.

13. The resist underlayer film forming composition according to claim 1, wherein the counter base or bases B¹ in the formula (1) of the component (a) and/or the base or bases B² in the component (c) are one, or two or more selected from N-methylmorpholine, N-isobutylmorpholine, N-allylmorpholine, and N,N-diethylaniline.

14. The resist underlayer film forming composition according to claim 1, wherein A¹ in the formula (1) is a methyl group, a trifluoromethyl group, a naphthyl group, a norbornanylmethyl group, a dimethylphenyl group, or a tolyl group.

15. The resist underlayer film forming composition according to claim 1, further comprising a crosslinking agent.

16. The resist underlayer film forming composition according to claim 15, wherein the crosslinking agent is an aminoplast crosslinking agent or a phenoplast crosslinking agent.

17. The resist underlayer film forming composition according to claim 16, wherein the aminoplast crosslinking agent is a highly alkylated, alkoxylated, or alkoxyalkylated melamine, benzoguanamine, glycoluril, or urea, or a polymer thereof.

18. The resist underlayer film forming composition according to claim 16, wherein the phenoplast crosslinking agent is a highly alkylated, alkoxylated, or alkoxyalkylated aromatic, or a polymer thereof.

19. The resist underlayer film forming composition according to claim 1, wherein the solvent (d) is a compound having an alcoholic hydroxyl group or a compound having a group capable of forming an alcoholic hydroxyl group.

20. The resist underlayer film forming composition according to claim 19, wherein the compound having an alcoholic hydroxyl group or the compound having a group capable of forming an alcoholic hydroxyl group is a propylene glycol solvent, an oxyisobutyric acid ester solvent, or a butylene glycol solvent.

21. The resist underlayer film forming composition according to claim 19, wherein the compound having an alcoholic hydroxyl group or the compound having a group capable of forming an alcoholic hydroxyl group is propylene glycol monomethyl ether, methyl 2-hydroxy-2-methylpropionate, cyclohexanone, propylene glycol monomethyl ether acetate, or ethyl lactate.

22. The resist underlayer film forming composition according to claim 1, further comprising a surfactant.

23. On a semiconductor substrate, a resist underlayer film comprising a baked product of a coating film comprising the resist underlayer film forming composition described in claim 1,

24. A method for forming a resist pattern used in semiconductor manufacturing, the method comprising a step of applying the resist underlayer film forming composition described in claim 1 onto a semiconductor substrate, and baking the resist underlayer film forming composition to form a resist underlayer film.

25. A method for manufacturing a semiconductor device, comprising:
a step of forming on a semiconductor substrate a resist underlayer film from the resist underlayer film forming composition described in claim 1;
a step of forming a resist film on the resist underlayer film;
a step of forming a resist pattern by irradiation with light or electron beam followed by development;
a step of etching the resist underlayer film through the resist pattern; and
a step of processing the semiconductor substrate through the resist underlayer film having been patterned.

26. A method for manufacturing a semiconductor device, comprising:
a step of forming on a semiconductor substrate a resist underlayer film from the resist underlayer film forming composition described in claim 1;
a step of forming a hard mask on the resist underlayer film;
a step of forming a resist film on the hard mask;
a step of forming a resist pattern by irradiation with light or electron beam followed by development;
a step of etching the hard mask through the resist pattern;
a step of etching the resist underlayer film through the hard mask having been patterned; and
a step of processing the semiconductor substrate through the resist underlayer film having been patterned.

27. A method for manufacturing a semiconductor device, comprising:
a step of forming on a semiconductor substrate a resist underlayer film from the resist underlayer film forming composition described in claim 1;
a step of forming a hard mask on the resist underlayer film;
a step of forming a resist film on the hard mask;
a step of forming a resist pattern by irradiation with light or electron beam followed by development;
a step of etching the hard mask through the resist pattern;
a step of etching the resist underlayer film through the hard mask having been patterned;
a step of removing the hard mask; and
a step of processing the semiconductor substrate through the resist underlayer film having been patterned.

28. A method for manufacturing a semiconductor device, comprising:
a step of forming on a semiconductor substrate a resist underlayer film from the resist underlayer film forming composition described in claim 1;
a step of forming a hard mask on the resist underlayer film;
a step of forming a resist film on the hard mask;
a step of forming a resist pattern by irradiation with light or electron beam followed by development;
a step of etching the hard mask through the resist pattern;
a step of etching the resist underlayer film through the hard mask having been patterned;
a step of removing the hard mask;
a step of forming a deposited film (a spacer) on the resist underlayer film cleaned of the hard mask;
a step of processing the deposited film (the spacer) by etching;
a step of removing the resist underlayer film having been patterned while leaving the deposited film (the spacer) having been patterned; and
a step of processing the semiconductor substrate through the deposited film (the spacer) having been patterned.

29. The manufacturing method according to claim 26, wherein the hard mask is formed by applying an inorganic substance or by depositing an inorganic substance.

30. The manufacturing method according to claim 25, wherein the resist film is patterned by a nanoimprinting method or by using a self-assembled film.

31. The method for manufacturing a semiconductor device according to claim 27, wherein the hard mask is removed by etching or with an alkaline chemical solution.
